(19) United States
(12) Patent Application Publication
(10) Pub. No.: US 2023/0109178 A1
(43) Pub. Date: Apr. 6, 2023

(54) LUMINESCENT MATERIAL HAVING MULTI-SUBSTITUTED PHENYL LIGAND

(71) Applicant: BEIJING SUMMER SPROUT TECHNOLOGY CO., LTD., Beijing (CN)

(72) Inventors: Zhihong Dai, Beijing (CN); Qi Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 17/867,132

(22) Filed: Jul. 18, 2022

(30) Foreign Application Priority Data
Jul. 23, 2021 (CN) 202110834298.6

(51) Int. Cl. C09K 11/06; C09K 11/02; C07F 15/00; H01L 51/00

(52) U.S. Cl. CPC C09K 11/06; C09K 11/02; C07F 15/0033; H01L 51/0085; C09K 2211/185; C09K 2211/1044; C09K 2211/1007; H01L 51/5012

(57) ABSTRACT

Provided is a luminescent material having a multi-substituted phenyl ligand, wherein the luminescent material is a metal complex, the metal complex has a general formula of M(Lₐ)ₘ(L_{b})ₙ(L_{c})_{q}, and the first ligand Lₐ has a structure of Formula 1. The metal complex can be used as luminescent materials in organic electroluminescent devices. This new metal complex can improve the device efficiency and provide more saturated deep red luminescence, thereby providing better device performance. Further provided are an electroluminescent device and a compound composition.

### CROSS-REFERENCE TO RELATED APPLICATION(S)

This application claims priority to Chinese Patent Application No. 202110834298.6 filed on Jul. 23, 2021, the disclosure of which is incorporated herein by reference in its entirety.

### TECHNICAL FIELD

The present disclosure relates to compounds for organic electronic devices, for example, an organic light-emitting device. More particularly, the present disclosure relates to a metal complex having a multi-substituted phenyl ligand, an organic electroluminescent device including the metal complex, and a compound composition.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modem organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Due to the wide application of OLED luminescent materials, the requirements for and standards to deep red luminescent materials are getting increasingly high. For example, in the display industry, the ultra high-definition display color gamut standard BT.2020 issued by the ITU Radiocommunication Sector (ITU-R) puts forward a wider color gamut standard. However, the maximum luminescent wavelength of red luminescent materials commonly used in the industry is often below 630 nm, and the emitted color is not deep red enough to meet the color gamut requirements. Therefore, it is urgent for the industry to develop more excellent deep red luminescent materials, especially the deep red luminescent materials with a maximum emission wavelength of above 640 nm.

### SUMMARY

The present disclosure aims to provide a series of metal complexes having a multi-substituted phenyl ligand to solve at least part of the above-mentioned problems. The metal complex having a general formula of M(Lₐ)ₘ(L_{b})ₙ(L_{c})_{q}, and the first ligand Lₐ has the structure of Formula 1. The metal complexes can be used as luminescent materials in organic electroluminescent devices. This novel metal complex can improve the device efficiency and provide more saturated deep red luminescence, thereby providing better device performance.

According to an embodiment of the present disclosure, a metal complex is disclosed, which has a general formula of M(Lₐ)ₘ(L_{b})ₙ(L_{c})_{q}, wherein the metal M is selected from metals with a relative atomic mass greater than 40; Lₐ, L_{b} and L_{c} are a first ligand, a second ligand and a third ligand of the complex, respectively; m is 1, 2 or 3; n is 0, 1 or 2; q is 0, 1 or 2; m+n+q is equal to the oxidation state of the metal M; when m is greater than 1, a plurality of Lₐ are identical or different; when n is 2, two L_{b} are identical or different; when q is 2, two L_{c} are identical or different; Lₐ, L_{b} and Lₑ can be optionally joined to form a multi-dentate ligand;

Lₐ has the structure represented by Formula 1:

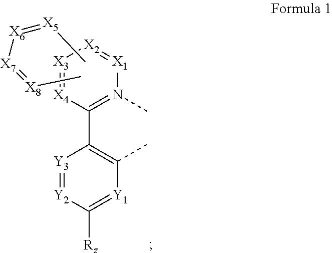

wherein,

X₁ to X₈ are, at each occurrence identically or differently, selected from C, CRₓ or N, and at least one of X₁ to X₈ is N;

Y₁ to Y₃ are, at each occurrence identically or differently, selected from CR_{y} or N;

Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

at least two of Y₁ to Y₃ are, at each occurrence identically or differently, selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{y} can be optionally joined to form a ring;

when R_{y} and R_{z} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms or combinations thereof, adjacent substituents R_{y}, R_{z} can be optionally joined to form a ring;

L_{b} and L_{c} are, at each occurrence identically or differently, selected from the group consisting of the following structures:

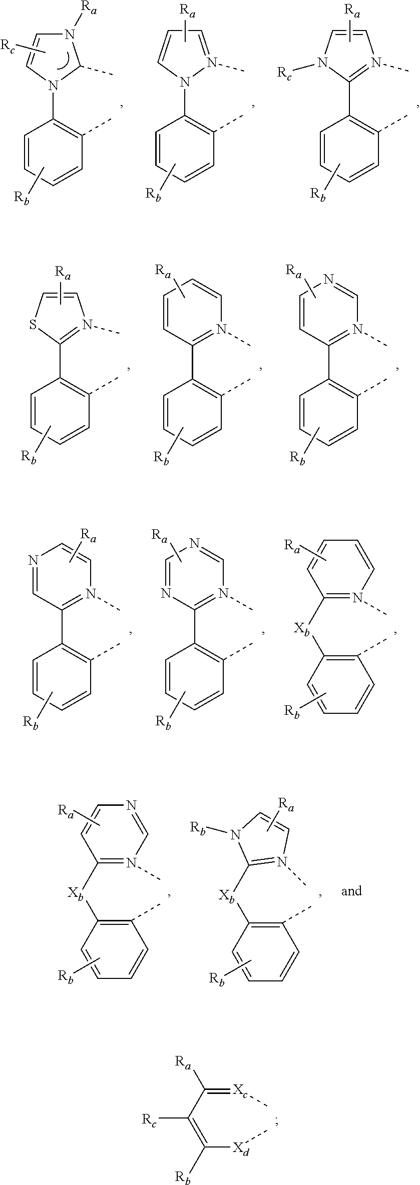

wherein,

Rₐ, R_{b} and R_{c} represent, at each occurrence identically or differently, mono-substitution, multiple substitutions or non-substitution;

X_{b} is, at each occurrence identically or differently, selected from the group consisting of: O, S, Se, NR_{N1} and CR_{C1}R_{C2};

X_{c} and X_{d} are, at each occurrence identically or differently, selected from the group consisting of: O, S, Se and NR_{N2}; Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₐ, R_{b}, R_{c}, R_{N1}, R_{N2}, R_{C1} and R_{C2} can be optionally joined to form a ring.

According to another embodiment of the present disclosure, an electroluminescent device is further disclosed, which comprises an anode, a cathode, and an organic layer disposed between the anode and the cathode, wherein the organic layer comprises the metal complex described above.

According to another embodiment of the present disclosure, a compound composition is further disclosed, which comprises the metal complex described above.

The new metal complex disclosed by the present disclosure has a general formula of M(Lₐ)ₘ(L_{b})ₙ(L_{c})_{q}, wherein the first ligand Lₐ has the structure of Formula 1, and can be used as luminescent materials in electroluminescent devices. This novel metal complex can improve the device efficiency and provide more saturated deep red luminescence, thereby providing better device performance.

### BRIEF DESCRIPTION OF DRAWINGS

FIG. 1 is a schematic diagram of an organic light-emitting device that may include a metal complex and a compound composition disclosed herein.

FIG. 2 is a schematic diagram of another organic light-emitting device that may include a metal complex and a compound composition disclosed herein.

### DETAILED DESCRIPTION

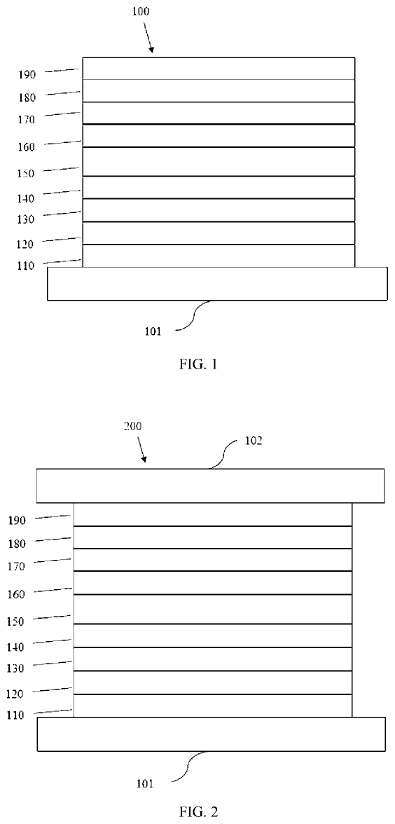

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

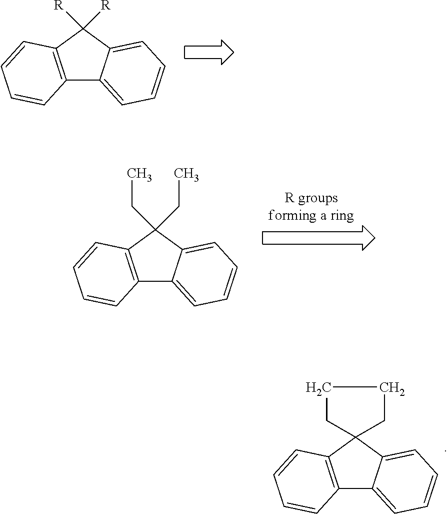

The expression that adjacent substituents can be optionally joined to form a ring is also intended to mean that two substituents bonded to carbon atoms which are directly bonded to each other are joined to each other via a chemical bond to form a ring, which can be exemplified by the following formula:

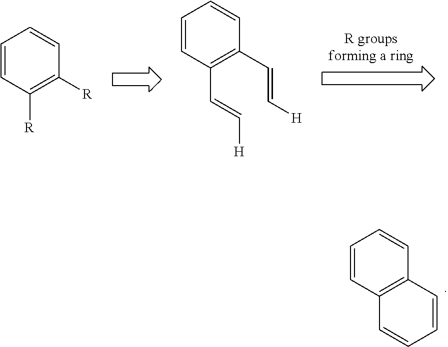

The expression that adjacent substituents can be optionally joined to form a ring is also intended to mean that two substituents bonded to further distant carbon atoms are joined to each other via a chemical bond to form a ring, which can be exemplified by the following formula:

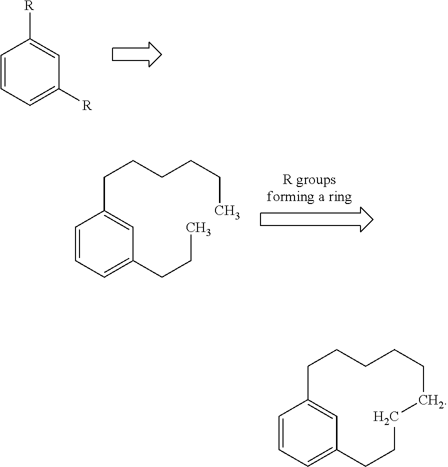

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

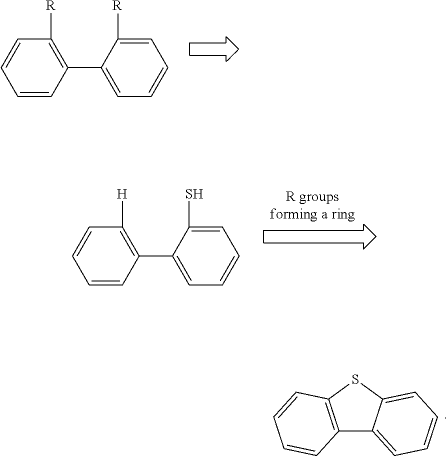

According to an embodiment of the present disclosure, a metal complex is disclosed, which has a general formula of M(Lₐ)ₘ(L_{b})ₙ(L_{c})_{q}, wherein the metal M is selected from metals with a relative atomic mass greater than 40; Lₐ, L_{b} and L_{c} are a first ligand, a second ligand and a third ligand of the complex, respectively; m is 1, 2 or 3; n is 0, 1 or 2; q is 0, 1 or 2; m+n+q is equal to the oxidation state of the metal M; when m is greater than 1, a plurality of Lₐ are identical or different; when n is 2, two L_{b} are identical or different; when q is 2, two L_{c} are identical or different; Lₐ, L_{b} and L_{c} can be optionally joined to form a multi-dentate ligand;

Lₐ has the structure represented by Formula 1:

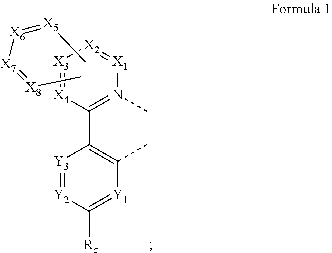

wherein,

X₁ to X₈ are, at each occurrence identically or differently, selected from C, CRₓ or N, and at least one of X₁ to X₈ is N;

Y₁ to Y₃ are, at each occurrence identically or differently, selected from CR_{y} or N;

Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

at least two of Y₁ to Y₃ are, at each occurrence identically or differently, selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{y} can be optionally joined to form a ring;

when R_{y} and R_{z} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms or combinations thereof, adjacent substituents R_{y}, R_{z} can be optionally joined to form a ring;

L_{b} and L_{c} are, at each occurrence identically or differently, selected from the group consisting of the following structures:

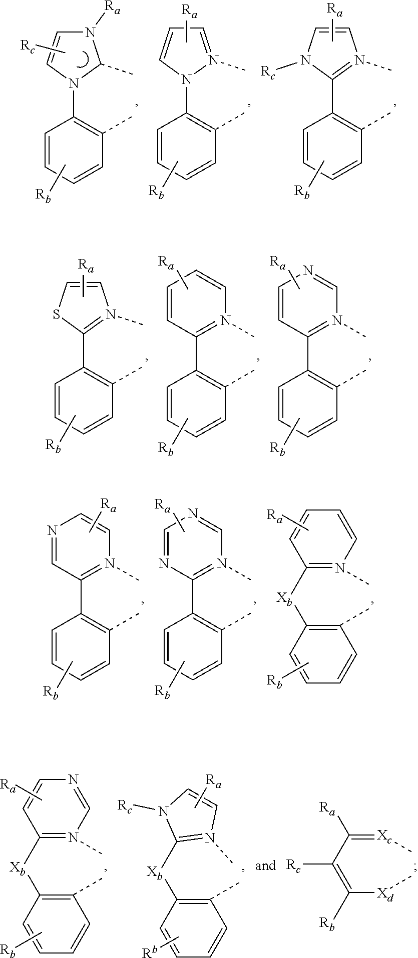

wherein,

Rₐ, R_{b} and R_{c} represent, at each occurrence identically or differently, mono-substitution, multiple substitutions or non-substitution;

X_{b} is, at each occurrence identically or differently, selected from the group consisting of: O, S, Se, NR_{N1} and CR_{C1}R_{C2};

X_{c} and X_{d} are, at each occurrence identically or differently, selected from the group consisting of: O, S, Se and NR_{N2};

Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents Rₐ, R_{b}, R_{c}, R_{N1}, R_{N2}, R_{C1} and R_{C2} can be optionally joined to form a ring.

In this embodiment, the expression that Lₐ, L_{b} and L_{c} can be optionally joined to form a multi-dentate ligand is intended to mean that any two or three of Lₐ, L_{b} and L_{c} can be joined to form a tetradentate ligand or a hexadentate ligand. Obviously, it is possible that none of Lₐ, L_{b}, and L_{c} are joined so that a multi-dentate ligand is not formed.

In the present disclosure, the expression that adjacent substituents Rₓ, R_{y} can be optionally joined to form a ring is intended to mean that any one or more of groups of adjacent substituents, such as adjacent substituents Rₓ and adjacent substituents Rₓ and R_{y}, can be joined to form a ring. Obviously, it is possible that none of these adjacent substituents are joined to form a ring.

In this embodiment, the expression that when R_{y} and R_{z} are selected from said group of substituents, adjacent substituents R_{y}, R_{z} can be optionally joined to form a ring is intended to mean that only when R_{y} and R_{z} are selected from said group of substituents consisting of alkyl, cycloalkyl, heteroalkyl, a heterocyclic group, arylalkyl, alkoxy, aryloxy, alkylsilyl, arylsilyl, alkylgermanyl, arylgermanyl and combinations thereof, adjacent substituents R_{y} and adjacent substituents R_{y} and R_{z} can be joined to form a ring. Obviously, it is also possible that when R_{y} and R_{z} are selected from said group of substituents, adjacent substituents R_{y}, R_{z} are not joined to form a ring. When R_{y} and/or R_{z} are selected from substituents other than said group of substituents, adjacent substituents R_{y} and adjacent substituents R_{y} and R_{z} are not joined to form a ring.

In the present disclosure, the expression that adjacent substituents Rₐ, R_{b}, R_{c}, R_{N1}, R_{N2}, R_{C1}, and R_{C2} can be optionally joined to form a ring is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. Obviously, it is possible that none of these substituents are joined to form a ring.

According to an embodiment of the present disclosure, wherein, the metal M is selected from Ir, Rh, Re, Os, Pt, Au or Cu.

According to an embodiment of the present disclosure, wherein, the metal M is selected from Ir, Pt or Os.

According to an embodiment of the present disclosure, wherein, the metal M is Ir.

According to an embodiment of the present disclosure, wherein, Lₐ is, at each occurrence identically or differently, selected from the structure represented by any one of Formula 2 to Formula 4:

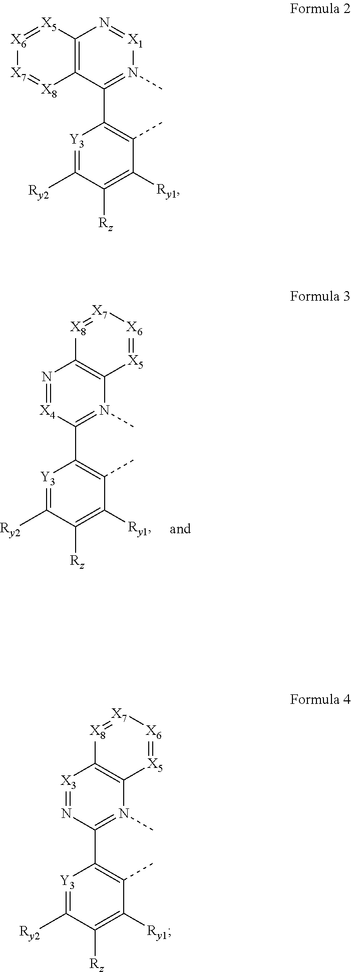

wherein,

X₁ and X₃ to X₈ are, at each occurrence identically or differently, selected from CRₓ or N;

Y₃ is, at each occurrence identically or differently, selected from CR_{y} or N;

Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R_{y1} and R_{y2} are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

adjacent substituents Rₓ, R_{y} can be optionally joined to form a ring;

when R_{y}, R_{y1}, R_{y2} and R_{z} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms or combinations thereof, adjacent substituents R_{y}, R_{y1}, R_{y2} and R_{z} can be optionally joined to form a ring.

In the present disclosure, the expression that when R_{y}, R_{y1}, R_{y2} and R_{z} are selected from said group of substituents, adjacent substituents R_{y}, R_{y1}, R_{y2} and R_{z} can be optionally joined to form a ring is intended to mean that only when R_{y}, R_{y1}, R_{y2} and R_{z} are selected from said group of substituents consisting of alkyl, cycloalkyl, heteroalkyl, a heterocyclic group, arylalkyl, alkoxy, aryloxy, alkylsilyl, arylsilyl, alkylgermanyl, arylgermanyl and combinations thereof, any one or more of groups of adjacent substituents, such as adjacent substituents R_{y} and R_{y2}, adjacent substituents R_{y1} and R_{z}, and adjacent substituents R_{y2} and R_{z}, can be joined to form a ring. Obviously, it is also possible that when R_{y}, R_{y1}, R_{y2} and R_{z} are selected from said group of substituents, adjacent substituents R_{y}, R_{y1}, R_{y2} and R_{z} are not joined to form a ring. When R_{y}, R_{y1}, R_{y2} and R_{z} are selected from substituents other than said group of substituents, adjacent substituents R_{y} and R_{y2}, adjacent substituents R_{y1} and R_{z} and adjacent substituents R_{y2} and R_{z} are not joined to form a ring.

According to an embodiment of the present disclosure, wherein, Lₐ is selected from the structure represented by Formula 2 or Formula 3.

According to an embodiment of the present disclosure, wherein, Lₐ is selected from the structure represented by Formula 2.

According to an embodiment of the present disclosure, wherein, in Formula 2 to Formula 4, R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein, in Formula 2 to Formula 4, R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein, in Formula 2 to Formula 4, R_{z} is selected from the group consisting of: methyl, ethyl, isopropyl, isobutyl, t-butyl, neopentyl, cyclopentyl, 1,1-dimethyl-1-cyanomethyl, 2-cyano-2,2-dimethyl-ethyl, 2,2,2-trifluoro-1,1-dimethylethyl, 3,3,3-trifluoro-2,2-dimethylpropyl, benzyl, 1,1-dimethyl-1-phenylmethyl, tetrahydropyranyl, adamantyl, norbornyl, phenyl, and any of the above groups that are partially or fully deuterated.

According to an embodiment of the present disclosure, wherein, in Formula 2 to Formula 4, R_{y1} and R_{y2} are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, and combinations thereof.

According to an embodiment of the present disclosure, wherein, in Formula 2 to Formula 4, R_{y1} and R_{y2} are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, and combinations thereof.

According to an embodiment of the present disclosure, wherein, in Formula 2 to Formula 4, R_{y1} and R_{y2} are, at each occurrence identically or differently, selected from the group consisting of: methyl, ethyl, isopropyl, t-butyl, cyclopentyl, cyclohexyl, cyano, trifluoromethyl, trimethylsilyl, trimethylgermanyl, methoxy, N,N-dimethylamino, phenyl, 2,4,6-triisopropylphenyl, tetrahydropyranyl, adamantyl, norbornyl, pyridyl, and any of the above groups that are partially or fully deuterated.

According to an embodiment of the present disclosure, wherein, in Formula 2 to Formula 4, Y₃ is, at each occurrence identically or differently, selected from CR_{Y}.

According to an embodiment of the present disclosure, wherein, in Formula 2 to Formula 4, Y₃ is, at each occurrence identically or differently, selected from CR_{y}, and the R_{y} is, at each occurrence identically or differently, selected from the group consisting of: hydrogen, deuterium, methyl and deuterated methyl.

According to an embodiment of the present disclosure, wherein, in Formula 2 to Formula 4, two or three of R_{z}, R_{y1} and R_{y2} are joined to form a ring.

According to an embodiment of the present disclosure, wherein, in Formula 2 to Formula 4, X₁ and X₃ to X₈ are, at each occurrence identically or differently, selected from CRₓ; the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, an isocyano group, a hydroxyl group, a sulfanyl group, and combinations thereof;

adjacent substituents Rₓ can be optionally joined to form a ring.

In the present disclosure, the expression that adjacent substituents Rₓ can be optionally joined to form a ring is intended to mean that any adjacent substituent Rₓ can be joined to form a ring. Obviously, it is possible that none of these adjacent substituents Rₓ are joined to form a ring.

According to an embodiment of the present disclosure, wherein, in Formula 2 to Formula 4, X₁ and X₃ to X₈ are, at each occurrence identically or differently, selected from CRₓ; the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, an isocyano group, a hydroxyl group, a sulfanyl group, and combinations thereof;

adjacent substituents Rₓ can be optionally joined to form a ring.

According to an embodiment of the present disclosure, wherein, in Formula 2, at least one or two of X₅ to X₈ is(are), at each occurrence identically or differently, selected from CRₓ; in Formula 3, at least one or two of X₄ and X₅ to X₈ is(are), at each occurrence identically or differently, selected from CRₓ; in Formula 4, at least one or two of X₃ and X₅ to X₈ is(are), at each occurrence identically or differently, selected from CRₓ; the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, in Formula 2, X₆ and/or X₇ are, at each occurrence identically or differently, selected from CRₓ; in Formula 3, X₄ and/or X₆ and/or X₇ are, at each occurrence identically or differently, selected from CRₓ; in Formula 4, X₃ and/or X₆ and/or X₇ are, at each occurrence identically or differently, selected from CRₓ; the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, and combinations thereof.

According to an embodiment of the present disclosure, wherein, in Formula 2, X₆ and/or X₇ are, at each occurrence identically or differently, selected from CRₓ; in Formula 3, X₄ and/or X₆ and/or X₇ are, at each occurrence identically or differently, selected from CRₓ; in Formula 4, X₃ and/or X₆ and/or X₇ are, at each occurrence identically or differently, selected from CRₓ; the Rₓ is, at each occurrence identically or differently, selected from the group consisting of: deuterium, fluorine, cyano, trifluoromethyl, methyl, isopropyl, isobutyl, t-butyl, neopentyl, cyclopentyl, cyclopentylmethyl, cyclohexyl, trimethylsilyl, triethylsilyl, trimethylgermanyl, phenyl, triazinyl, norbornyl, adamantyl, and combinations thereof.

According to an embodiment of the present disclosure, wherein, in Formula 2 to Formula 4, X₅ to X₈ are, at each occurrence identically or differently, selected from CRₓ, and at least two of adjacent Rₓ are joined to form a ring.

According to an embodiment of the present disclosure, wherein, in Formula 2 to Formula 4, X₅ to X₈ are, at each occurrence identically or differently, selected from CRₓ, at least two of adjacent Rₓ are joined to form a ring, the formed ring is an aromatic ring having 6 to 10 carbon atoms or a heteroaromatic ring having 3 to 10 carbon atoms, and the aromatic ring or the heteroaromatic ring may be substituted with one or more substituents selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, in Formula 2 to Formula 4, X₅ to X₈ are, at each occurrence identically or differently, selected from CRₓ, at least two of adjacent Rₓ are joined to form a ring, the formed ring is a benzene ring, a naphthalene ring, a thiophene ring or a furan ring, and the benzene ring, the naphthalene ring, the thiophene ring or the furan ring may be substituted with one or more substituents selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, in Formula 2 to Formula 4, X₈ is selected from CRₓ, Y₃ is selected from CR_{y}, and the Rₓ and R_{y} are joined to form a ring.

According to an embodiment of the present disclosure, wherein, Lₐ is, at each occurrence identically or differently, selected from the group consisting of Lₐ₁ to Lₐ₉₁₂; for the specific structures of Lₐ₁ to Lₐ₉₁₂, reference is made to claim 9.

According to an embodiment of the present disclosure, wherein, hydrogen in the structures Lₐ₁ to Lₐ₉₁₂ can be partially or fully substituted with deuterium.

According to an embodiment of the present disclosure, wherein, L_{b} is, at each occurrence identically or differently, selected from the following structure:

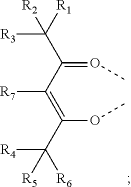

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, wherein, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof.

According to an embodiment of the present disclosure, wherein, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

According to an embodiment of the present disclosure, wherein, L_{b} is selected from the group consisting of L_{b1} to L_{b322}, and L_{c} is selected from the group consisting of L_{c1} to L_{c231}; for the specific structures of L_{b1} to L_{b322} and L_{c1} to L_{c231}, reference is made to claim 11.

According to an embodiment of the present disclosure, wherein, the metal complex is an Ir complex and has a structure represented by any one of Ir(Lₐ)(L_{b})(L_{c}), Ir(Lₐ)₂(L_{b}), Ir(Lₐ)₂(L_{c}) and Ir(Lₐ)(L_{c})₂; when the metal complex has a structure of Ir(Lₐ)(L_{b})(L_{c}), Lₐ is selected from any one of the group consisting of Lₐ₁ to Lₐ₉₁₂, L_{b} is selected from any one of the group consisting of L_{b1} to L_{b322}, and L_{c} is selected from any one of the group consisting of L_{c1} to L_{c231}; when the metal complex has a structure of Ir(Lₐ)₂(L_{b}), Lₐ is selected from any one or any two of the group consisting of Lₐ₁ to Lₐ₉₁₂, and L_{b} is selected from any one of the group consisting of L_{c1} to L_{c322}; when the metal complex has a structure of Ir(Lₐ)₂(L_{c}), Lₐ is selected from any one or any two of the group consisting of Lₐ₁ to Lₐ₉₁₂, and L_{c} is selected from any one of the group consisting of L_{c1} to L_{c231}; when the metal complex has a structure of Ir(Lₐ)(L_{c})₂, Lₐ is selected from any one of the group consisting of Lₐ₁ to Lₐ₉₁₂, and L_{c} is selected from any one or any two of the group consisting of L_{c1} to L_{c231}.

According to an embodiment of the present disclosure, wherein, the metal complex is selected from the group consisting of Compound 1 to Compound 378; for the specific structures of Compound 1 to Compound 37, reference is made to claim 12.

According to an embodiment of the present disclosure, an electroluminescent device is further disclosed, which comprises:

an anode,

a cathode, and

an organic layer disposed between the anode and the cathode, wherein the organic layer comprises a metal complex, and the specific structure of the metal complex is shown in any of the embodiments described above.

According to an embodiment of the present disclosure, in the device, the organic layer is an emissive layer, and the compound is a luminescent material.

According to an embodiment of the present disclosure, wherein, the device emits red light or white light.

According to an embodiment of the present disclosure, in the device, the emissive layer further comprises at least one host material.

According to an embodiment of the present disclosure, in the device, the at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, in the device, the emissive layer may include two or more host materials; the host material may be a p-type host material, an n-type host material, a bipolar host material or a neutral host material; the host material may be a conventional host material in the existing art and, for example, may typically include the following host materials without limitation:

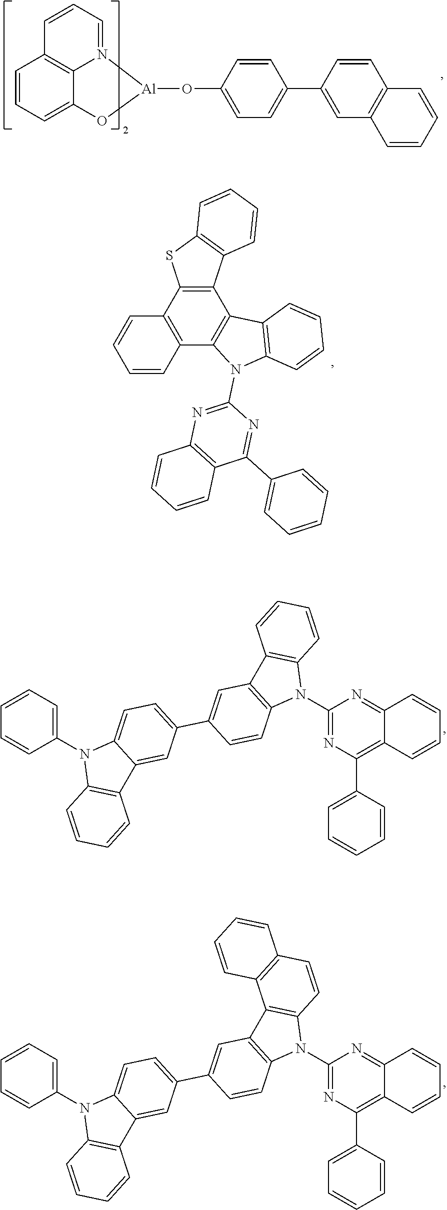

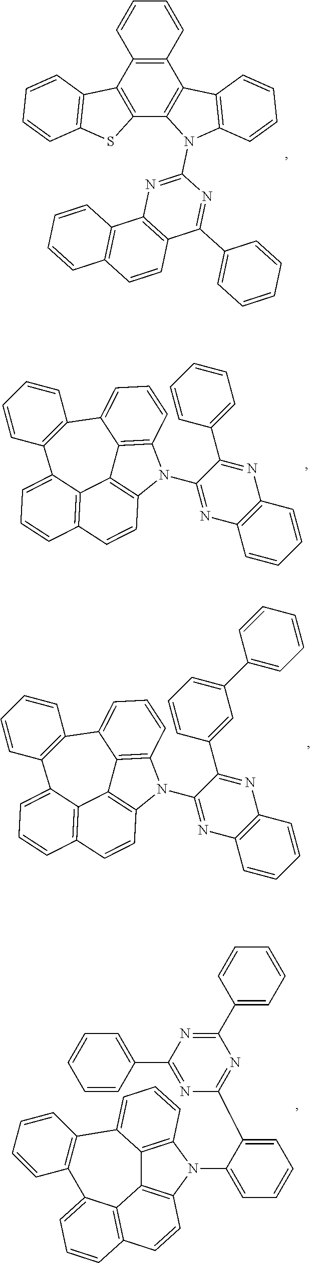

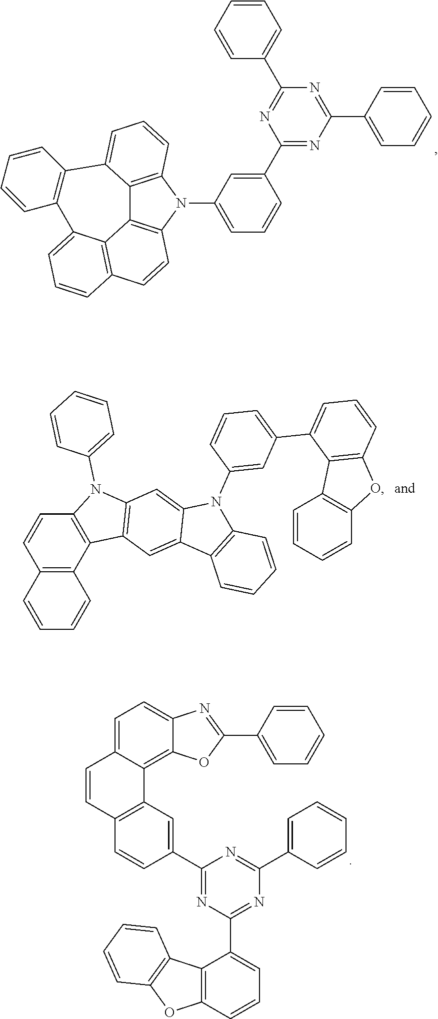 [SMILES: c1ccc(-c2nc(-c3ccccc3)nc(-c3cccc(-n4c5cccc6c5c5c7c(cccc7ccc54)-c4ccccc4-6)c3)n2)cc1 ; c1ccc(-n2c3cc4c(cc3c3c5ccccc5ccc32)c2ccccc2n4-c2cccc(-c3cccc4oc5ccccc5c34)c2)cc1 ; c1ccc(-c2nc(-c3ccc4ccc5ccc6nc(-c7ccccc7)oc6c5c4c3)nc(-c3cccc4oc5ccccc5c34)n2)cc1]

According to another embodiment of the present disclosure, a compound composition is further disclosed, which comprises a metal complex, and the specific structure of the metal complex is shown in any of the embodiments described above.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, the compounds disclosed herein may be used in combination with a wide variety of emissive dopants, hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art.

As the persons skilled in the art are aware of the above-mentioned equipment use, test methods and other related contents, the inherent data of the sample can be obtained with certainty and without influence, so the above related contents are not further described in this present disclosure.

### MATERIAL SYNTHESIS EXAMPLE

The method for preparing a compound of the present disclosure is not limited herein.

Typically, the following compounds are taken as examples without limitations, and synthesis routes and preparation methods thereof are described below.

### Synthesis Example 1: Synthesis of Compound 92

Step 1: Synthesis of Intermediate 3

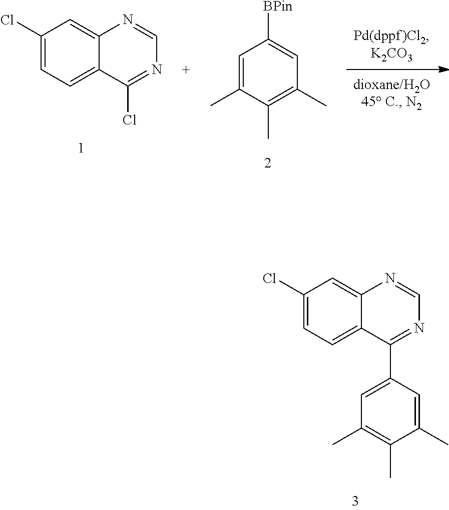

4,7-dichloroquinazoline (Intermediate 1, 5 g, 25 mmol), Intermediate 2 (6.77 g, 27.5 mmol), Pd(dppf)Cl₂ (914 mg, 1.25 mmol) and K₂CO₃ (10.4 g, 75 mmol) were mixed in dioxane/H₂O (180 mL/60 mL), purged with nitrogen and reacted overnight at 45° C. After TLC detected that the reaction was completed, the reaction was cooled to room temperature, the reaction solution was diluted with ethyl acetate and extracted, and the organic phase was collected, concentrated and purified by column chromatography to give Intermediate 3 (4.4 g).

Step 2: Synthesis of Intermediate 5

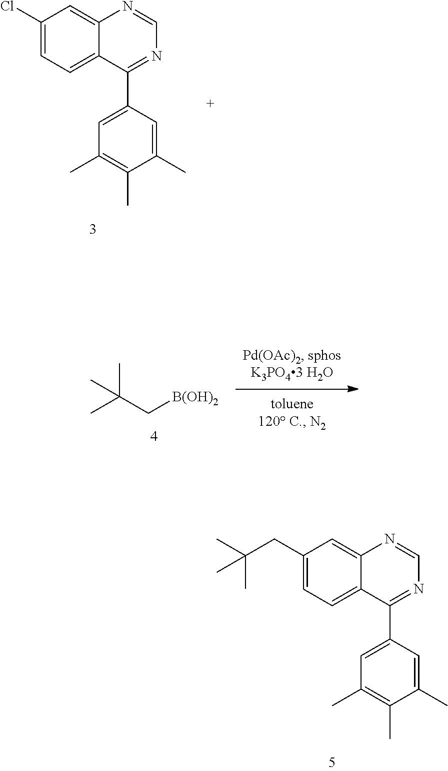

Intermediate 3 (3.8 g, 13.5 mmol), neopentylboronic acid (Intermediate 4, 3.2 g, 27 mmol), Pd(OAc)₂ (90 mg, 0.4 mmol), sphos (329 mg, 0.8 mmol), and K₃PO₄ 3H₂O (10.8 g, 40.5 mmol) were mixed in toluene (67.5 mL), purged with nitrogen, and refluxed overnight at 120° C. After TLC detected that the reaction was completed, the reaction was cooled to room temperature, the reaction solution was filtered with Celite, concentrated and purified by column chromatography to give Intermediate 5 (2.95 g).

Step 3: Synthesis of Iridium dimer 6

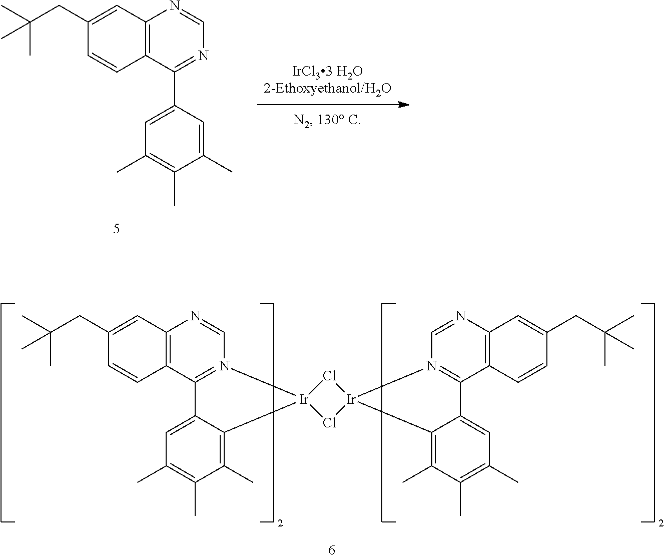

Intermediate 5 (2.1 g, 6.6 mmol) and IrCl₃ 3H₂O (776 mg, 2.2 mmol) were mixed in 2-ethoxyethanol (27 mL)/water (9 mL), purged with nitrogen and refluxed at 130° C. for 24 hours. After the reaction was cooled to room temperature, the produced red precipitate was filtered, and the filter cake was washed with ethanol and dried to give iridium dimer 6, which was directly used for the next step without further purification.

Step 4: Synthesis of Compound 92

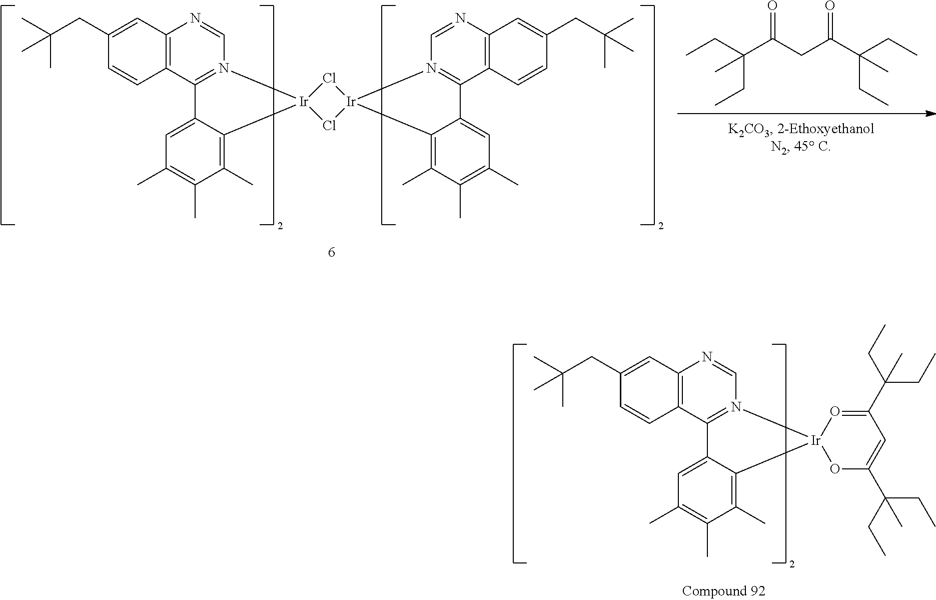

Iridium dimer 6 prepared in step 3, and 3,7-diethyl-3,7-dimethyl-4,6-nonanedione (790 mg, 3.3 mmol), K₂CO₃ (1.5 g, 11 mmol) and 2-ethoxyethanol (36 mL) were mixed in a 100 mL single-necked flask, purged with nitrogen, and reacted overnight at 45° C. After TLC detected that the reaction was completed, the reaction was cooled to room temperature. The reaction solution was filtered with Celite, the filter cake was washed with an appropriate amount of EtOH, and the crude product was dissolved with DCM. EtOH (about 10 mL) was added to the dissolved crude product, the dissolved crude product was concentrated at room temperature until the product was precipitated and then filtered, and the filter cake was washed with an appropriate amount of EtOH to give the product Compound 92 (500 mg). The product was confirmed as the target product with a molecular weight of 1066.57.

The persons skilled in the art will appreciate that the above preparation methods are merely examples. The persons skilled in the art can obtain other compound structures of the present disclosure through the modifications of the preparation methods.

### DEVICE EXAMPLE

### Device Example 1

First, a glass substrate having an indium tin oxide (ITO) anode with a thickness of 120 nm was cleaned and then treated with oxygen plasma and UV ozone. After the treatment, the substrate was dried in a glovebox to remove moisture. Next, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10⁻⁸ torr. Compound HI was used as a hole injection layer (HIL) with a thickness of 100 Å. Compound HT was used as a hole transporting layer (HTL) with a thickness of 400 Å. Compound EB was used as an electron blocking layer (EBL) with a thickness of 50 Å. Compound 92 of the present disclosure was doped in a host compound RH to be used as an emissive layer (EML, at a weight ratio of 2:98) with a thickness of 400 Å. Compound HB was used as a hole blocking layer (HBL) with a thickness of 50 Å. On the HBL, Compound ET and 8-hydroxyquinolinolato-lithium (Liq) were co-deposited as an electron transporting layer (ETL) with a thickness of 350 Å. Finally, Liq with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Comparative Example 1

The preparation method in Device Comparative Example 1 was the same as that in Device Example 1, except that Compound 92 of the present disclosure was replaced with Compound RD-A in the emissive layer (EML).

The structures and thicknesses of part layers of the devices are shown in the following table. The layer using more than one material was obtained by doping different compounds at their weight proportions as recorded.

TABLE 1
Part structures of devices in Device Example and Device Comparative Example

| Device No. | HIL | HTL | EBL | EML | HBL | ETL |
|---|---|---|---|---|---|---|
| Example 1 | Compound | Compound | Compound | Compound | Compound | Compound |
| | HI | HT | EB | RH:Compound | HB | ET:Liq |
| | (100 Å) | (400 Å) | (50 Å) | 92 (98:2) | (50 Å) | (40:60) |
| | | | | (400 Å) | | (350 Å) |
| Comparative | Compound | Compound | Compound | Compound | Compound | Compound |
| Example 1 | HI | HT | EB | RH:Compound | HB | ET:Liq |
| | (100 Å) | (400 Å) | (50 Å) | RD-A (98:2) | (50 Å) | (40:60) |
| | | | | (400 Å) | | (350 Å) |

The structures of the materials used in the devices are shown as follows:

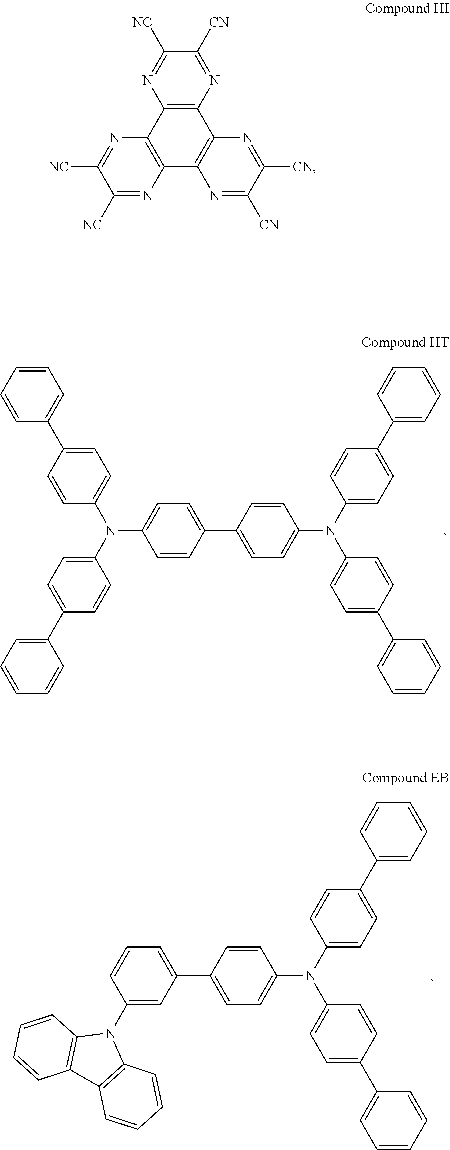 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

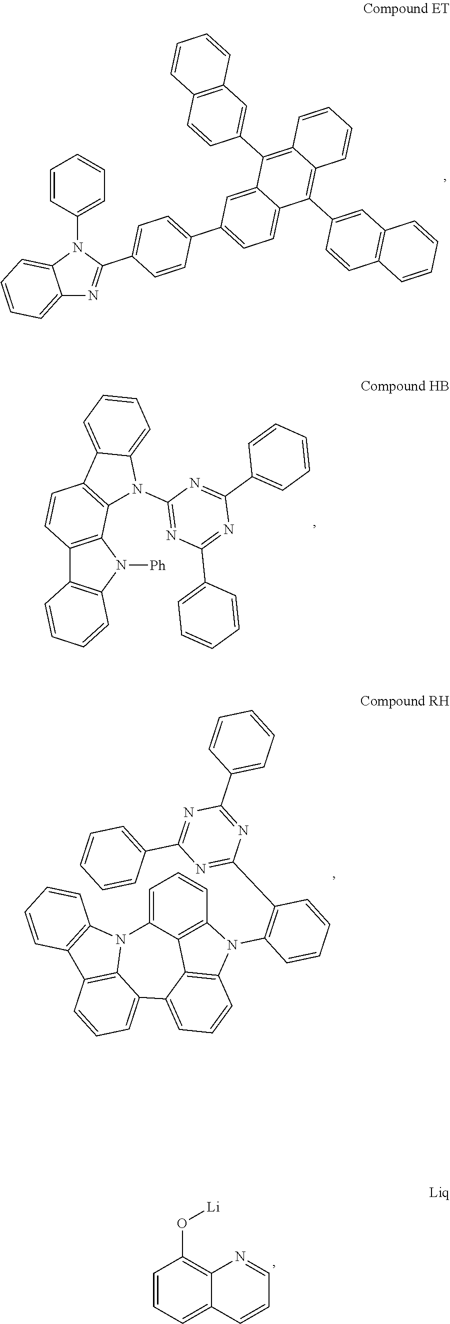

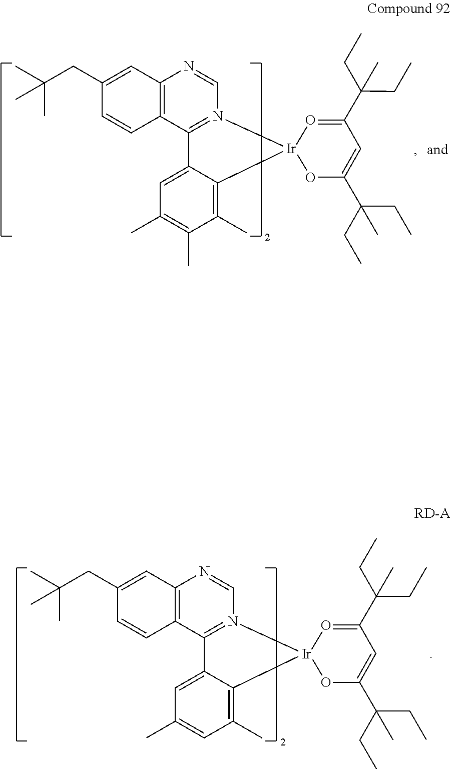

The IVL characteristics of the devices were measured. Table 2 shows the data on the maximum emission wavelength (λₘₐₓ), full width at half maximum (FWHM) and external quantum efficiency (EQE) measured at a current density of 15 mA/cm².

TABLE 2
Device data

| Device No. | λₘₐₓ (nm) | FWHM (nm) | EQE (%) |
|---|---|---|---|
| Example 1 | 649 | 56.0 | 20.73 |
| Comparative Example 1 | 657 | 57.4 | 18.39 |

As can be seen from the data in Table 2, both the metal complex of the present disclosure and the comparative Compound RD-A could make the device emit deep red light and met the wider color gamut requirements of BT.2020, but more importantly, the device performance of Example 1 was significantly improved compared with Comparative Example 1: the EQE of Example 1 was improved by 12.7% compared with Comparative Example 1 (20.73% vs 18.39%), and the improvement of the efficiency is significant; the FWHM of Example 1 was narrower than that of Comparative Example 1 (56.0 nm vs 57.4 nm), which caused the saturation of the emitted light to be higher. It shows that the metal complex disclosed by the present disclosure can provide higher external quantum efficiency and color saturation in the deep red luminescent region, thereby providing more excellent performance.

Spectral Data

The photoluminescence (PL) spectra data of the compound of the present disclosure and the comparative Compounds RD-B and RD-C were measured using a fluorescence spectrophotometer F98 produced by SHANGHAI LENGGUANG TECHNOLOGY CO., LTD. To-be-measured samples were prepared into solutions each with a concentration of 3×10⁻⁵ mol/L using HPLC-grade dichloromethane and then excited at room temperature (298 K) using light with a wavelength of 500 nm, and their emission spectra were measured. Measurement results are shown in Table 3.

TABLE 3
PL data

| Compound No. | Photoluminescence spectra λₘₐₓ (nm) |
|---|---|
| Compound 92 | 642 |
| Compound RD-B | 621 |
| Compound RD-C | 610 |

The structures of Compounds RD-B and RD-C are as follows:

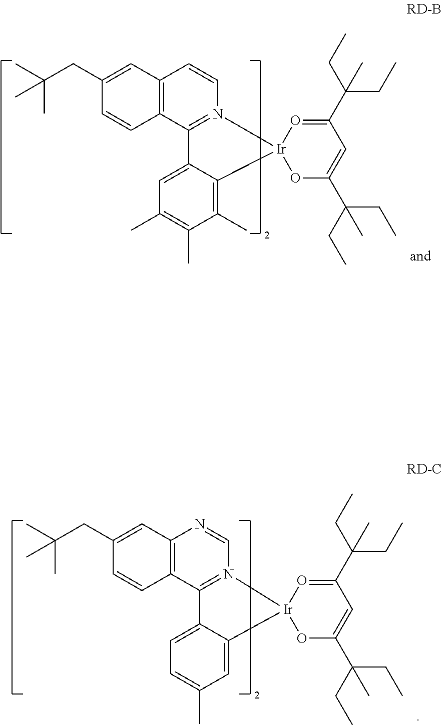

As can be seen from Table 3, the maximum emission wavelengths of Compounds RD-B and RD-C were far less than 630 nm, which could only meet the requirements of general display (about 620 nm) and could not meet the requirements of deep red luminescent materials in the industry; the maximum emission wavelength of Compound 92 of the present disclosure exceeded 640 nm, which could better meet the requirements of deep red luminescence.

To sum up, the metal complex disclosed by the present disclosure can provide higher external quantum efficiency and color saturation in the deep red luminescent region, thereby providing more excellent performance.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. A metal complex, having a general formula of M(Lₐ)ₘ(L_{b})ₙ(L_{c})_{q}, wherein the metal M is selected from metals with a relative atomic mass greater than 40; Lₐ, L_{b} and L_{c} are a first ligand, a second ligand and a third ligand of the complex, respectively; m is 1, 2 or 3; n is 0, 1 or 2; q is 0, 1 or 2; m+n+q is equal to the oxidation state of the metal M; when m is greater than 1, a plurality of Lₐ are identical or different; when n is 2, two L_{b} are identical or different; when q is 2, two L_{c} are identical or different; Lₐ, L_{b} and L_{c} can be optionally joined to form a multi-dentate ligand;
Lₐ has a structure represented by Formula 1: 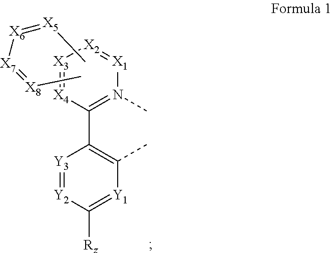
wherein,
X₁ to X₈ are, at each occurrence identically or differently, selected from C, CRₓ or N, and at least one of X₁ to X₈ is N;
Y₁ to Y₃ are, at each occurrence identically or differently, selected from CR_{y} or N;
Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least two of Y₁ to Y₃ are, at each occurrence identically or differently, selected from CR_{y}, and the R_{y} is, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y} can be optionally joined to form a ring;
when R_{y} and R_{z} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms or combinations thereof, adjacent substituents R_{y}, R_{z} can be optionally joined to form a ring;
L_{b} and L_{c} are, at each occurrence identically or differently, selected from the group consisting of the following structures: 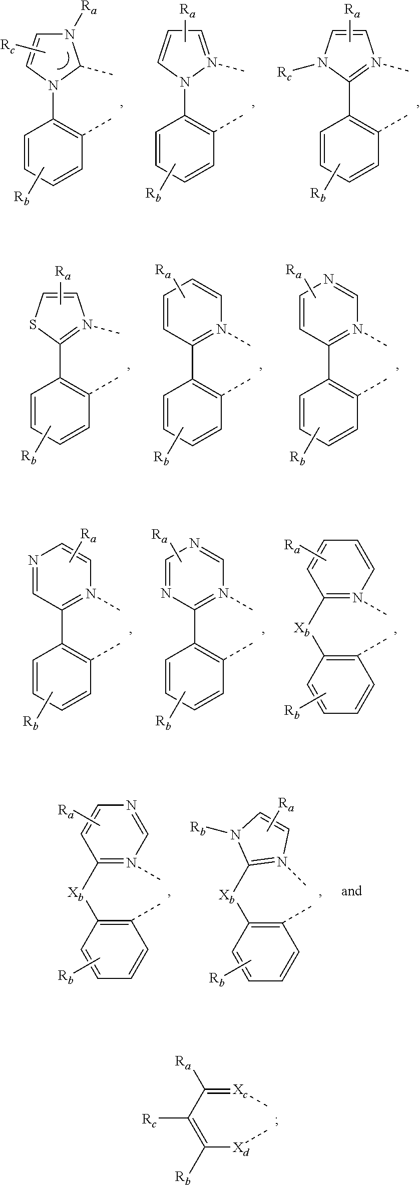
wherein,
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1} and R_{C2} can be optionally joined to form a ring.

2. The metal complex of claim 1, wherein the metal M is selected from Ir, Rh, Re, Os, Pt, Au or Cu; preferably, the metal M is selected from Ir, Pt or Os; more preferably, the metal M is Ir.

3. The metal complex of claim 1, wherein Lₐ has, at each occurrence identically or differently, a structure represented by any one of Formula 2 to Formula 4: 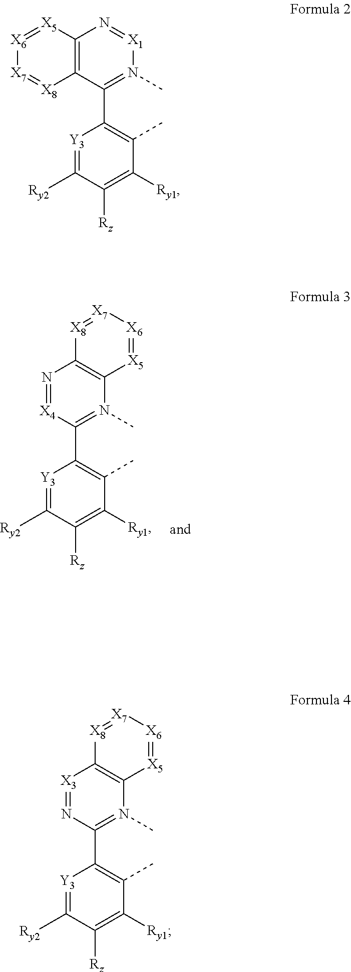
wherein,
X₁ and X₃ to X₈ are, at each occurrence identically or differently, selected from CRₓ or N;
Y₃ is, at each occurrence identically or differently, selected from CR_{y} or N;
Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R_{y1} and R_{y2} are, at each occurrence identically or differently, selected from the group consisting of: halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y} can be optionally joined to form a ring;
when R_{y}, R_{y1}, R_{y2} and R_{z} are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms or combinations thereof, adjacent substituents R_{y}, R_{y1}, R_{y2} and R_{z} can be optionally joined to form a ring;
preferably, Lₐ is selected from a structure represented by Formula 2 or Formula 3;
more preferably, Lₐ is selected from a structure represented by Formula 2.

4. The metal complex of claim 3, wherein in Formula 2 to Formula 4, R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted aryl having 6 to 30 carbon atoms, substituted or unsubstituted heteroaryl having 3 to 30 carbon atoms, and combinations thereof;
preferably, R_{z} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, and combinations thereof;
more preferably, R_{z} is selected from the group consisting of: methyl, ethyl, isopropyl, isobutyl, t-butyl, neopentyl, cyclopentyl, 1,1-dimethyl-1-cyanomethyl, 2-cyano-2,2-dimethyl-ethyl, 2,2,2-trifluoro-1,1-dimethylethyl, 3,3,3-trifluoro-2,2-dimethylpropyl, benzyl, 1,1-dimethyl-1-phenylmethyl, tetrahydropyranyl, adamantyl, norbornyl, phenyl, and any of the above groups that are partially or fully deuterated.

5. The metal complex of claim 3, wherein in Formula 2 to Formula 4, R_{y1} and R_{y2} are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, and combinations thereof;
preferably, R_{y1} and R_{y2} are, at each occurrence identically or differently, selected from the group consisting of: methyl, ethyl, isopropyl, t-butyl, cyclopentyl, cyclohexyl, cyano, trifluoromethyl, trimethylsilyl, trimethylgermanyl, methoxy, N,N-dimethylamino, phenyl, 2,4,6-triisopropylphenyl, tetrahydropyranyl, adamantyl, norbornyl, pyridyl, and any of the above groups that are partially or fully deuterated.

6. The metal complex of claim 3, wherein in Formula 2 or Formula 4, Y₃ is, at each occurrence identically or differently, selected from CR_{y}; preferably, the R_{y} is, at each occurrence identically or differently, selected from the group consisting of: hydrogen, deuterium, methyl and deuterated methyl.

7. The metal complex of claim 3, wherein in Formula 2 to Formula 4, X₁ and X₃ to X₈ are, at each occurrence identically or differently, selected from CRₓ; the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, an isocyano group, a hydroxyl group, a sulfanyl group, and combinations thereof;
adjacent substituents Rₓ can be optionally joined to form a ring;
preferably, the Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, an isocyano group, a hydroxyl group, a sulfanyl group, and combinations thereof.

8. The metal complex of claim 3, wherein in Formula 2, at least one or two of X₅ to X₈ is(are), at each occurrence identically or differently, selected from CRₓ; in Formula 3, at least one or two of X₄ and X₅ to X₈ is(are), at each occurrence identically or differently, selected from CRₓ; in Formula 4, at least one or two of X₃ and X₅ to X₈ is(are), at each occurrence identically or differently, selected from CRₓ; the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, in Formula 2, X₆ and/or X₇ are, at each occurrence identically or differently, selected from CRₓ; in Formula 3, X₄ and/or X₆ and/or X₇ are, at each occurrence identically or differently, selected from CRₓ; in Formula 4, X₃ and/or X₆ and/or X₇ are, at each occurrence identically or differently, selected from CRₓ; the Rₓ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group, and combinations thereof;
more preferably, the Rₓ is, at each occurrence identically or differently, selected from the group consisting of: deuterium, fluorine, cyano, trifluoromethyl, methyl, isopropyl, isobutyl, t-butyl, neopentyl, cyclopentyl, cyclopentylmethyl, cyclohexyl, trimethylsilyl, triethylsilyl, trimethylgermanyl, phenyl, triazinyl, norbornyl, adamantyl, and combinations thereof.

9. The metal complex of claim 1, wherein Lₐ is, at each occurrence identically or differently, selected from the group consisting of the following structures: 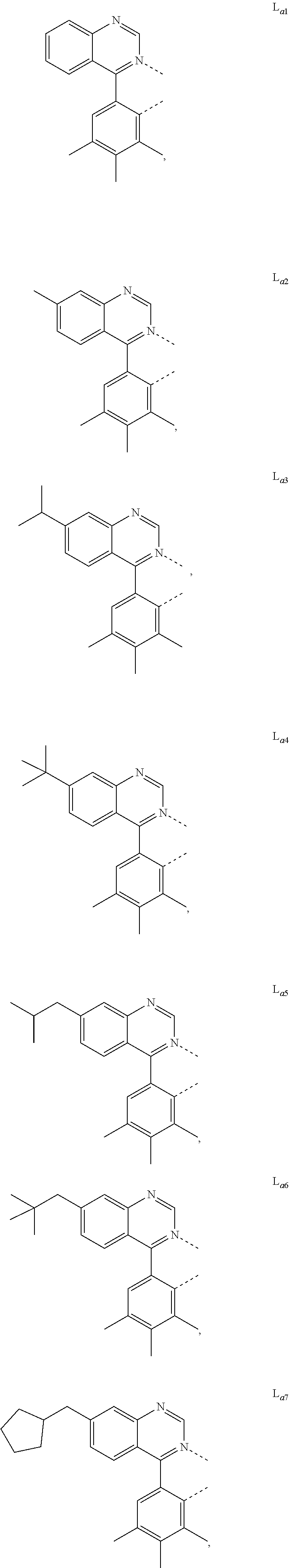 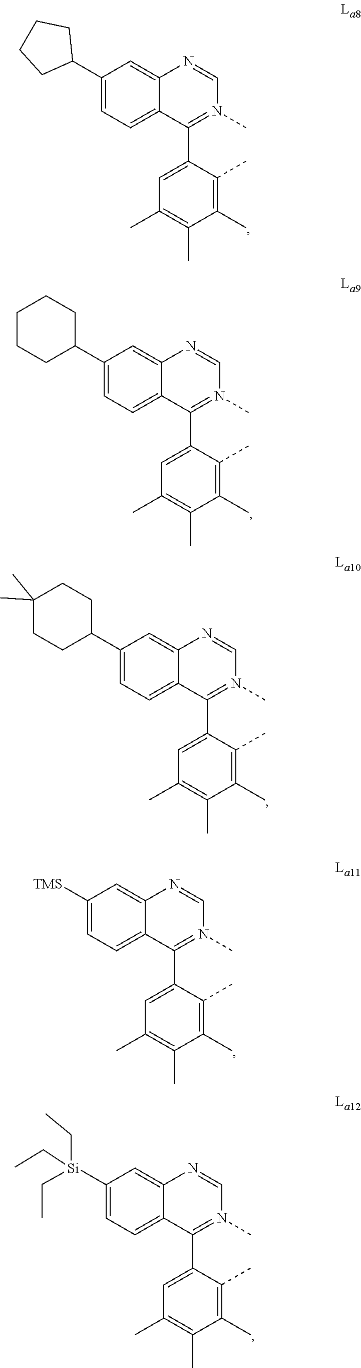 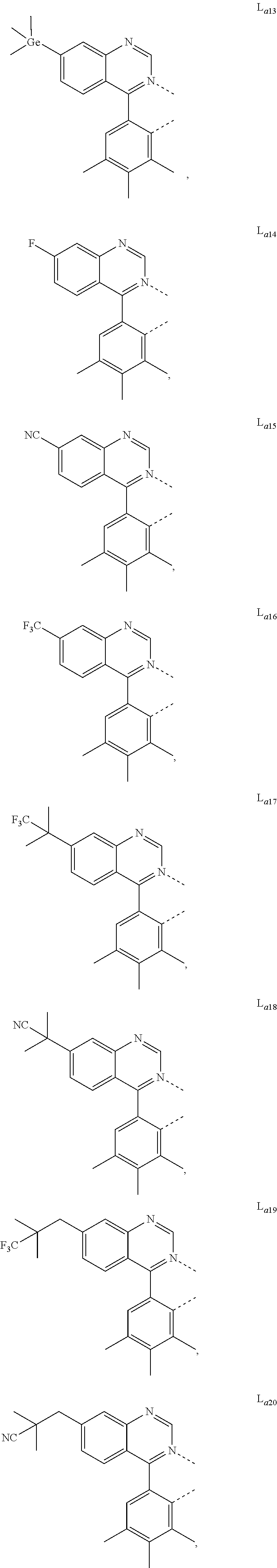 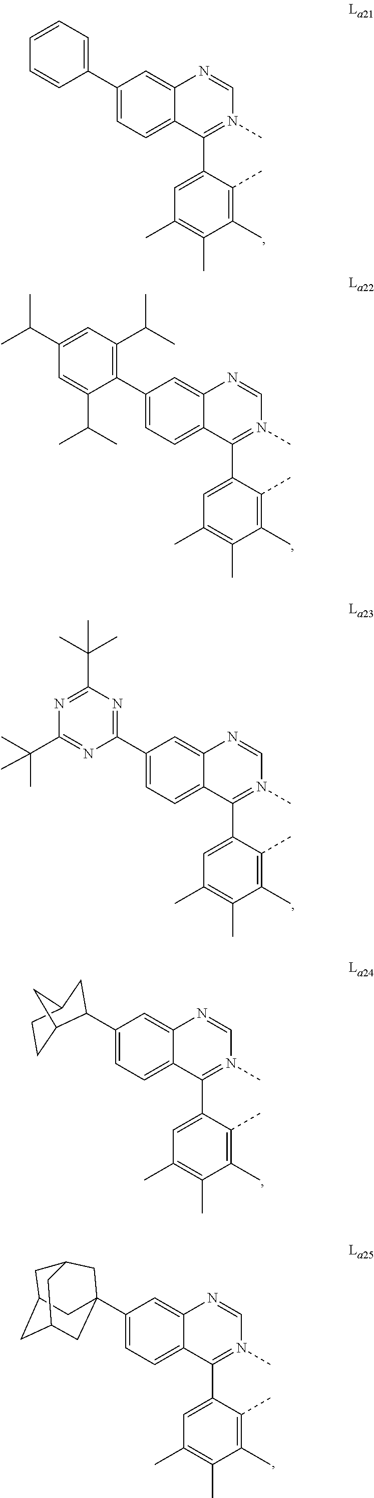 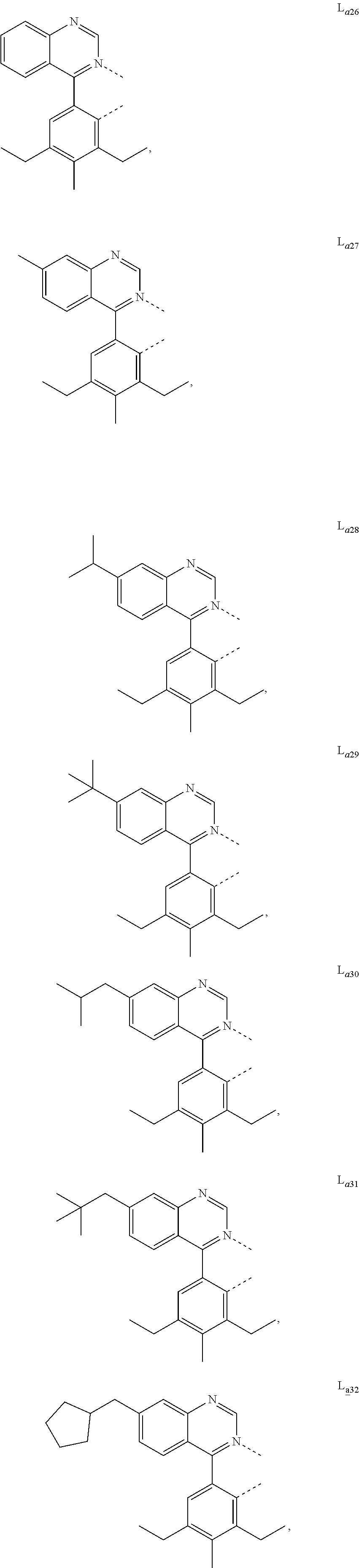 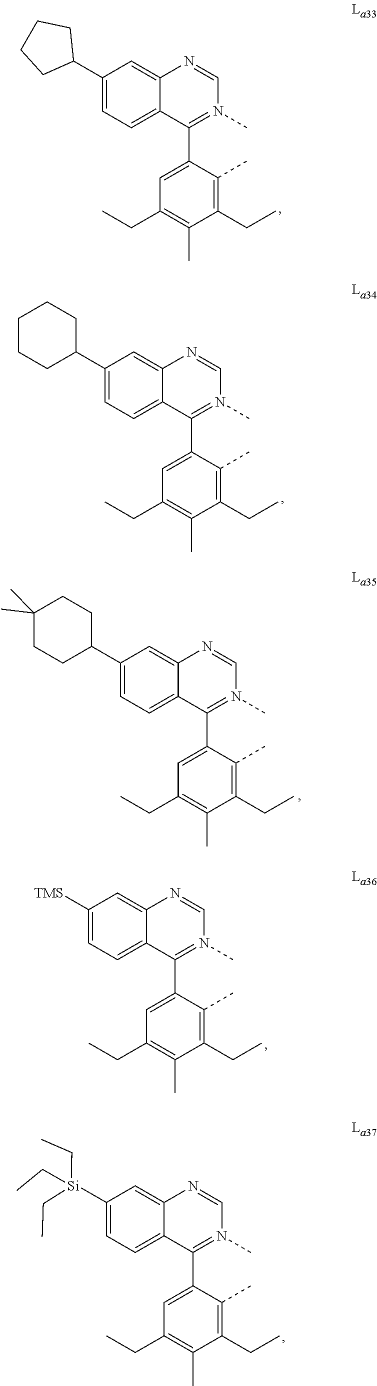 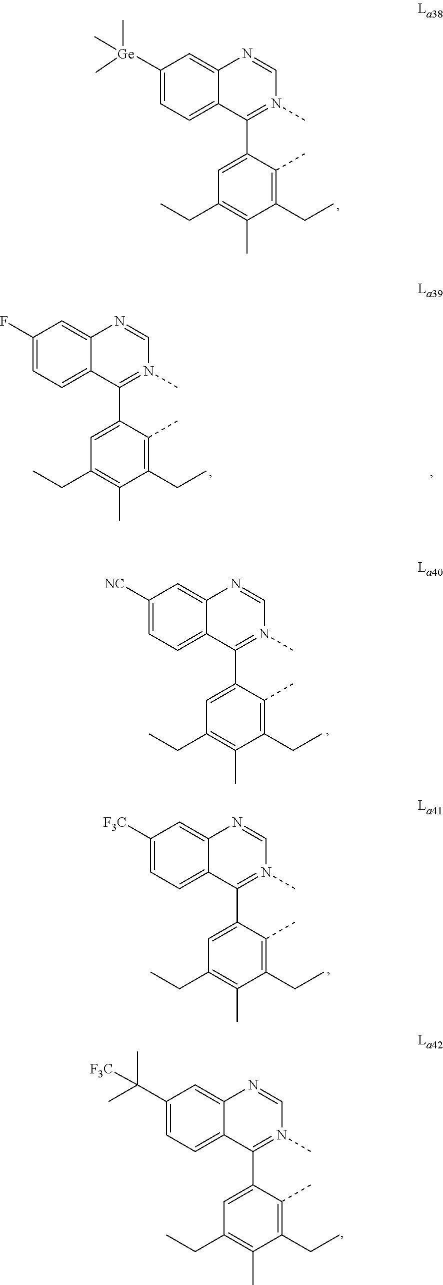 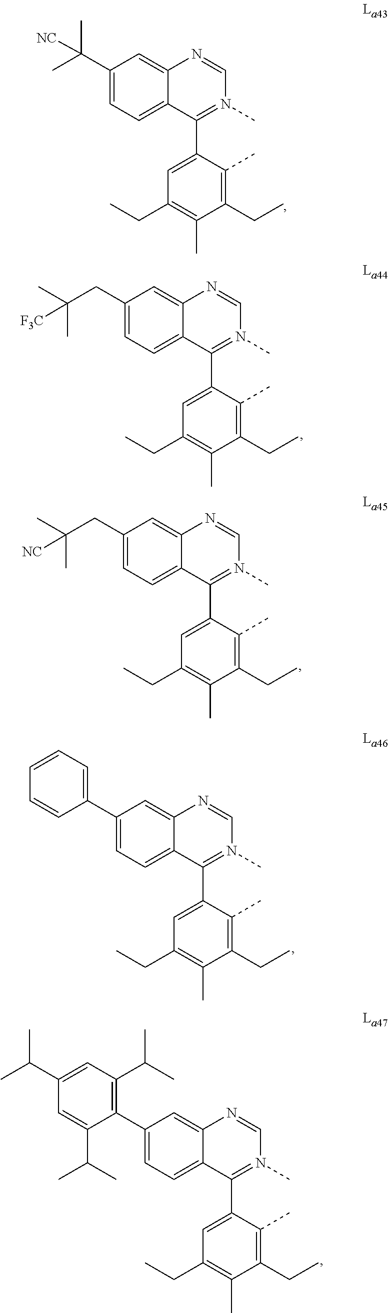 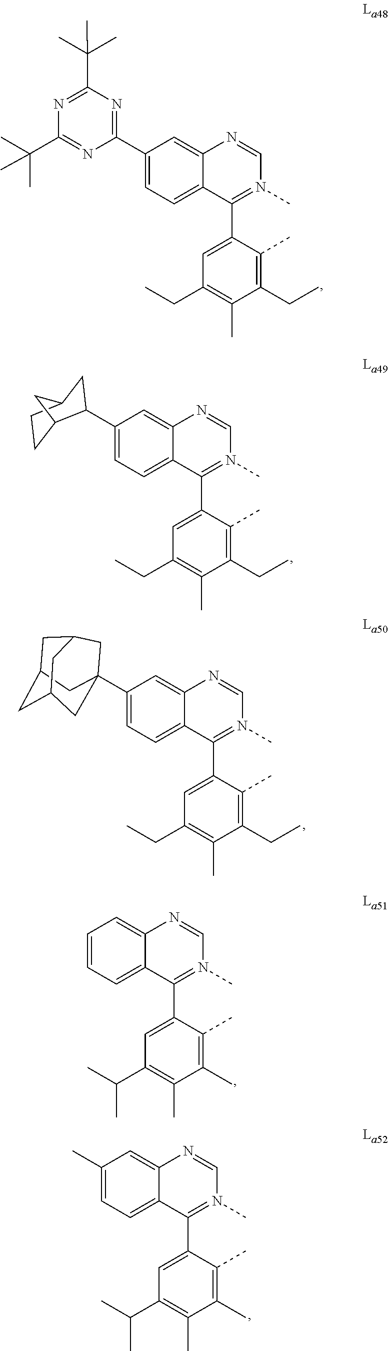 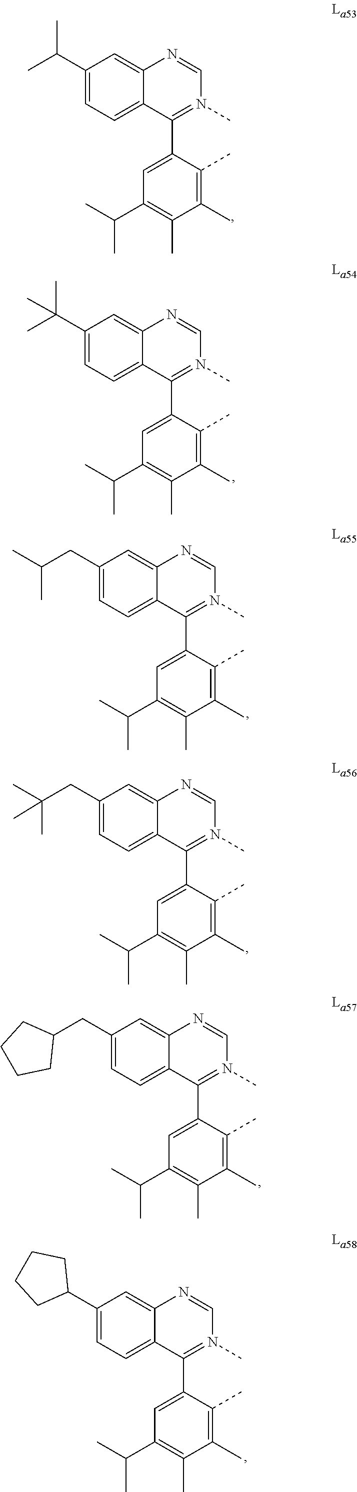 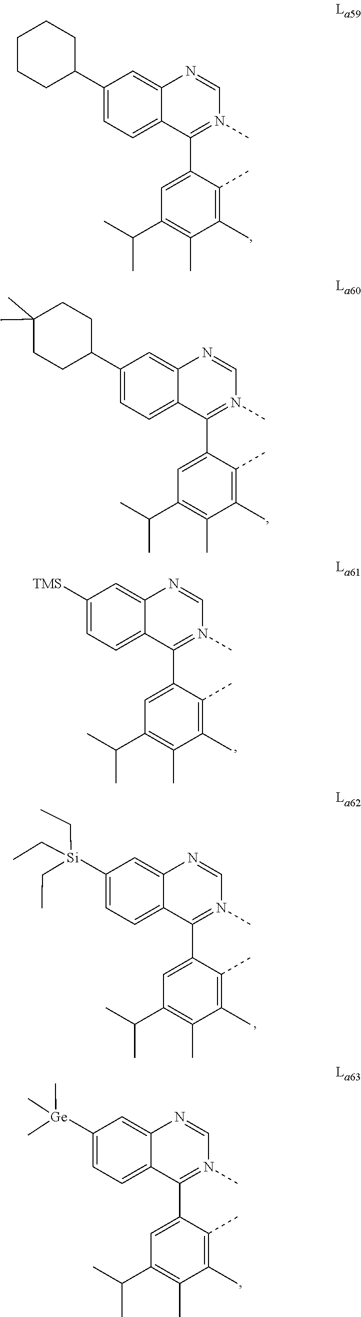 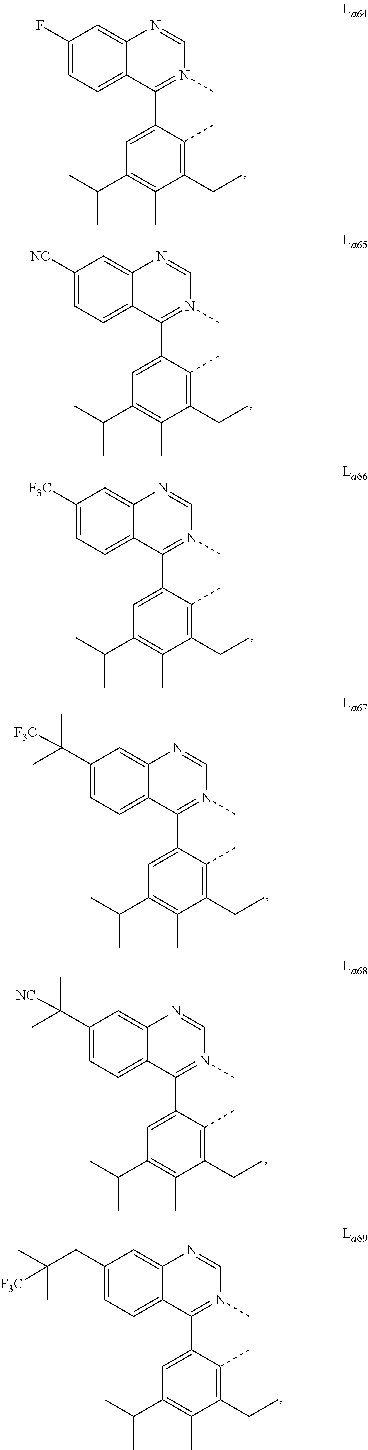 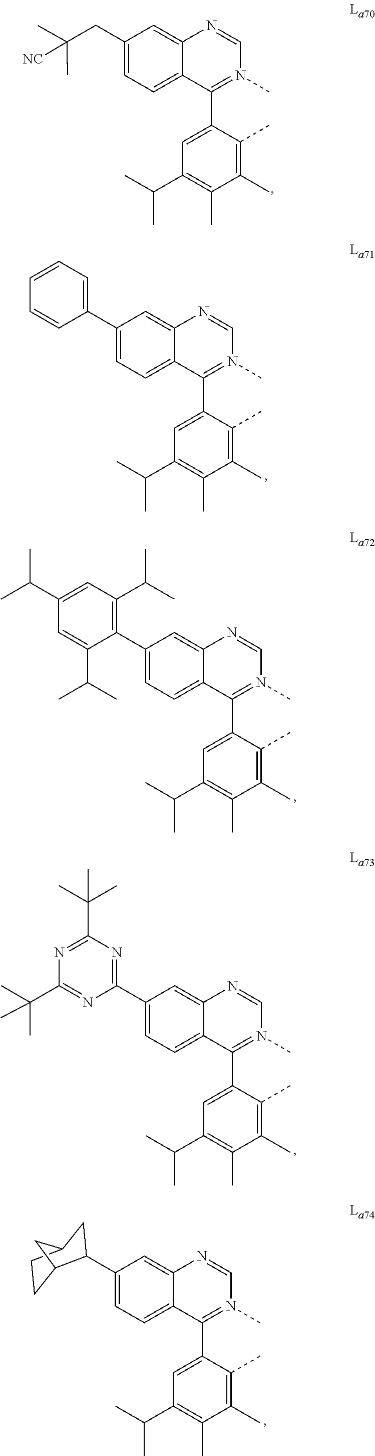 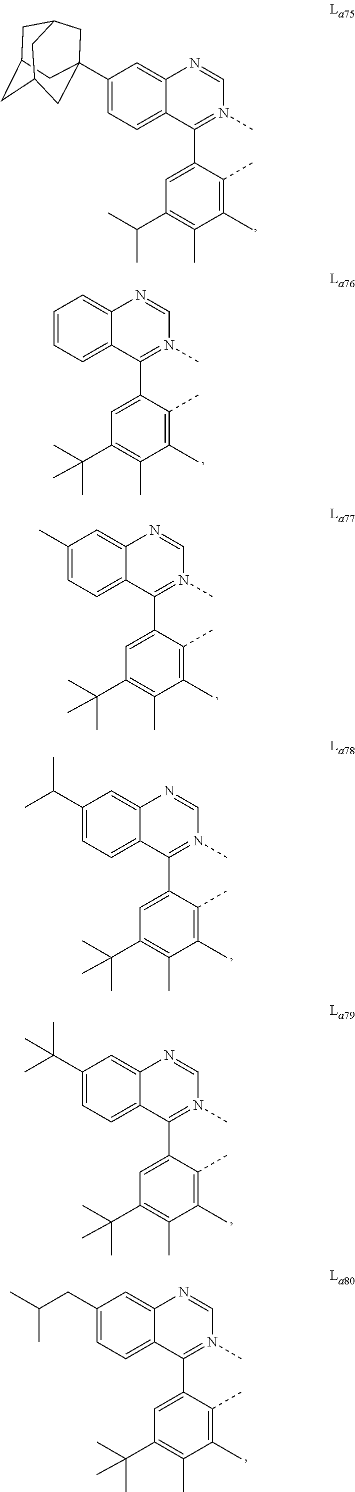 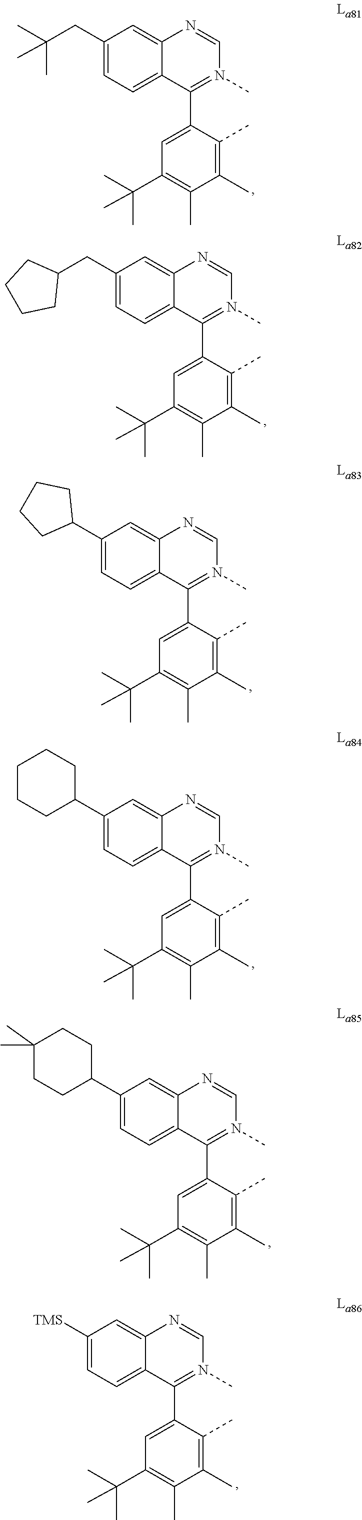 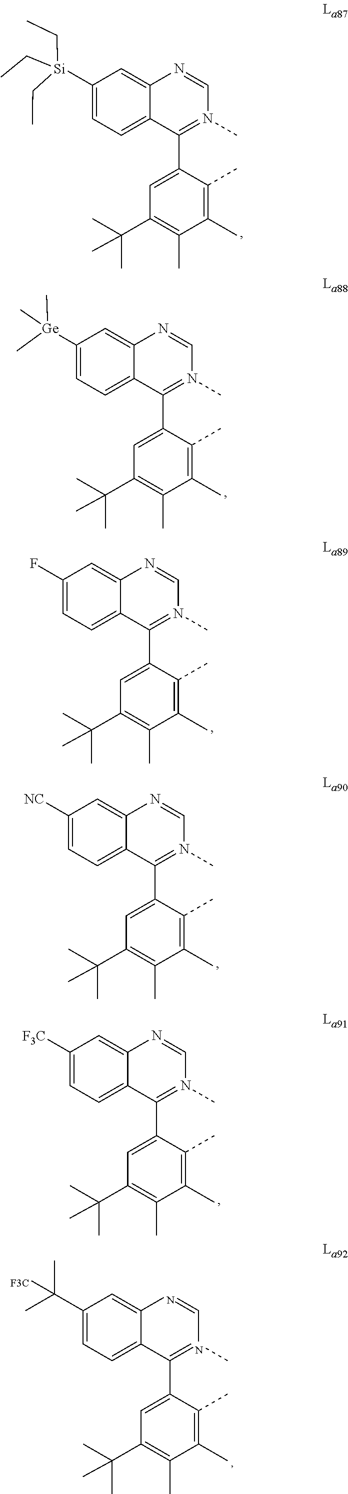 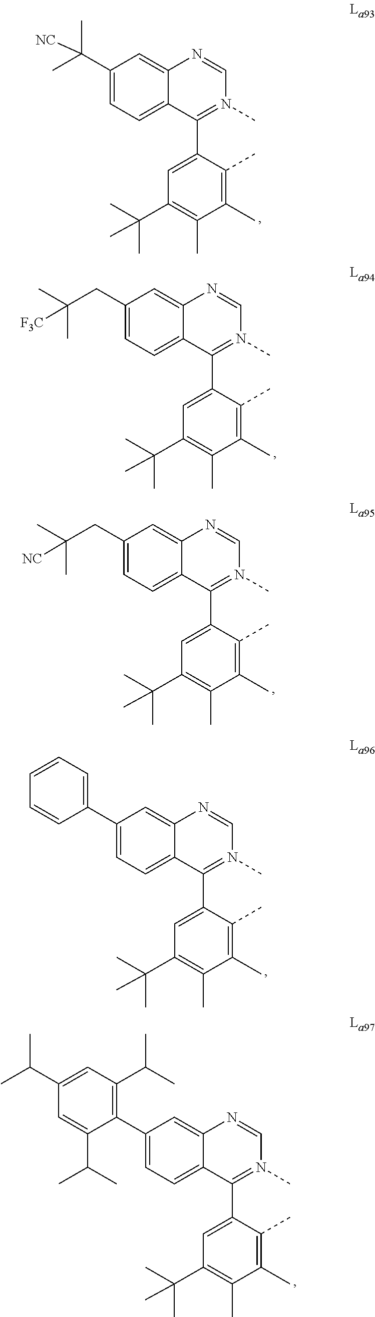 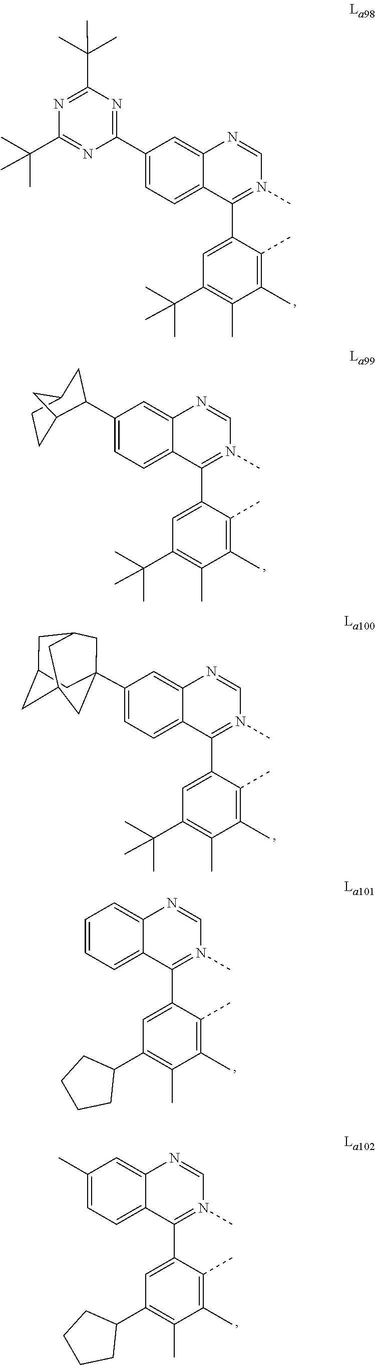 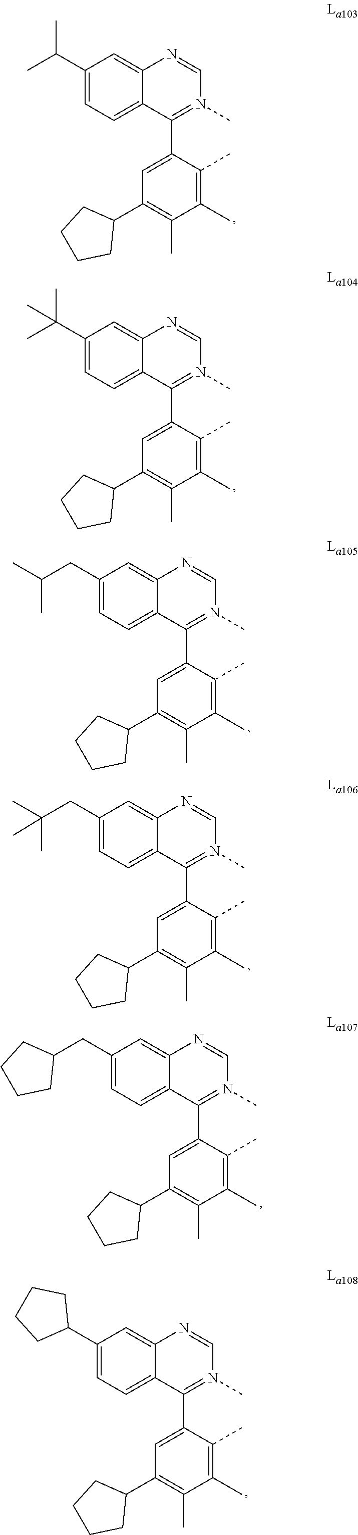 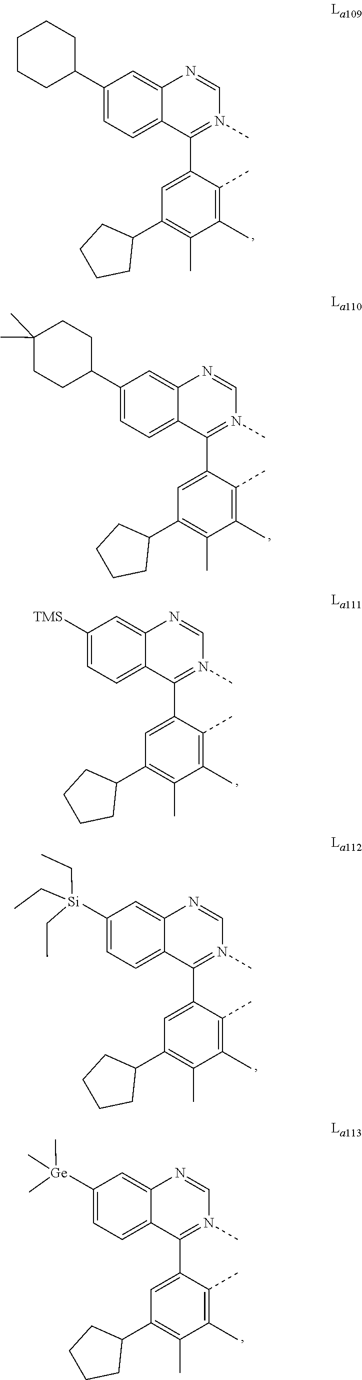 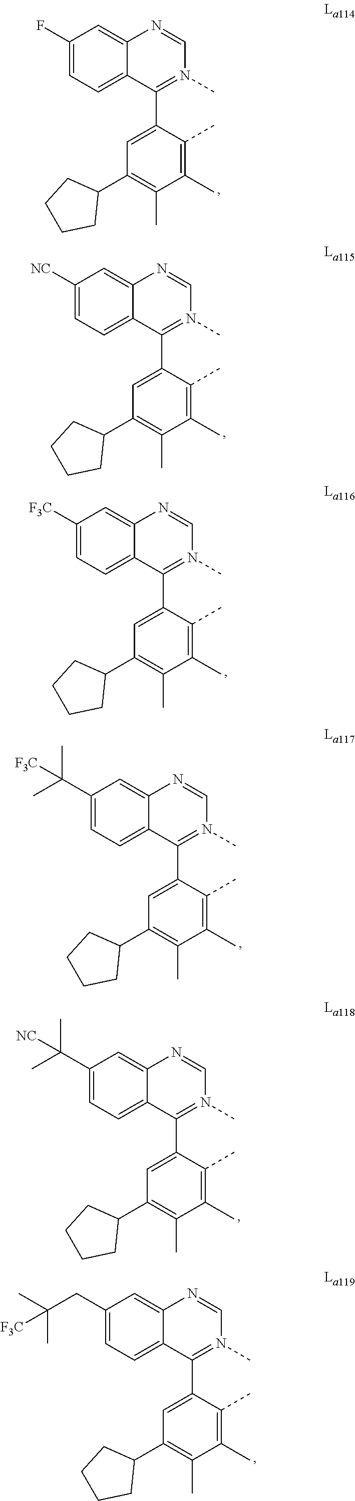 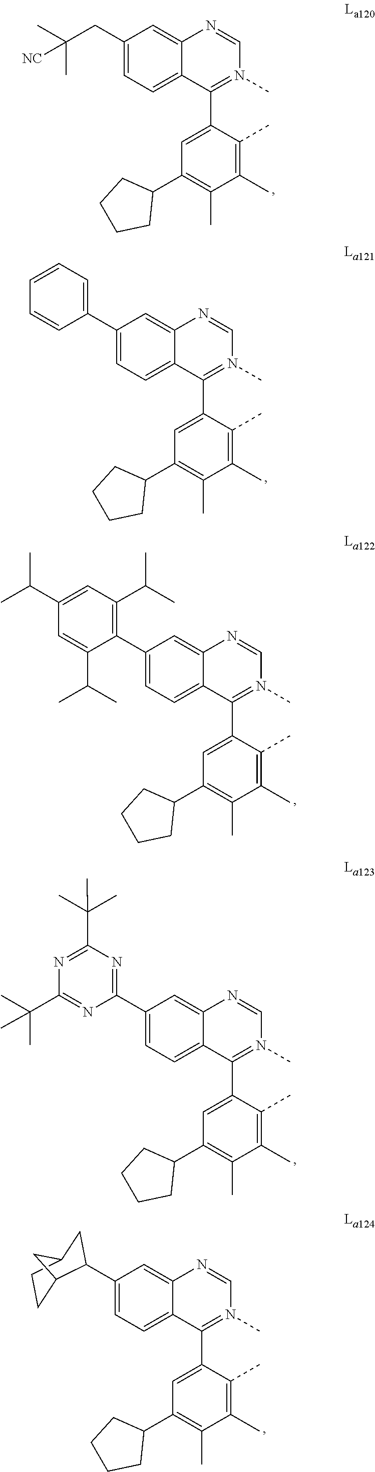 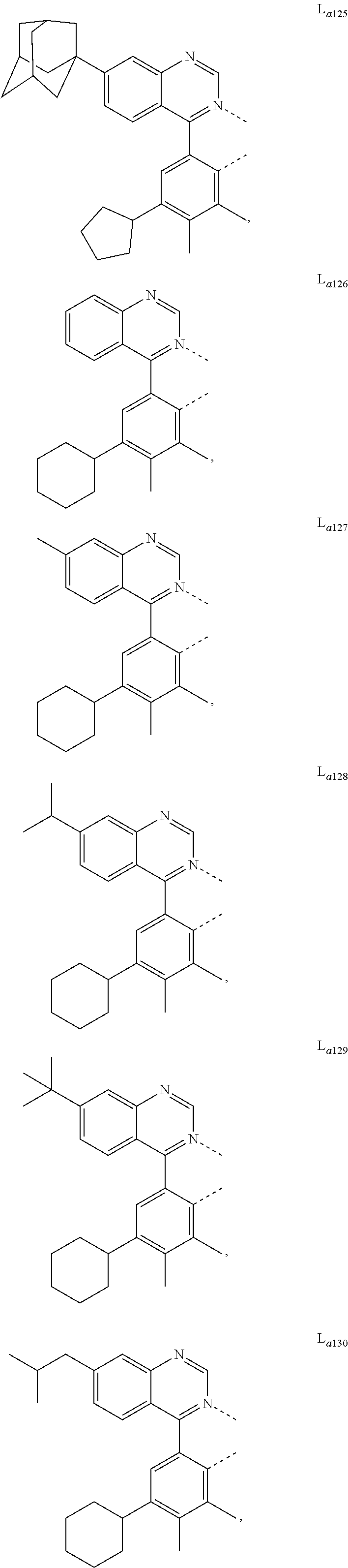 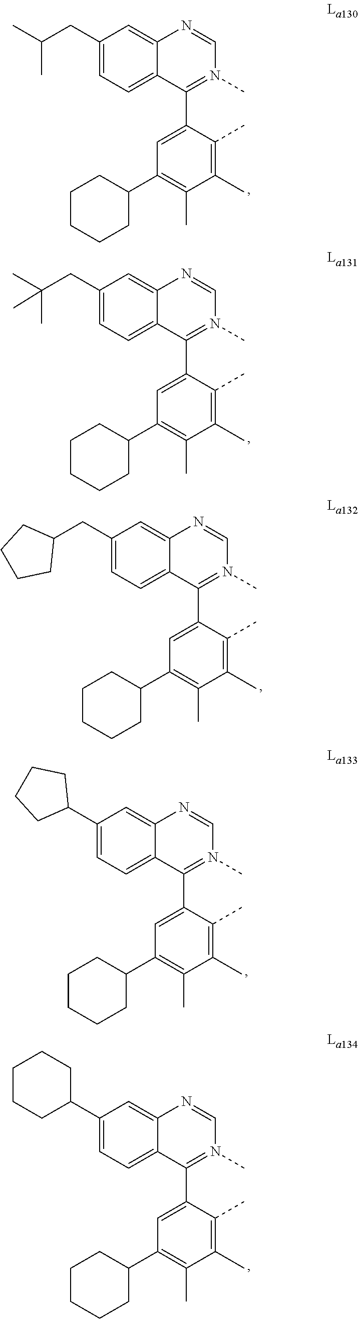 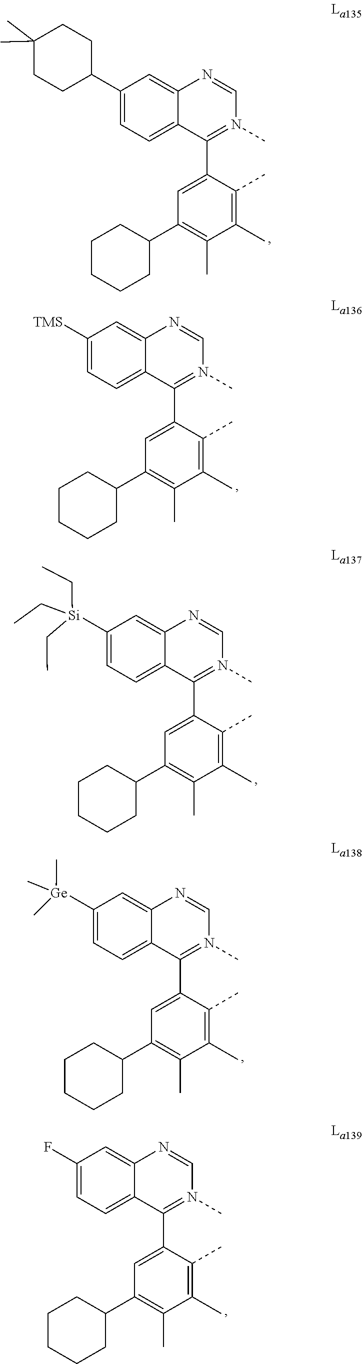 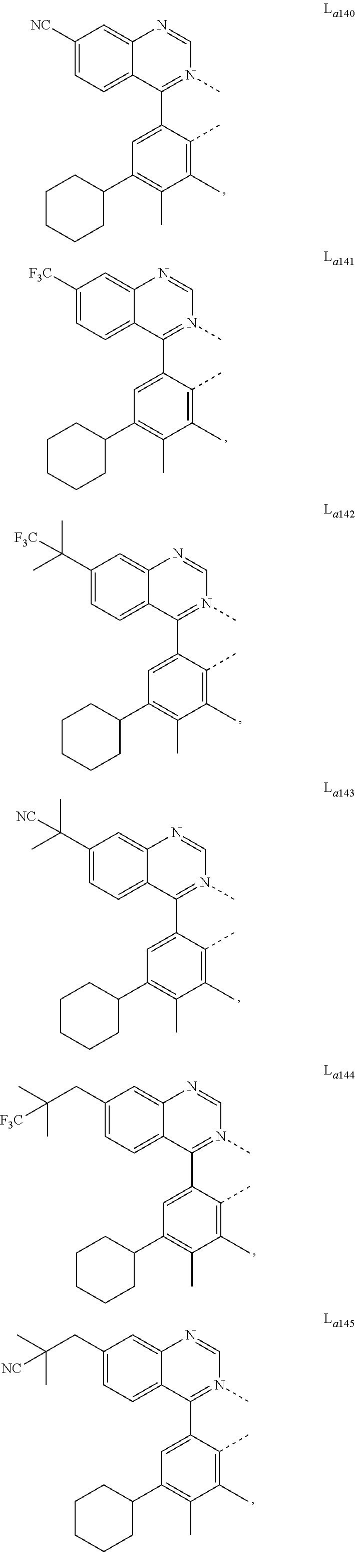 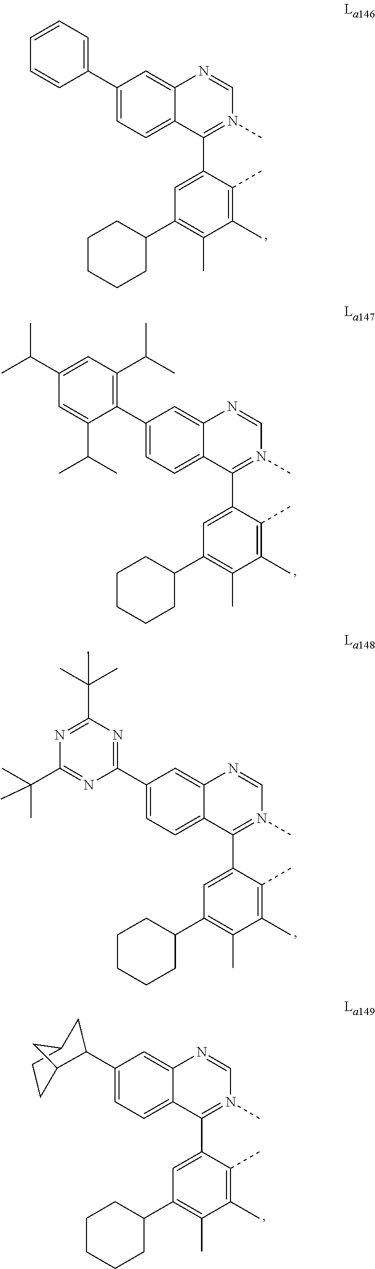 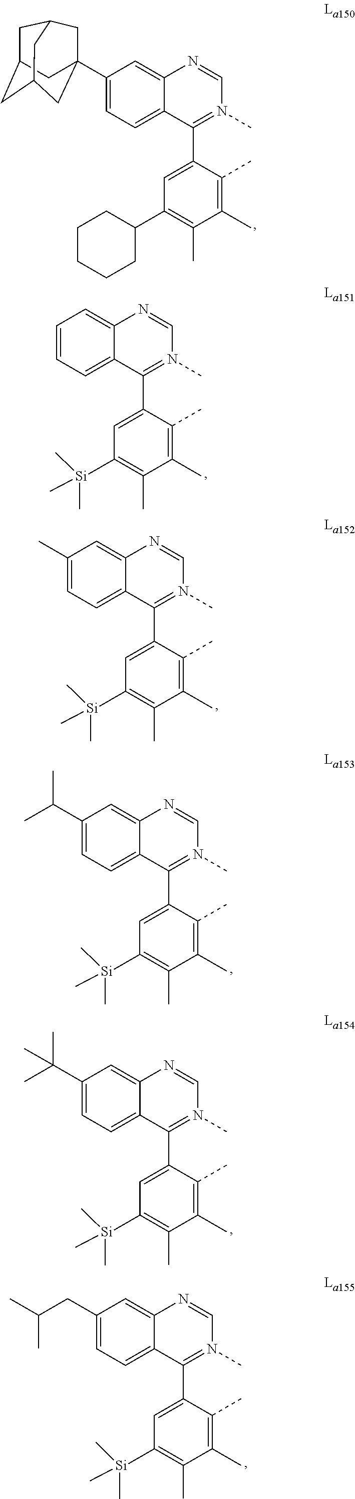 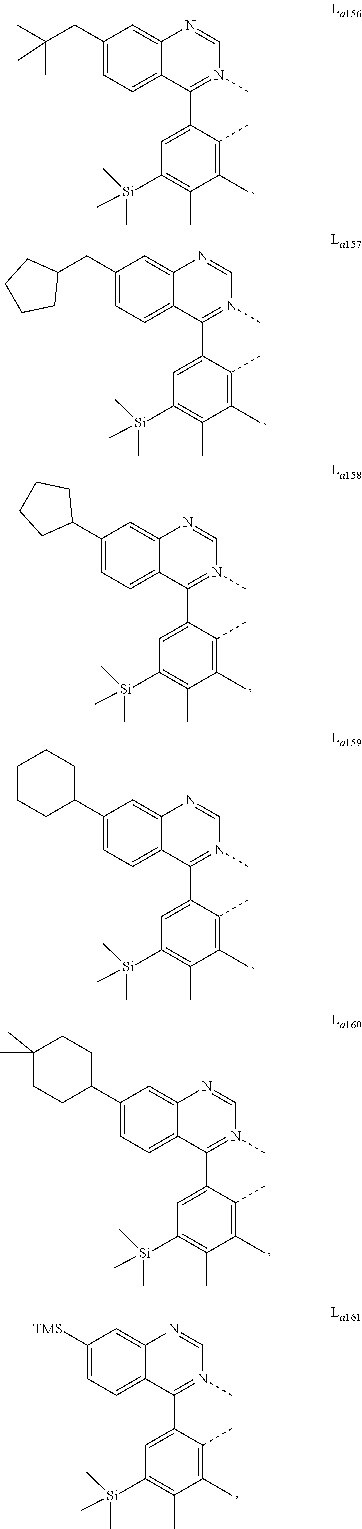 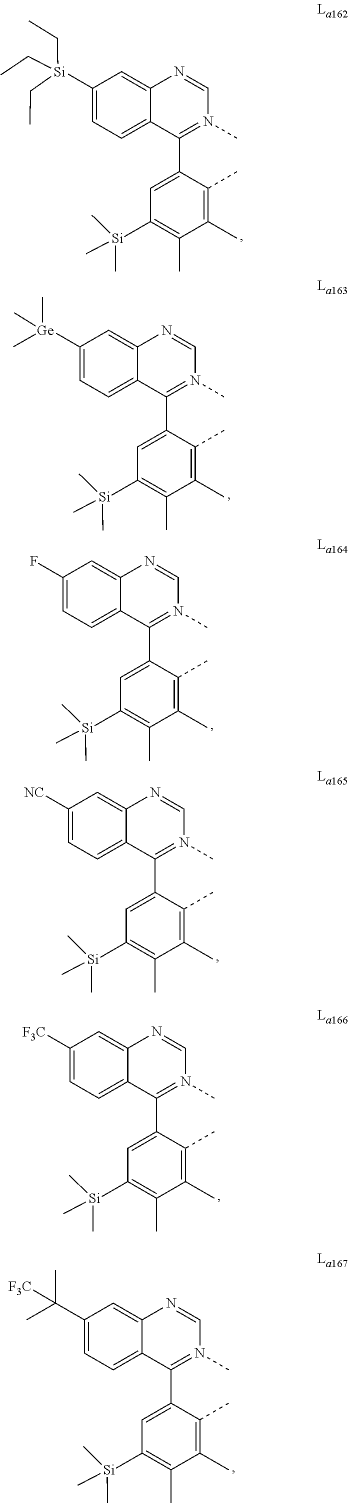 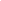 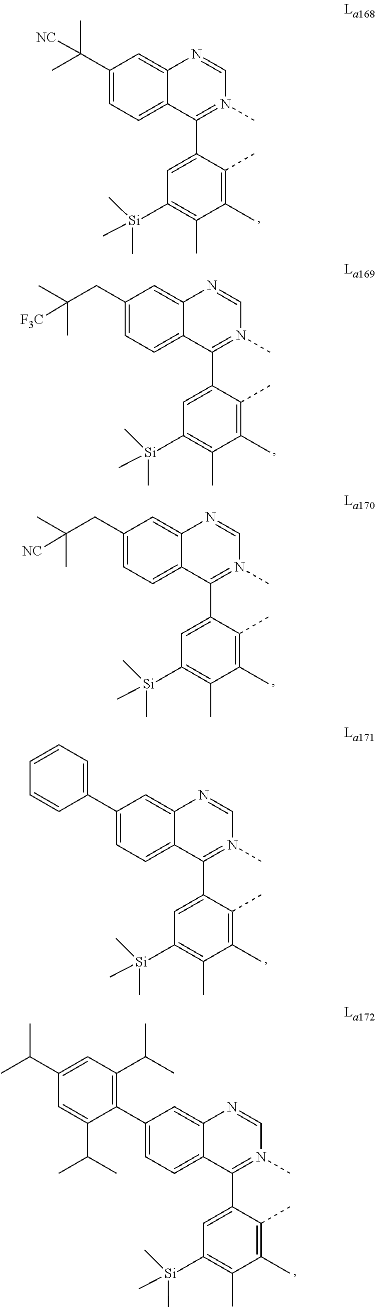 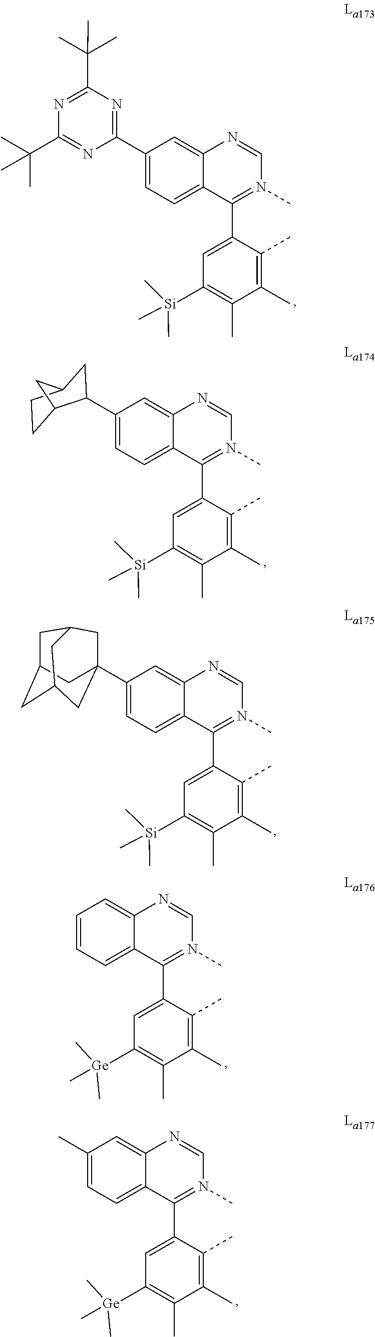 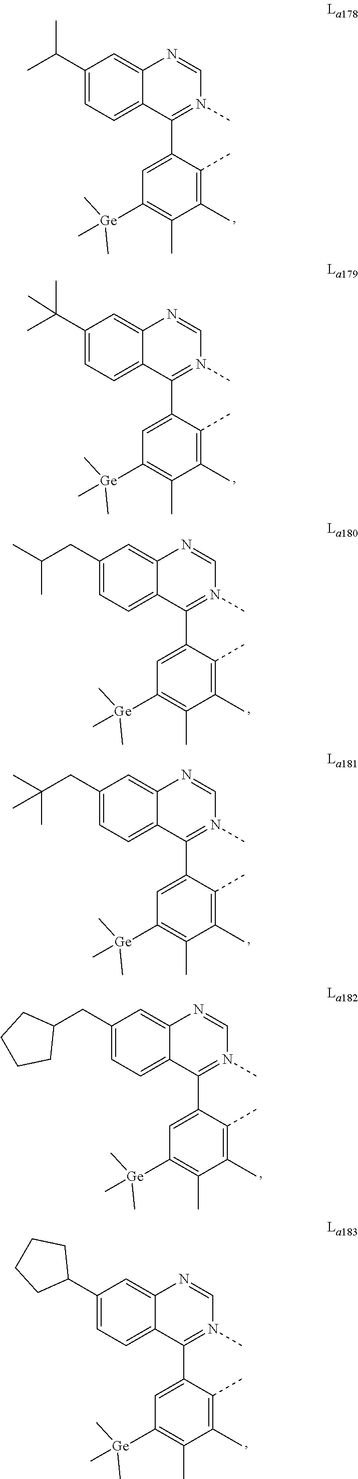 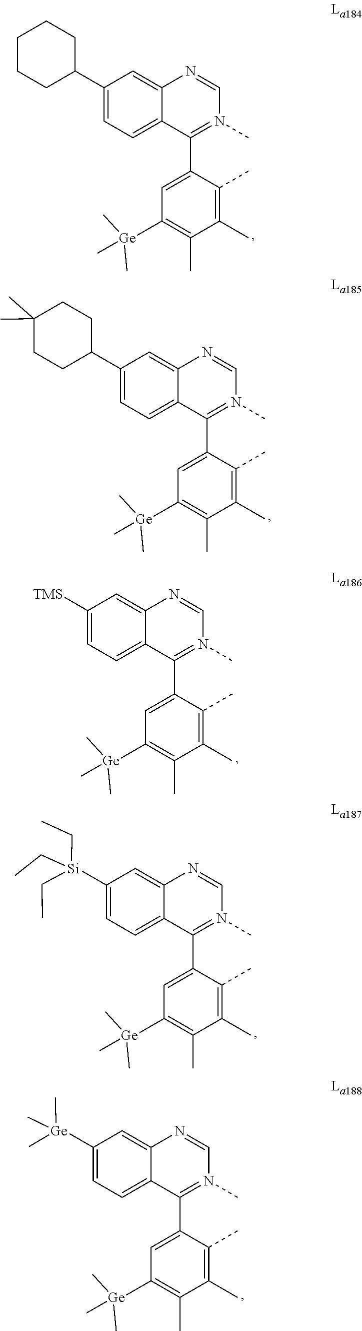 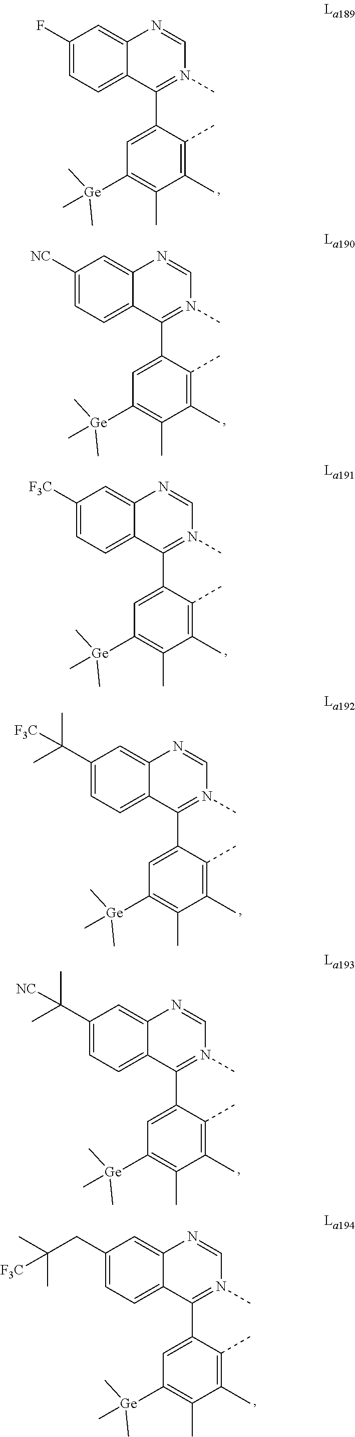 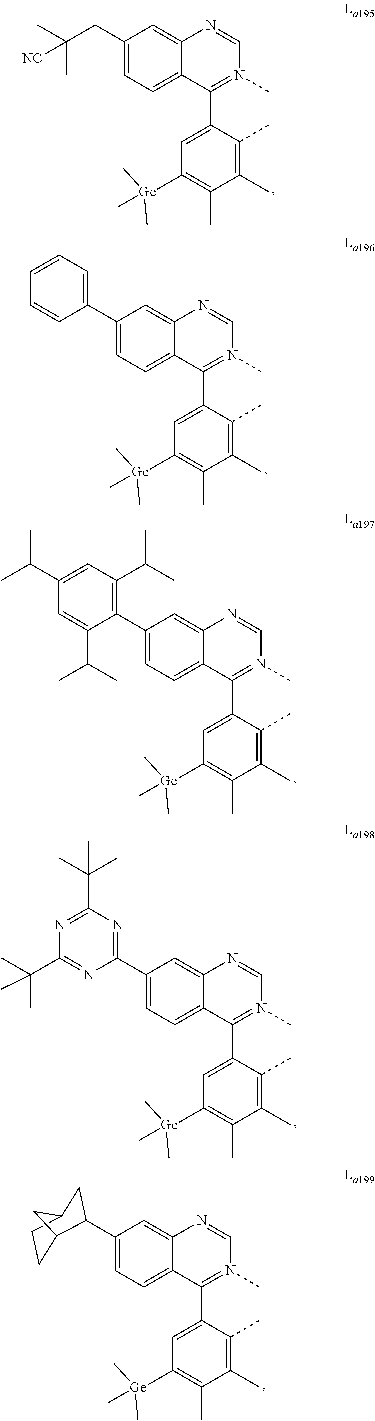 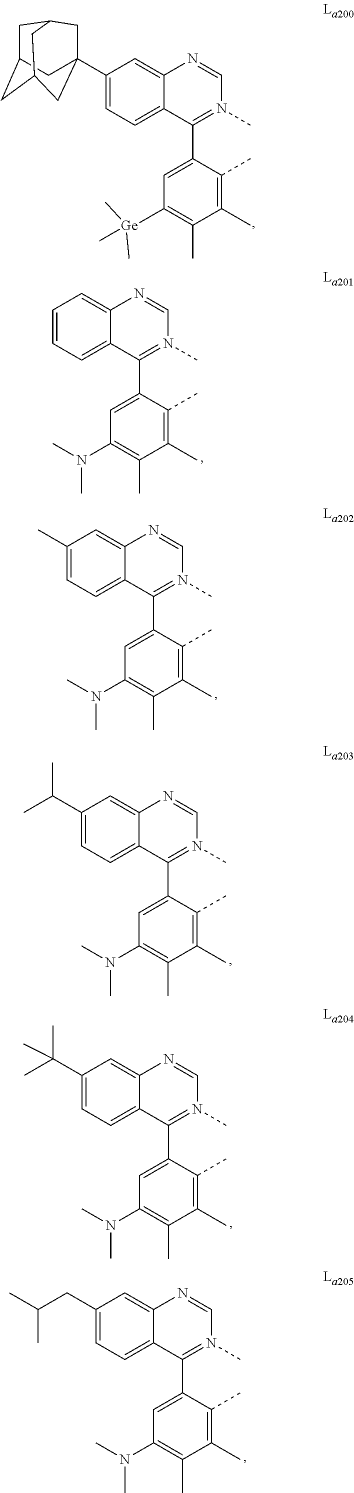 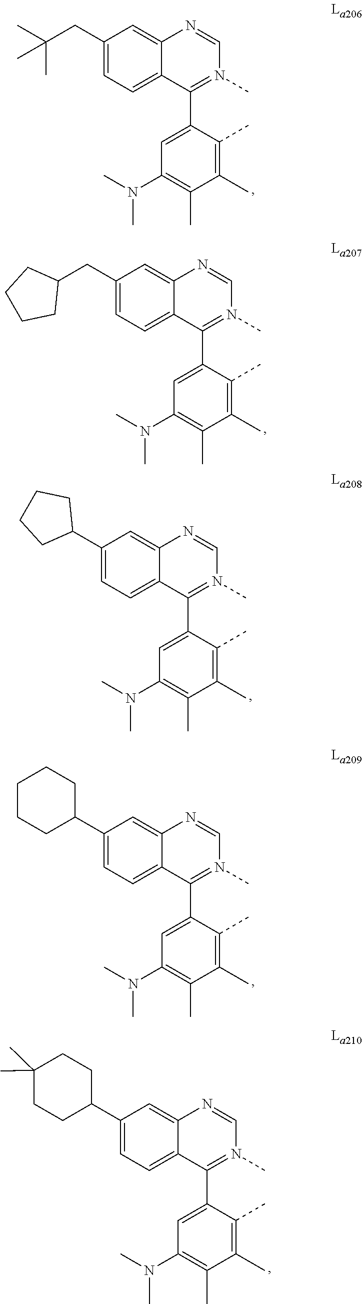 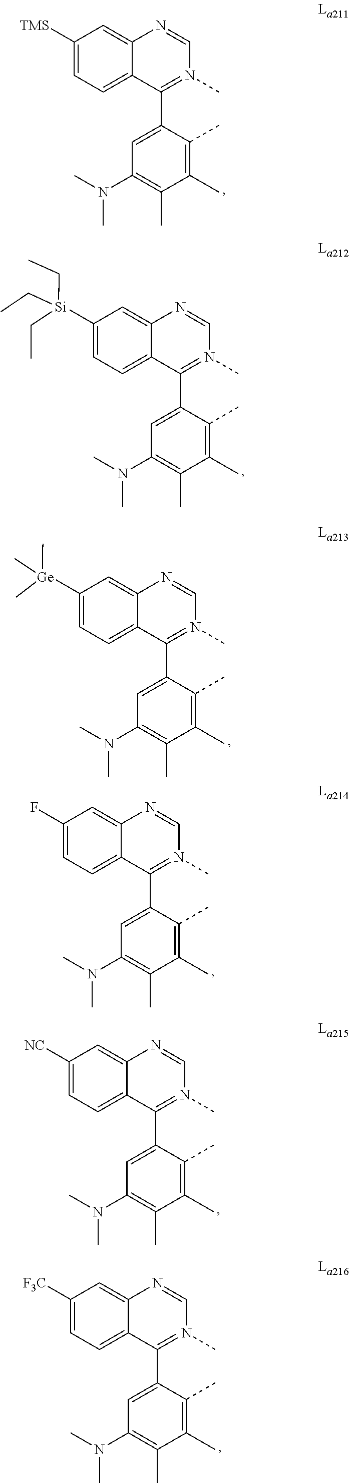 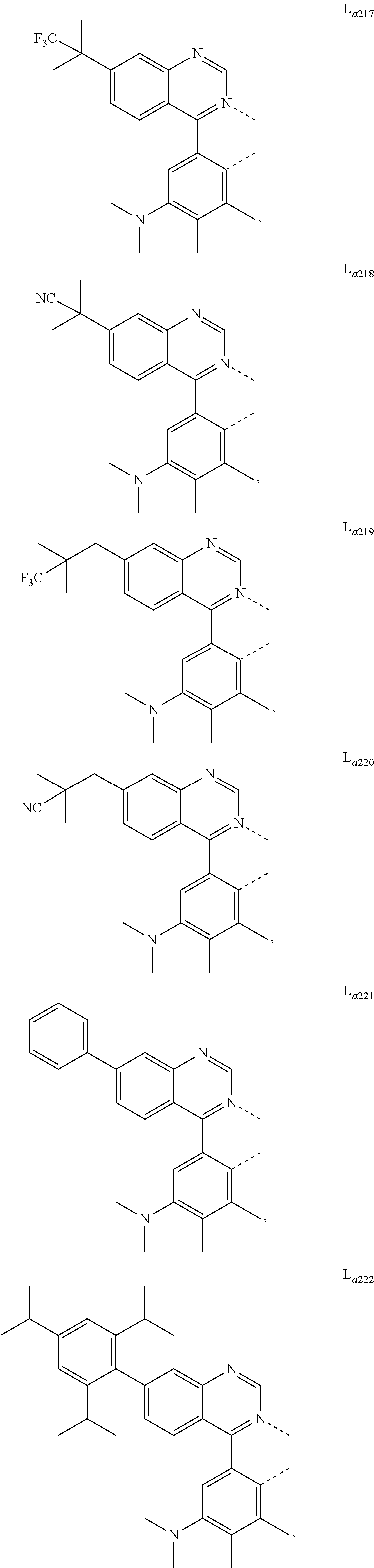 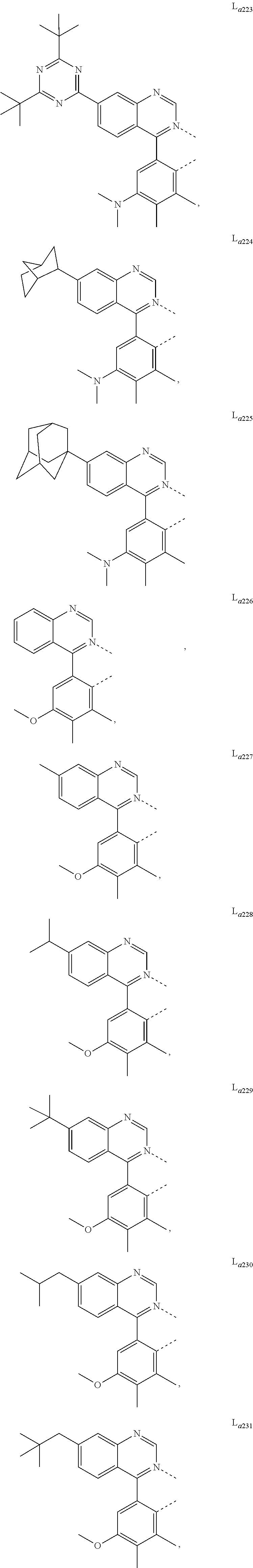 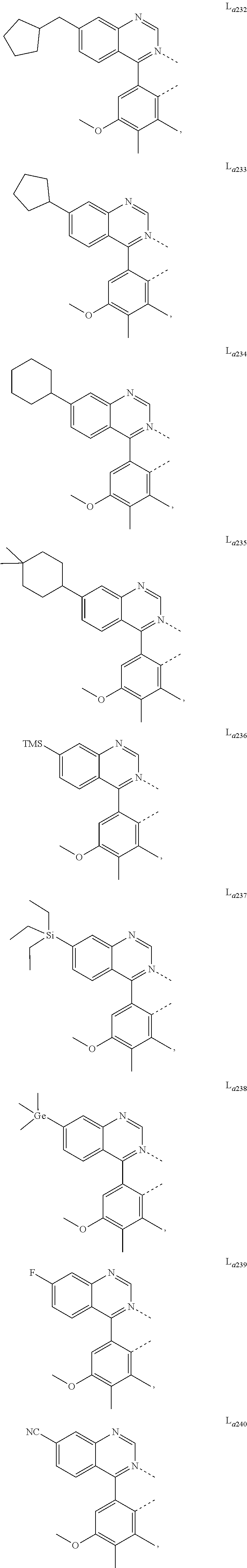 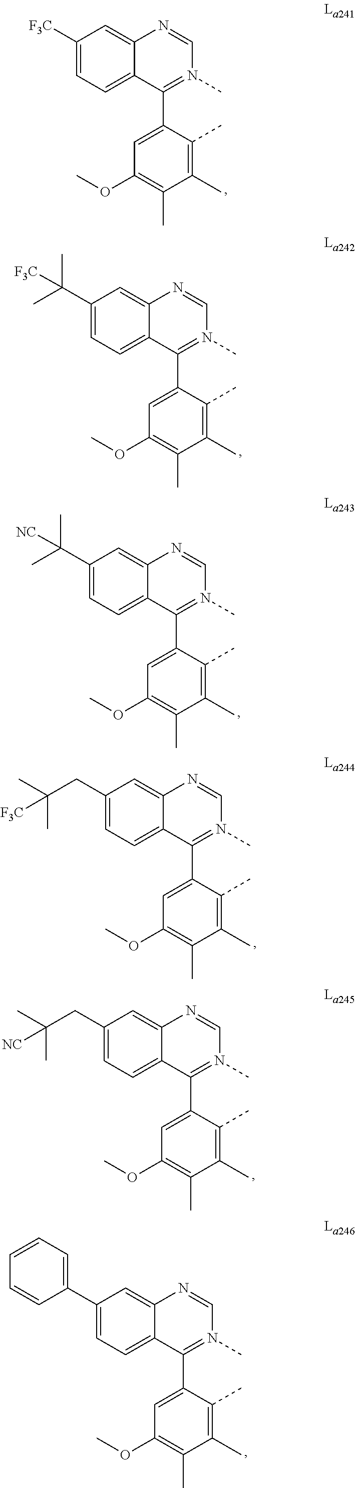 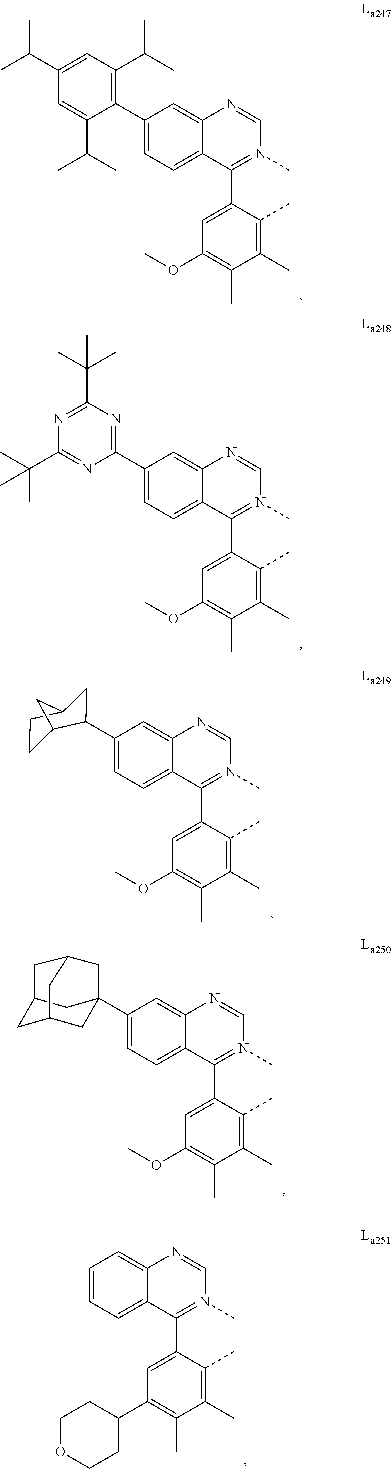 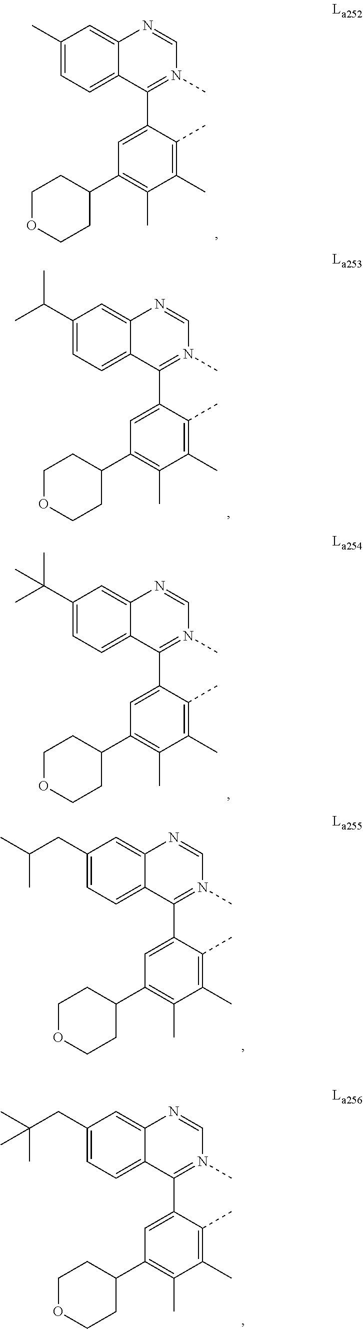 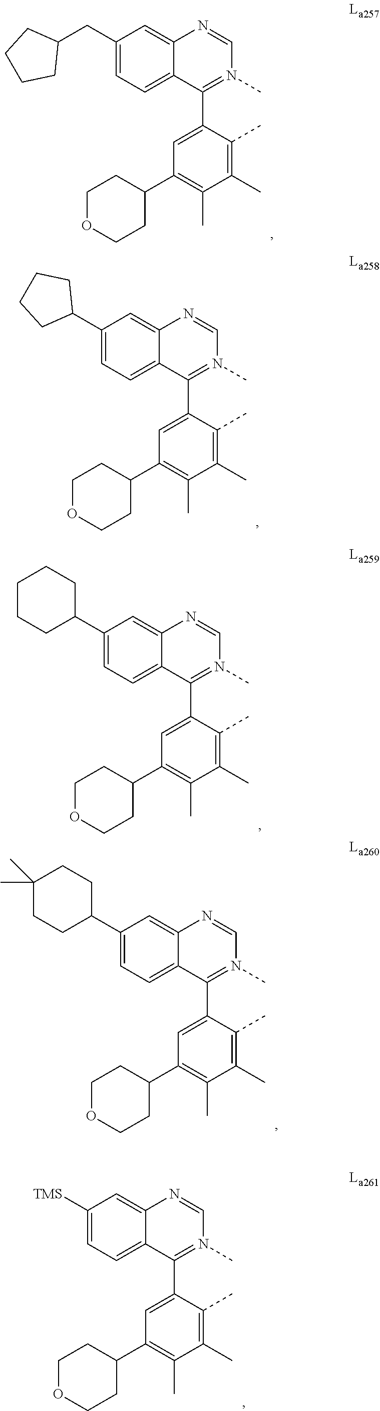 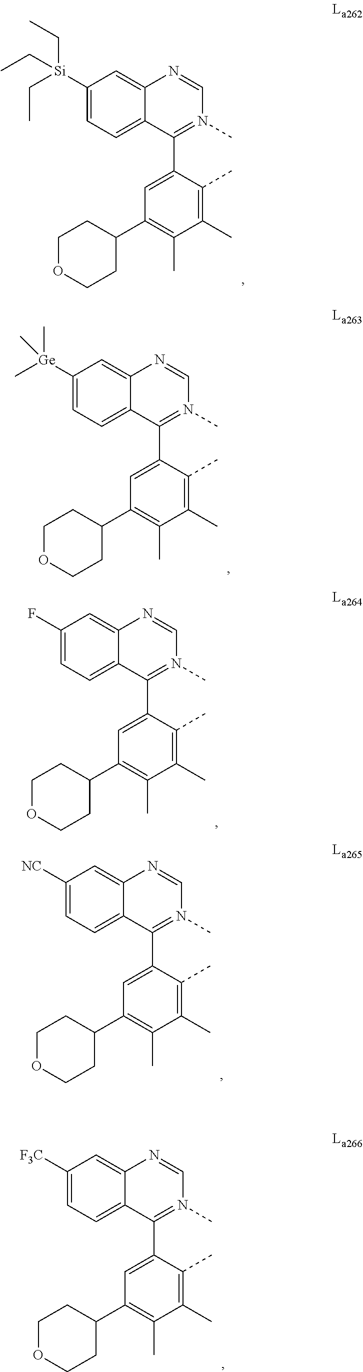 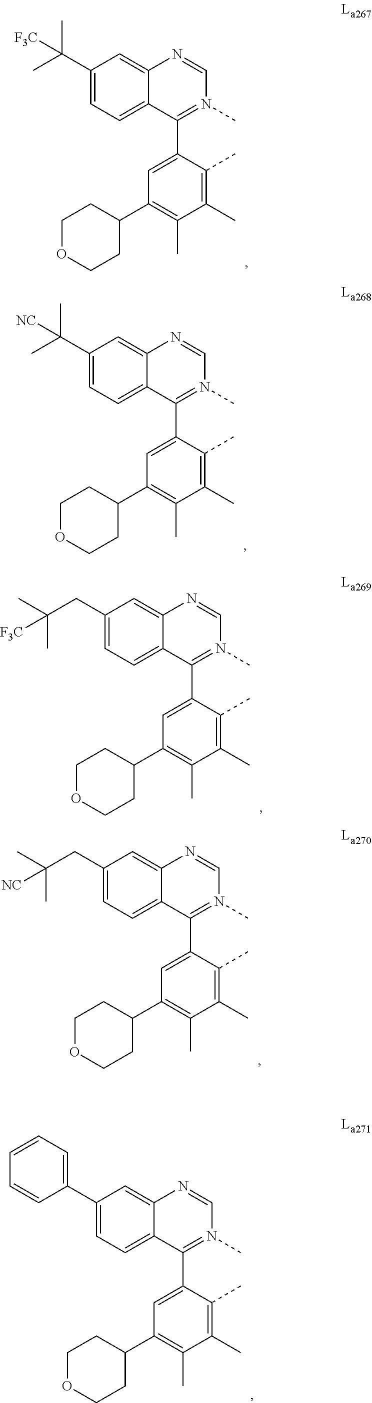 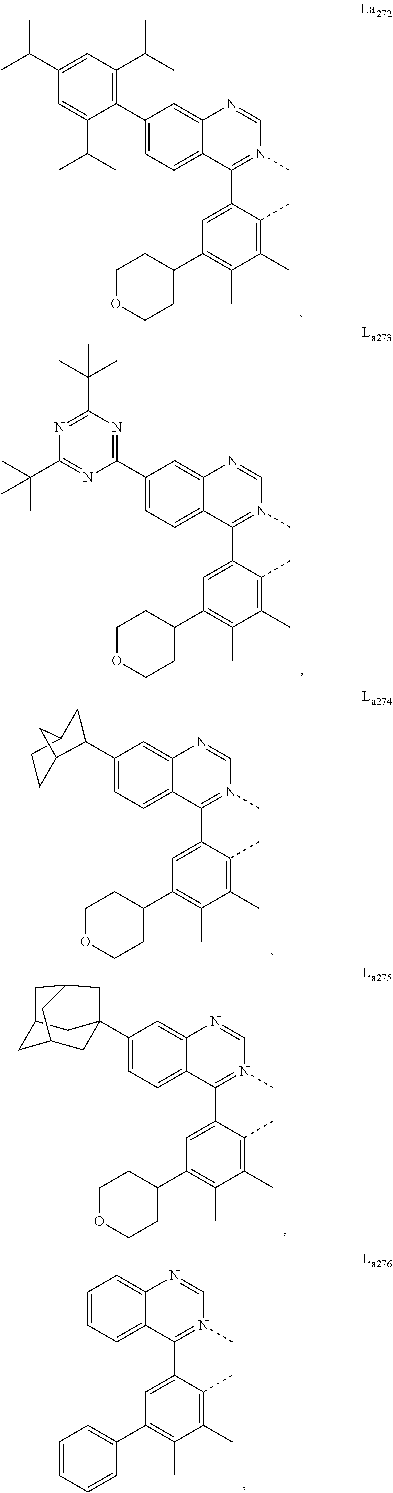 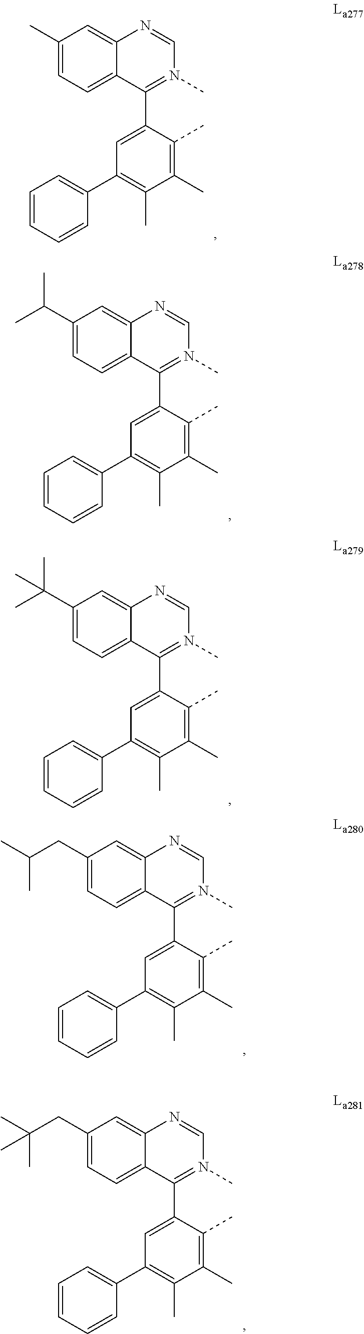 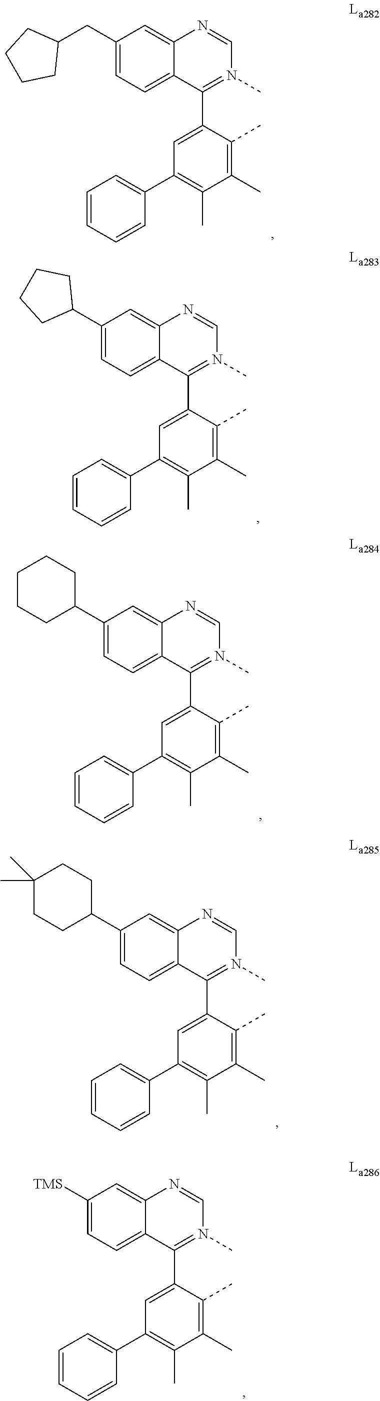 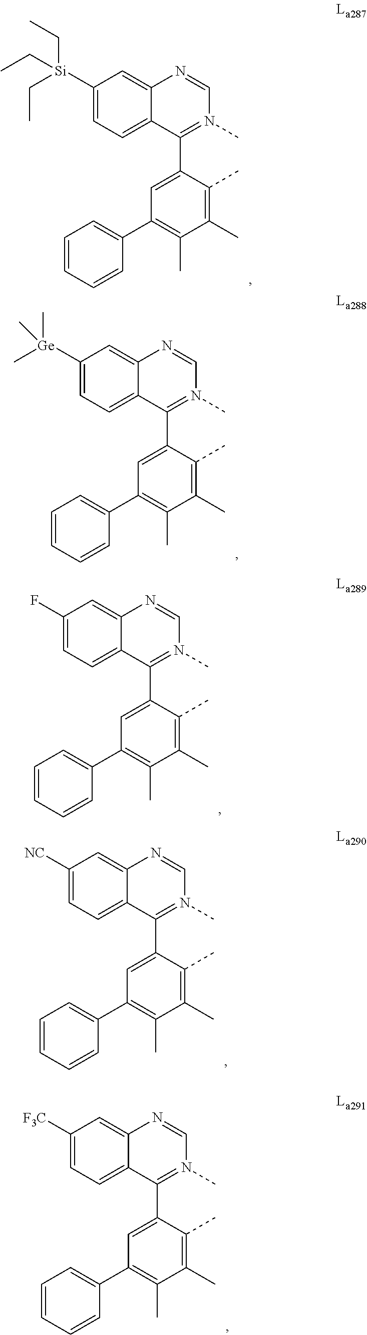 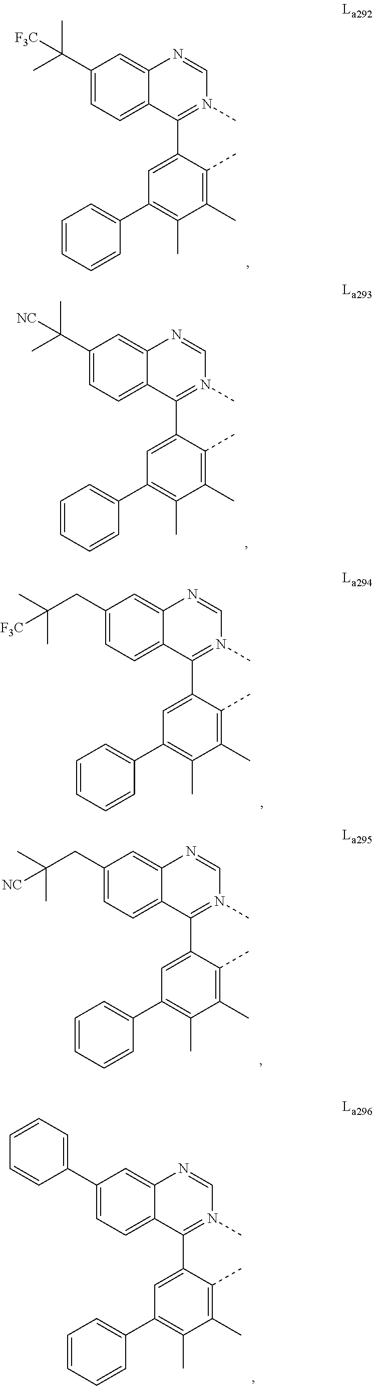 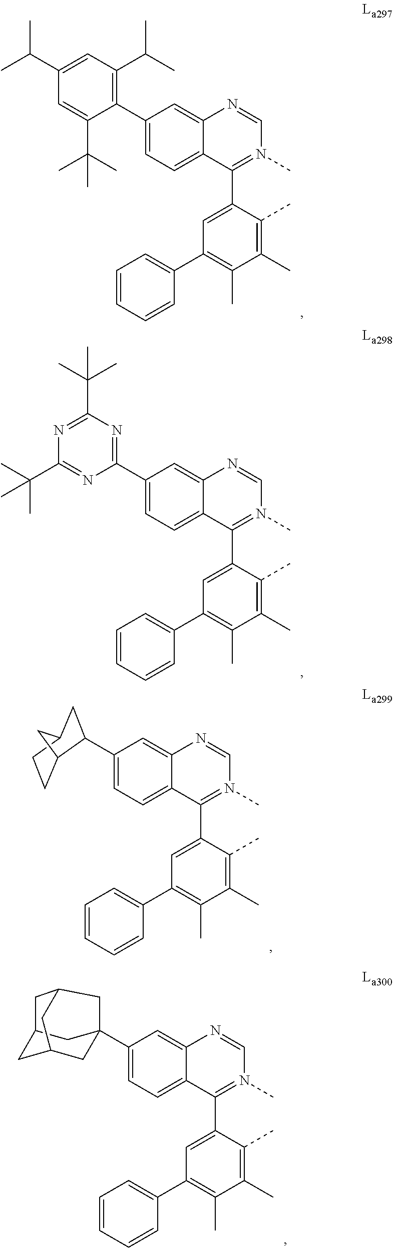 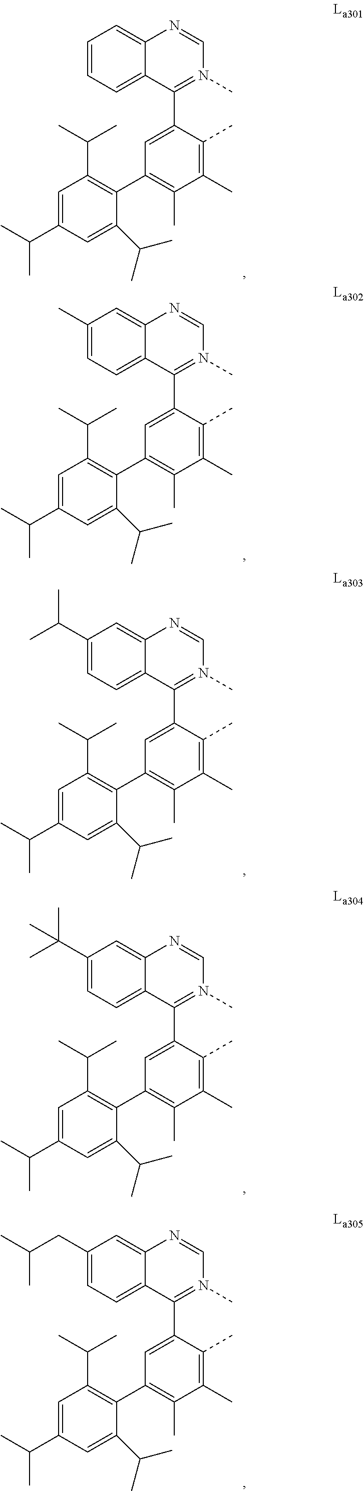 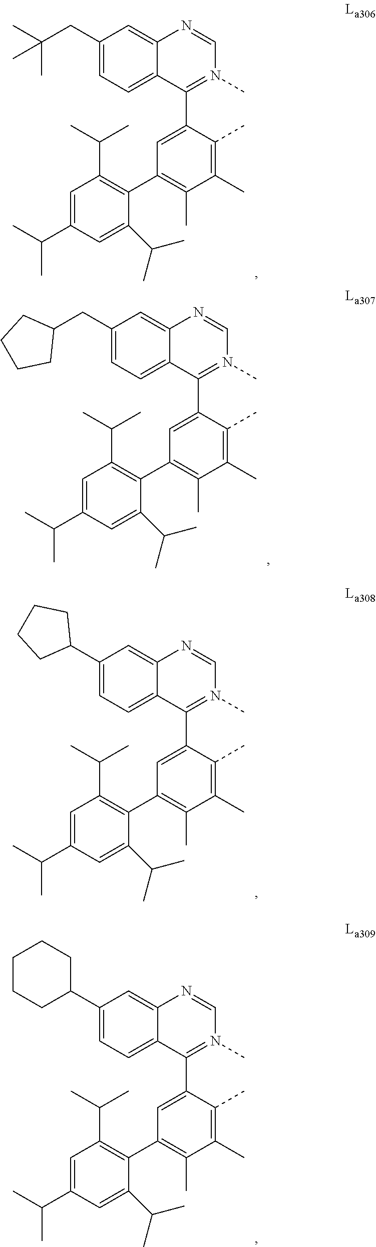 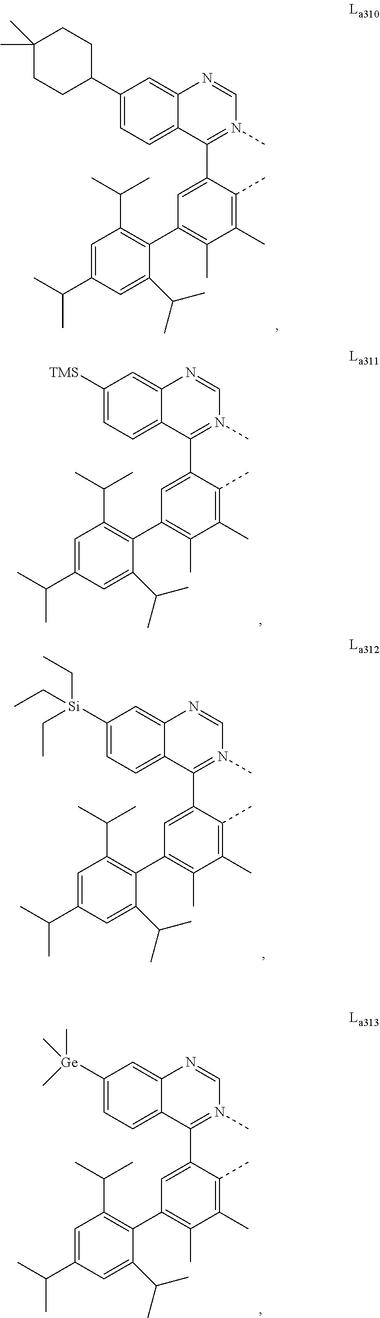 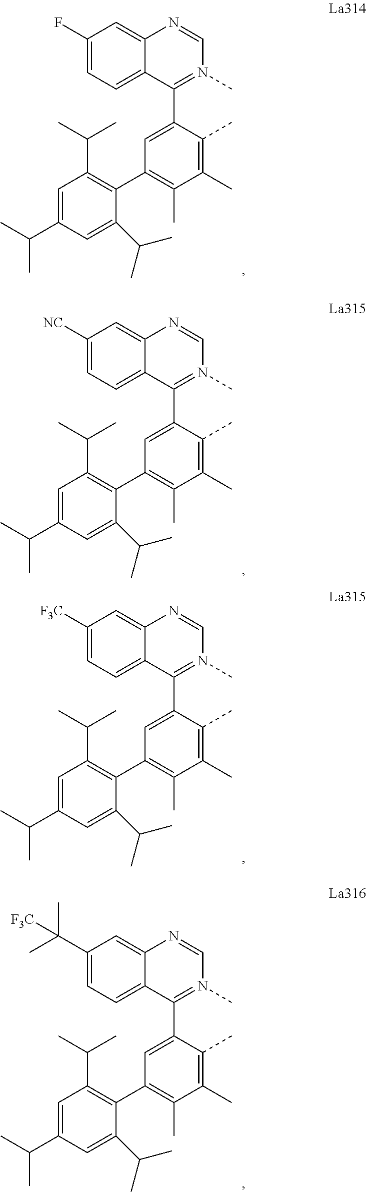 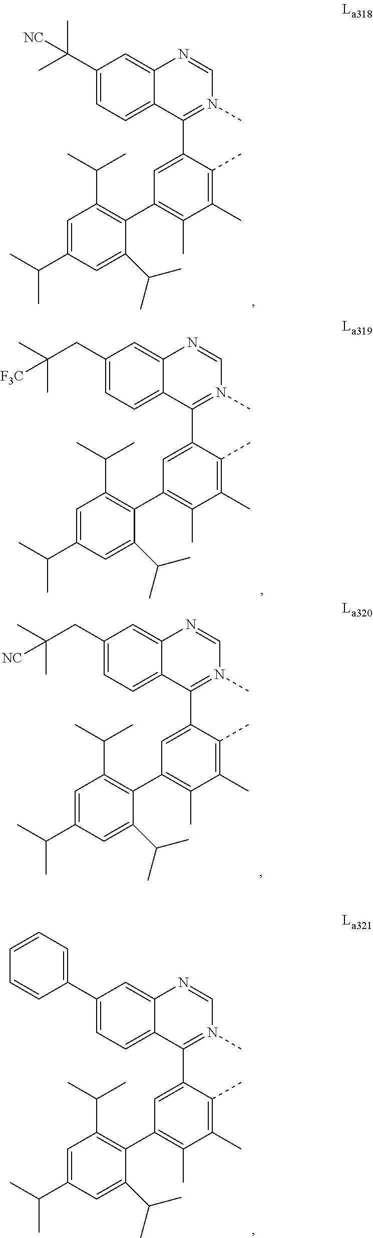 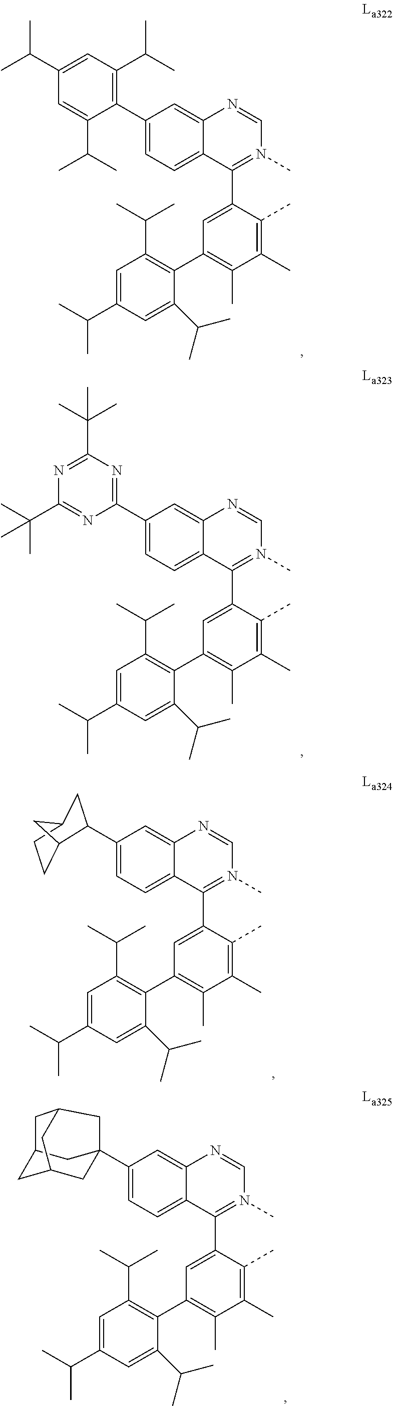 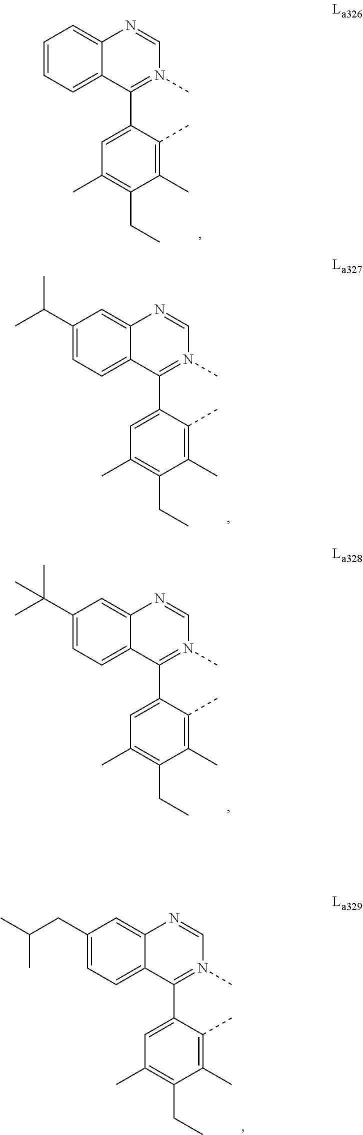 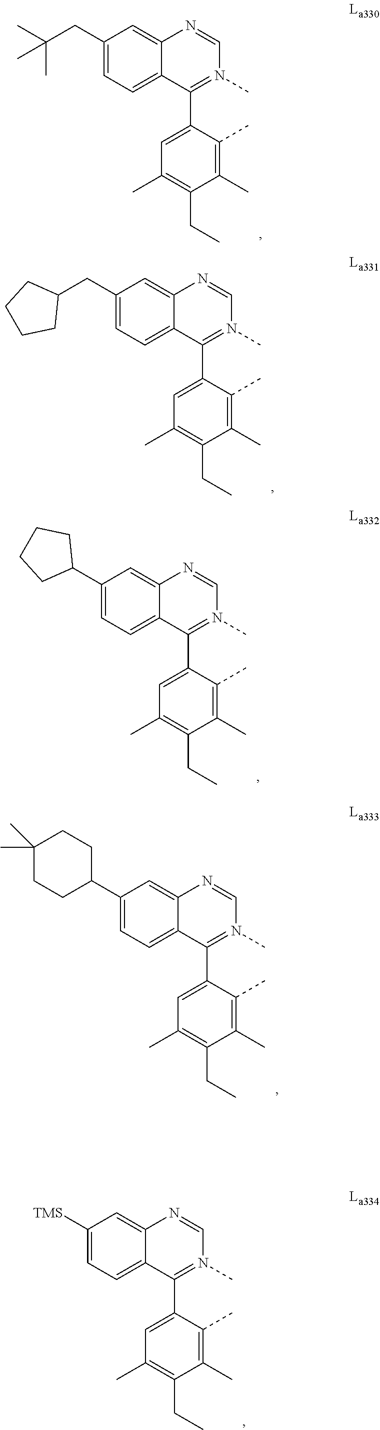 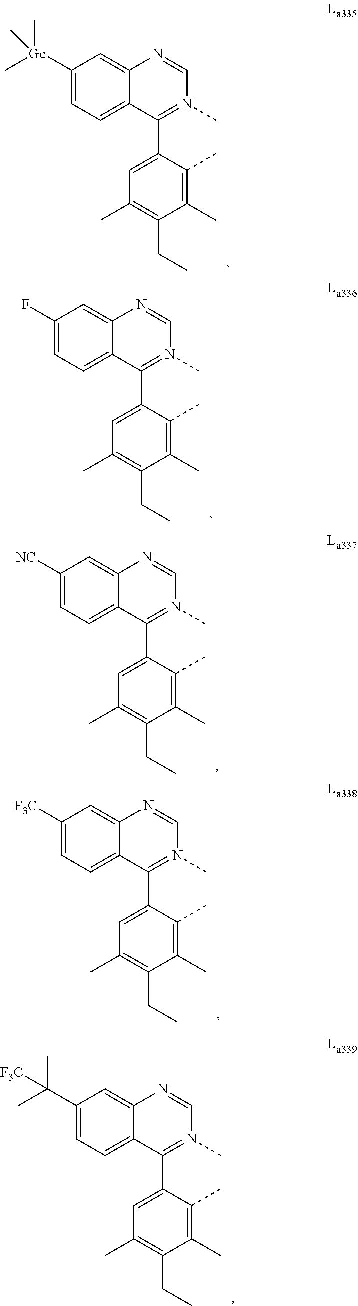 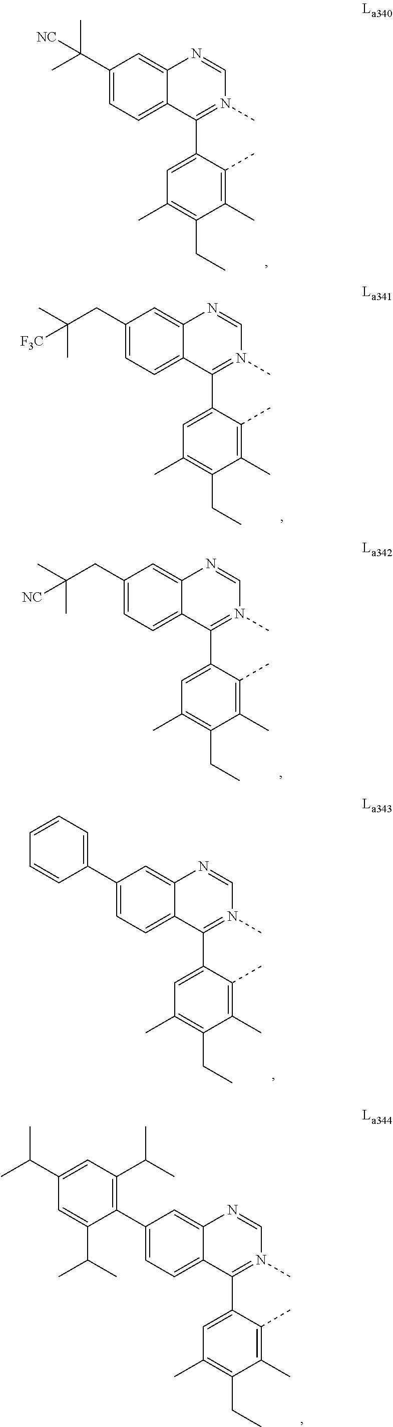 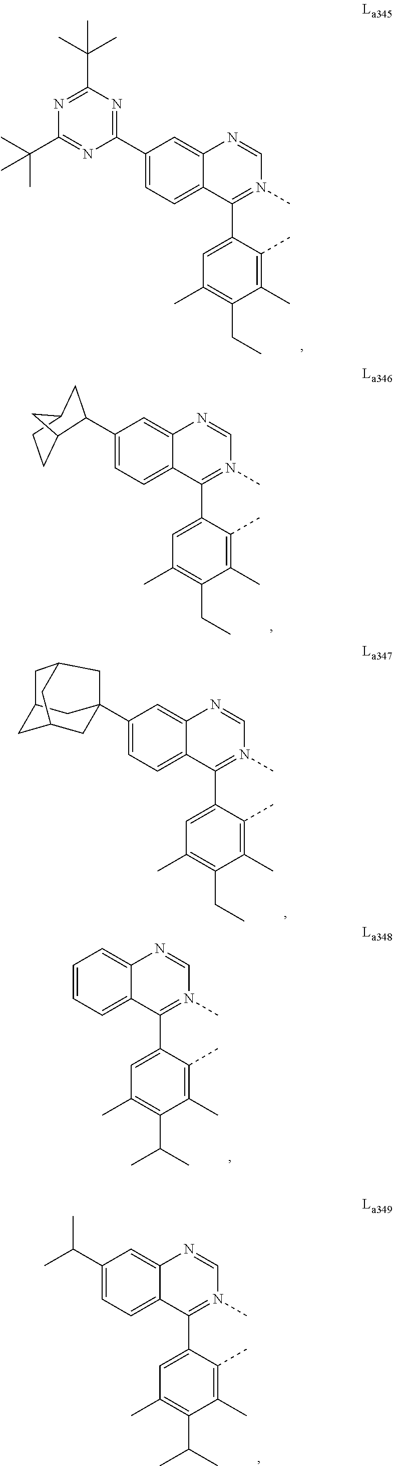 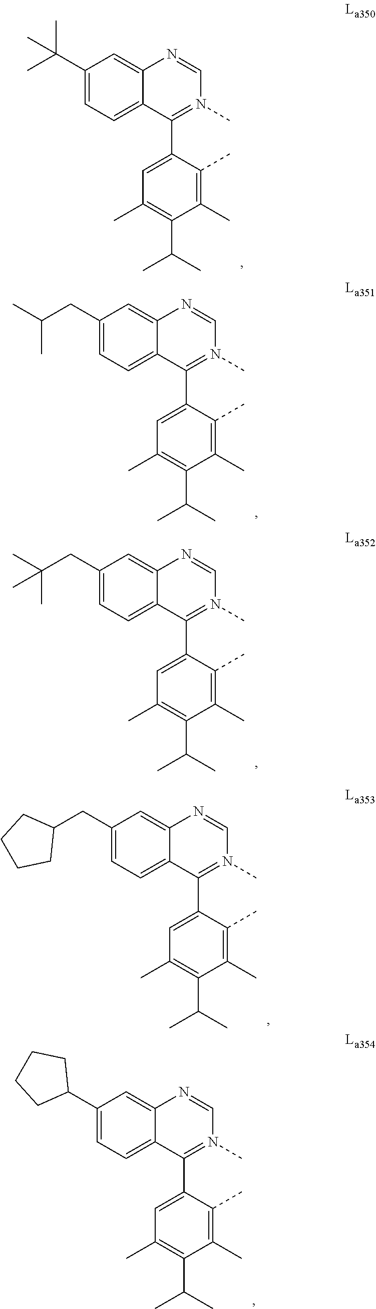 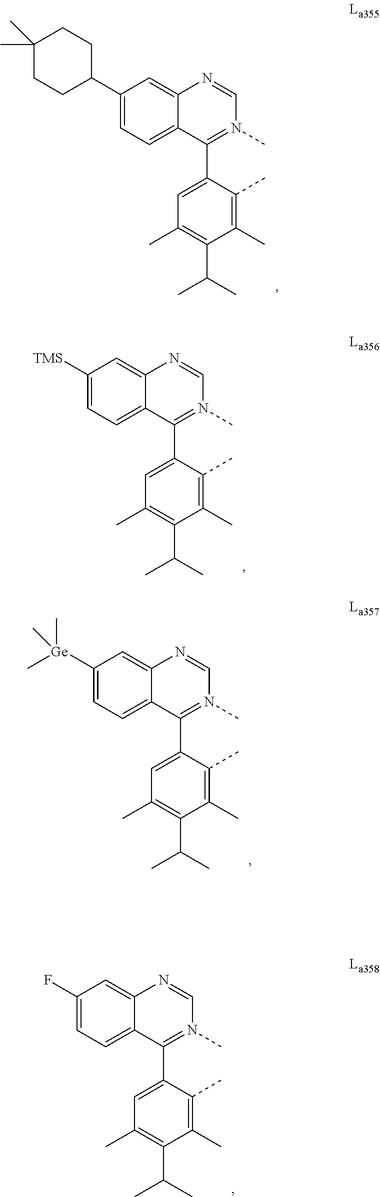 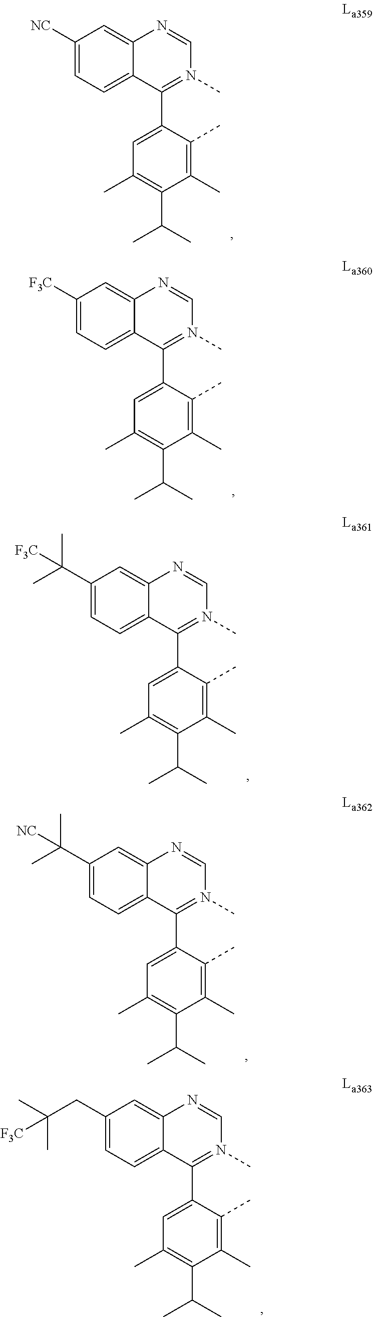 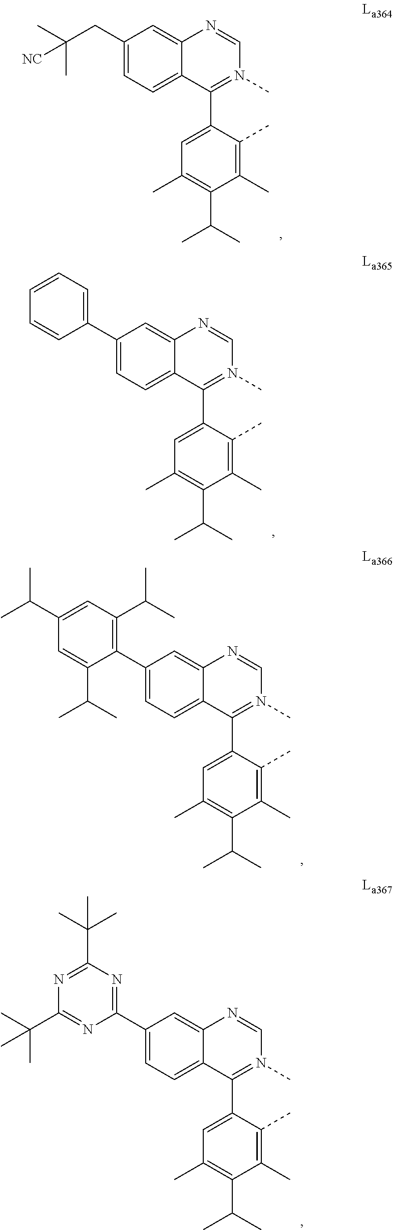 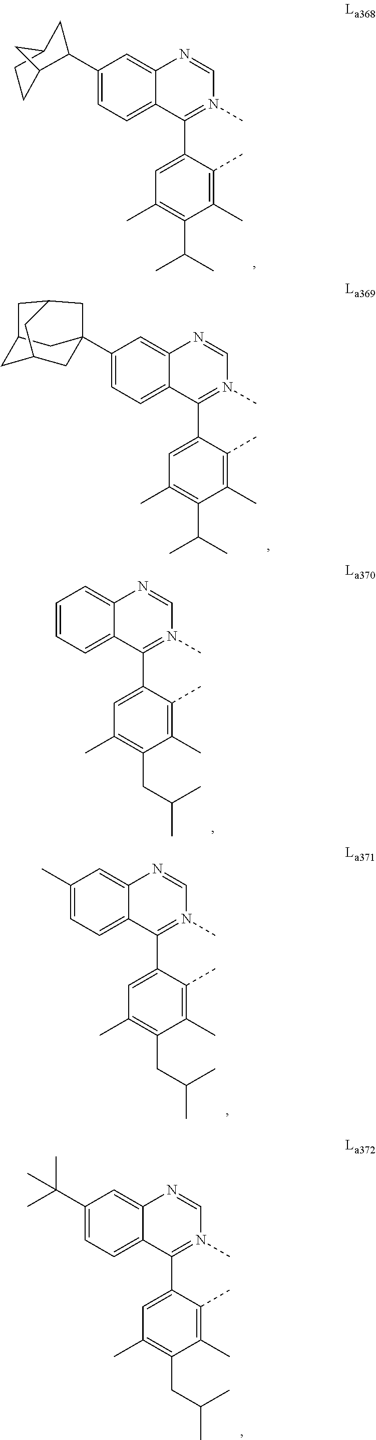 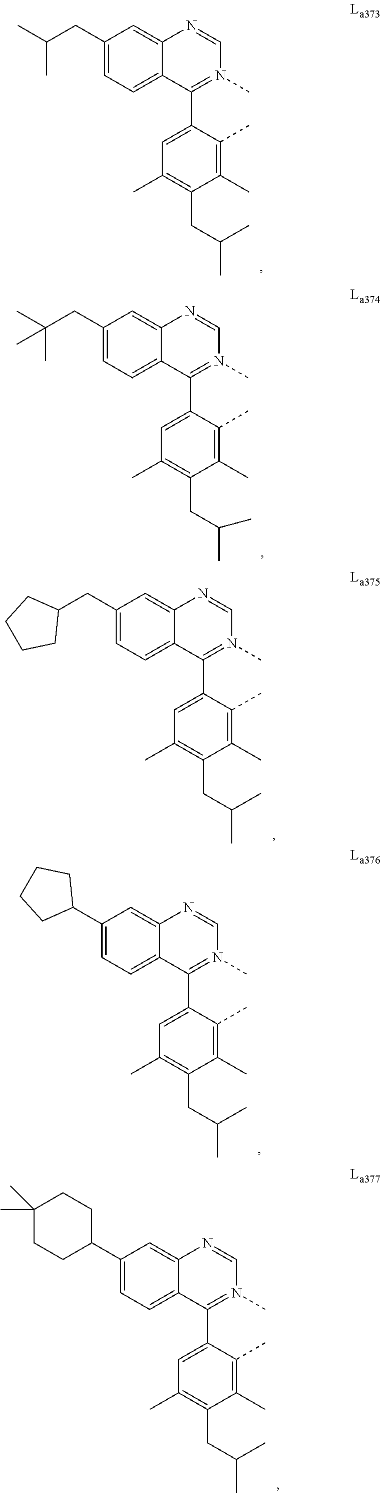 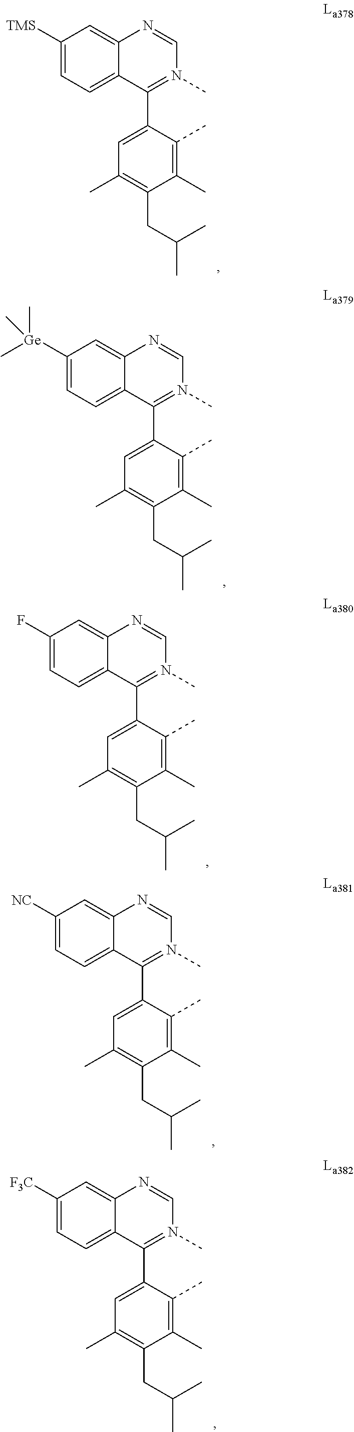 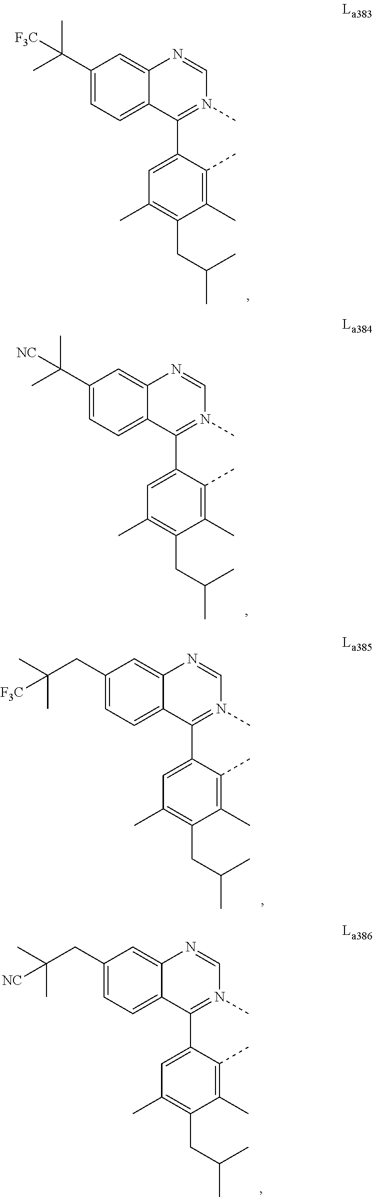 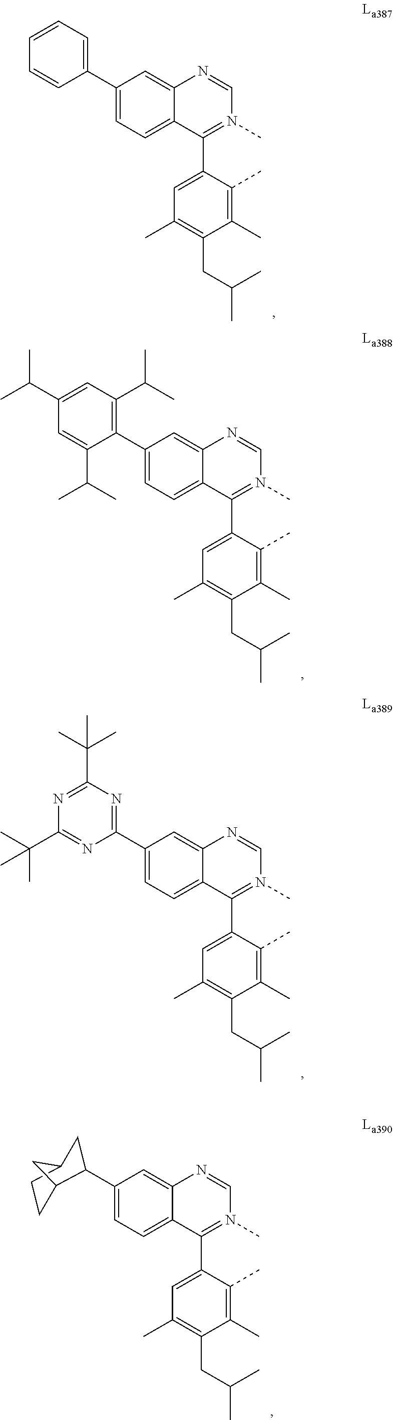 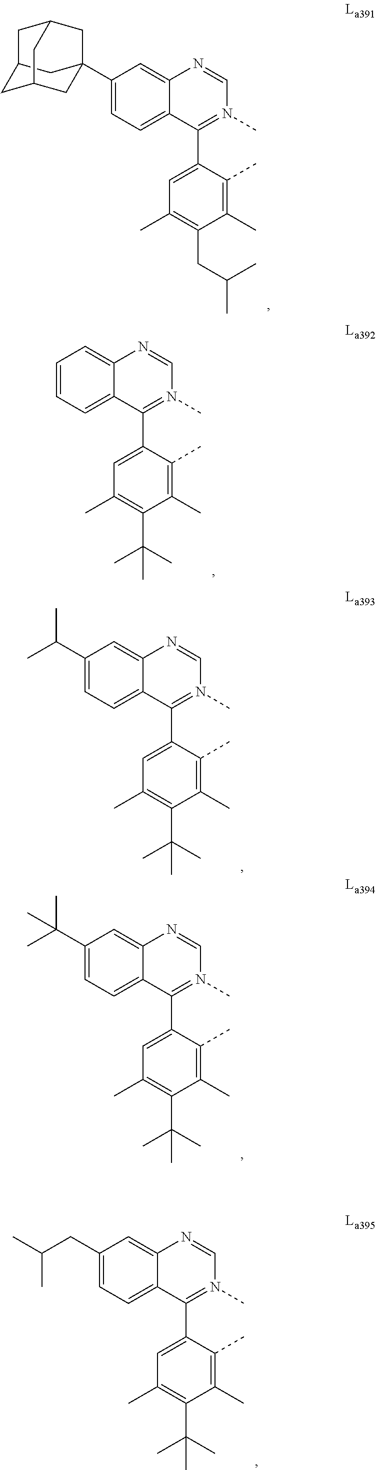 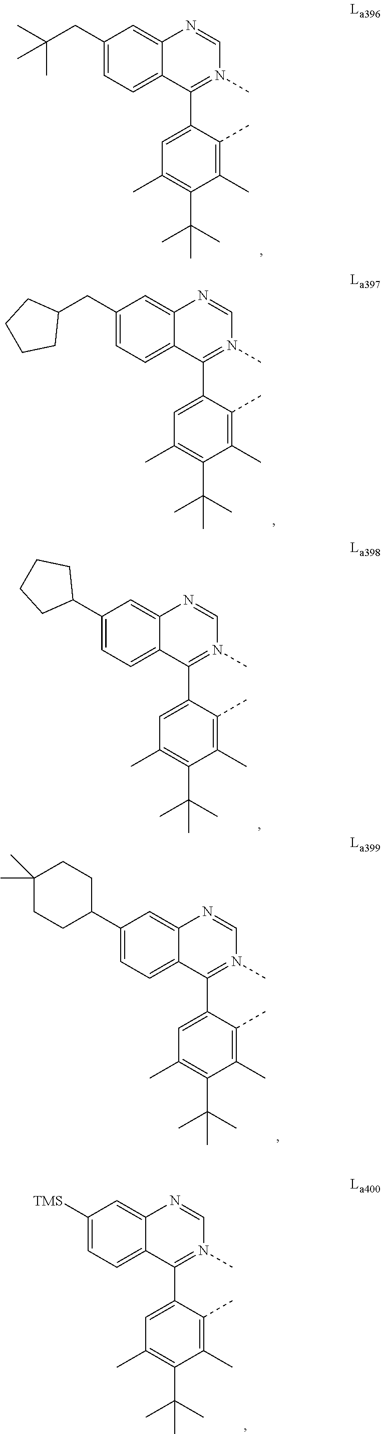 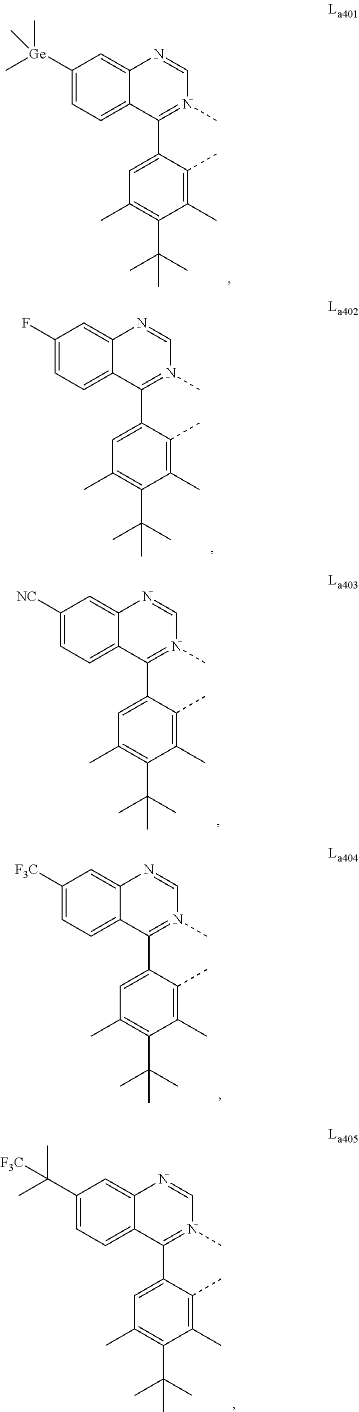 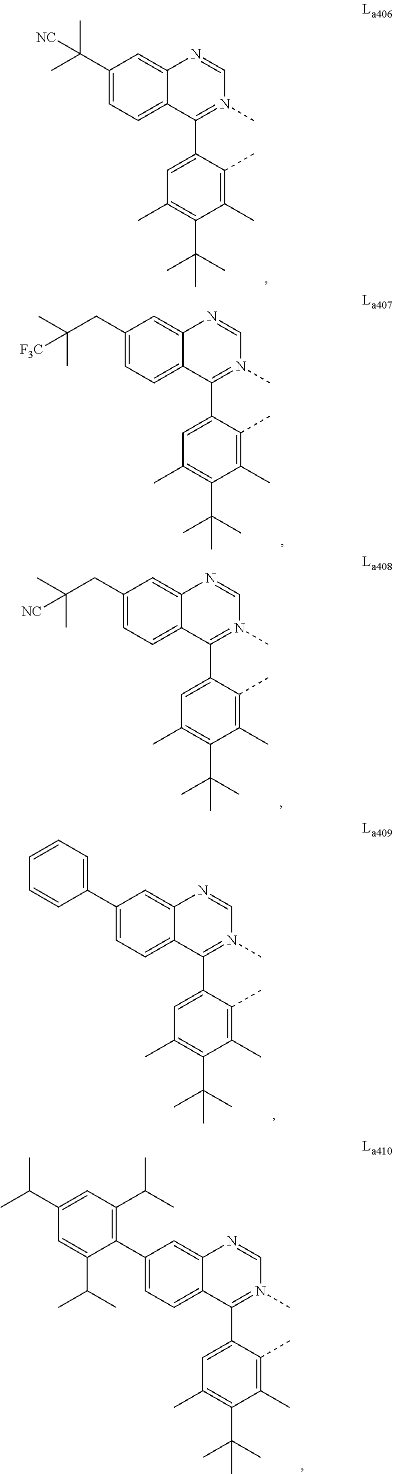 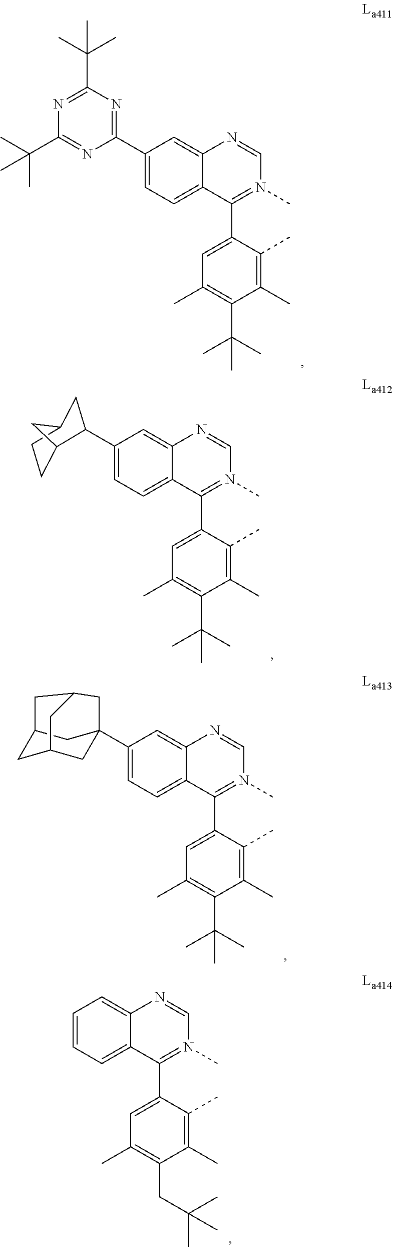 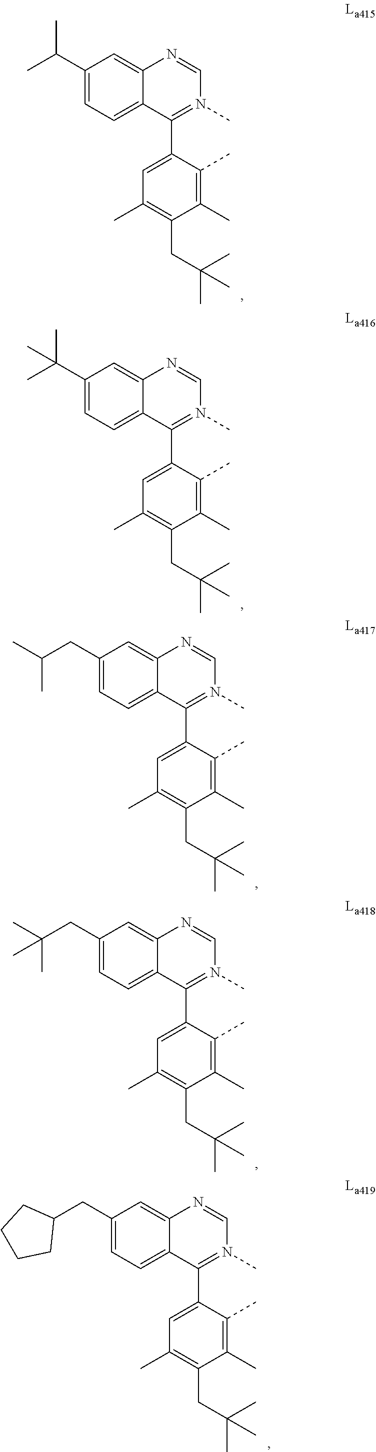 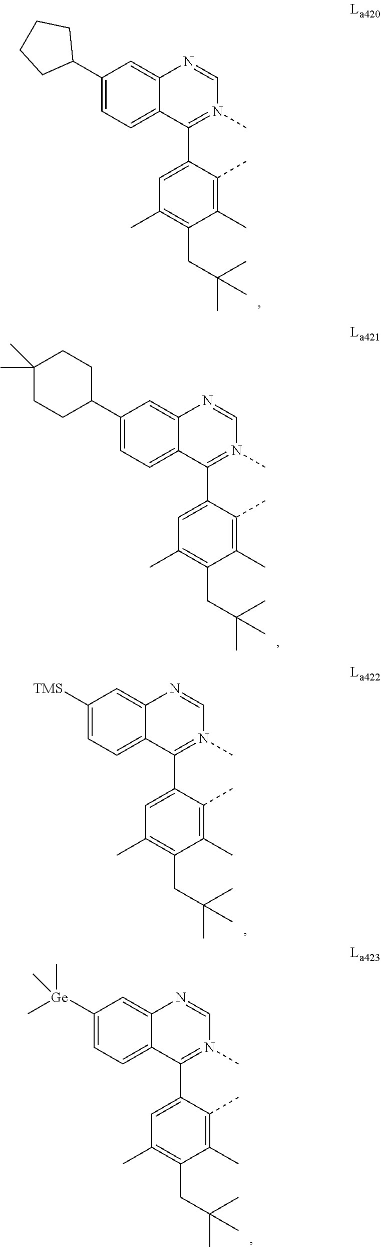 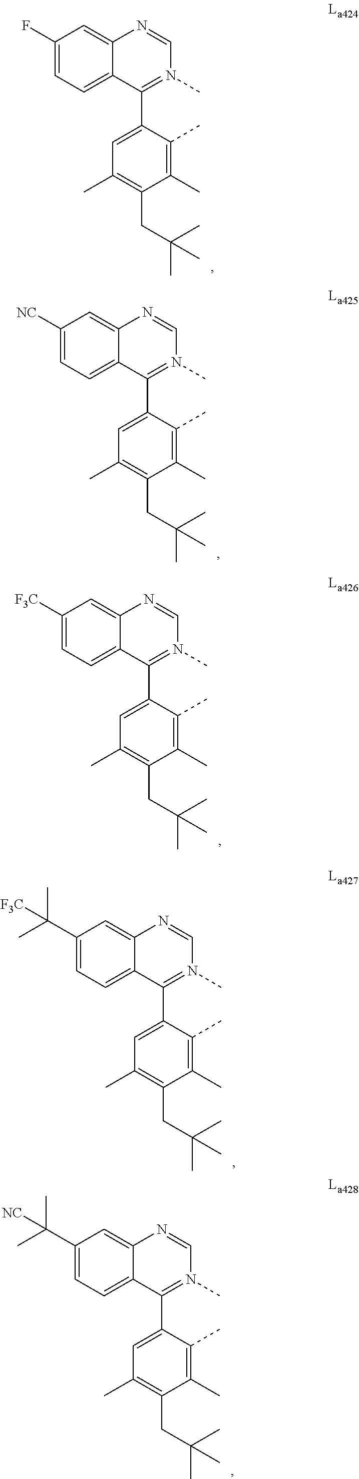 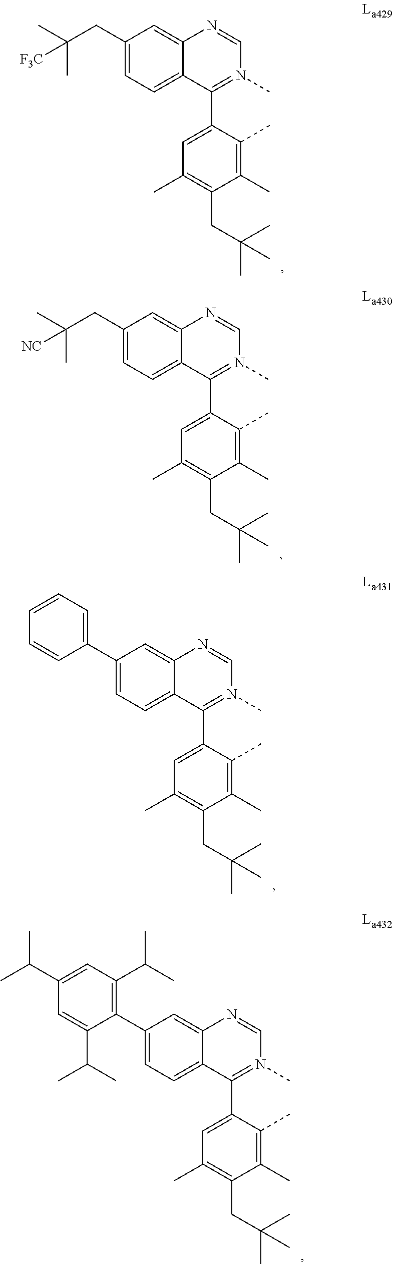 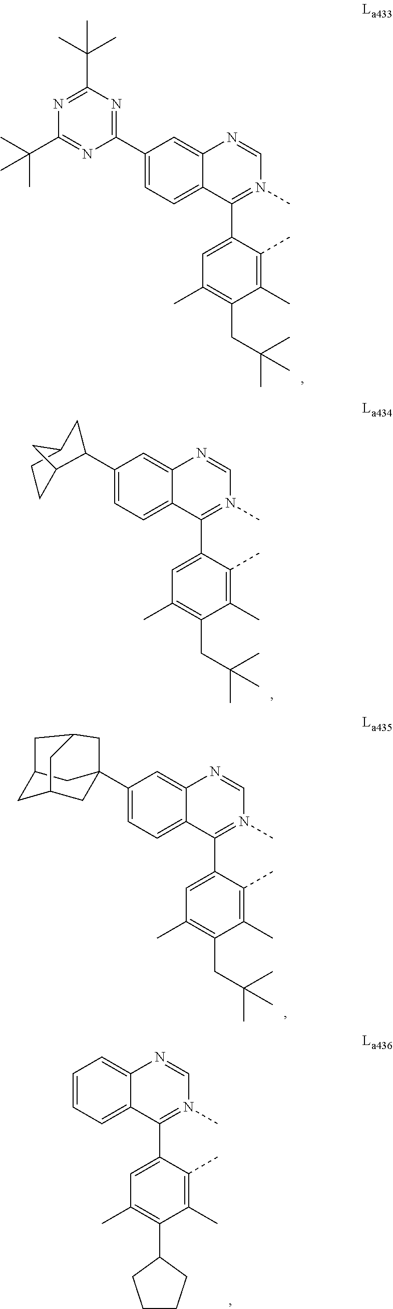 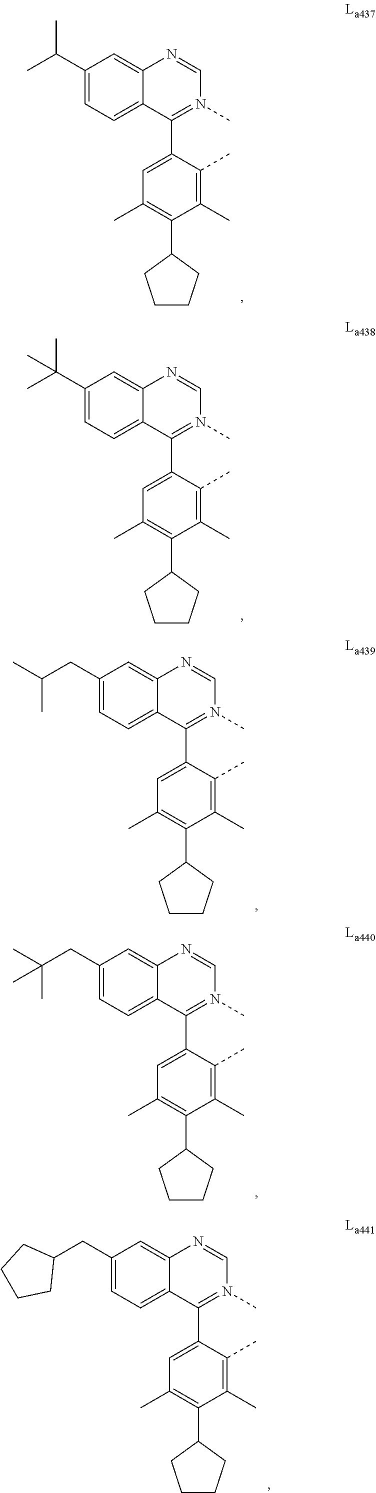 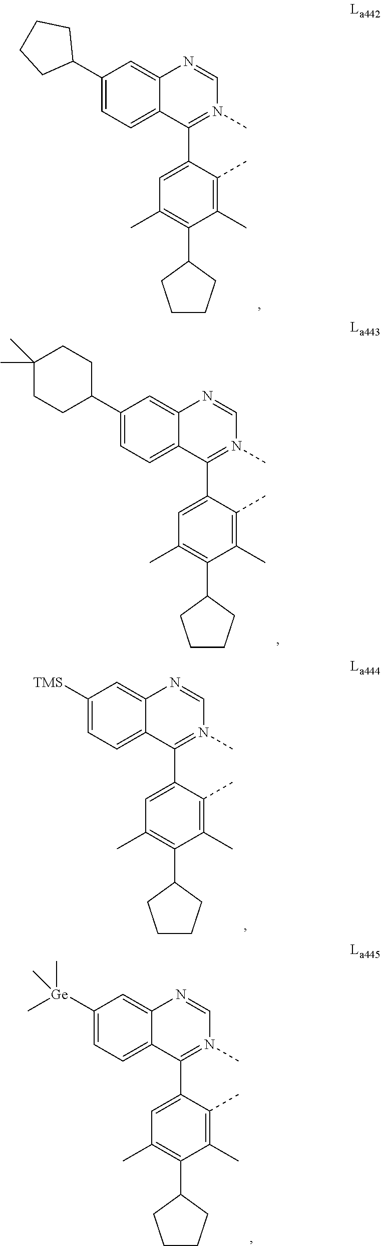 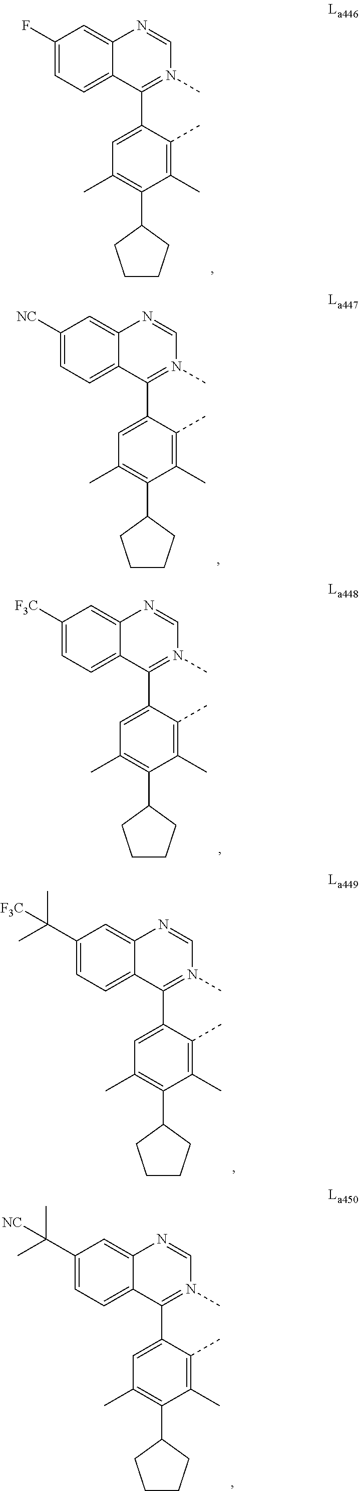 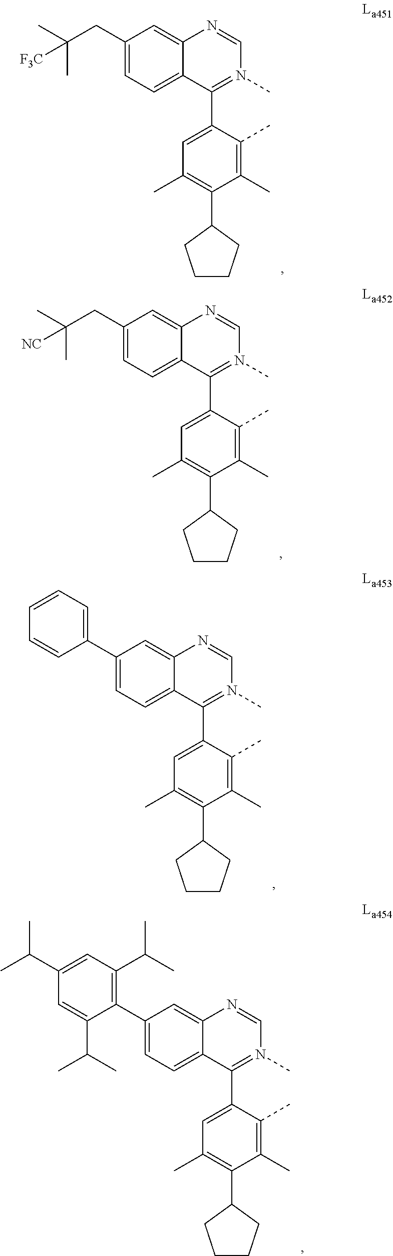 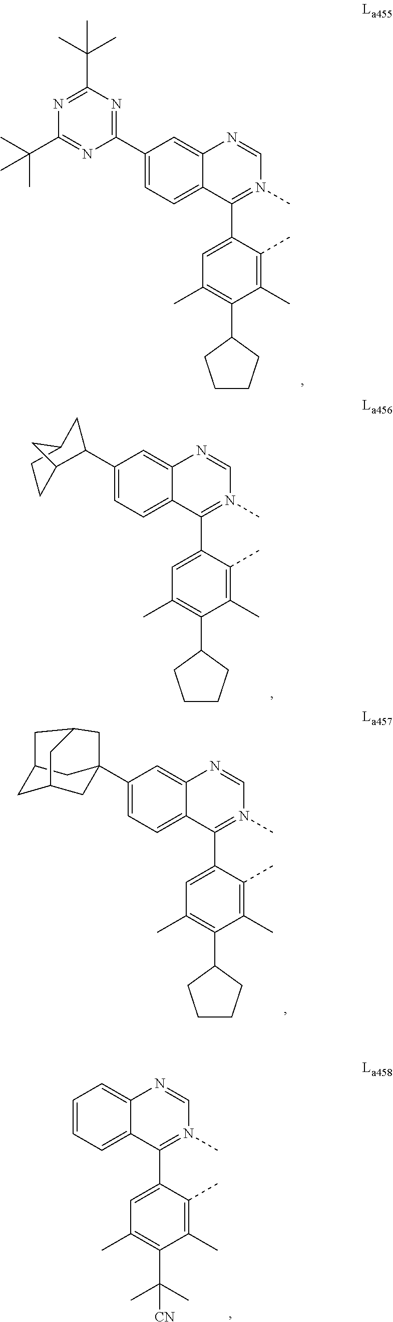 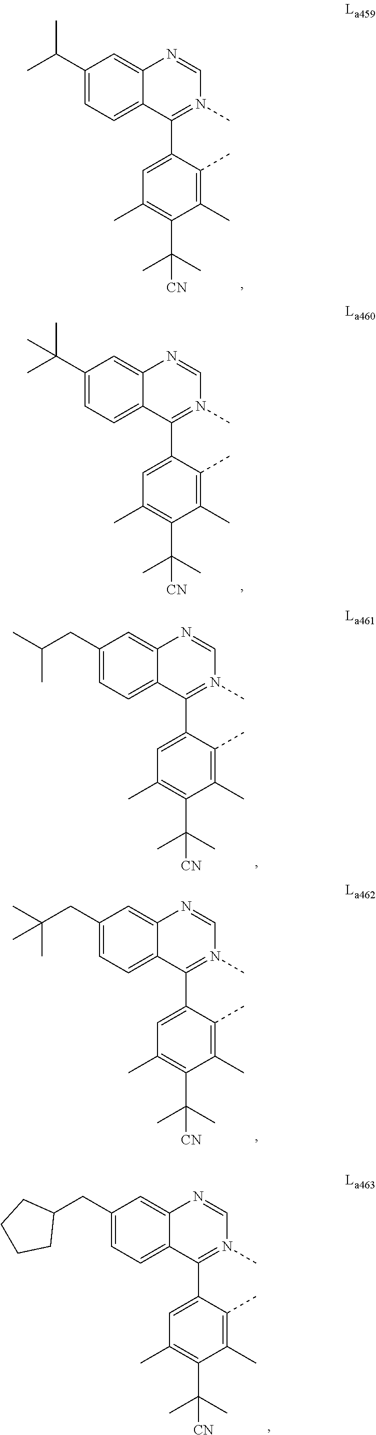 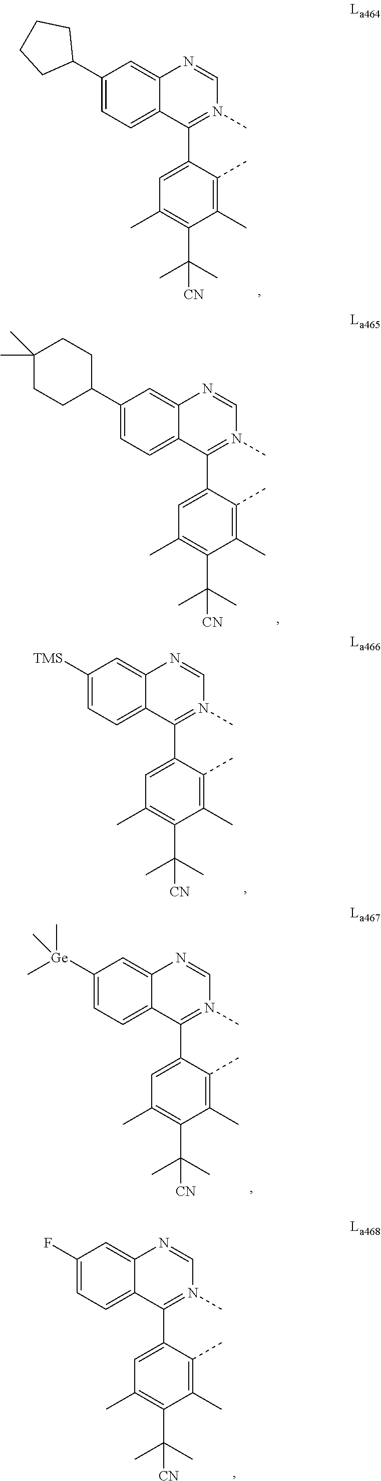 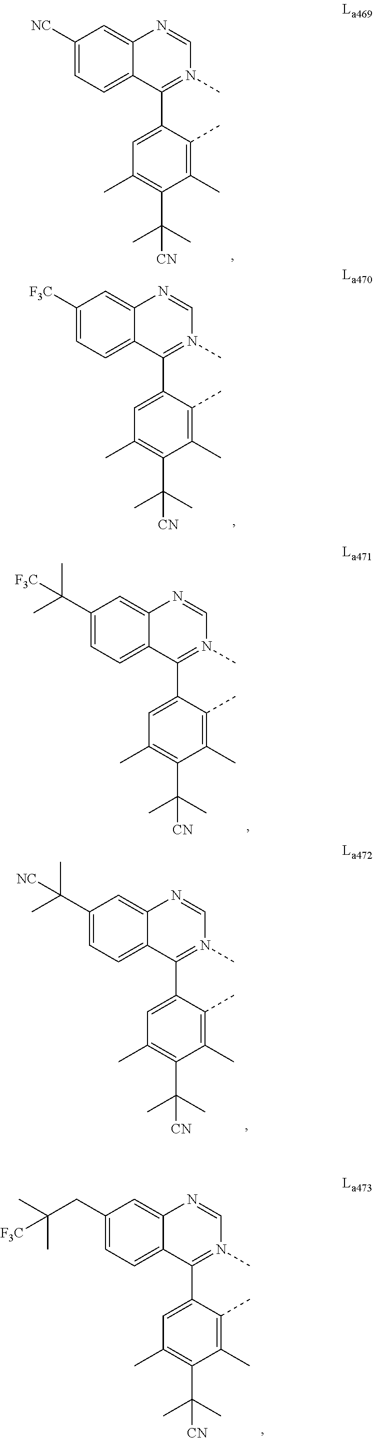 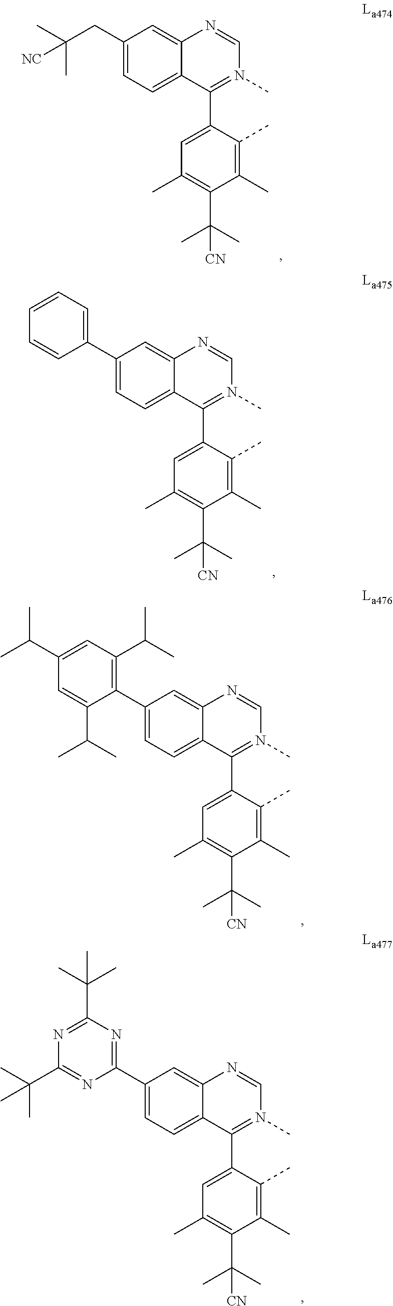 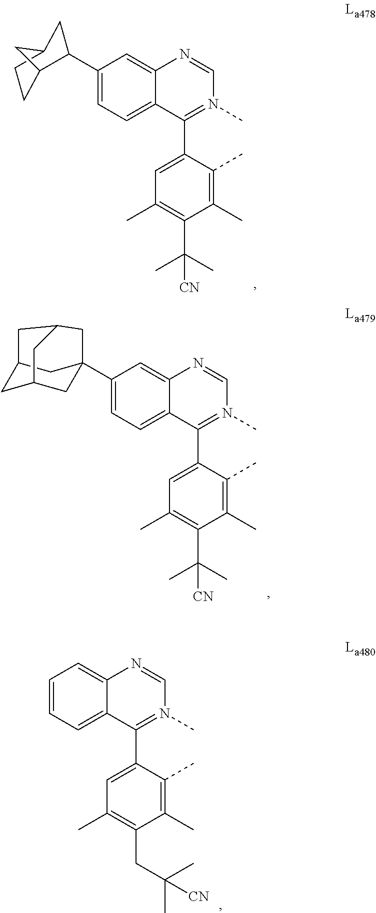 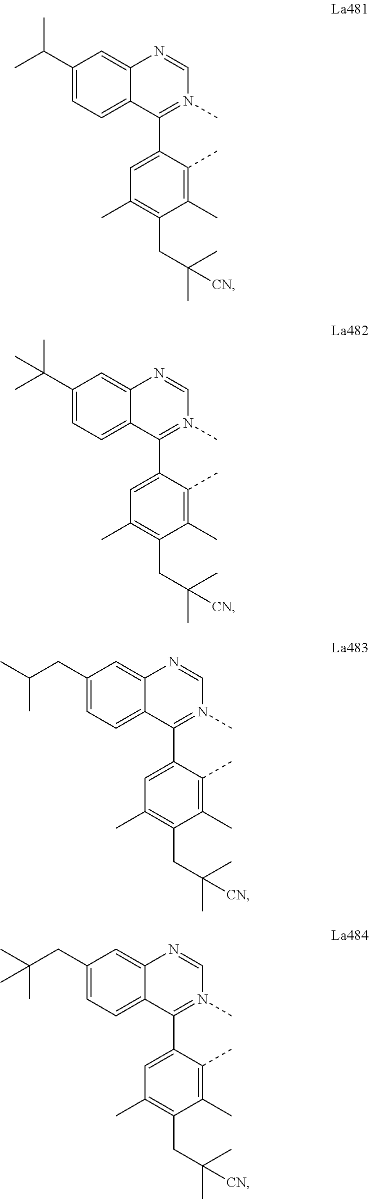 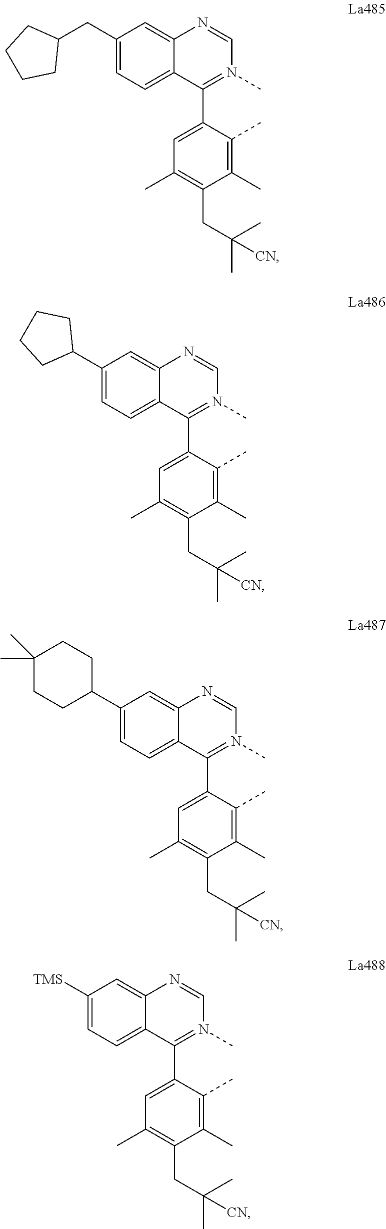 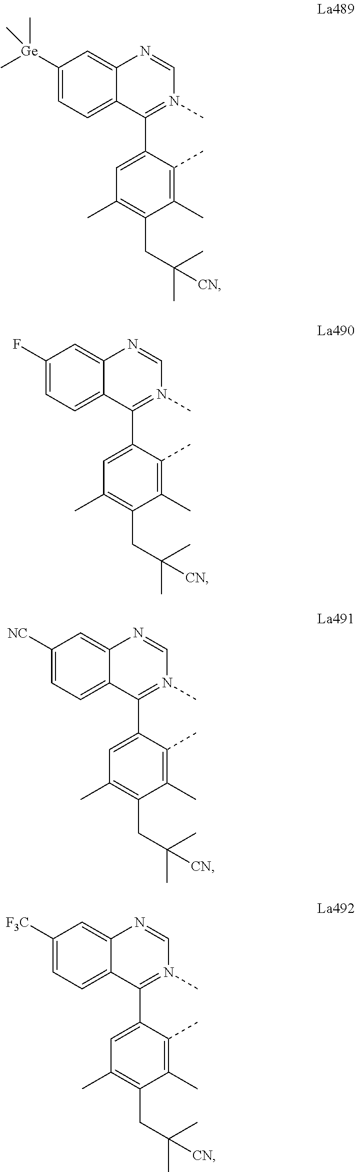 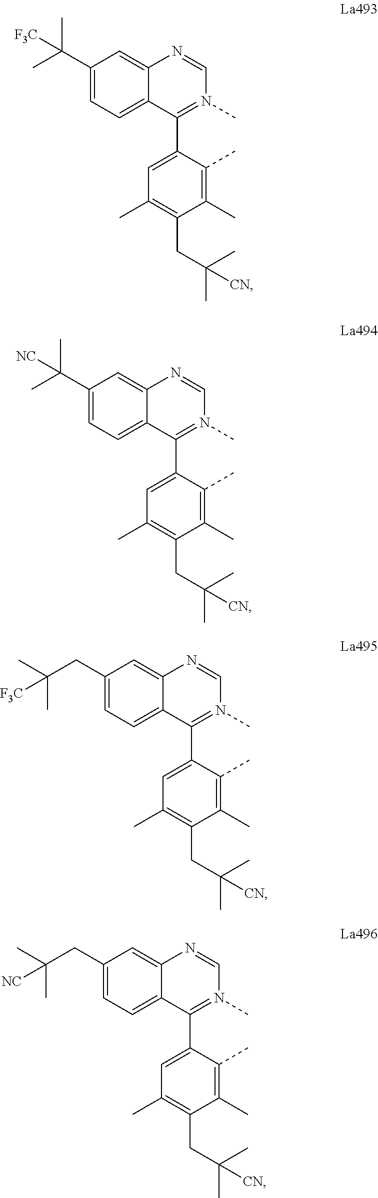 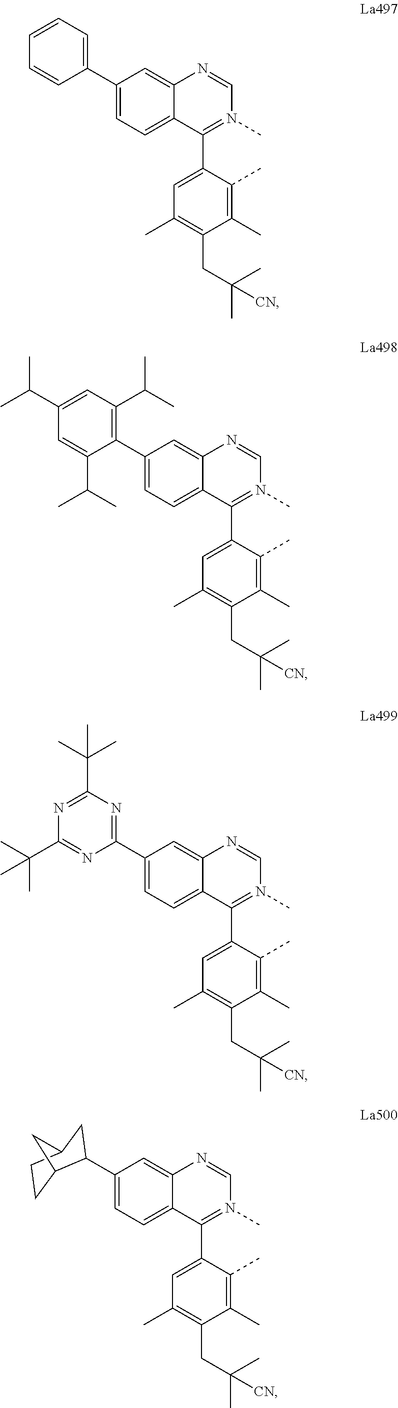 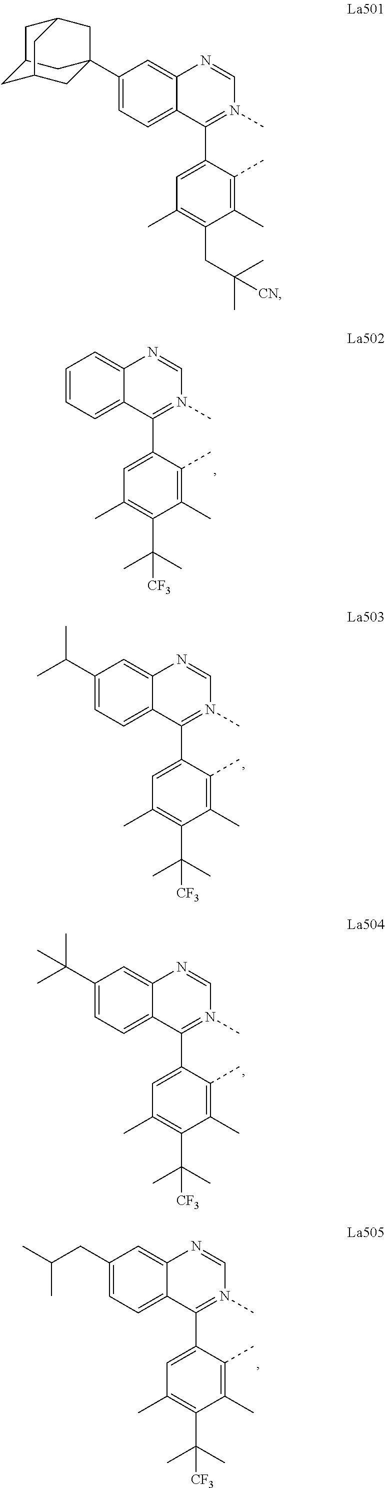 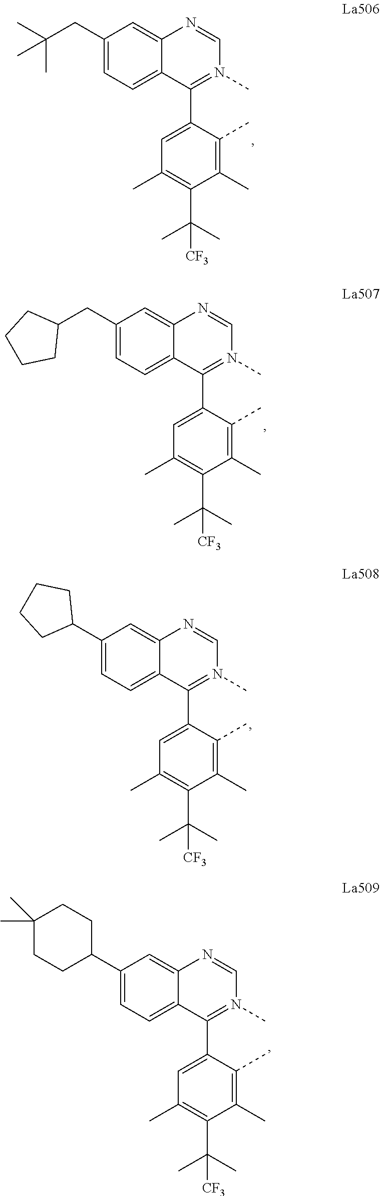 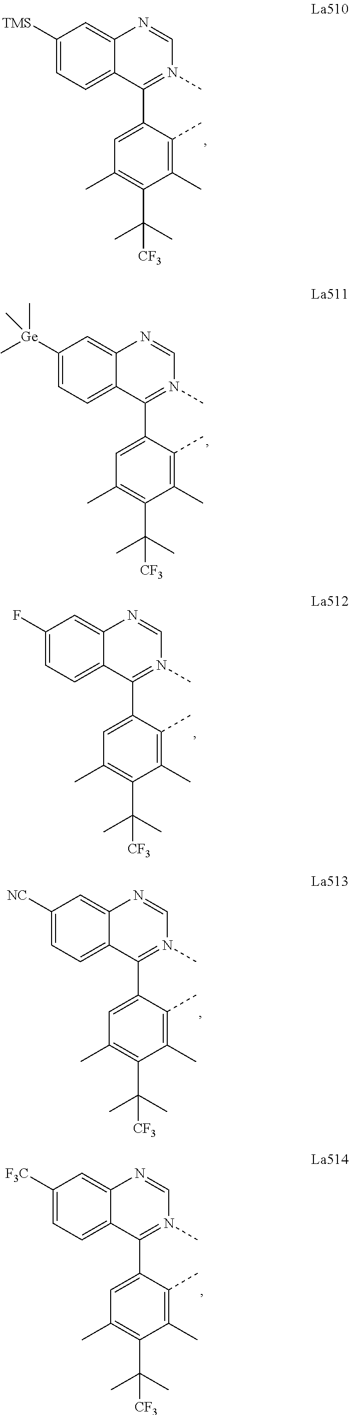 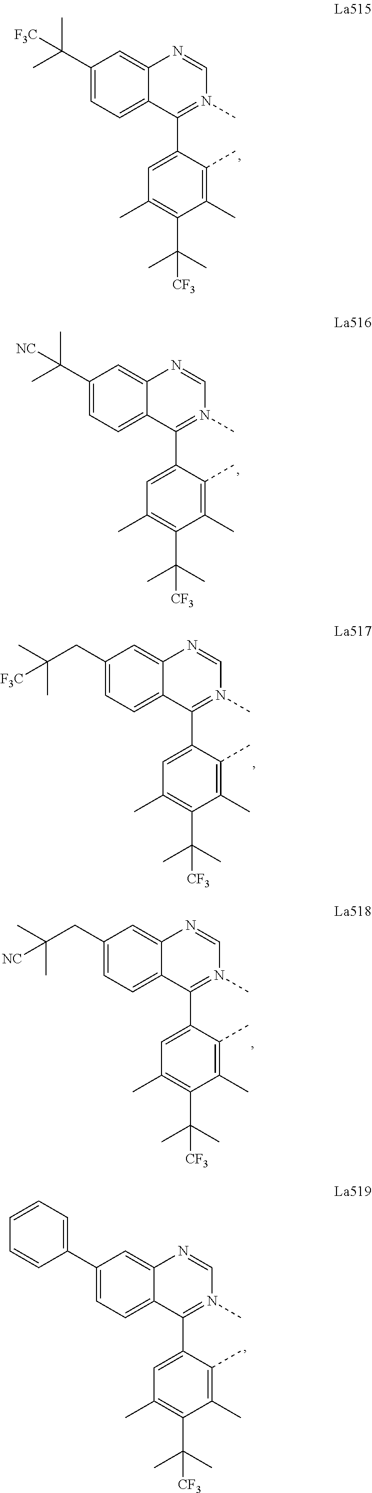 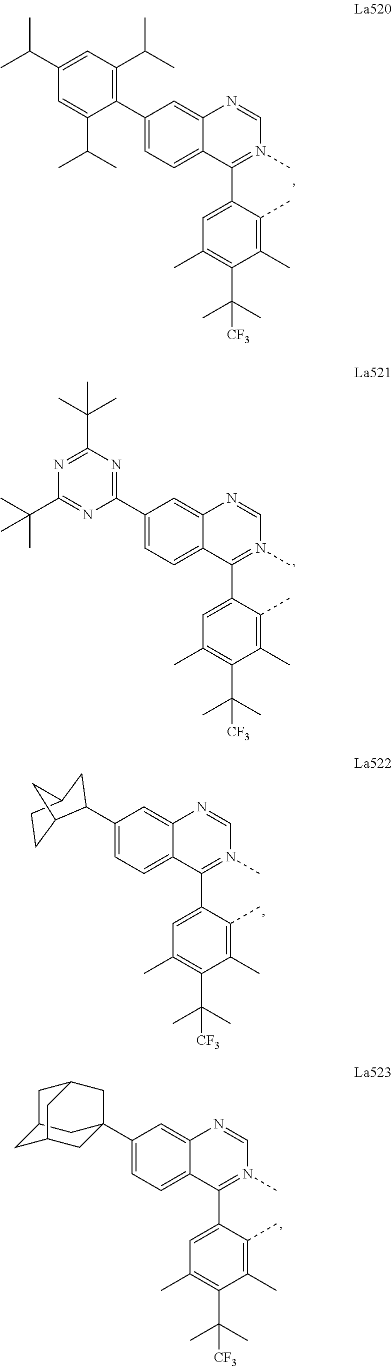 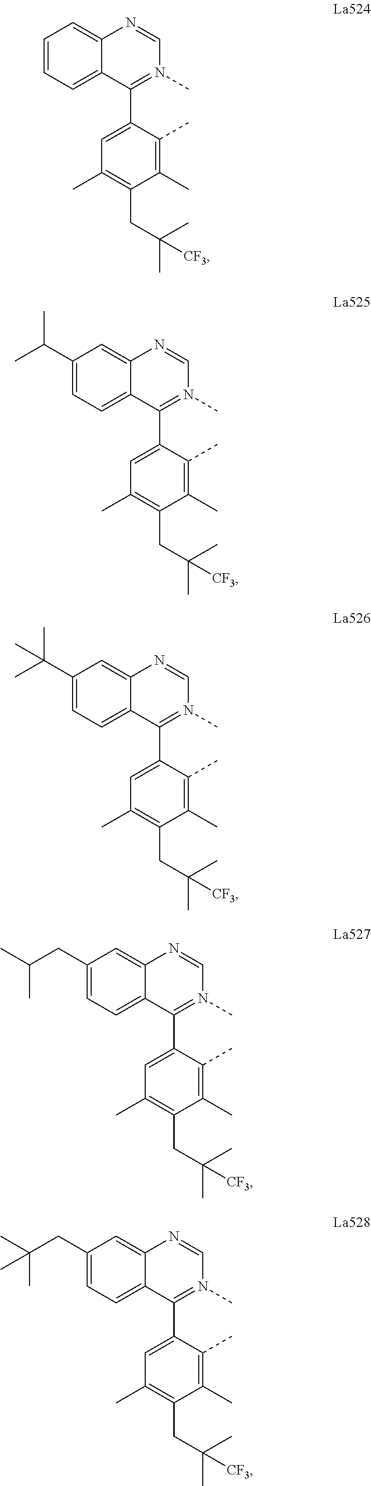 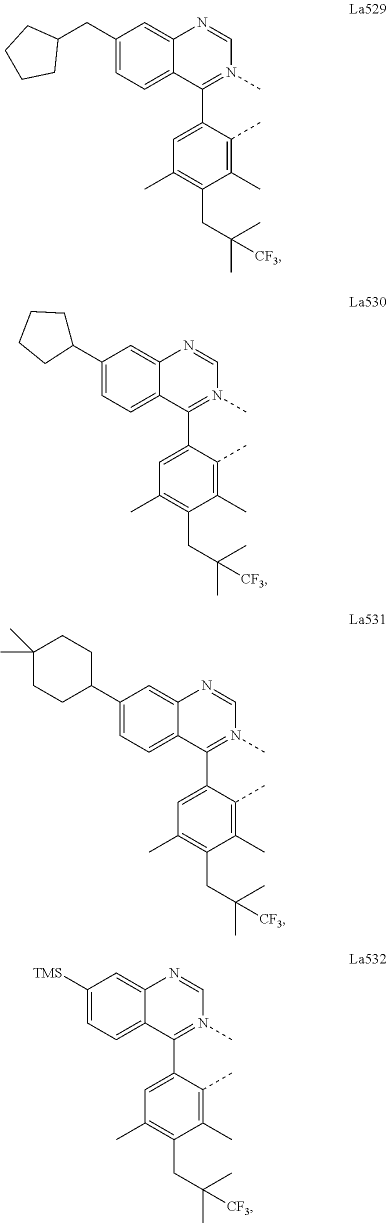 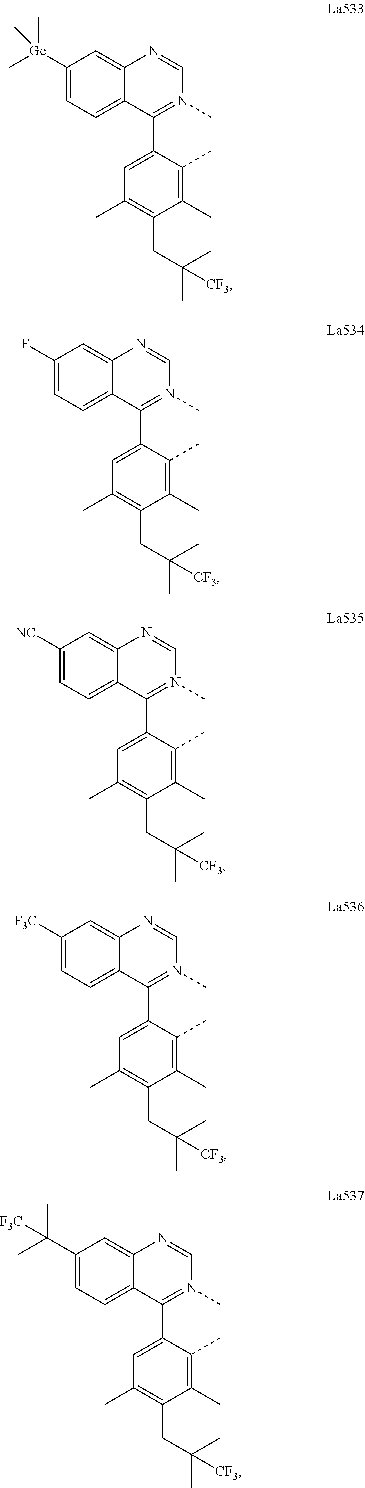 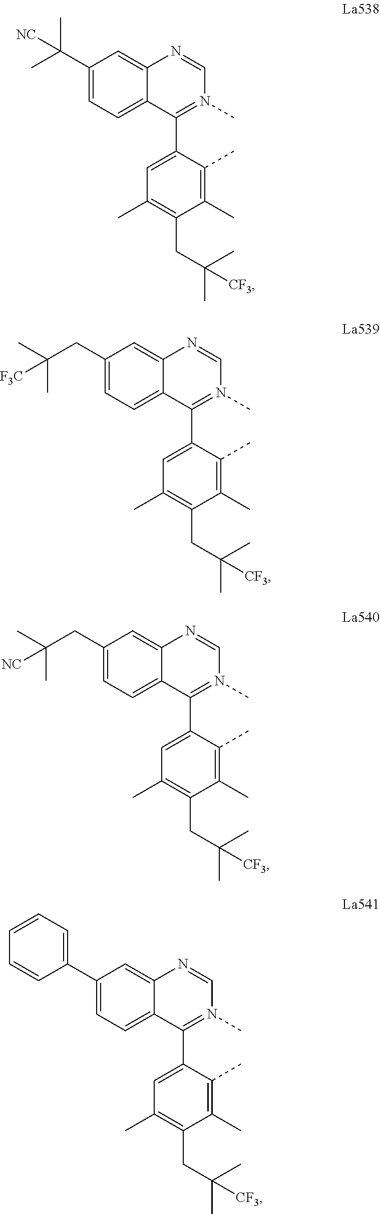 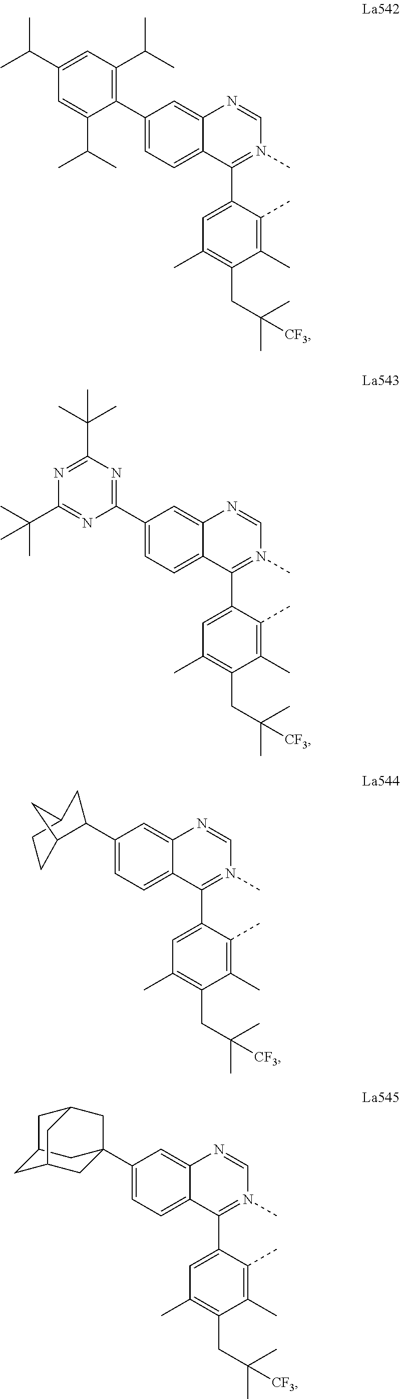 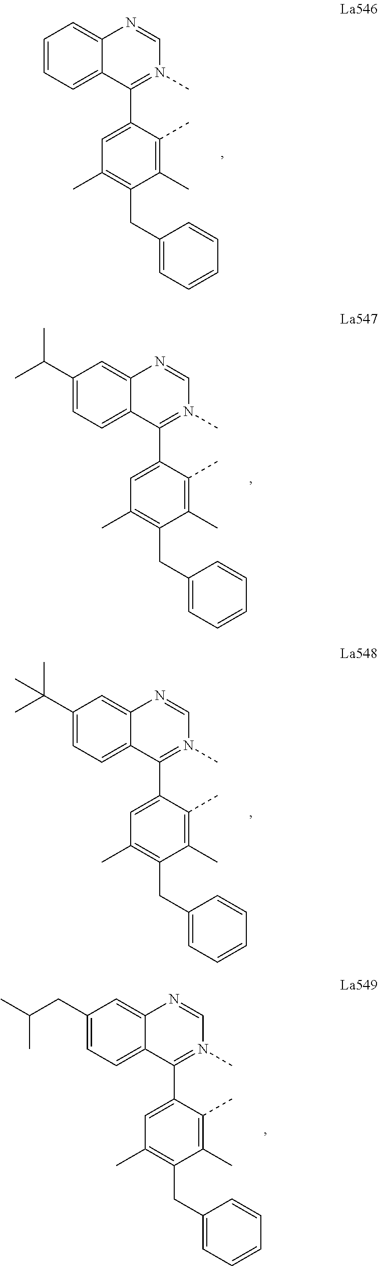 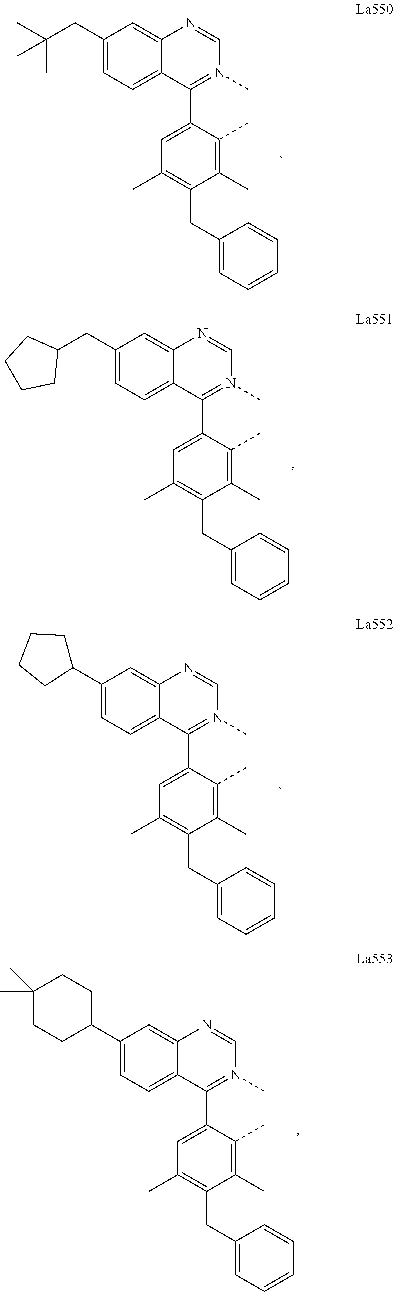 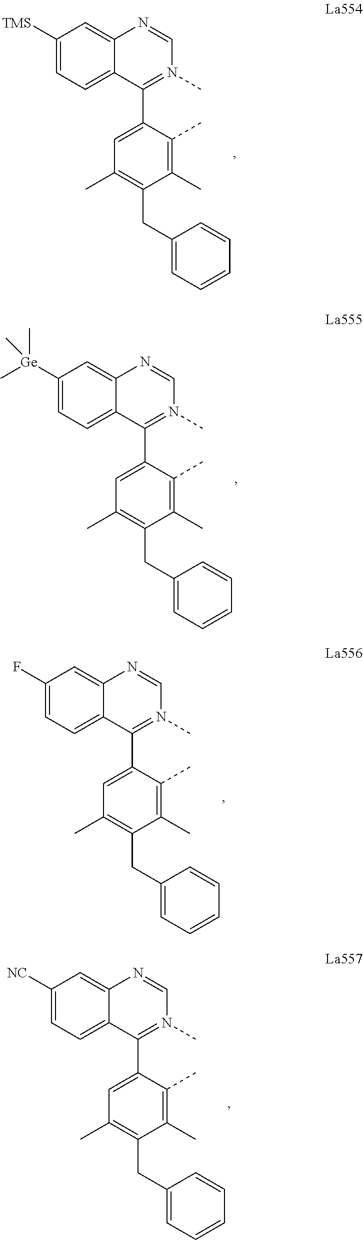 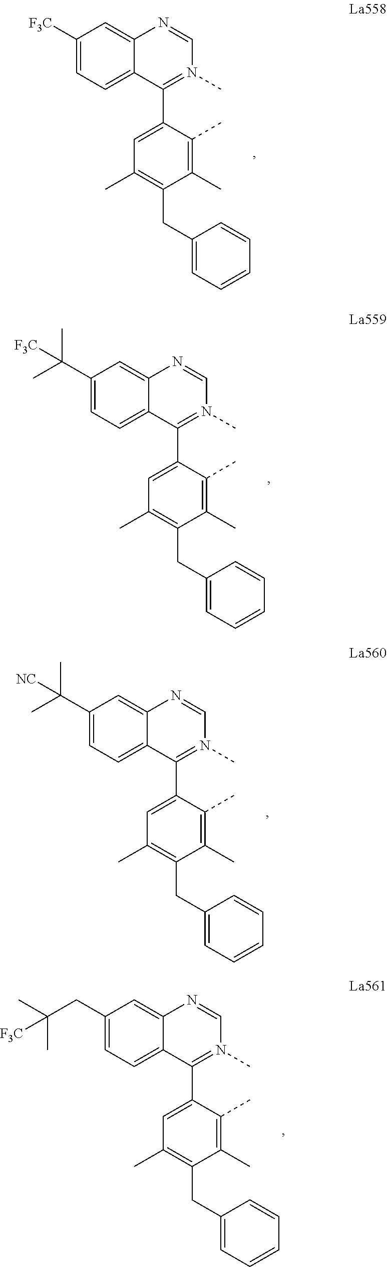 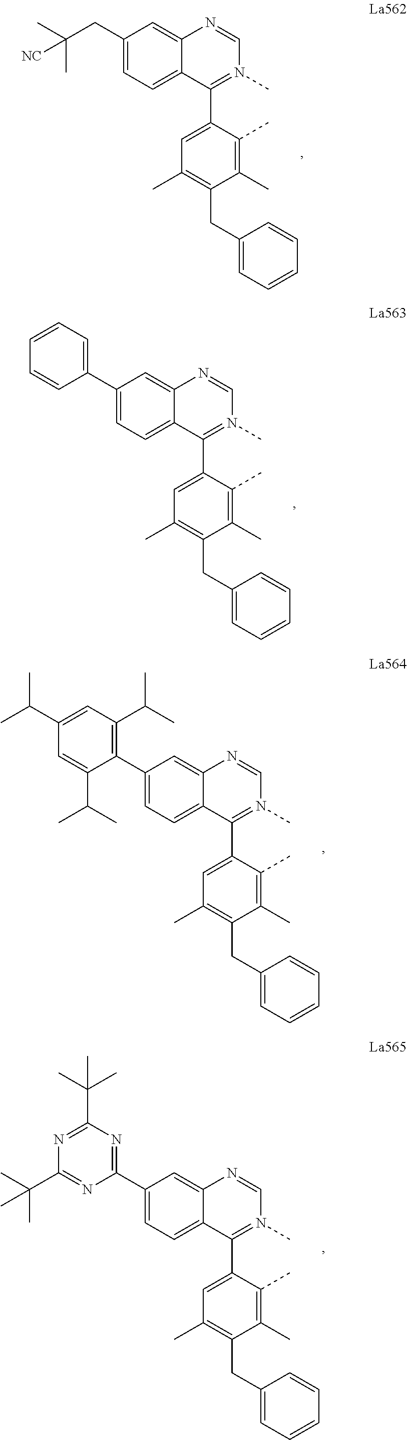 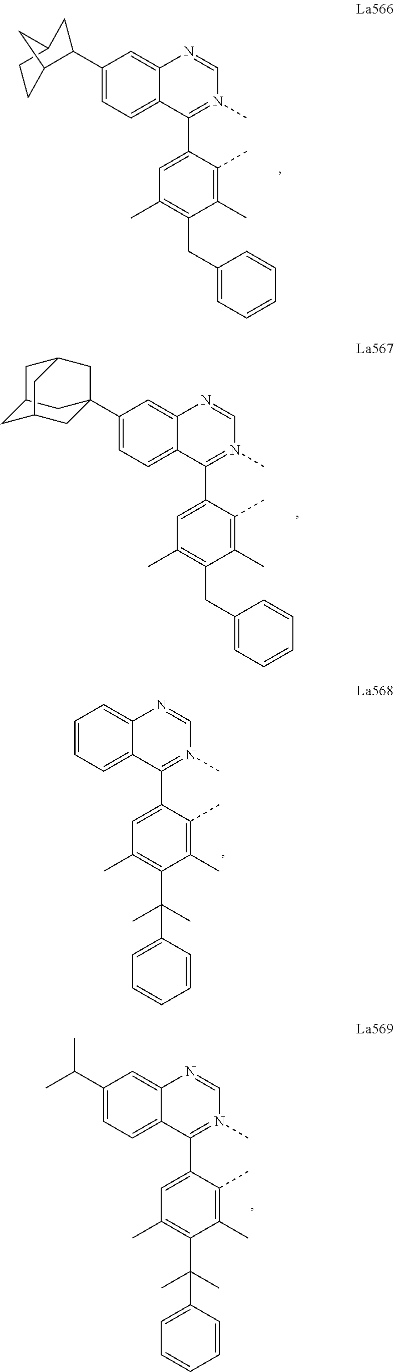 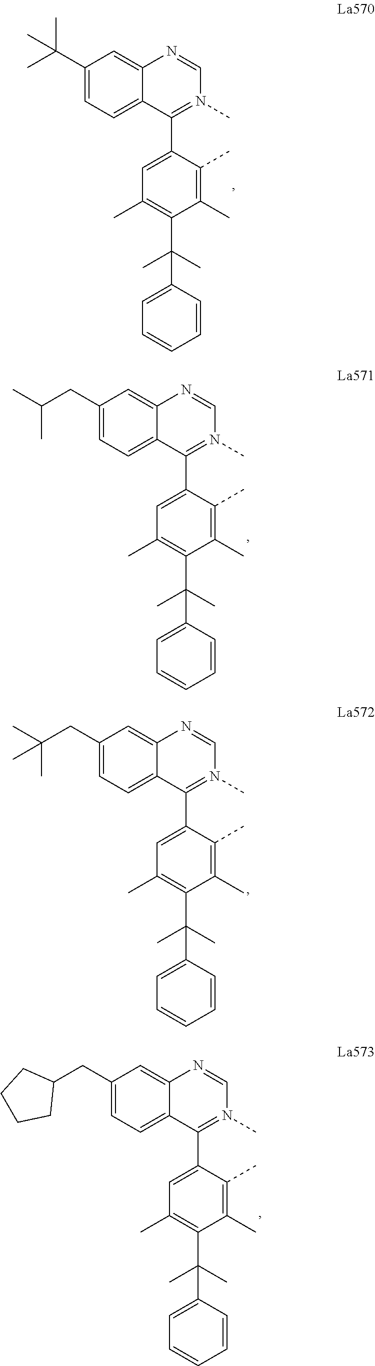 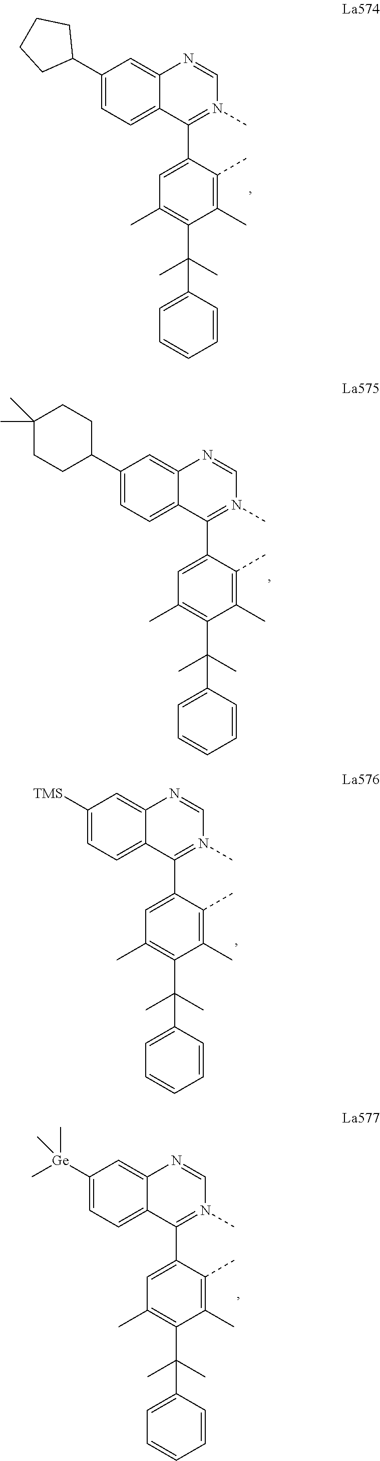 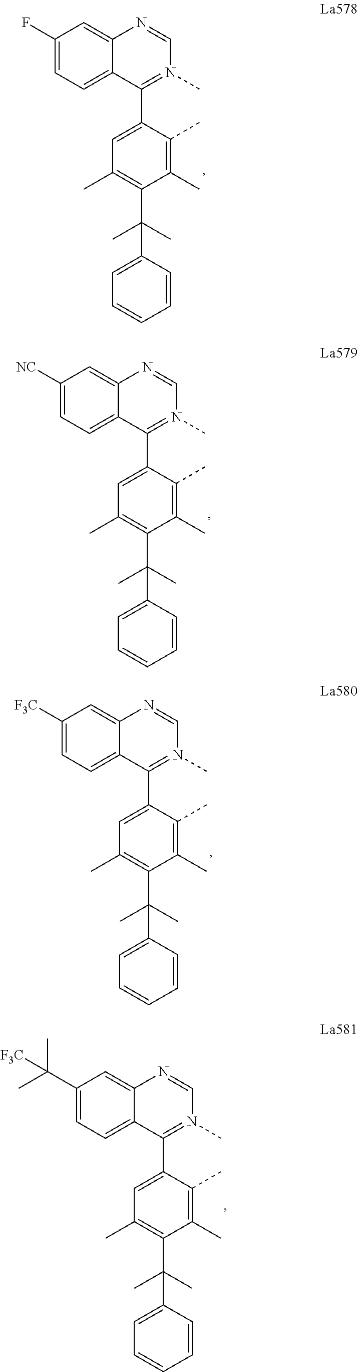 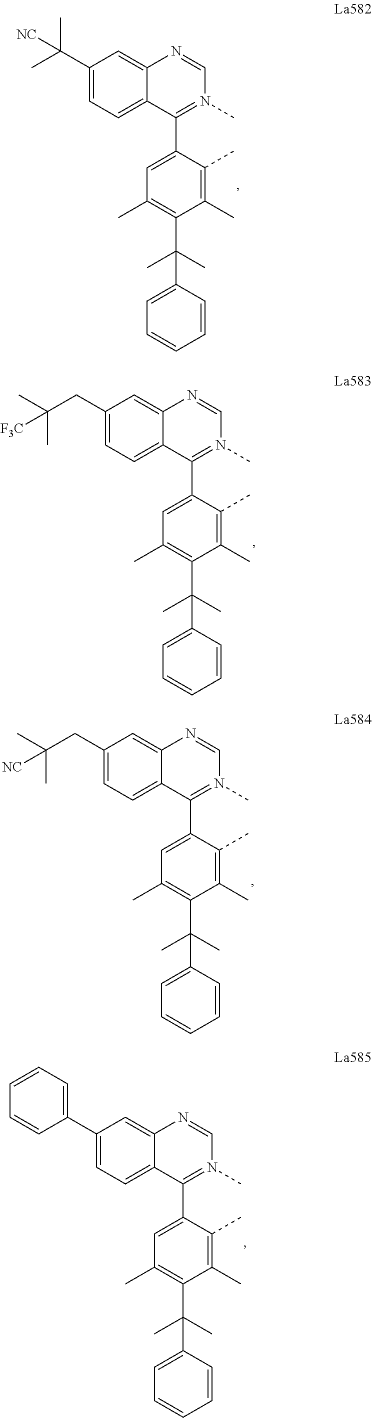 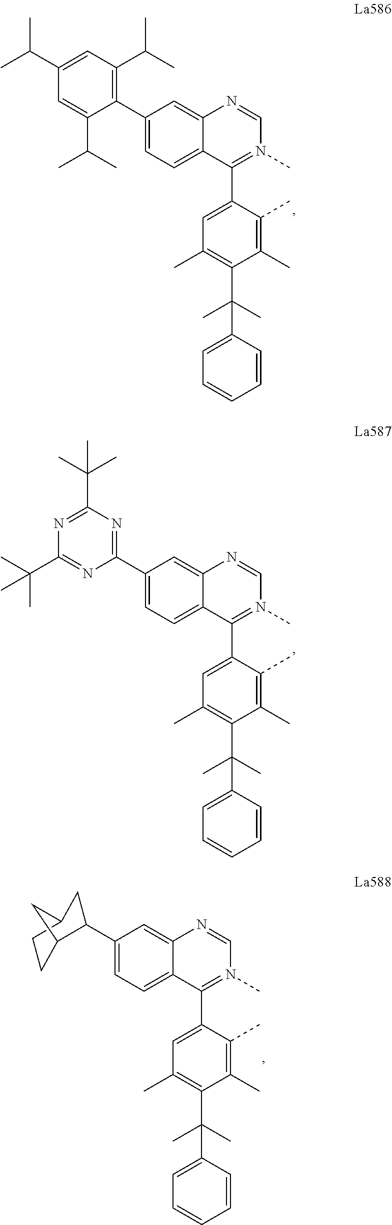 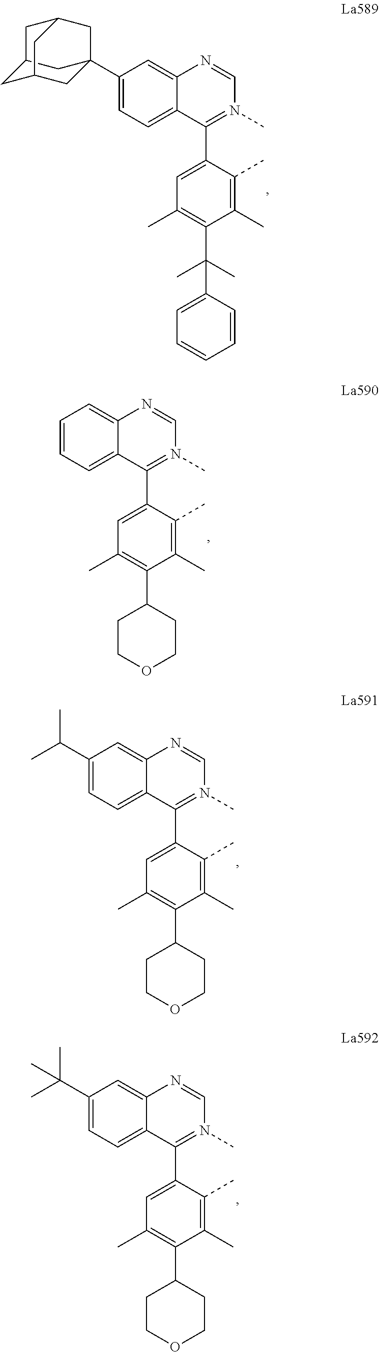 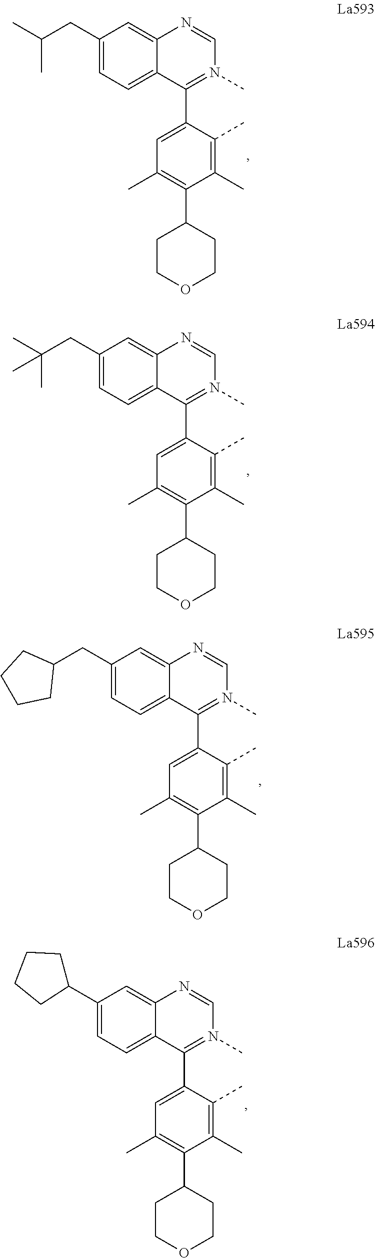 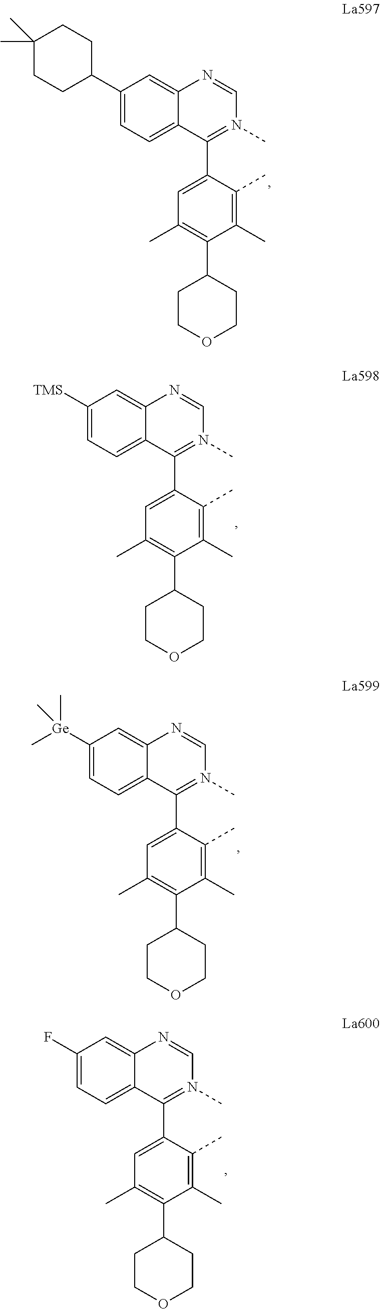 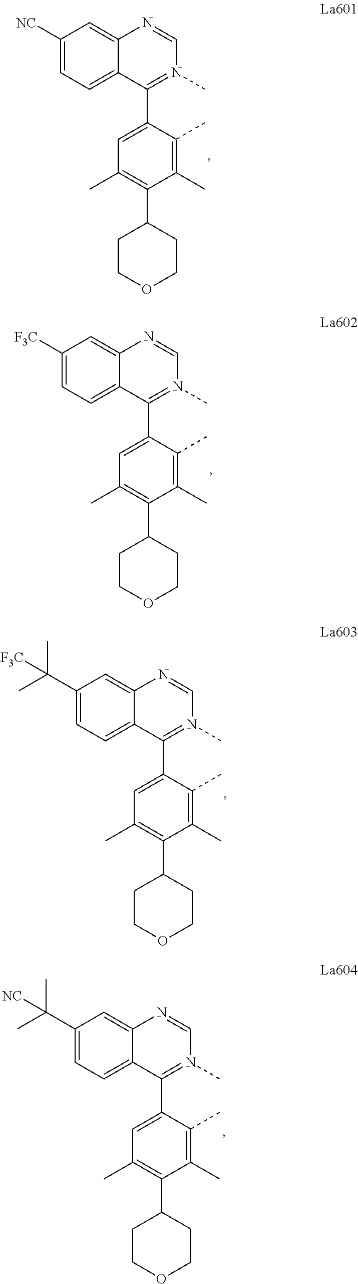 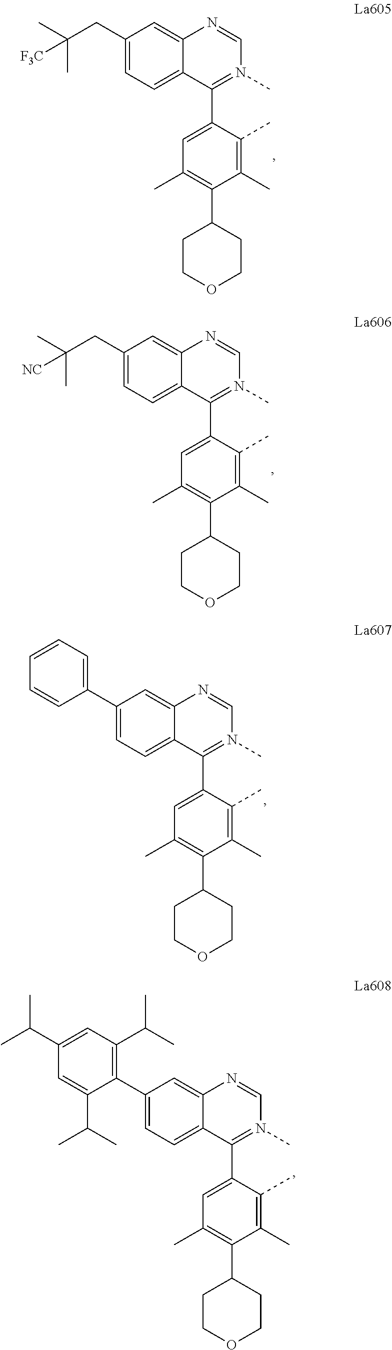 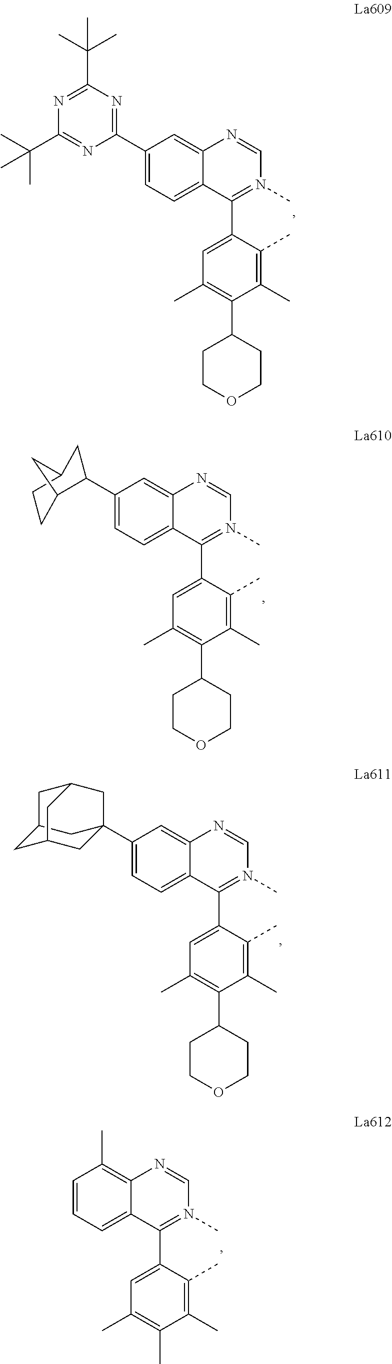 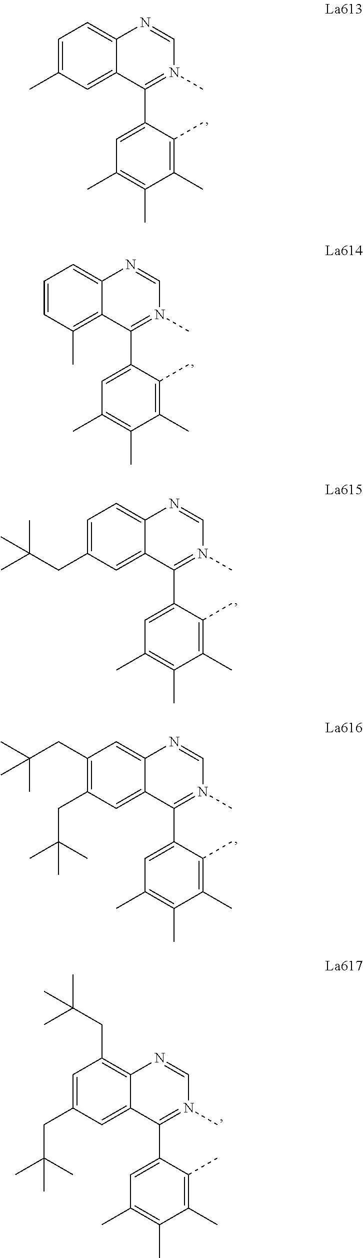 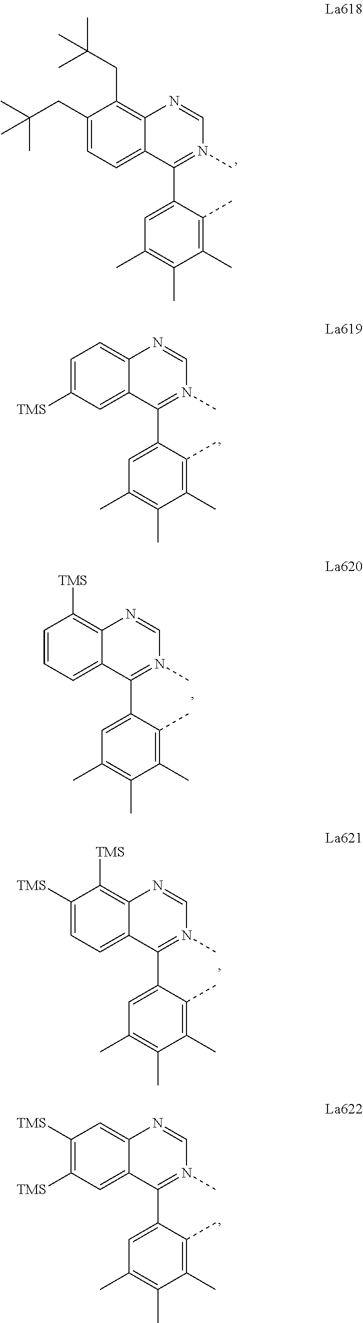 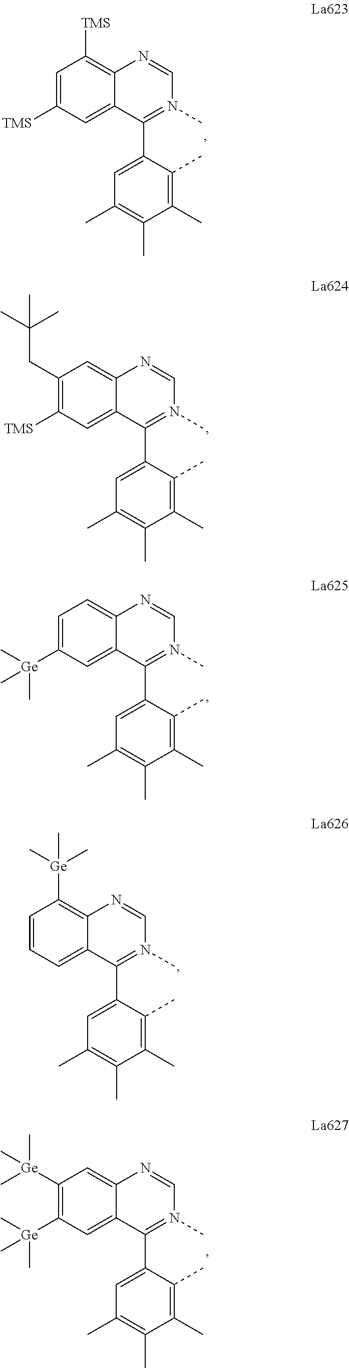 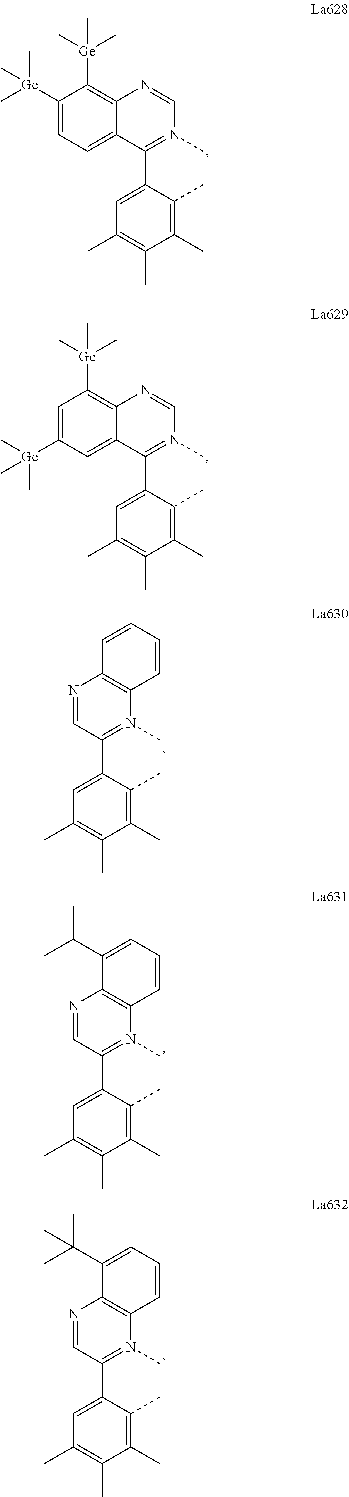 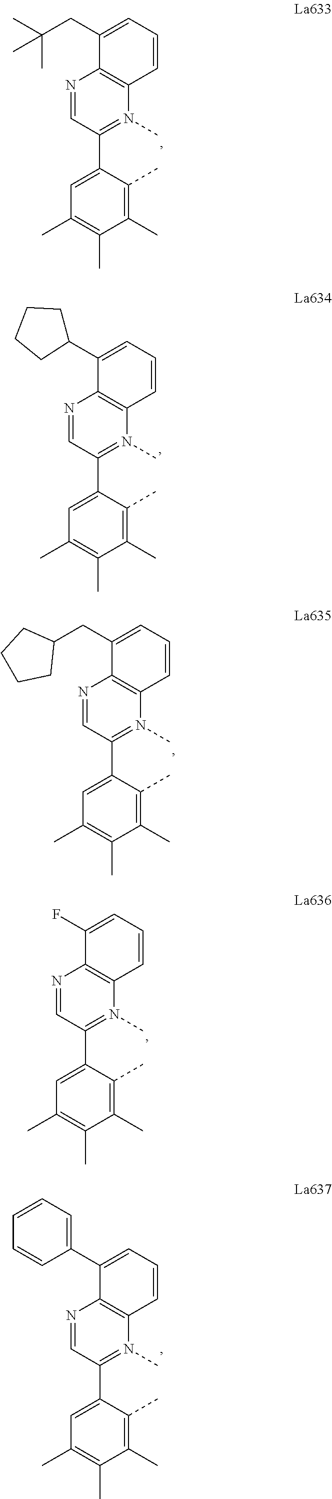 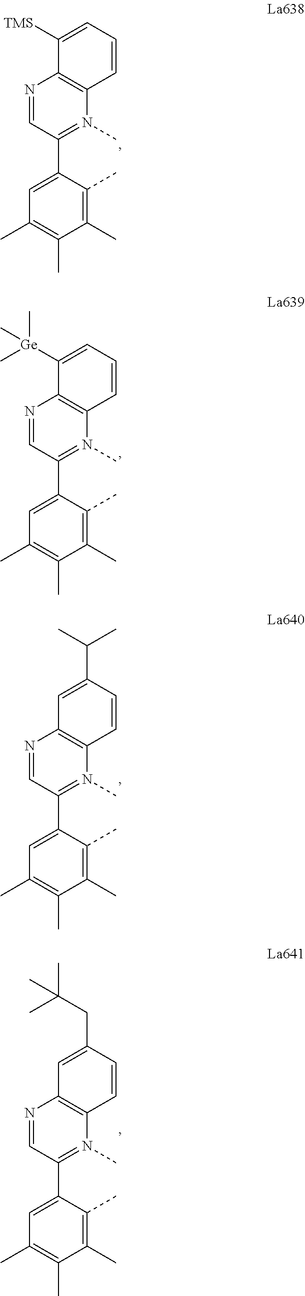 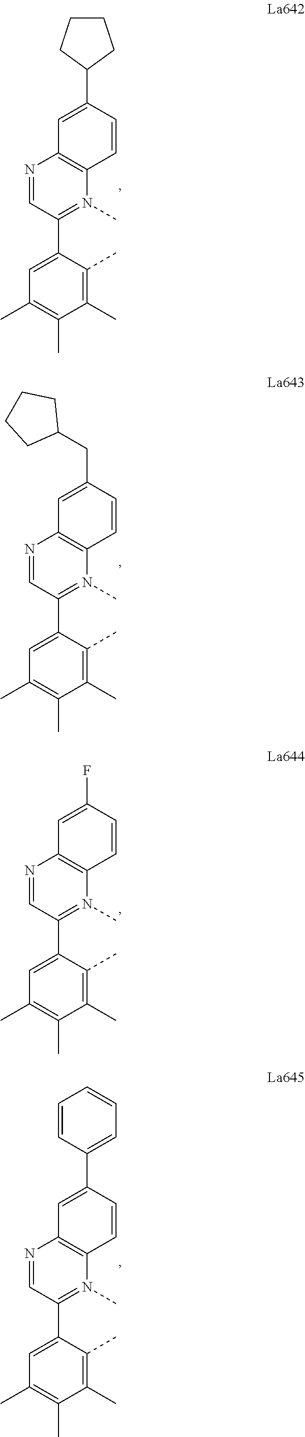 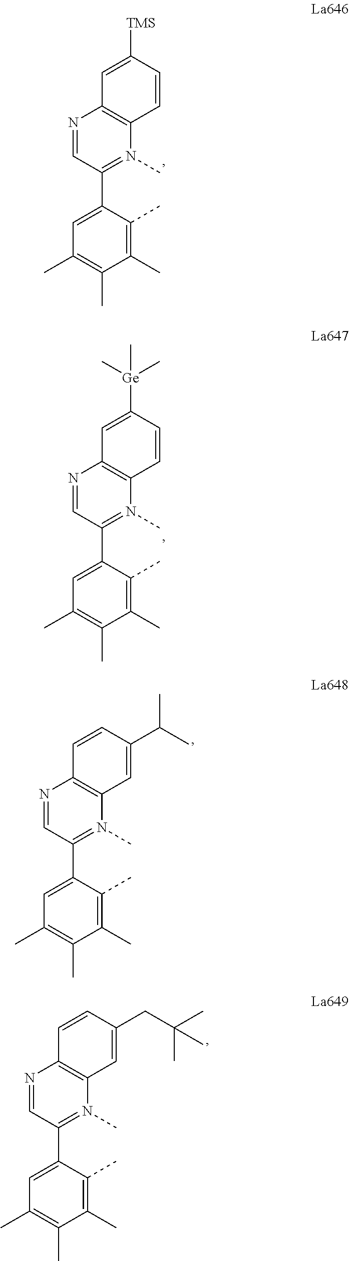 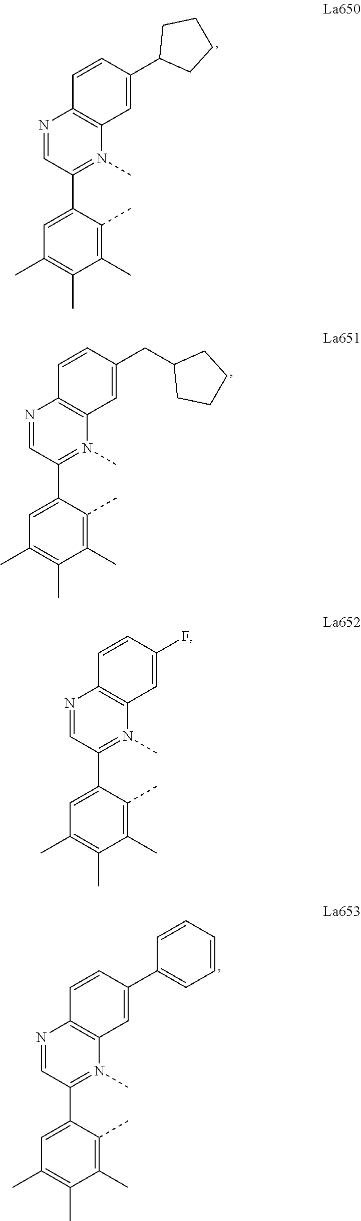 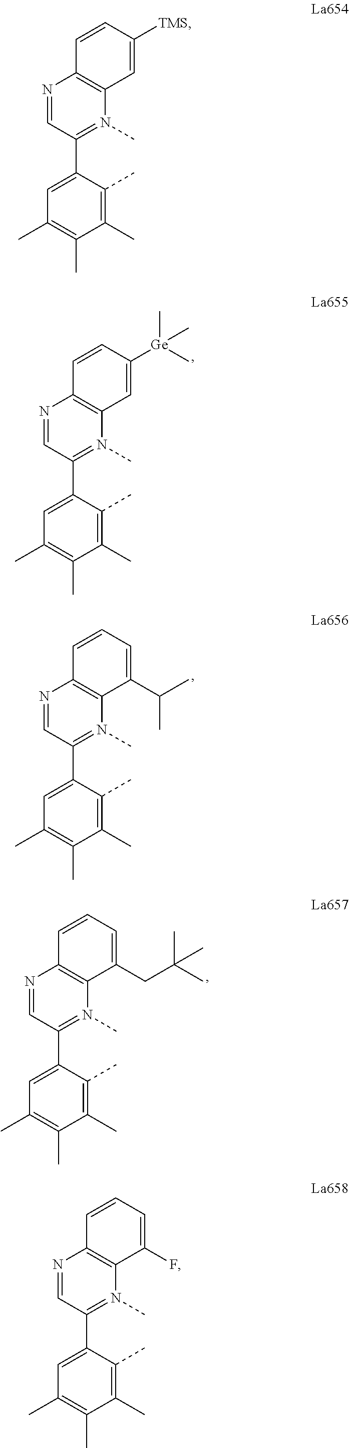 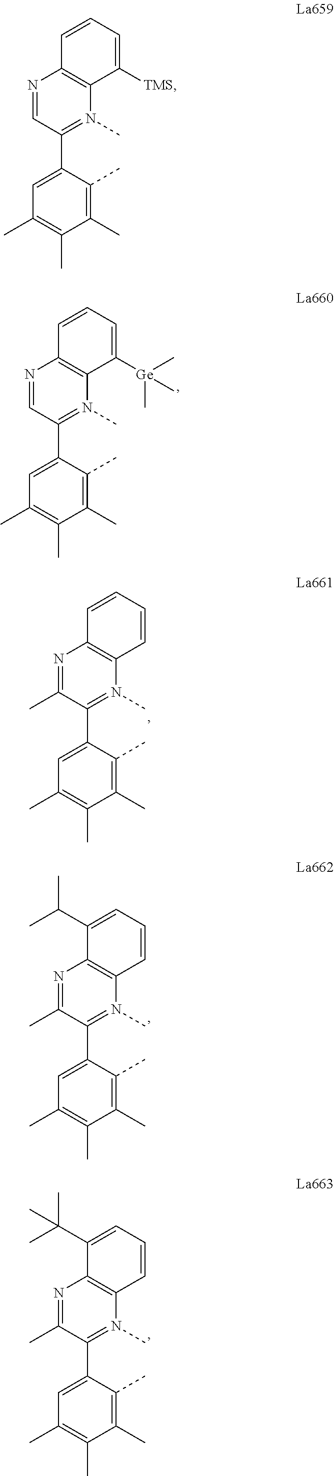 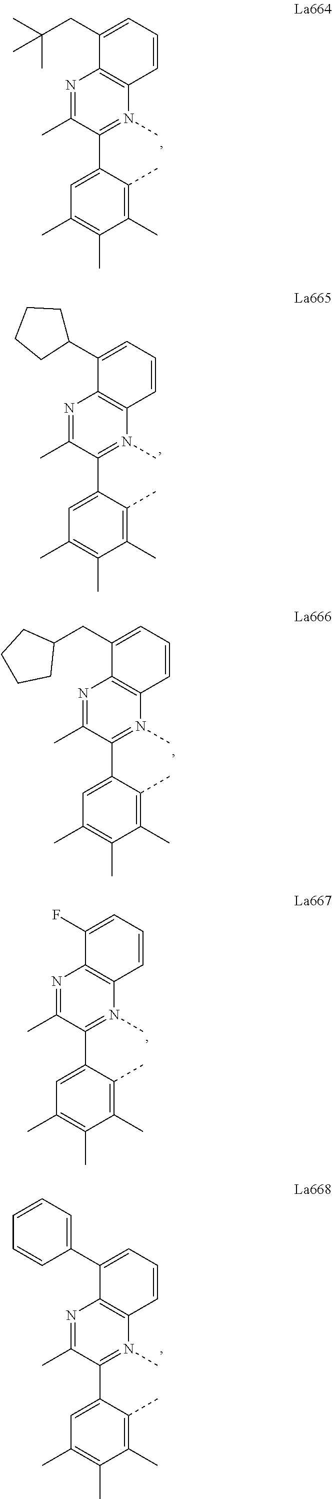 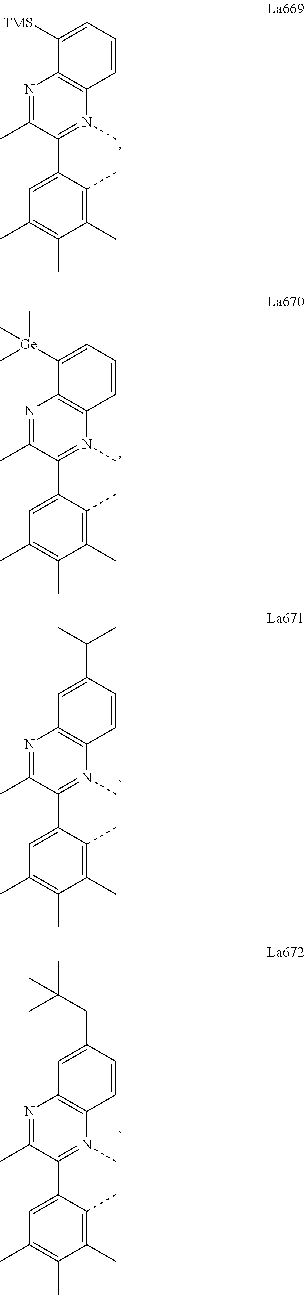 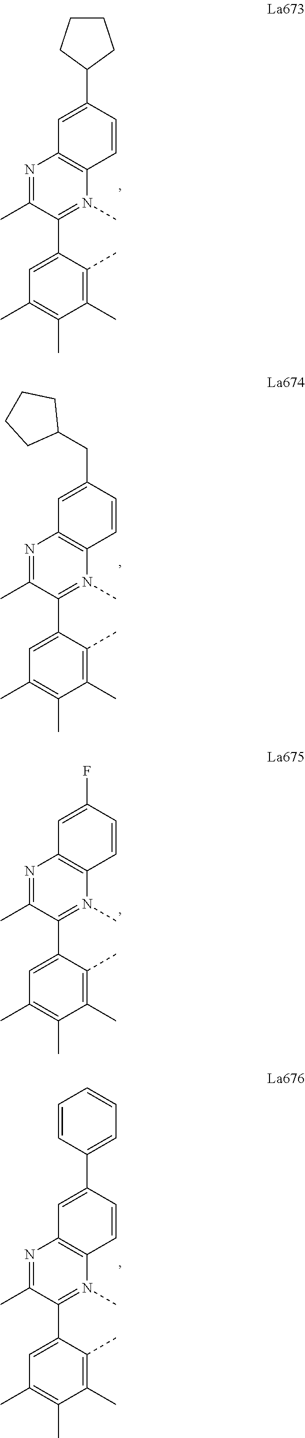 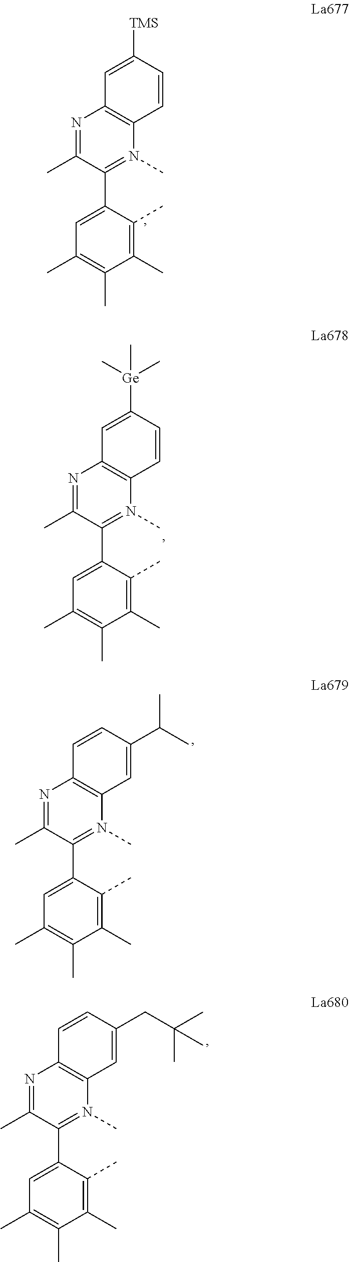 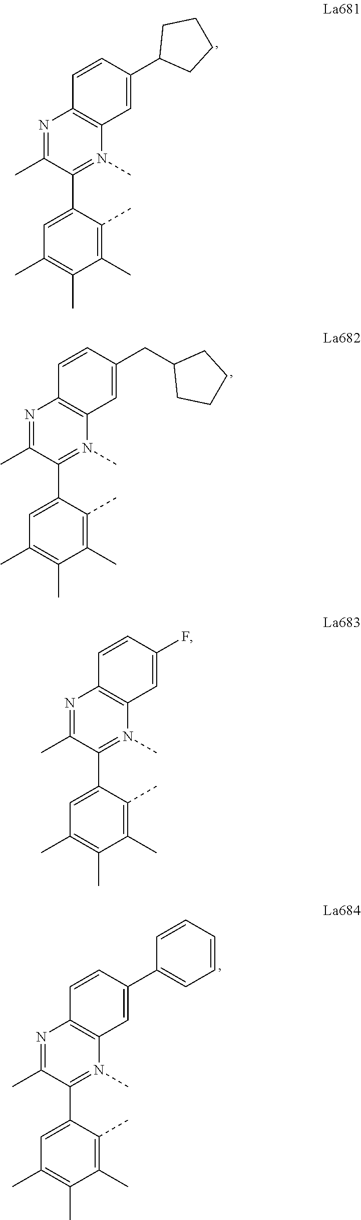 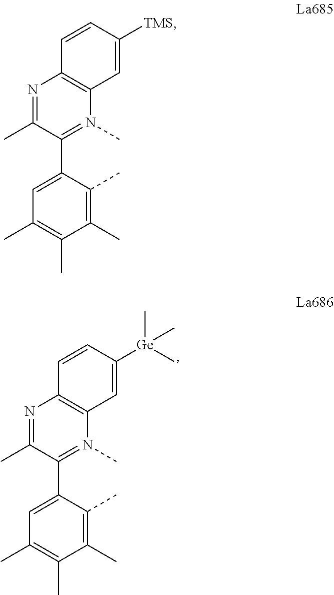 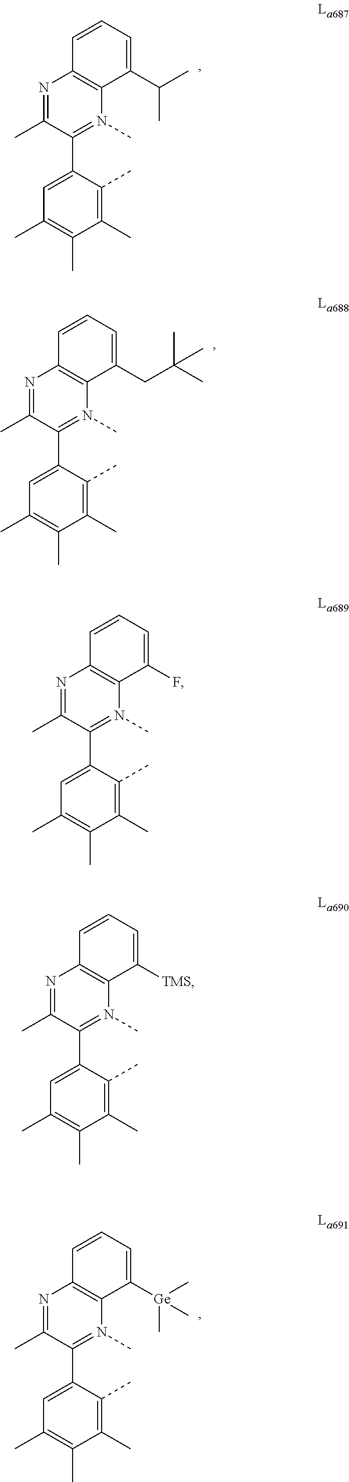 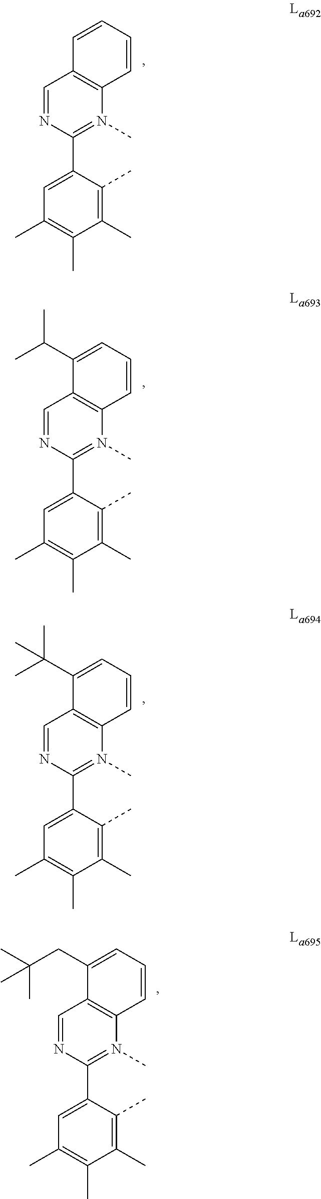 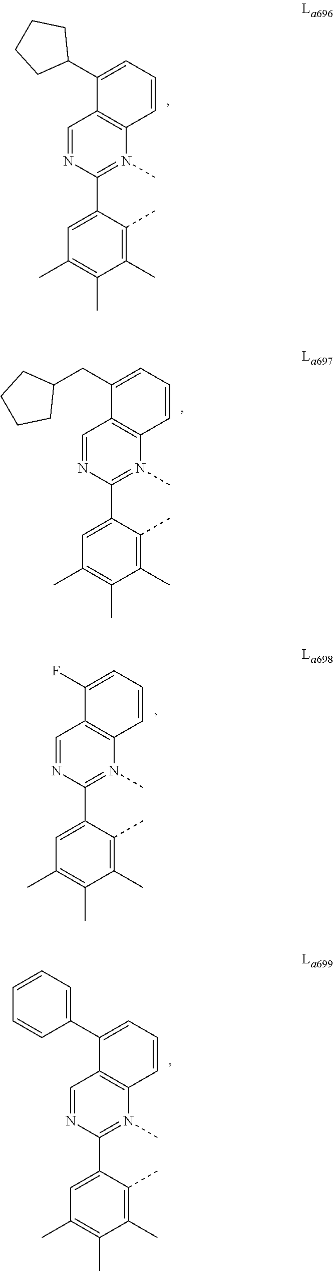 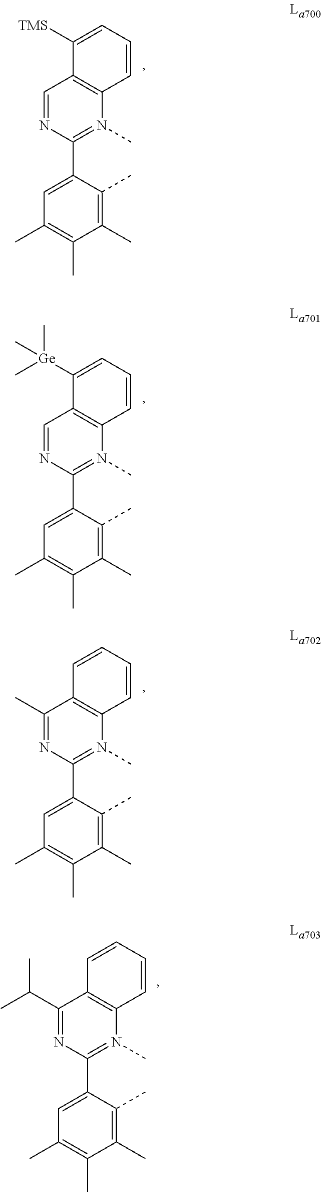 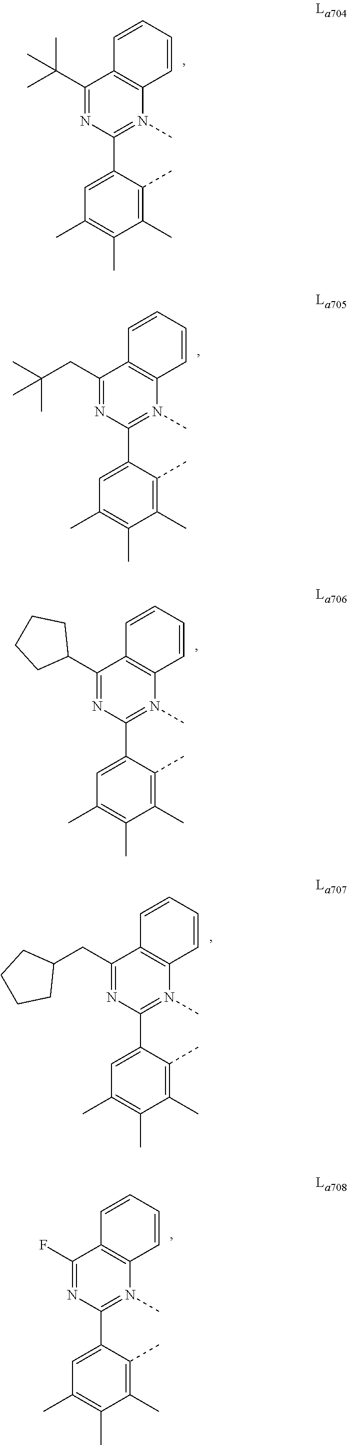 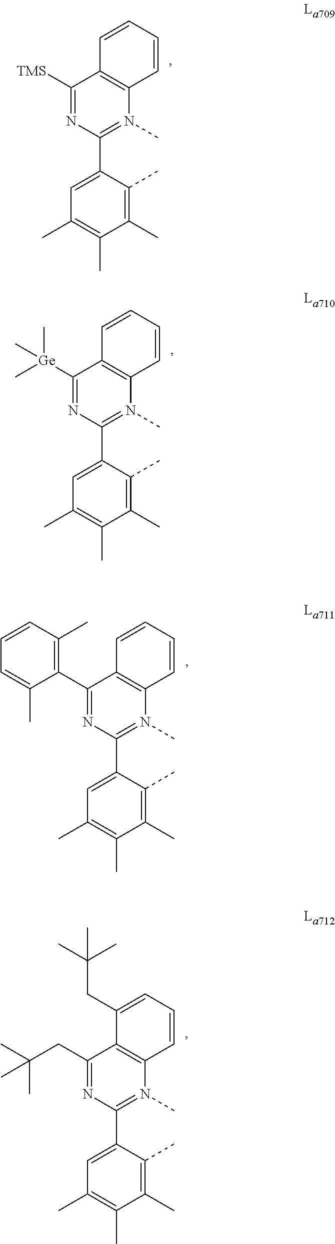 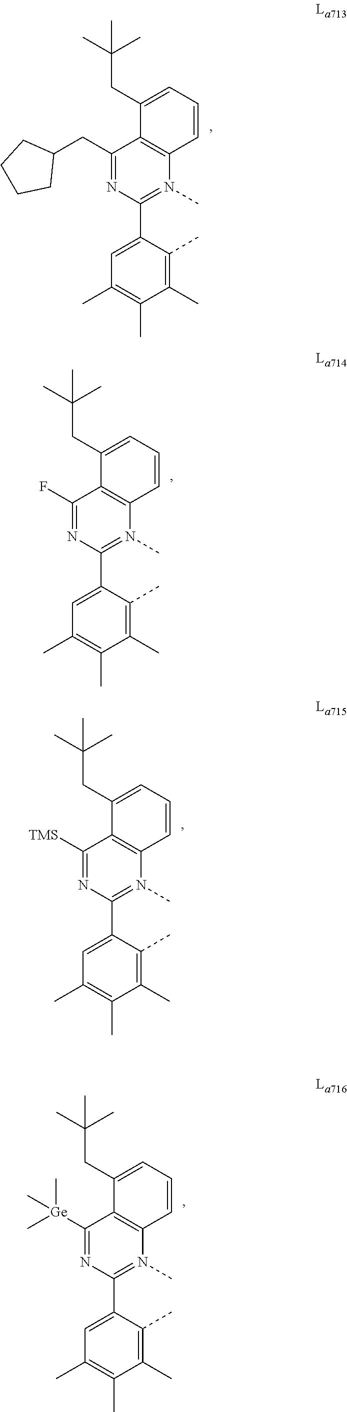 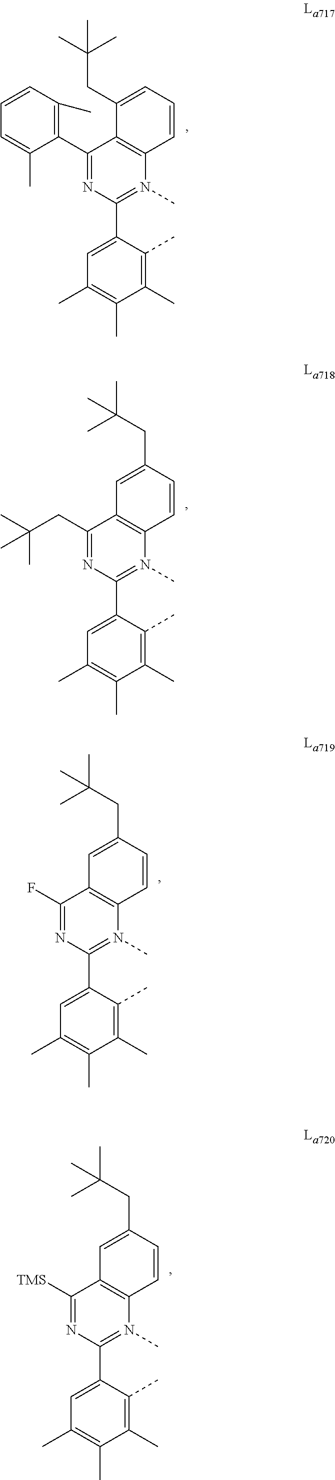 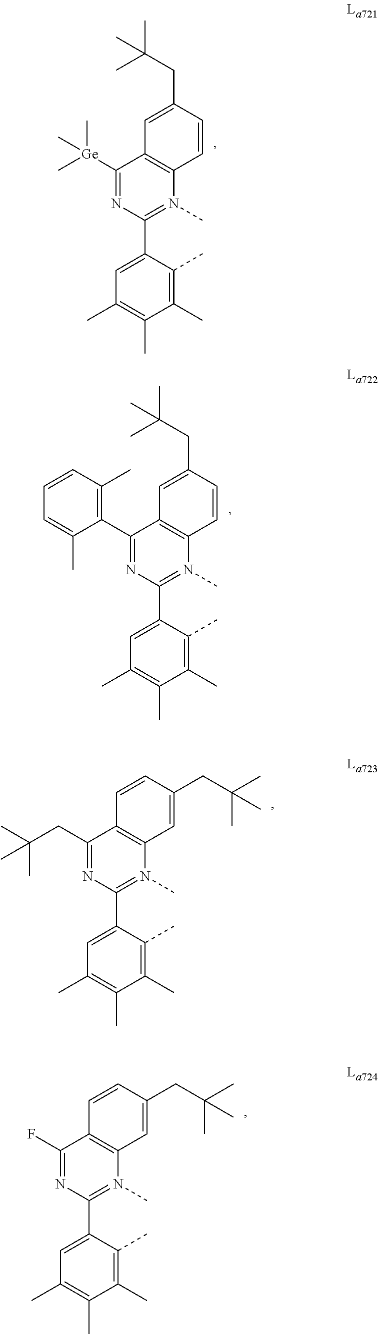 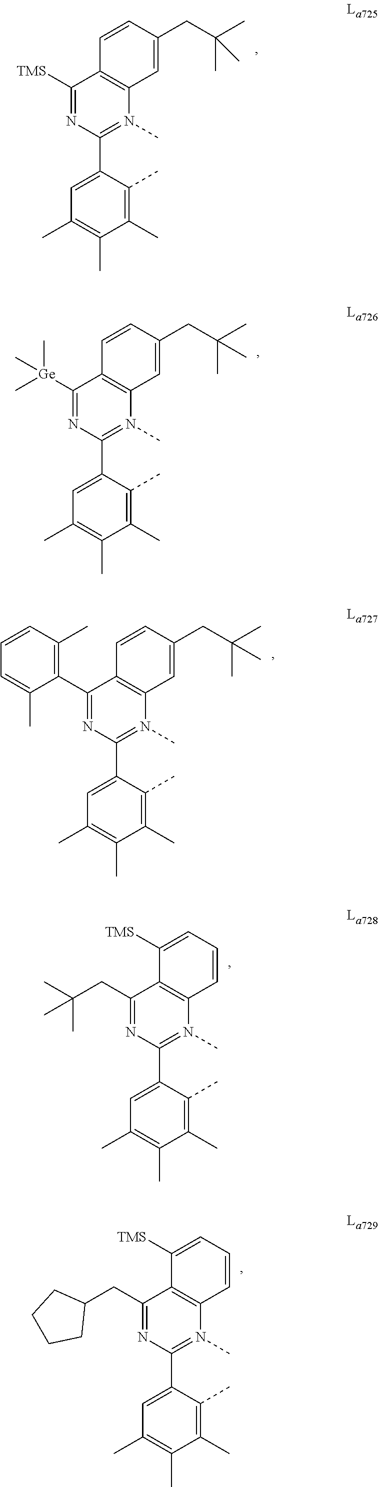 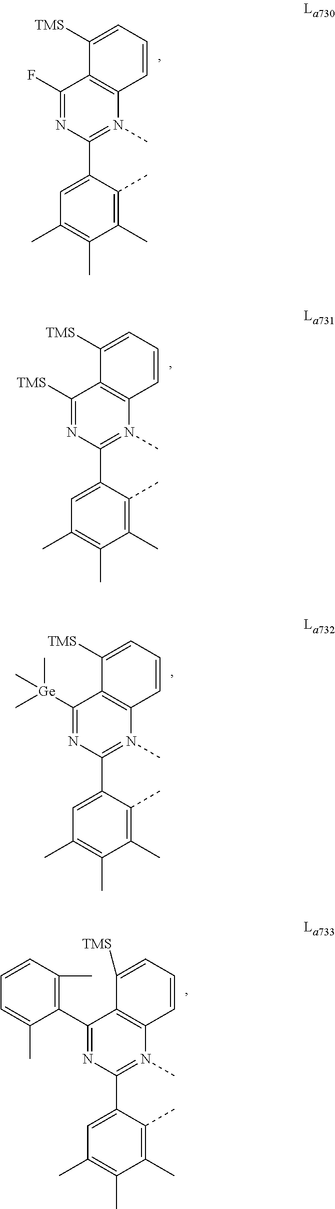 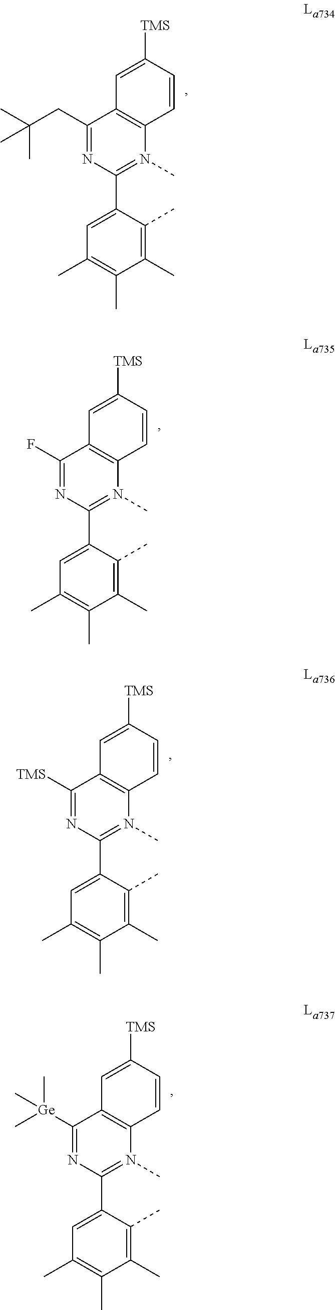 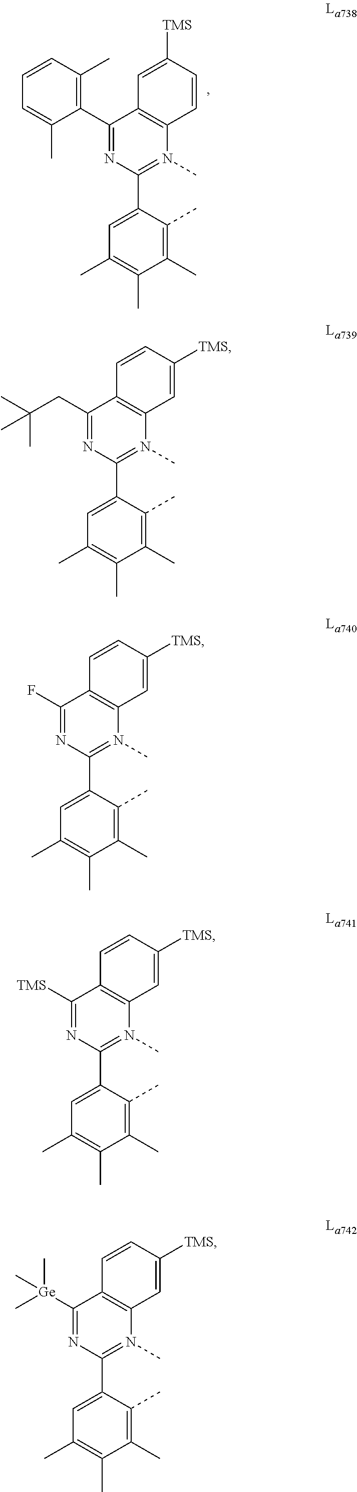 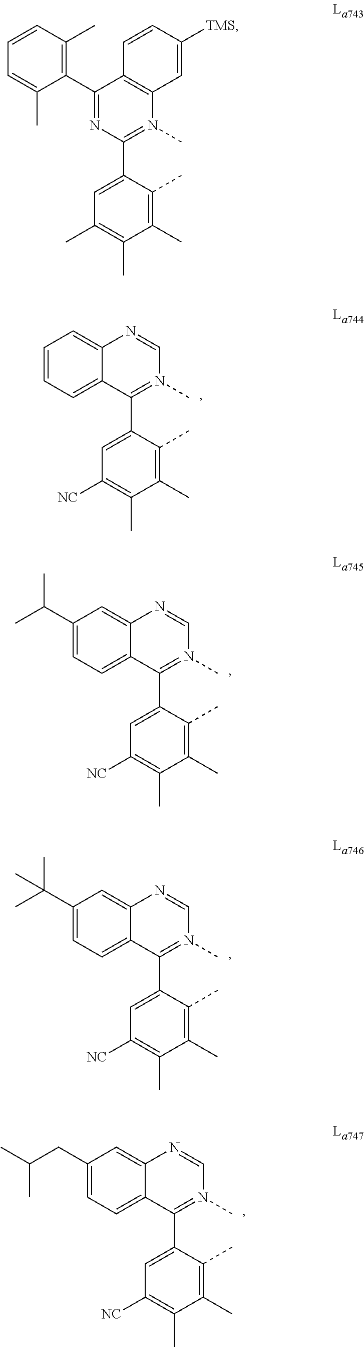 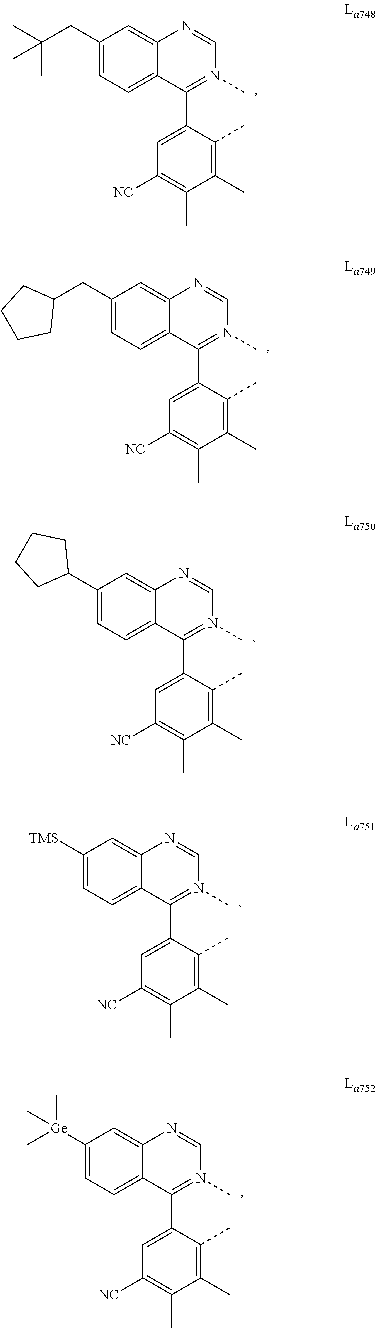 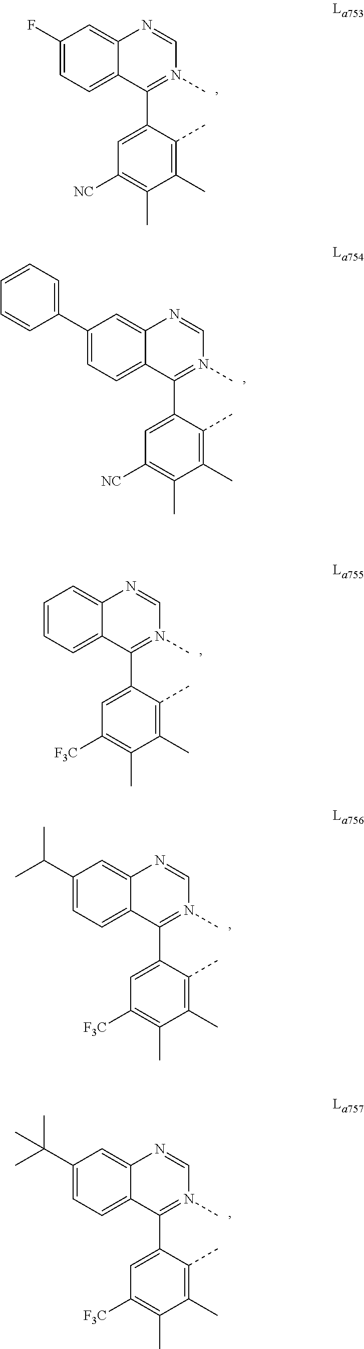 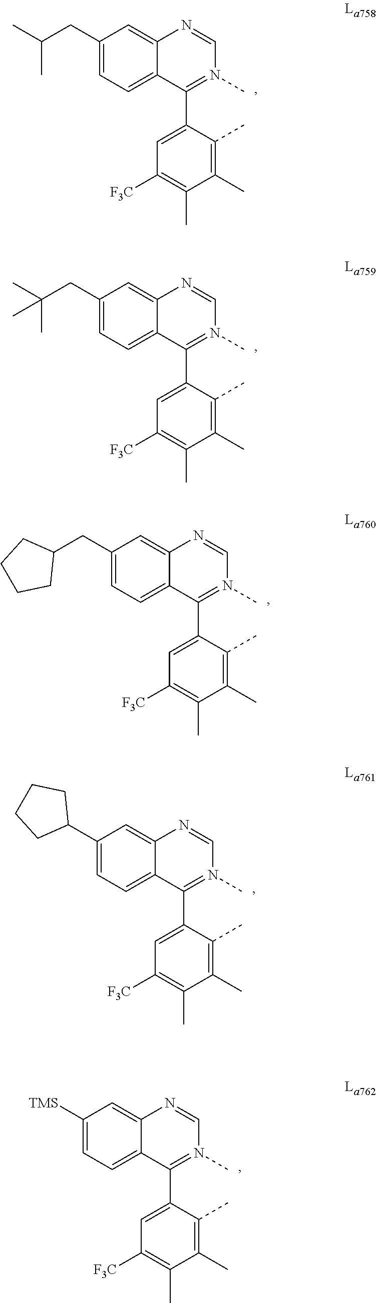 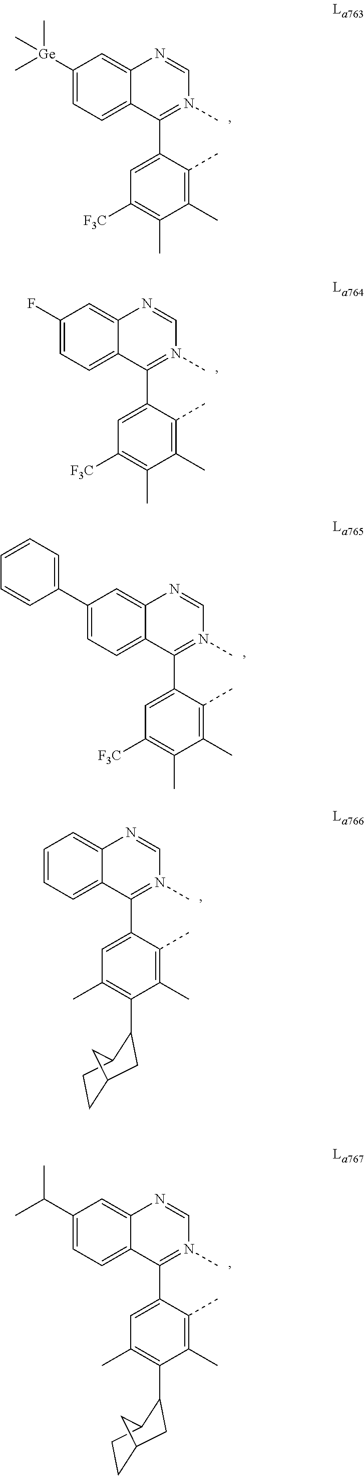 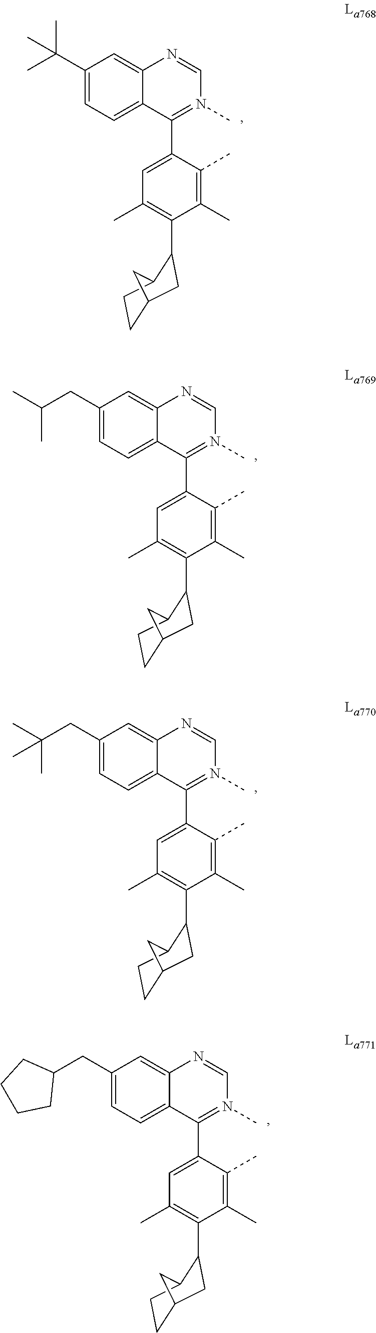 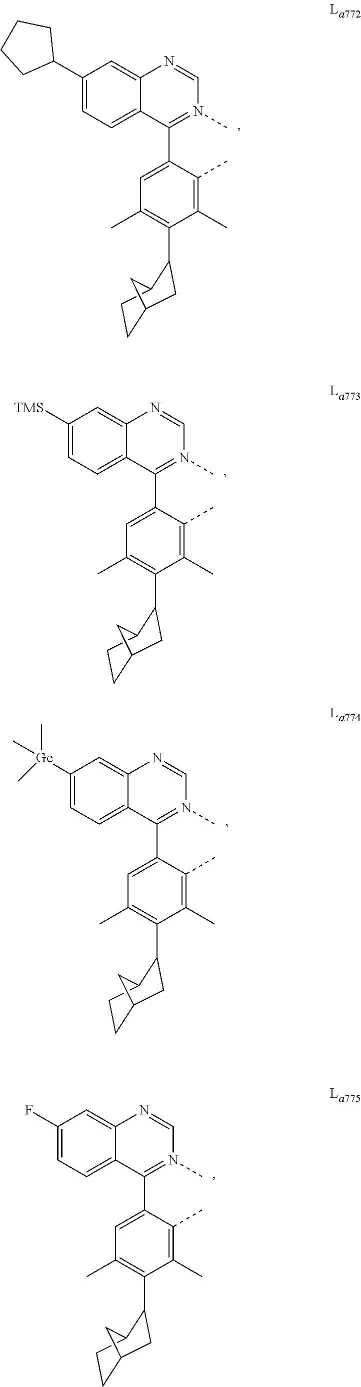 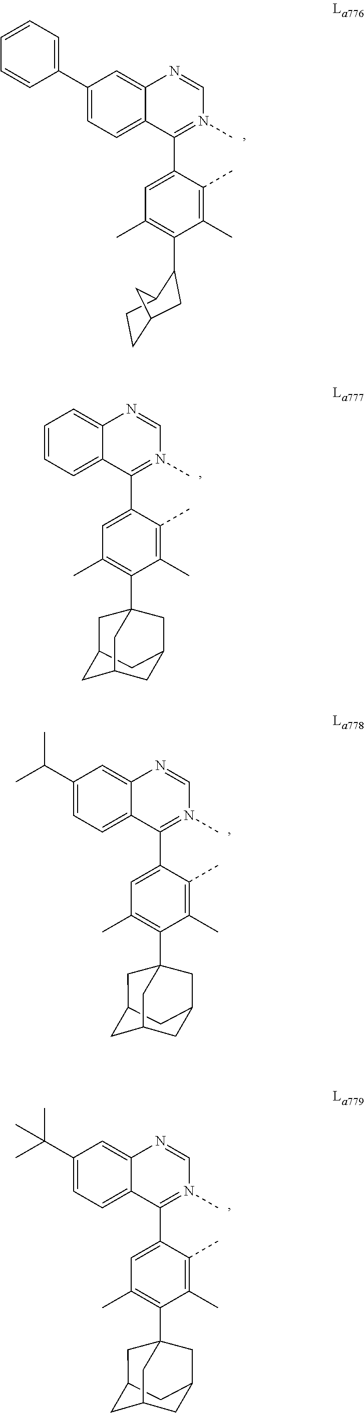 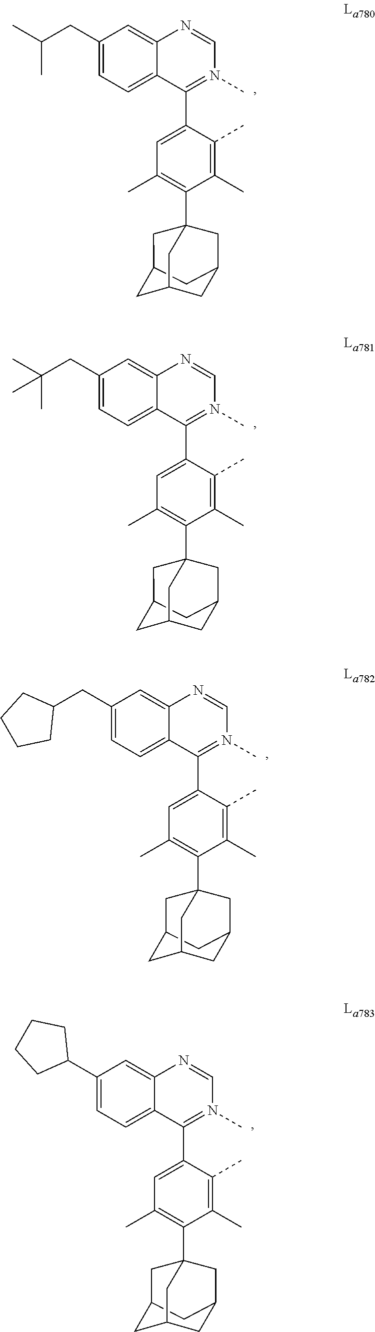 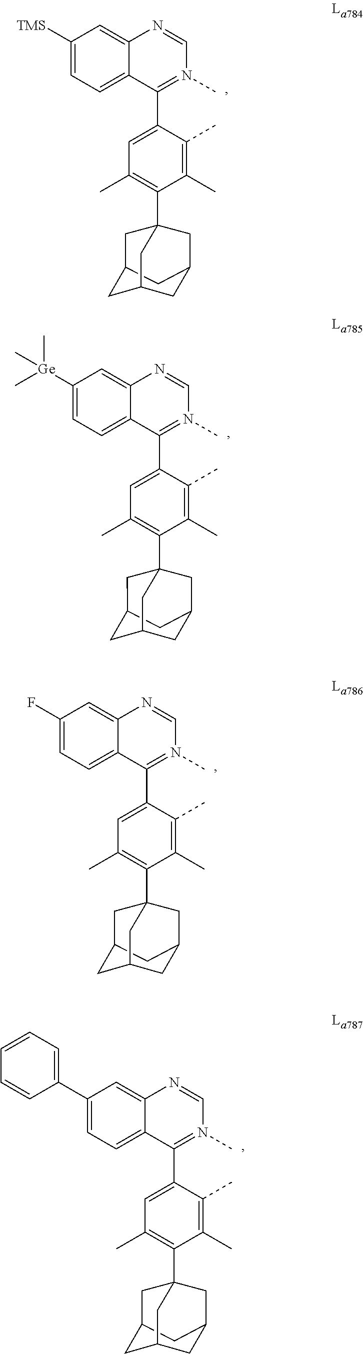 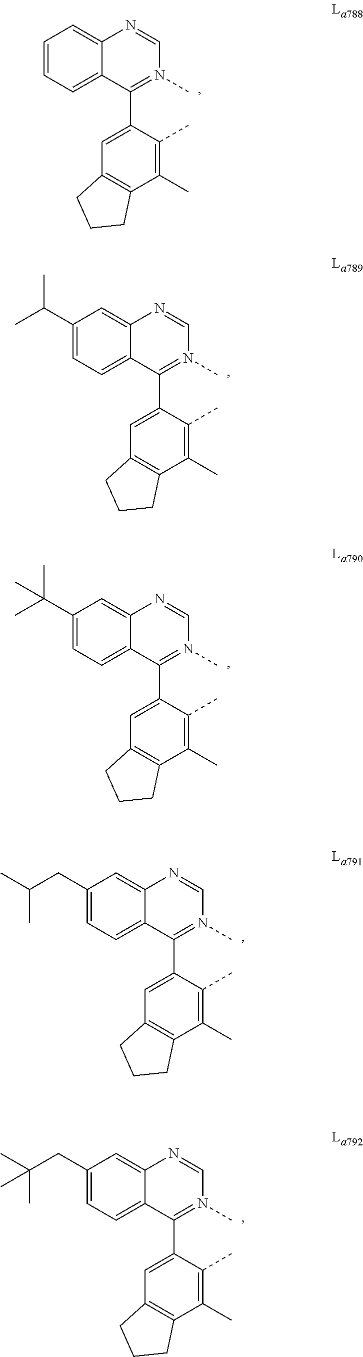 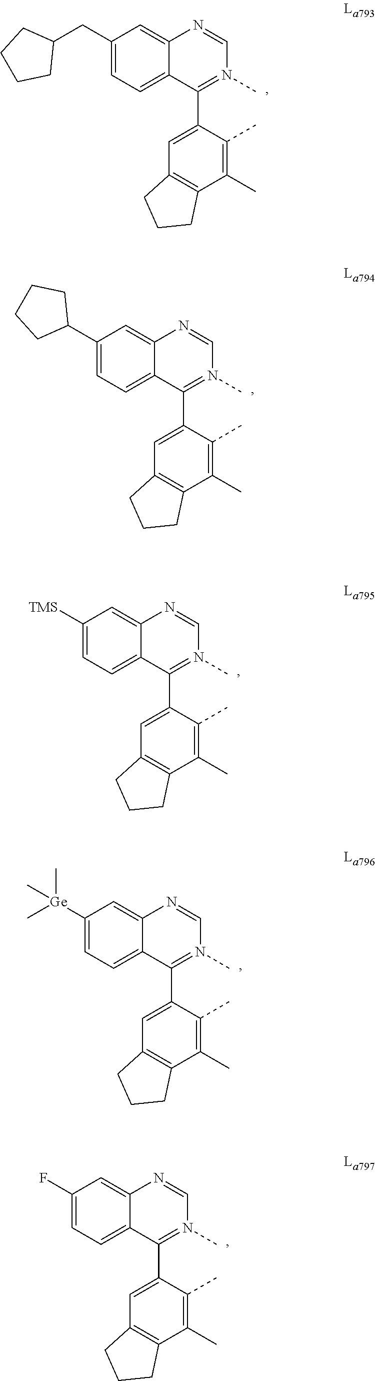 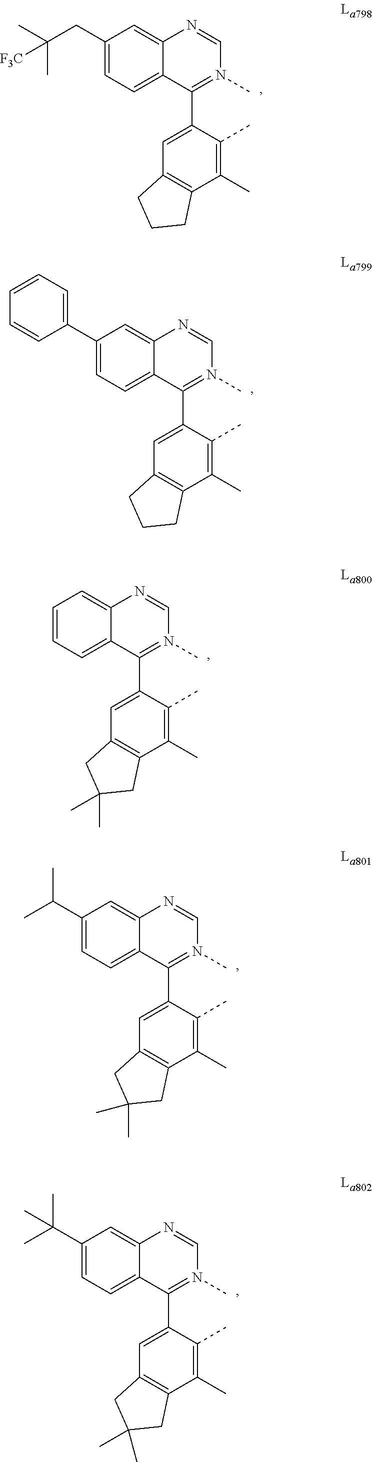 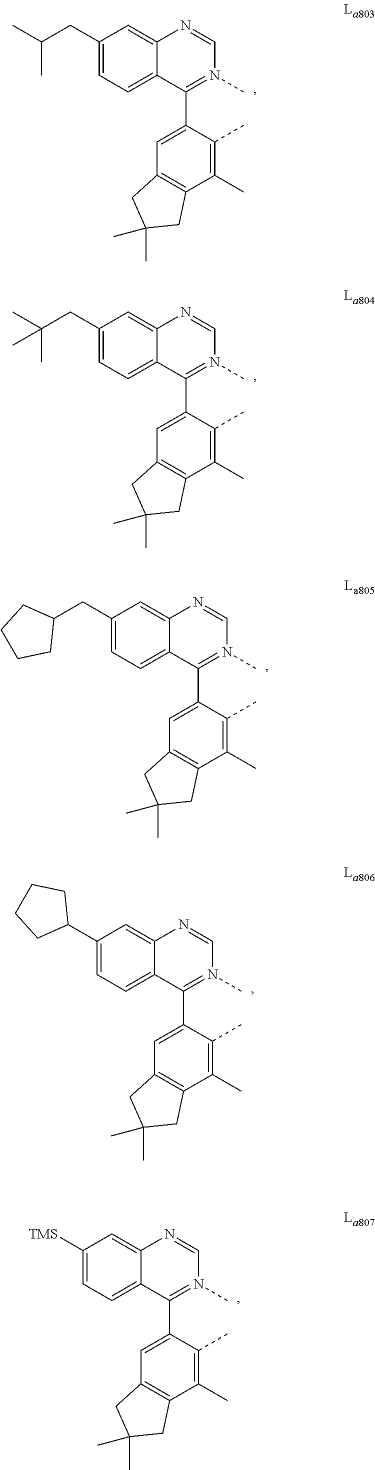 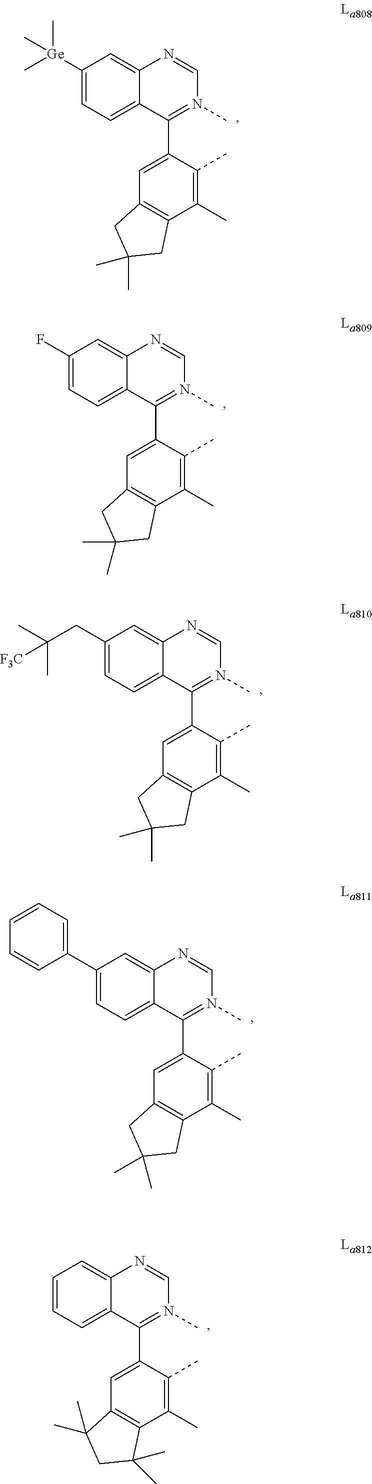 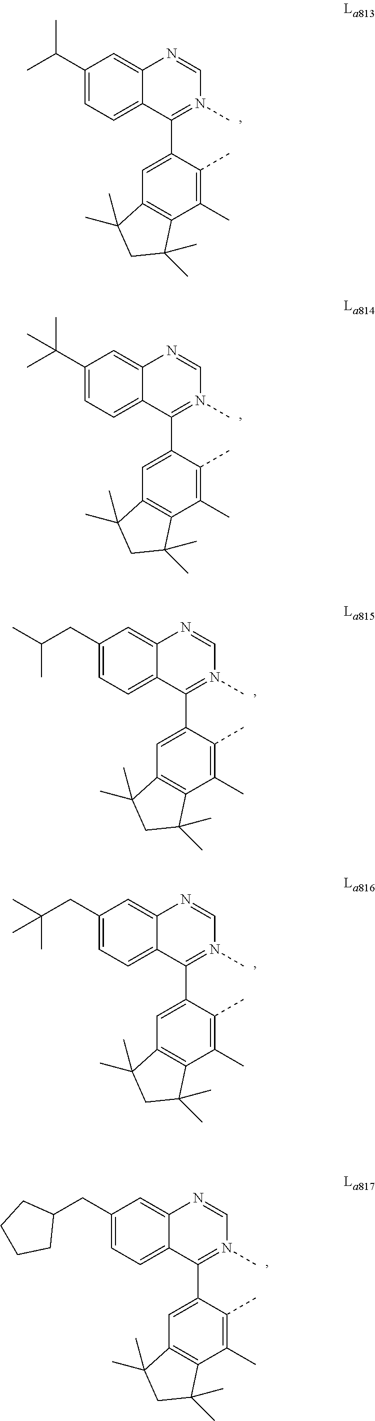 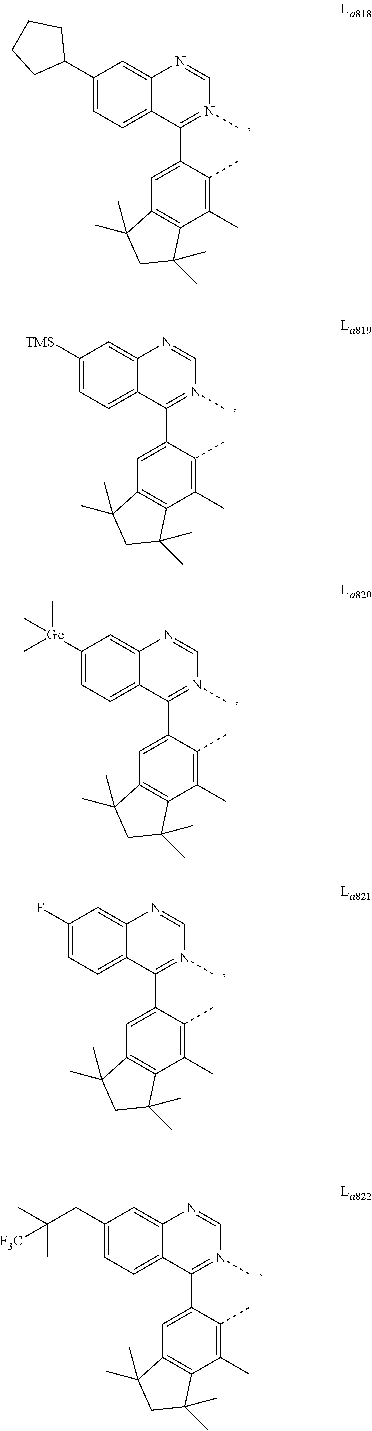 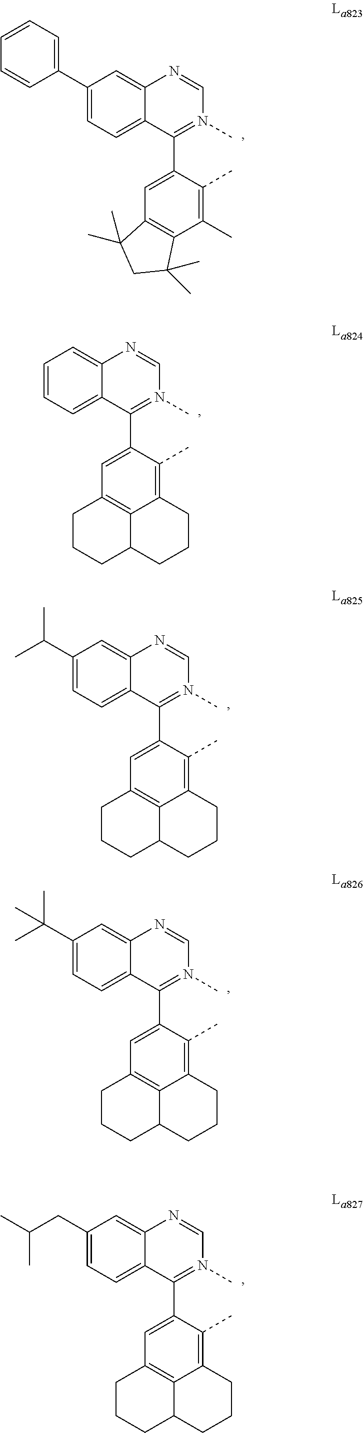 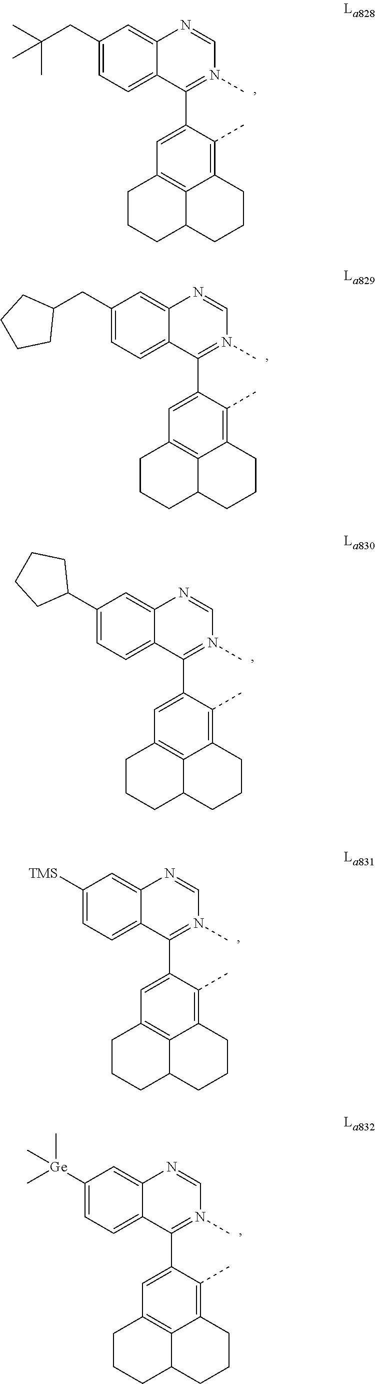 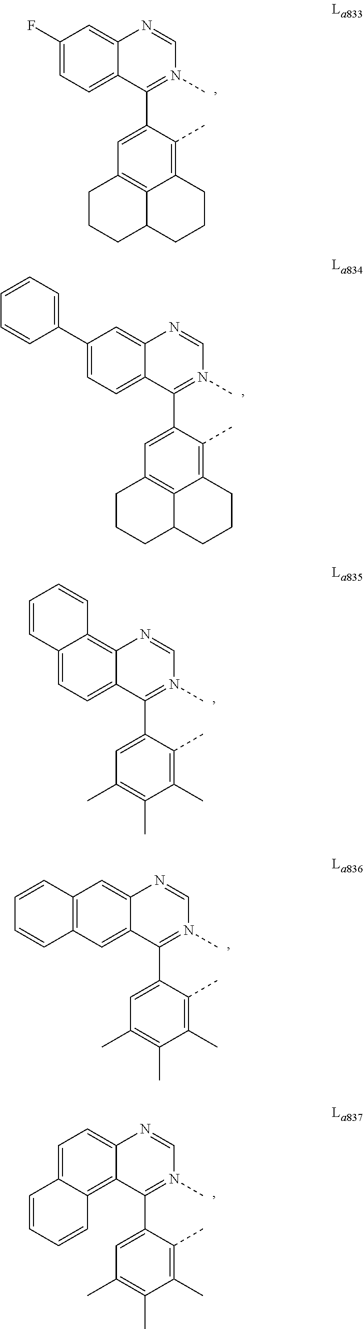 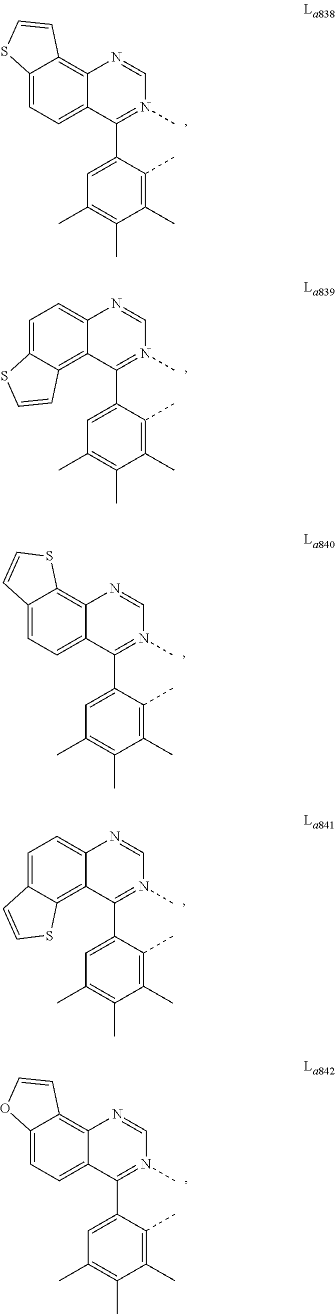 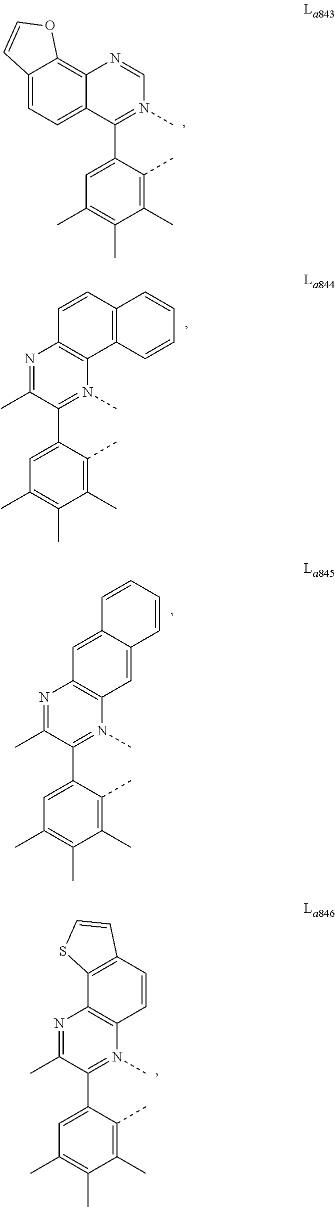 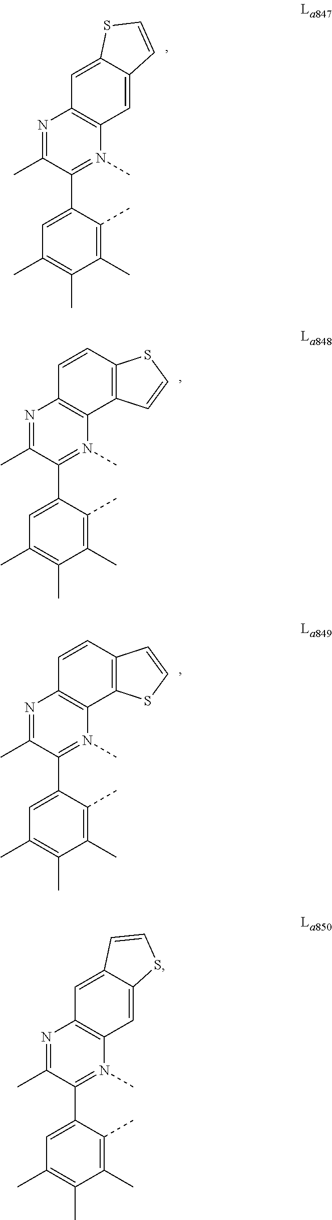 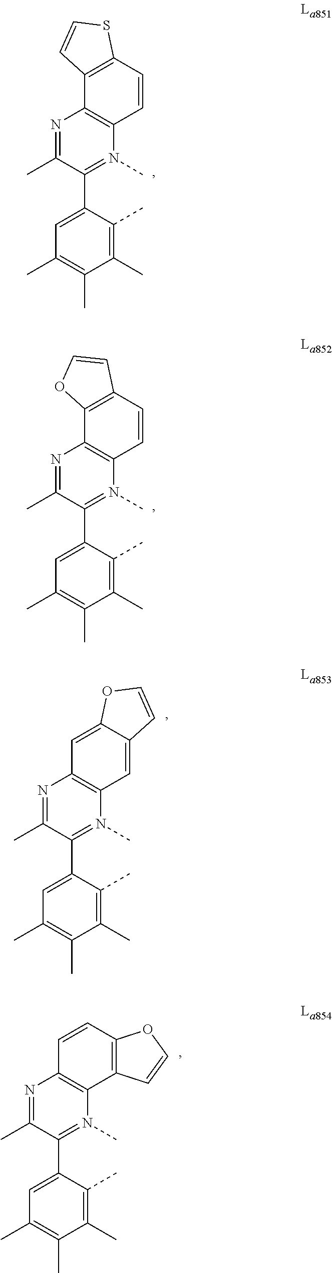 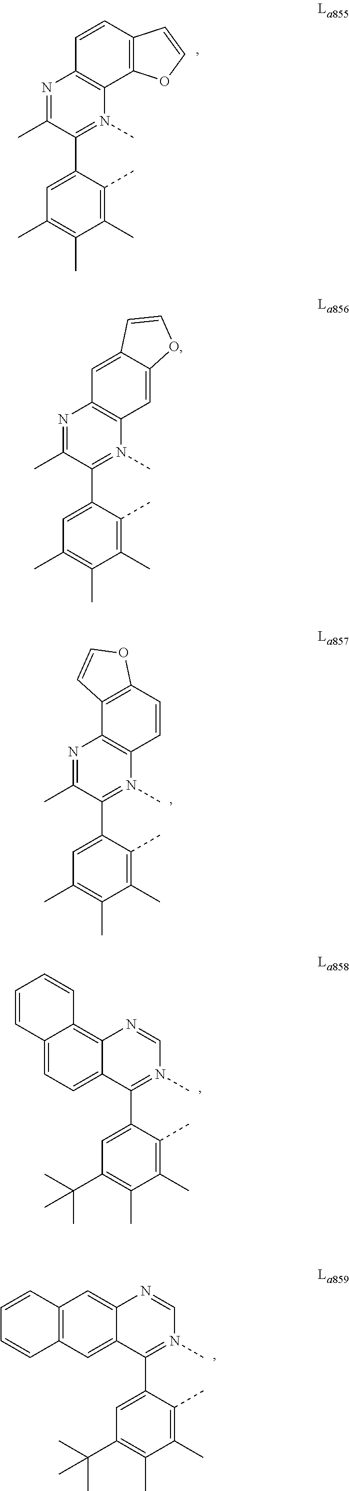 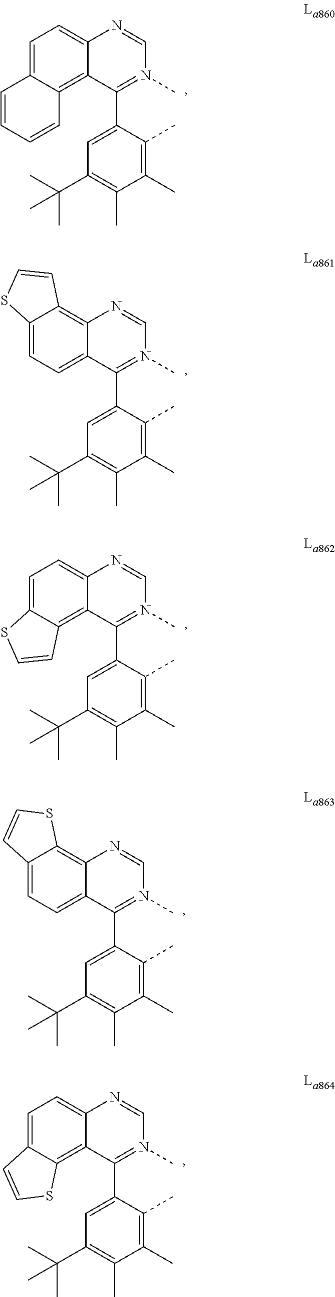 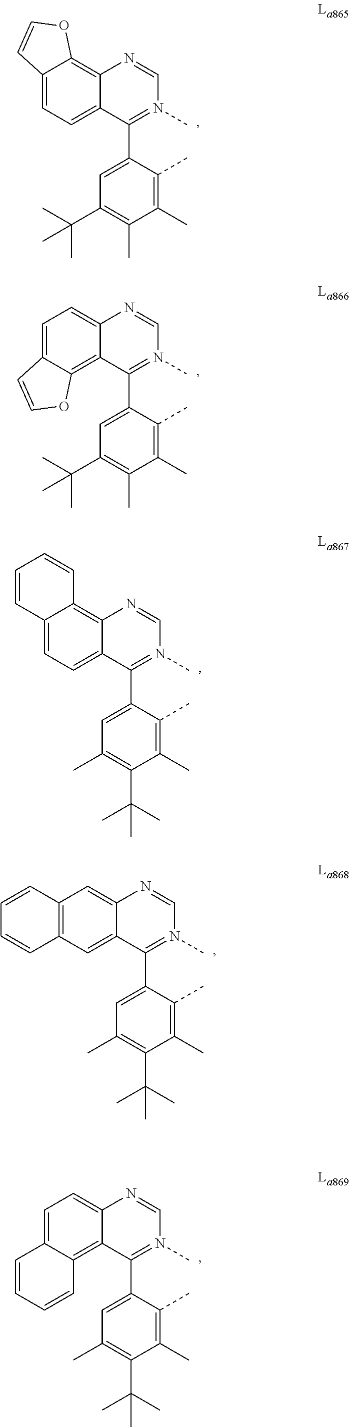 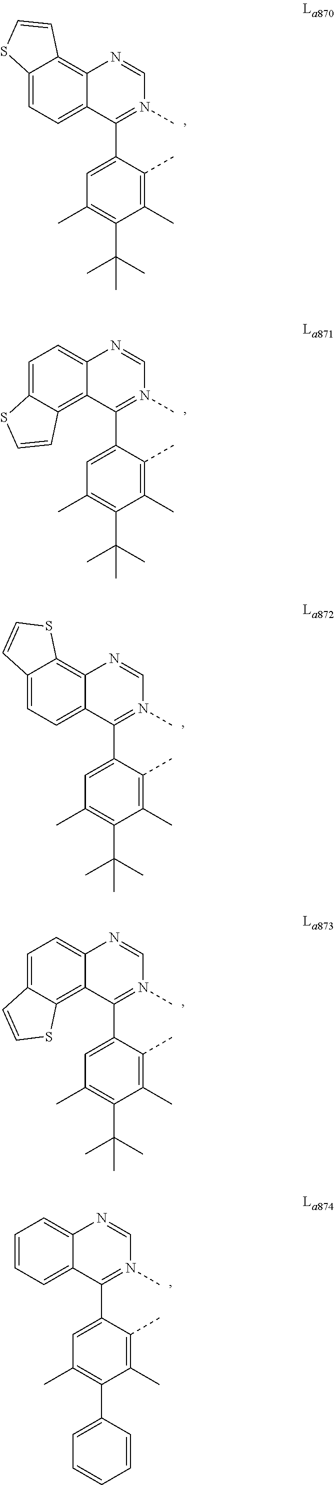 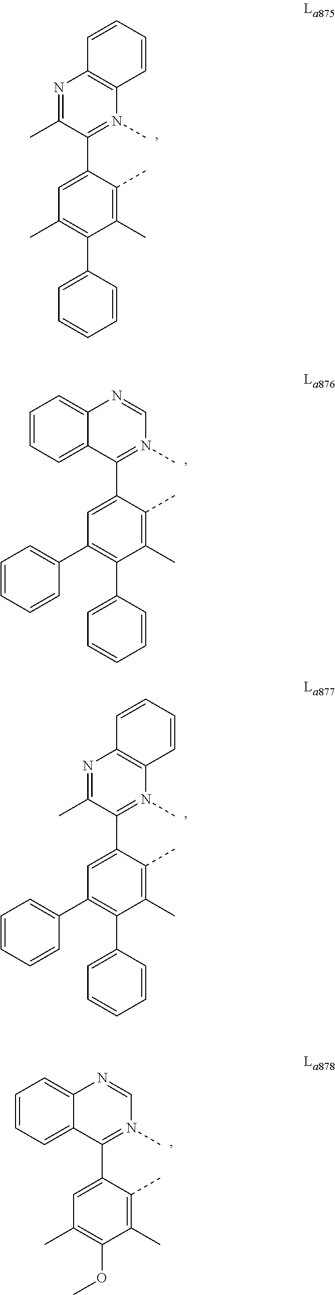 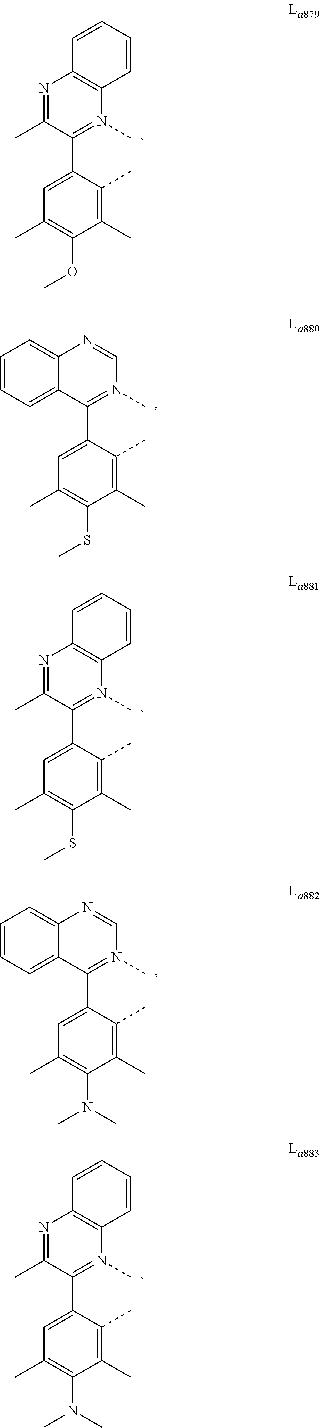 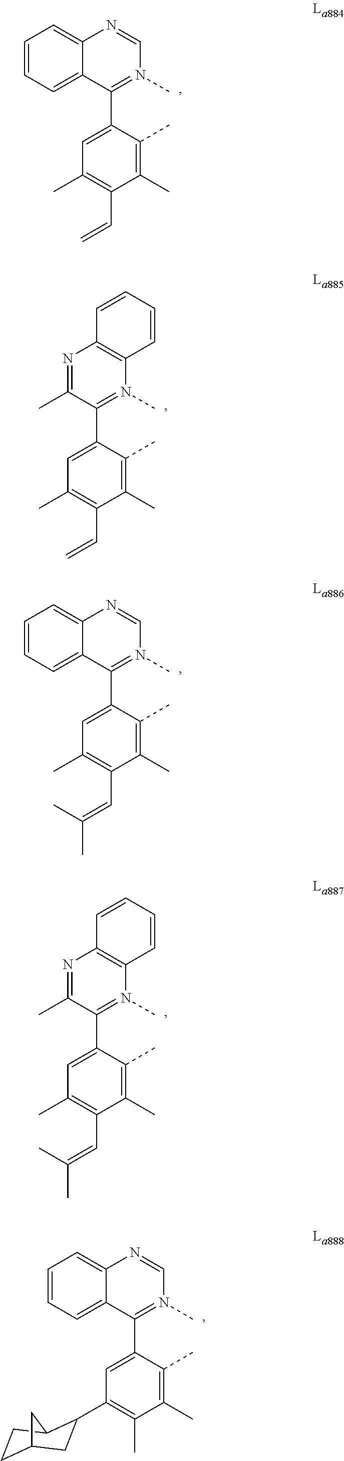 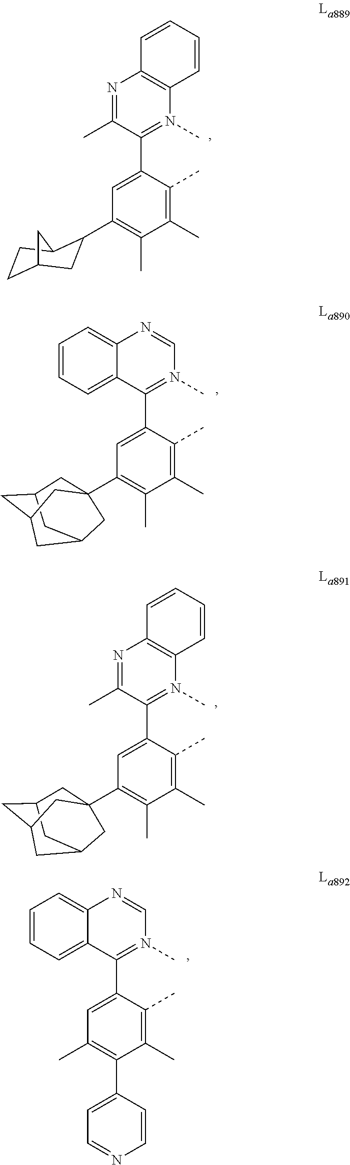 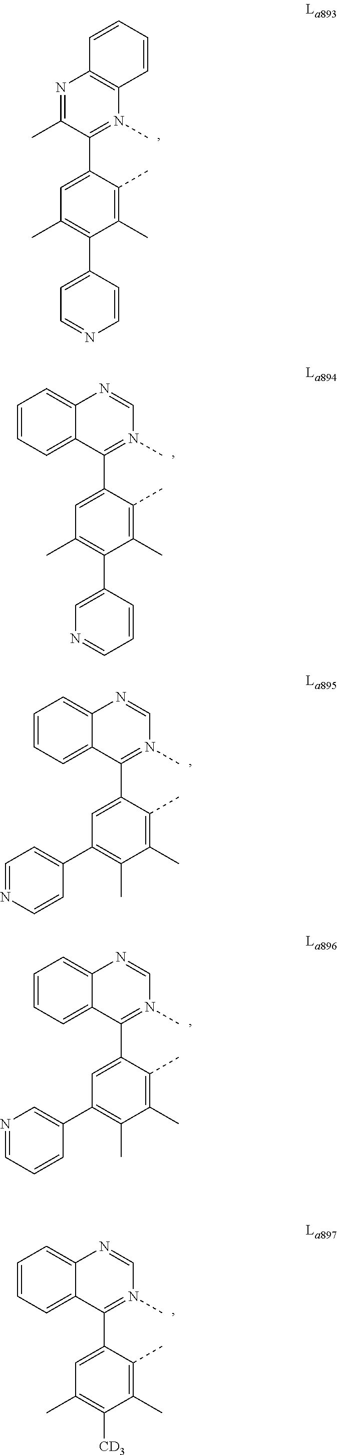 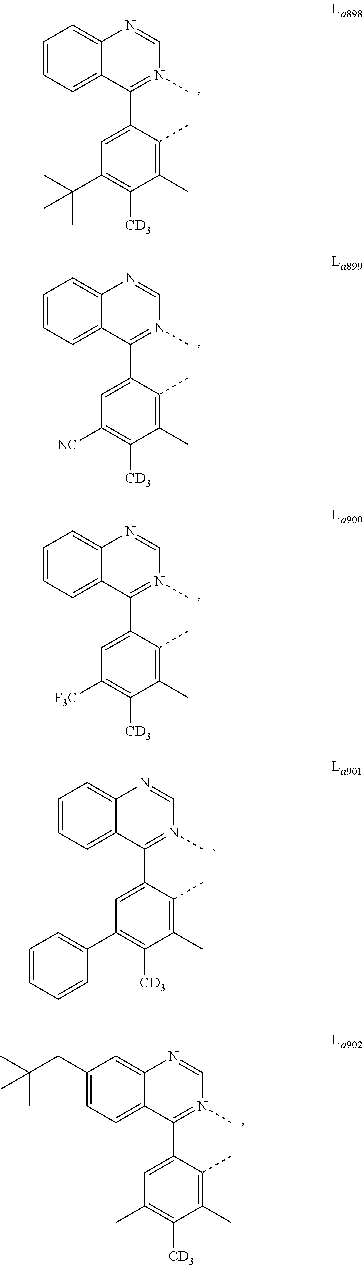 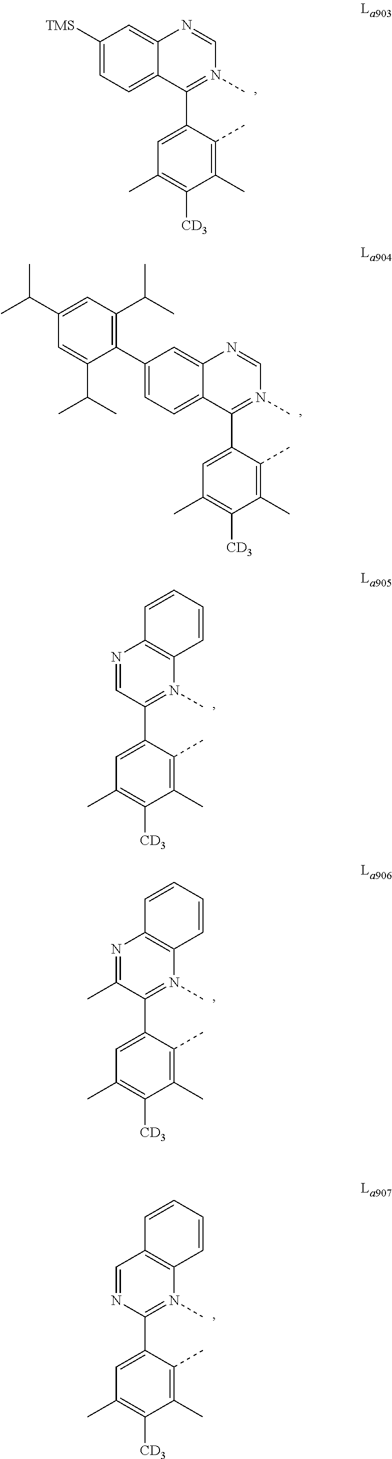 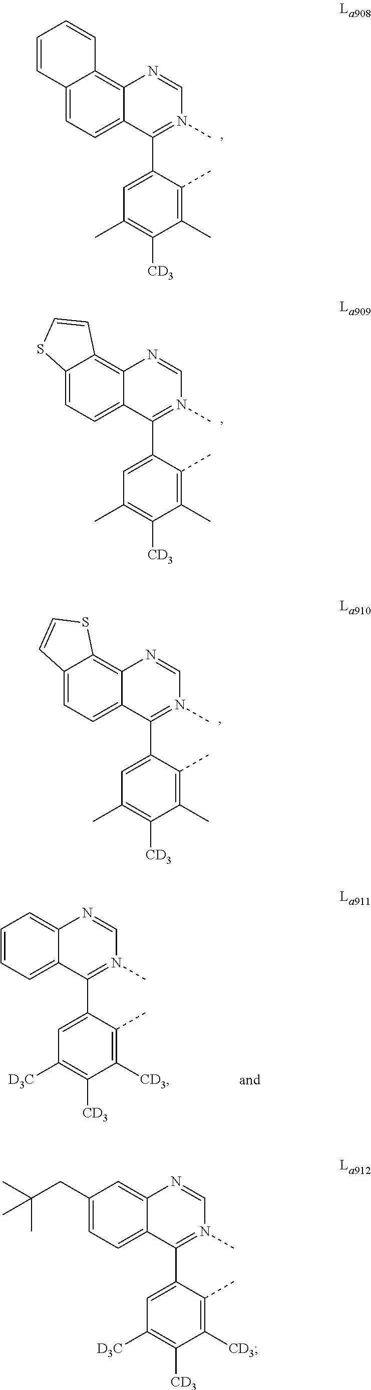
in the above structures, TMS is trimethylsilyl;
optionally, hydrogen in the structures Lₐ₁ to Lₐ₉₁₂ can be partially or fully substituted with deuterium.

10. The metal complex of claim 1, wherein L_{b} is, at each occurrence identically or differently, selected from the following structure: 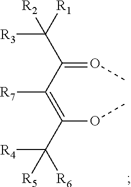
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one or two of R₁ to R₃ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one or two of R₄ to R₆ is(are), at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof;
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

11. The metal complex of claim 1, wherein L_{b} is, at each occurrence identically or differently, selected from the group consisting of the following structures: 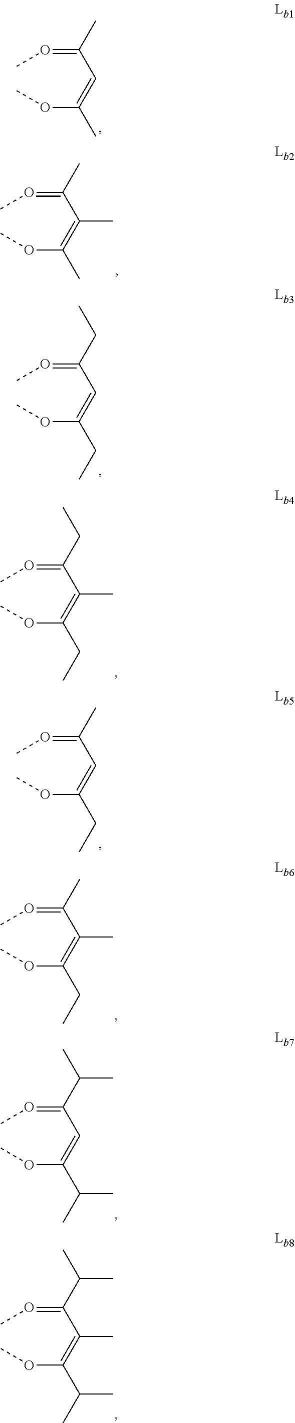 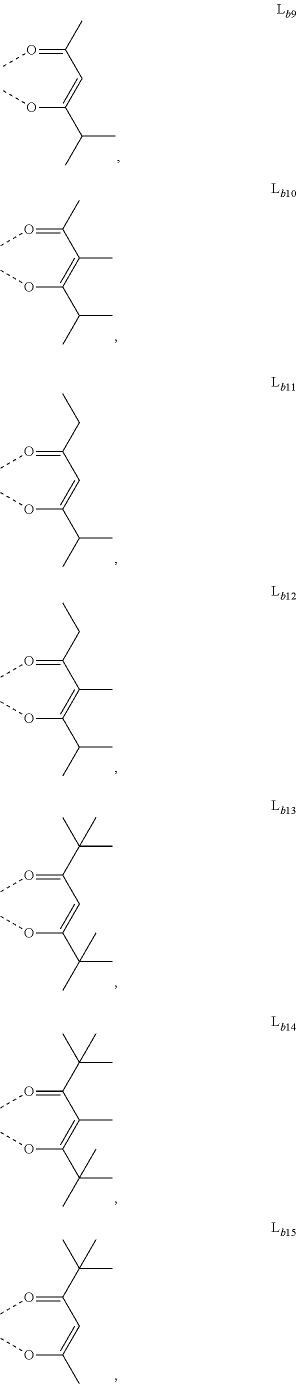 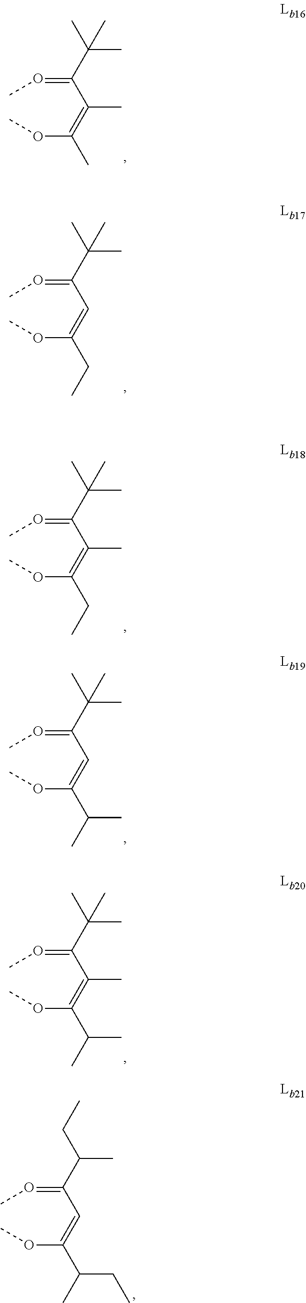 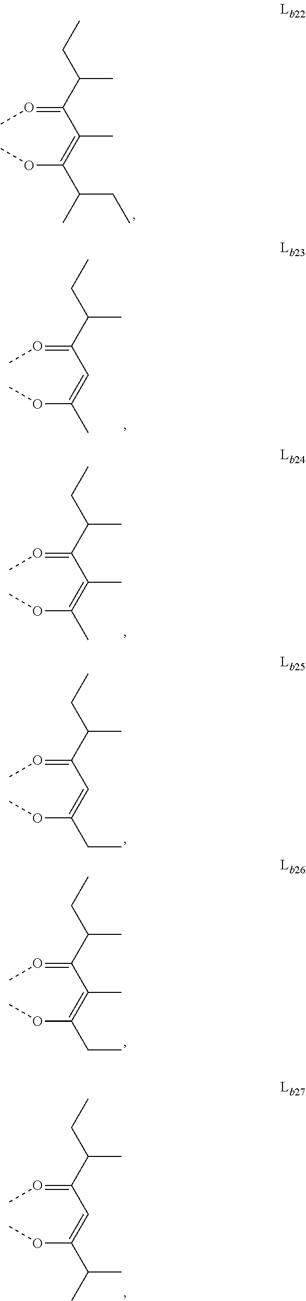 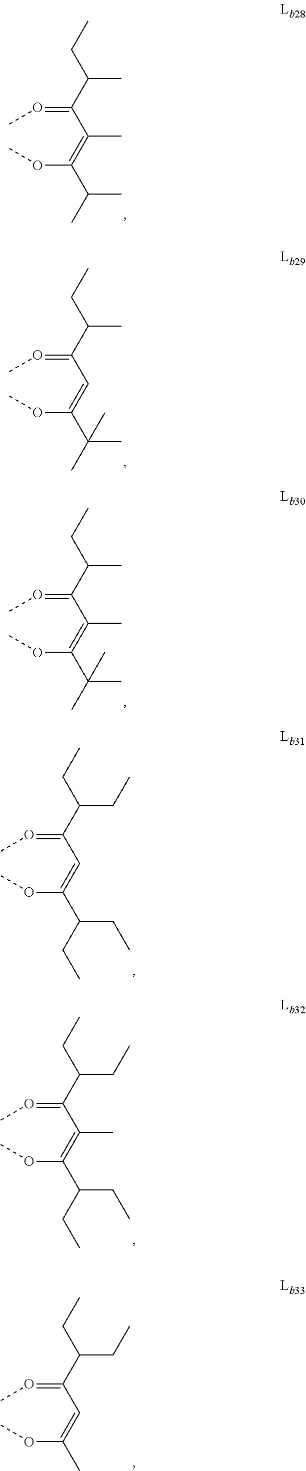 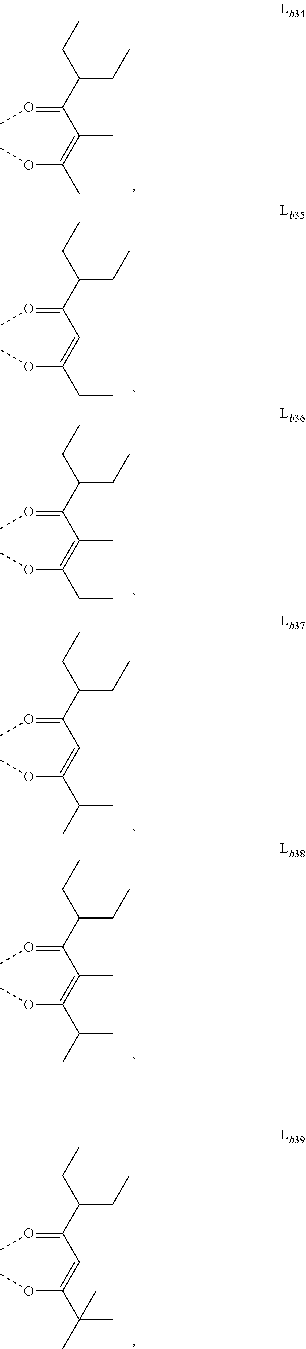 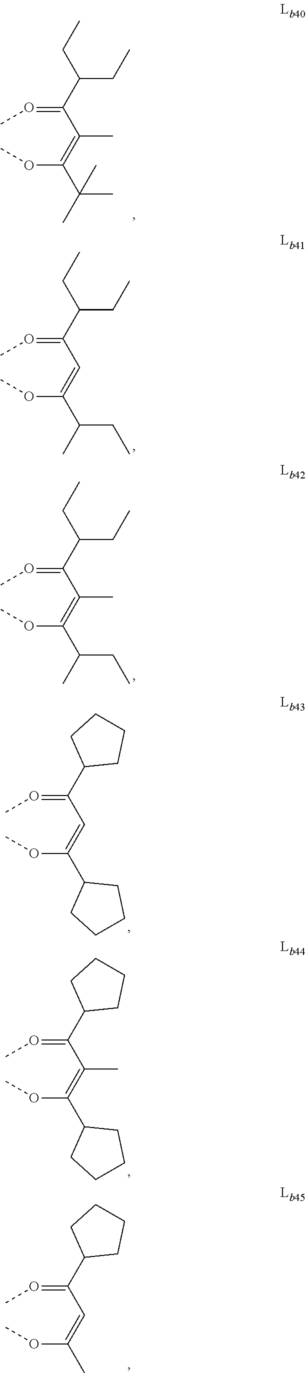 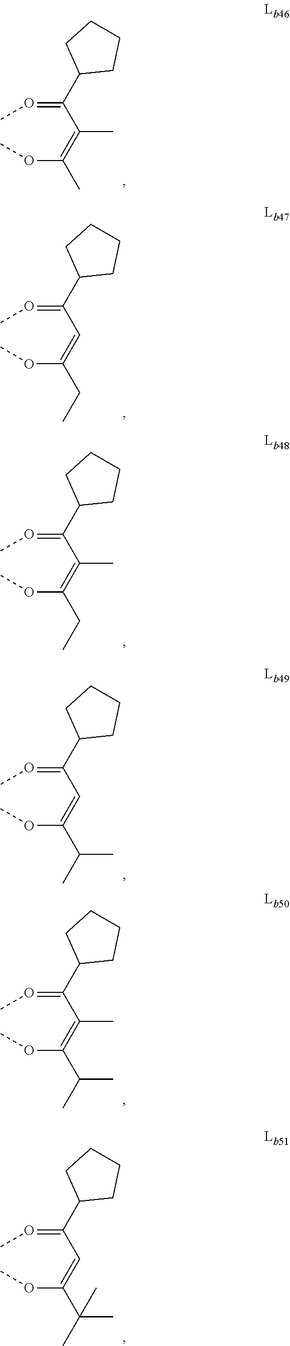 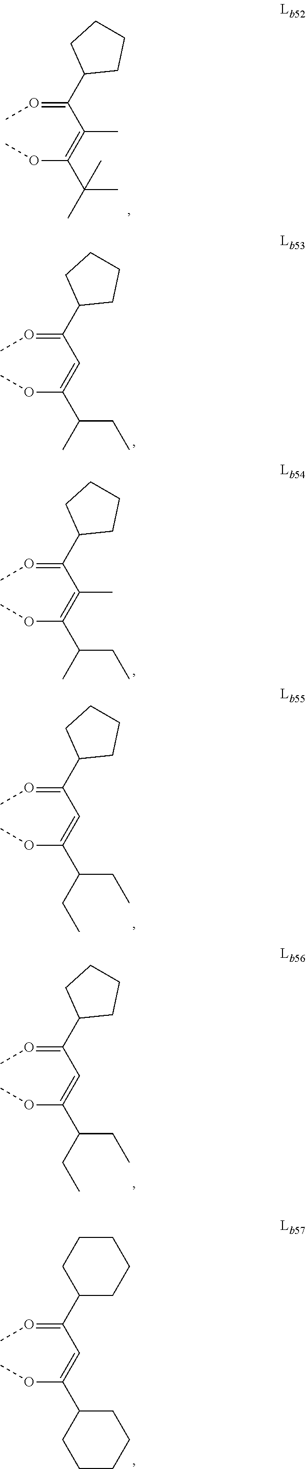 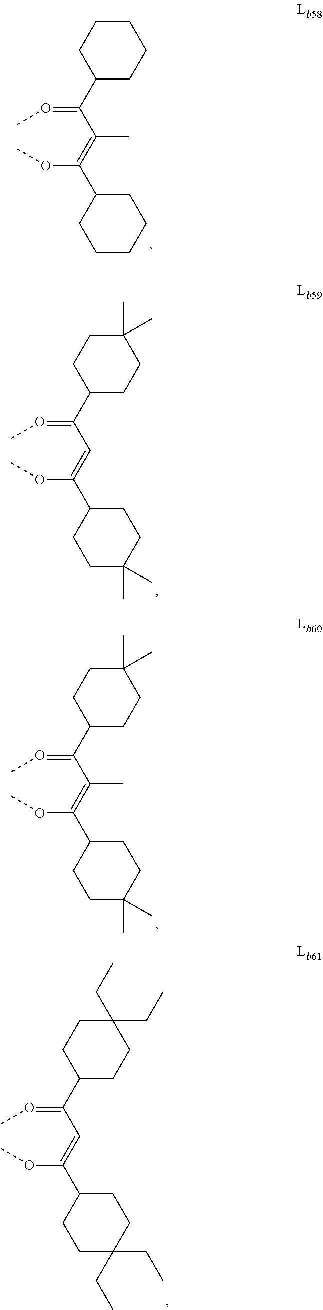 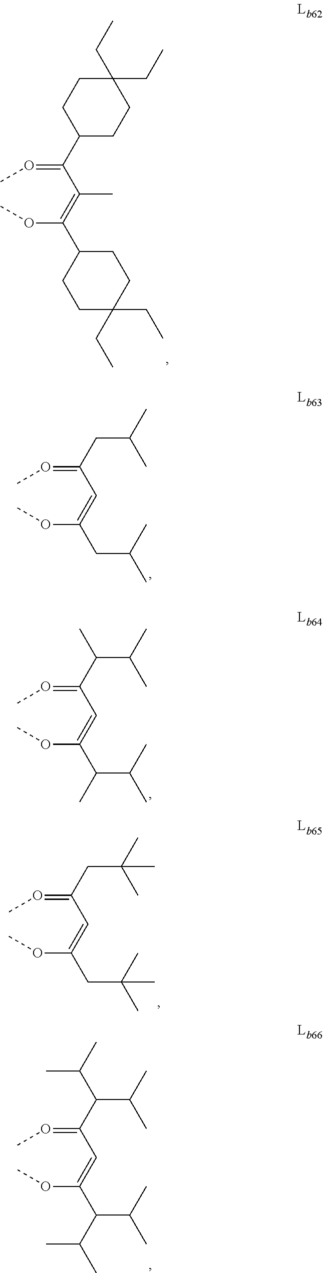 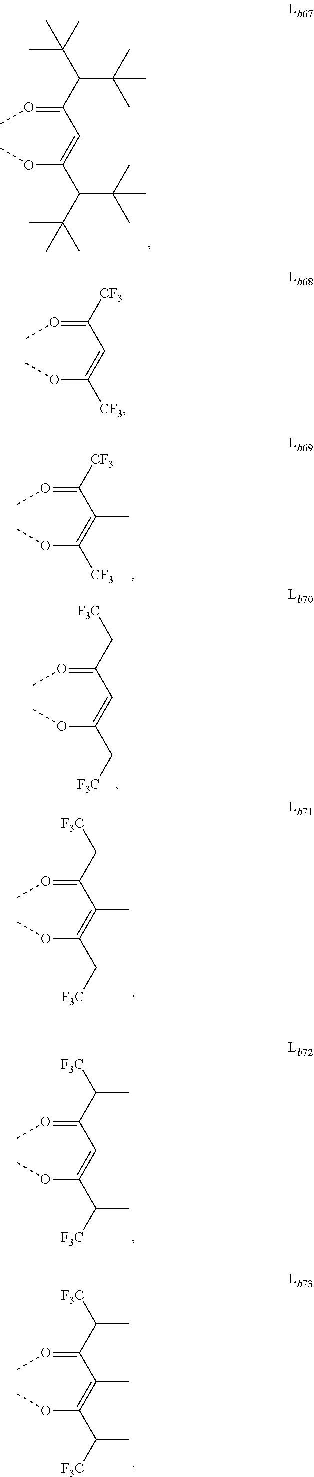 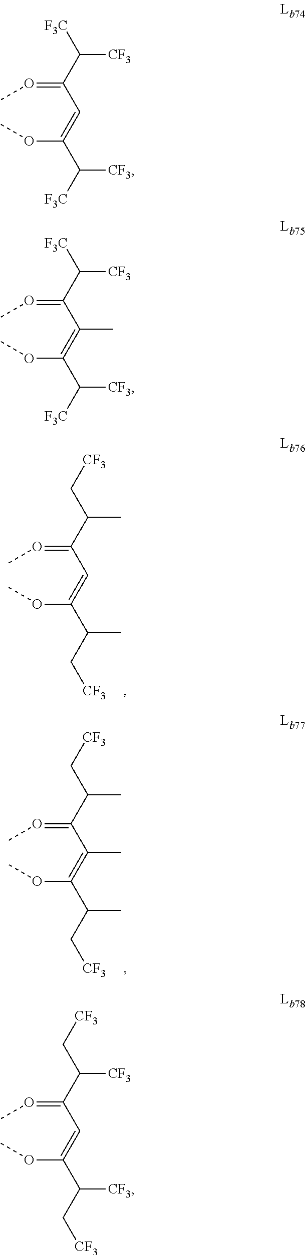 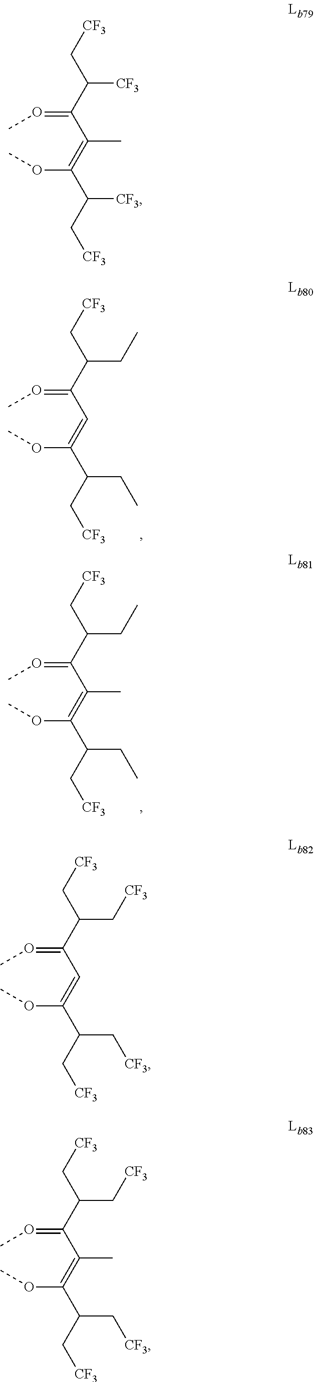 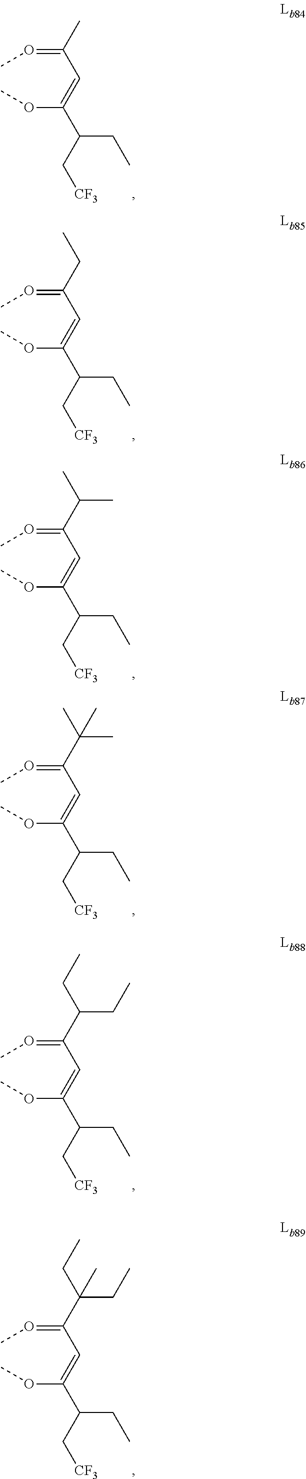 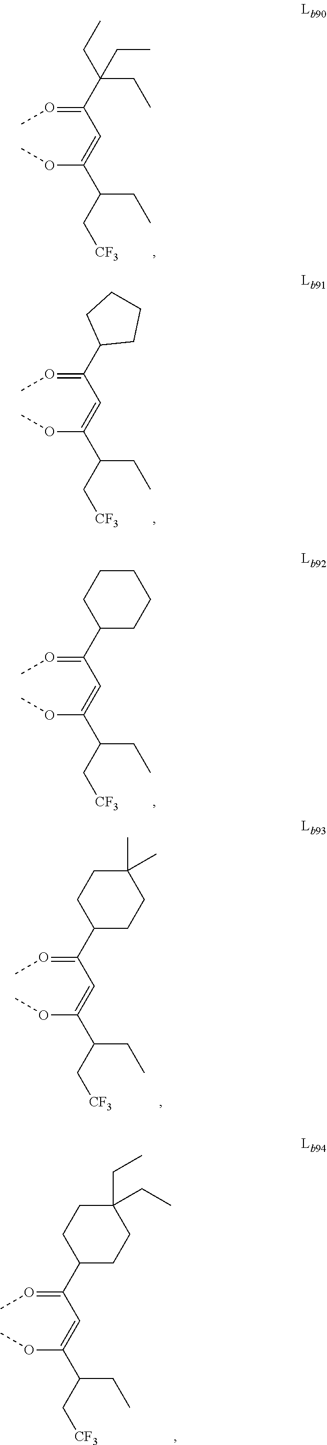 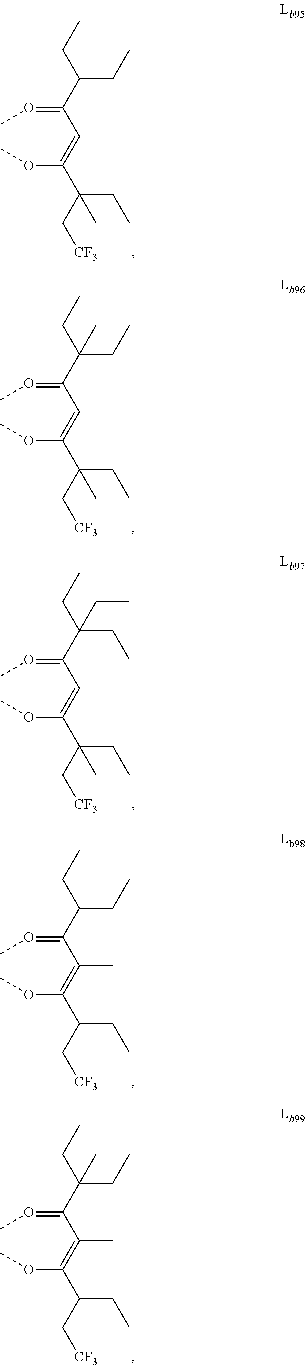 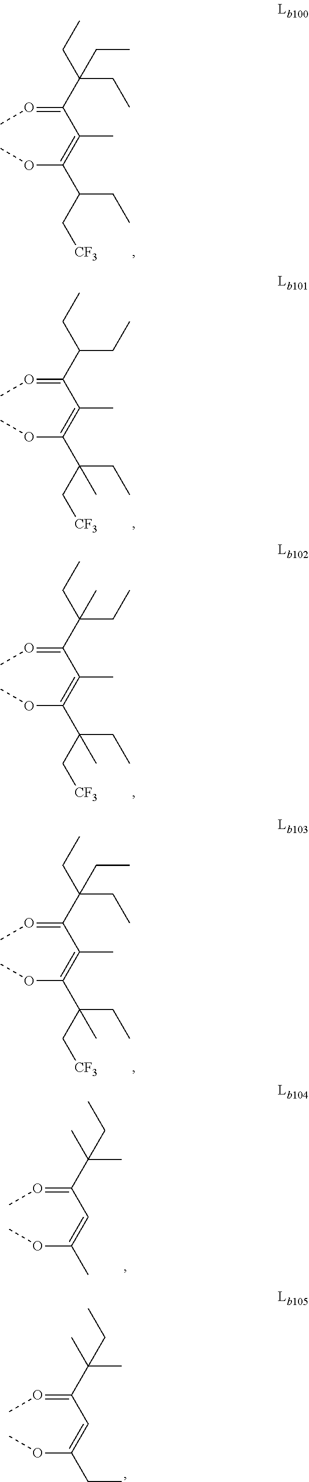 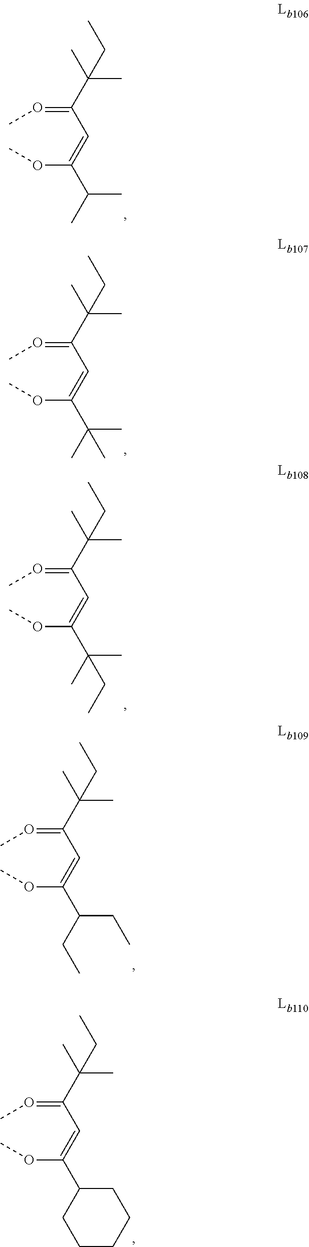 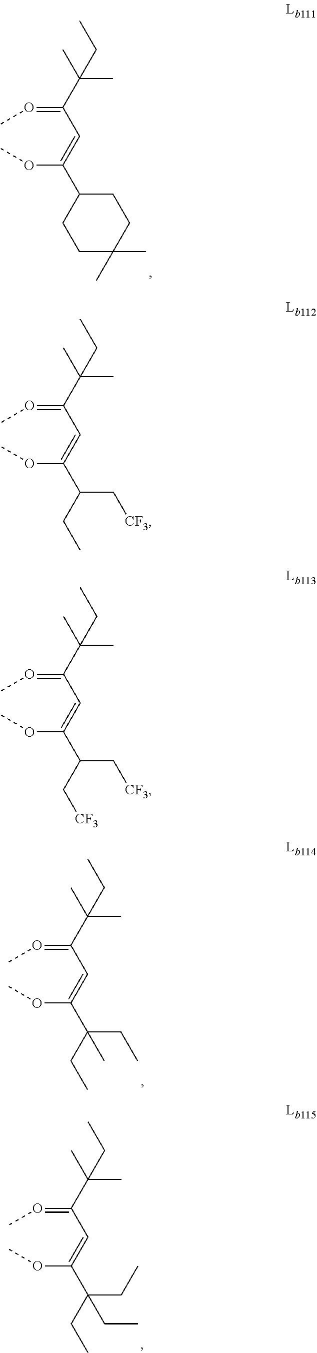 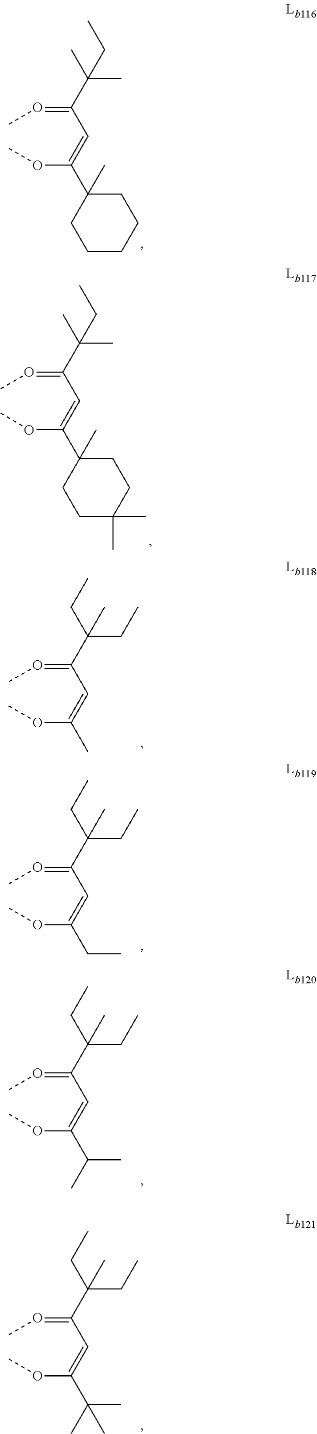 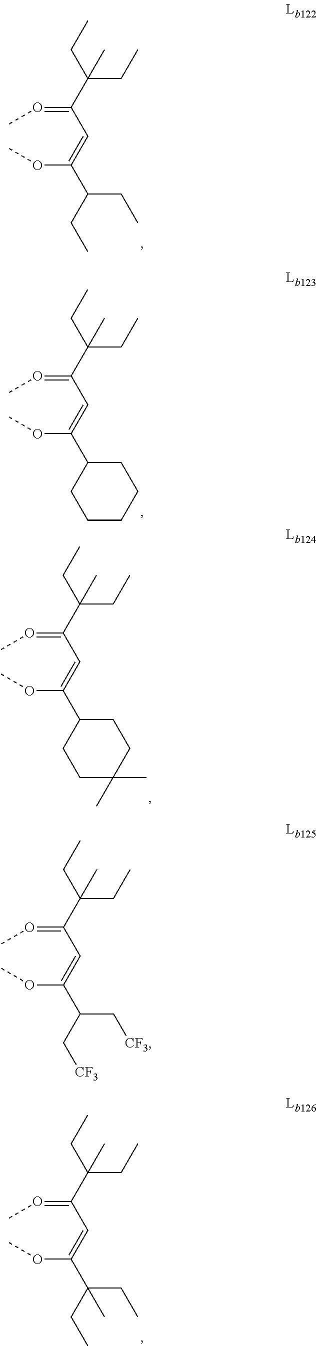 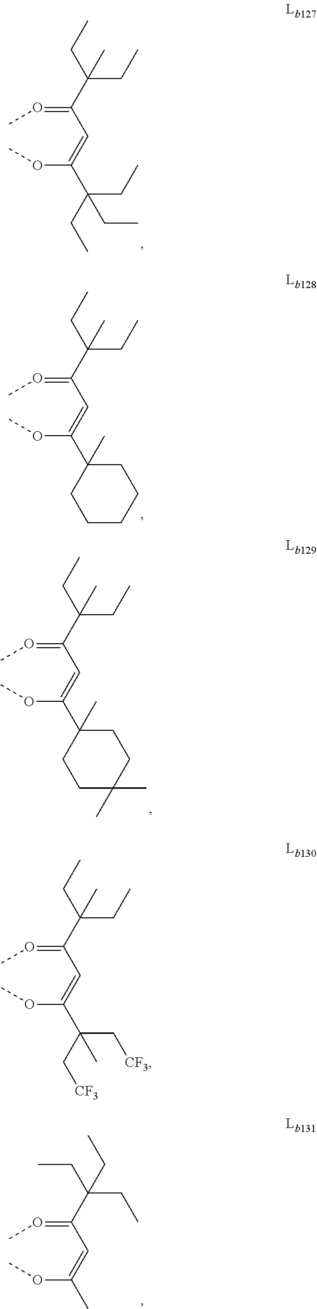 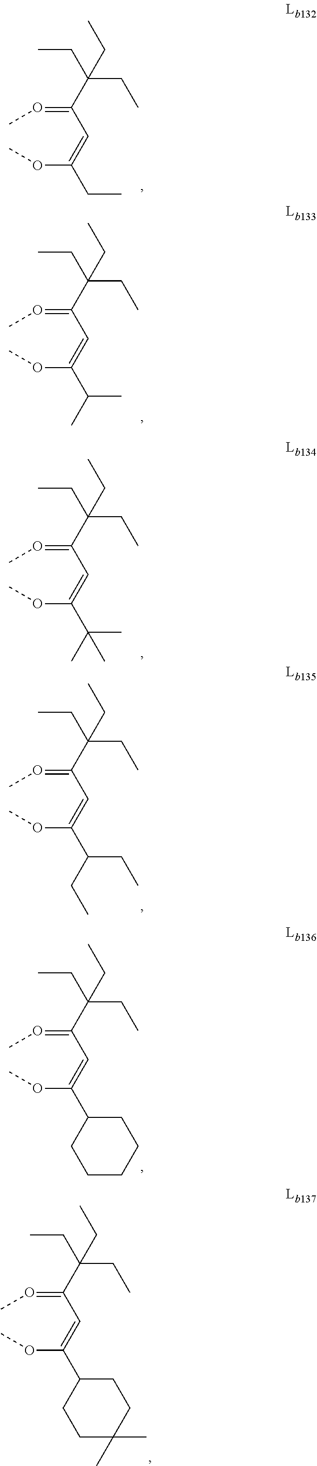 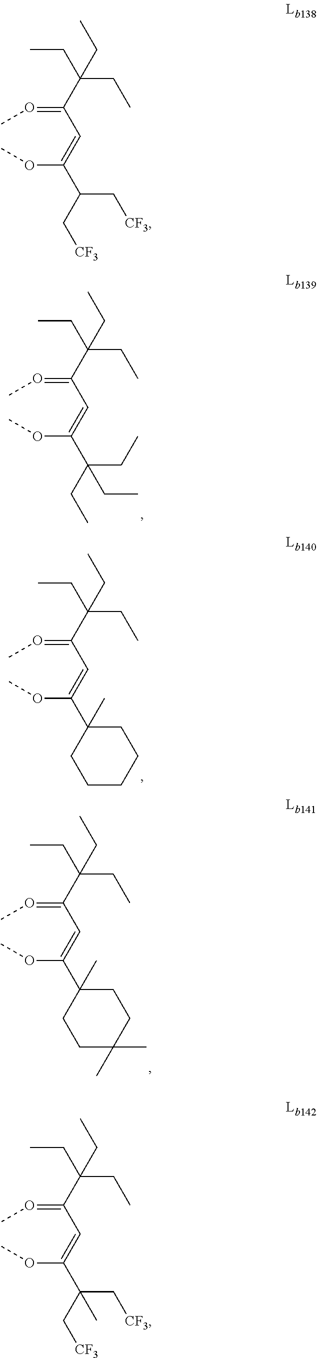 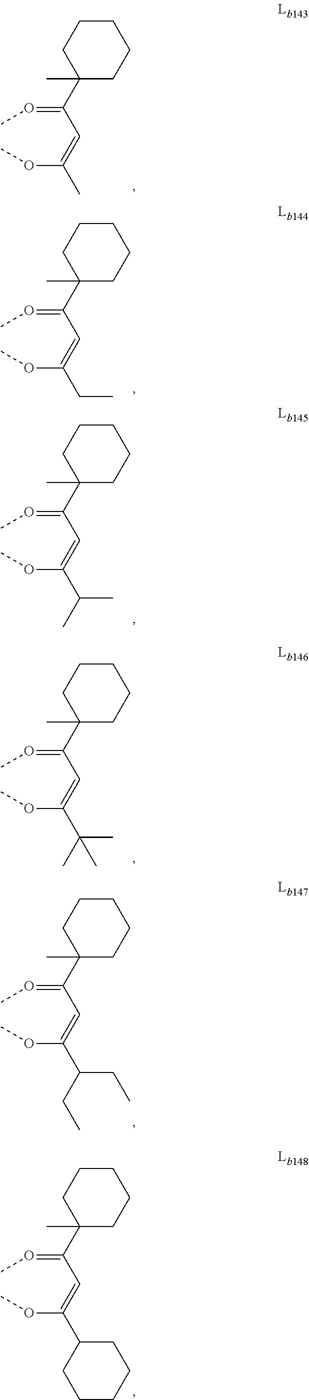 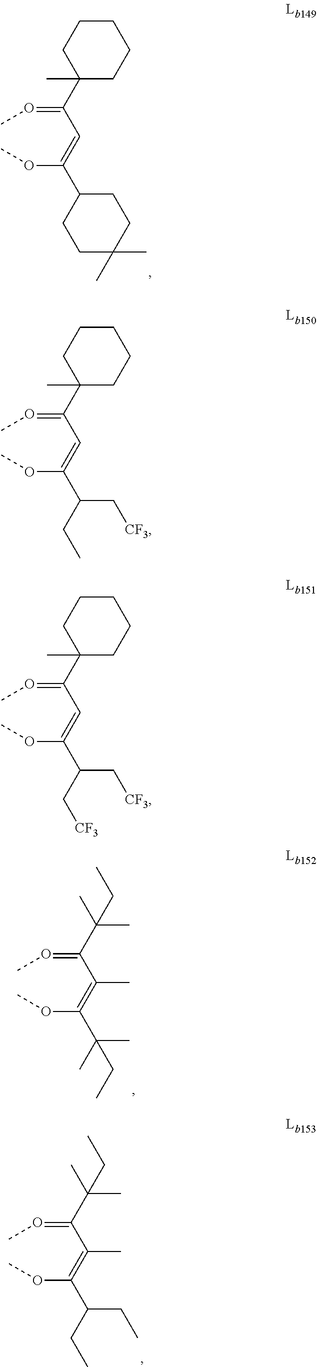 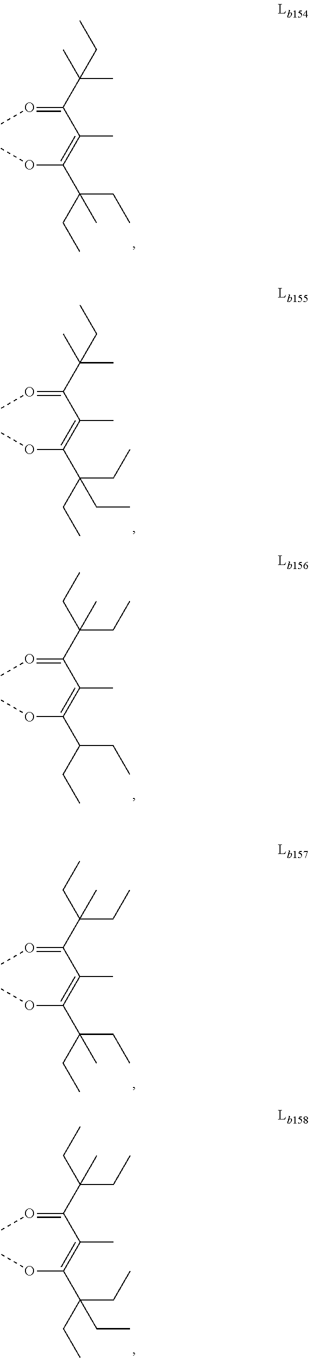 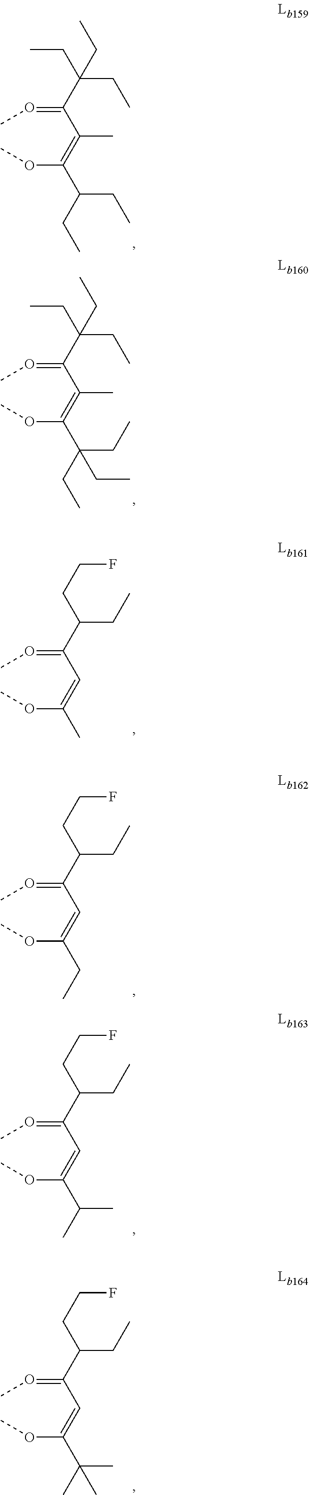 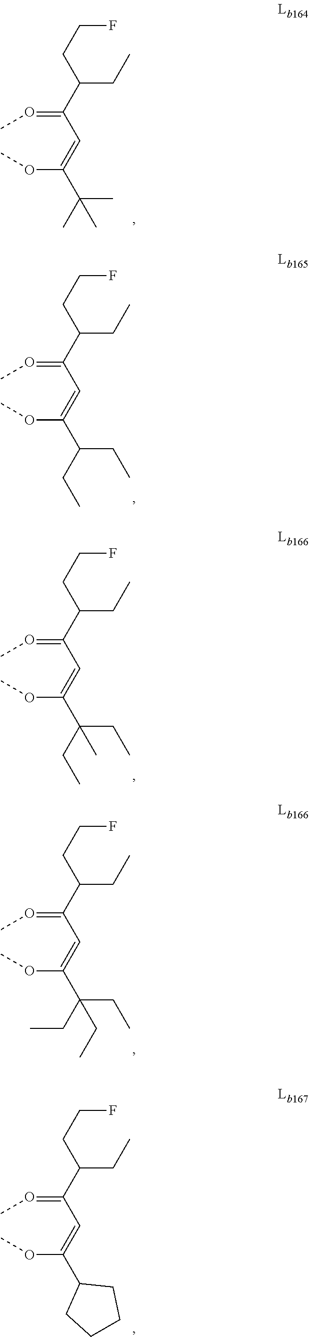 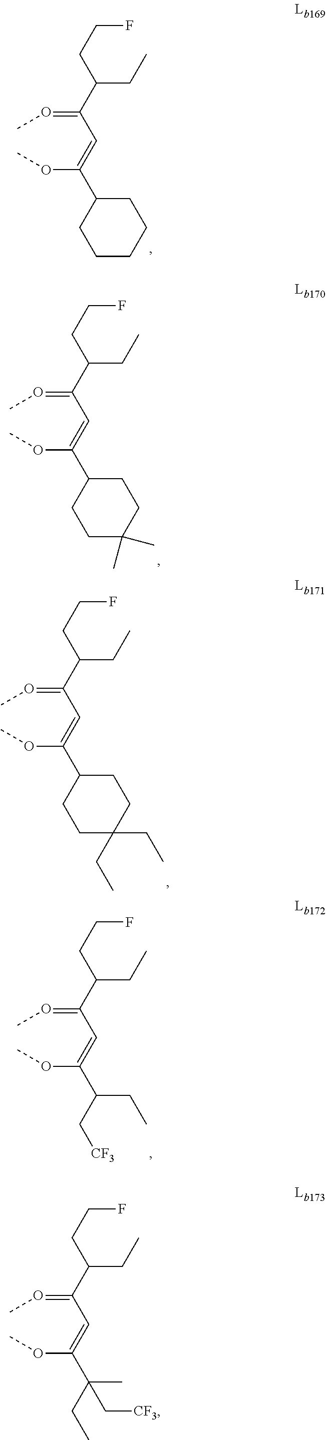 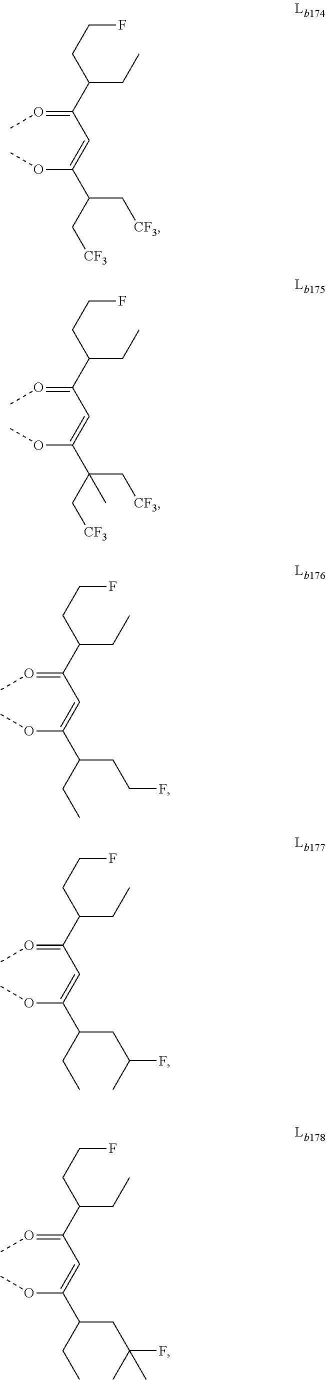 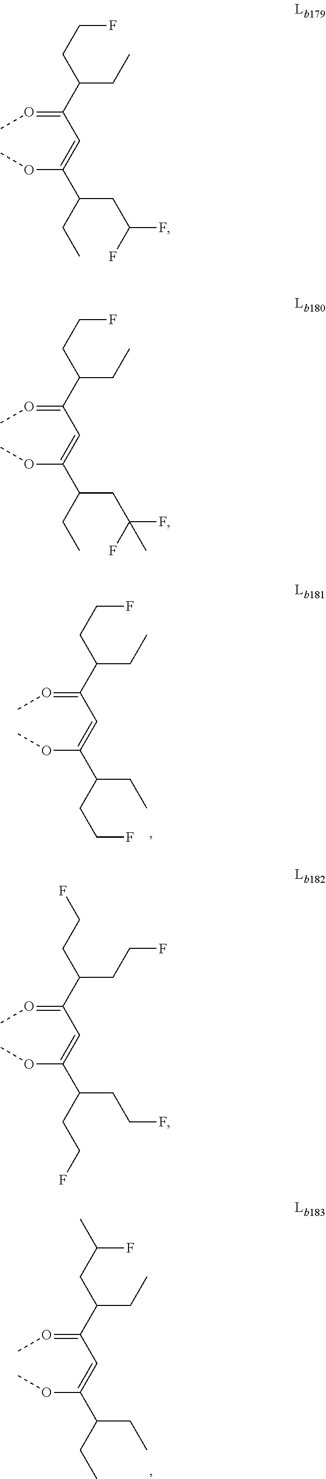 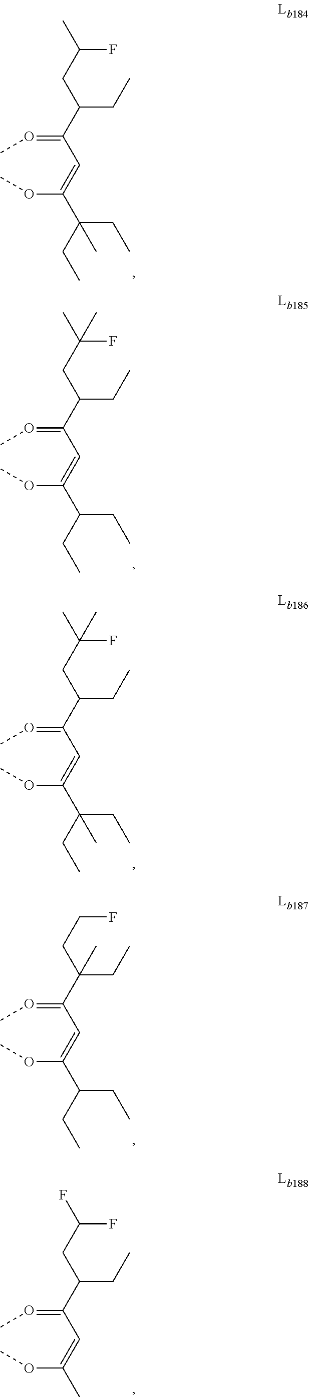 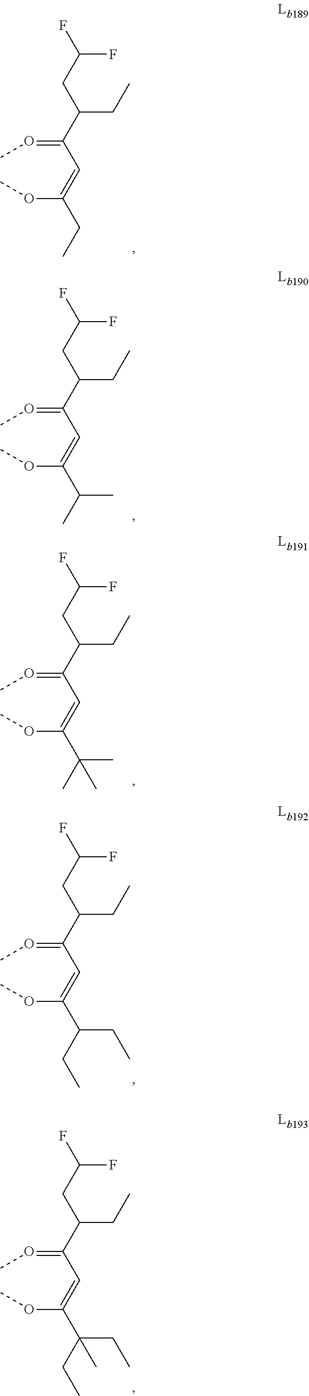 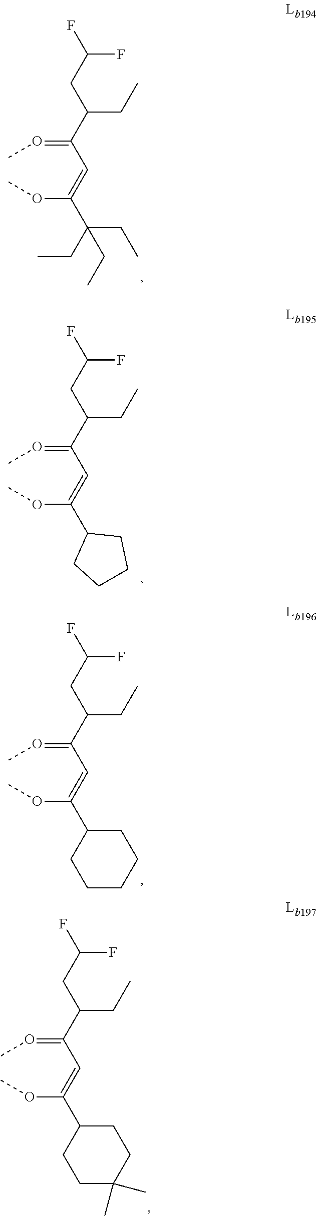 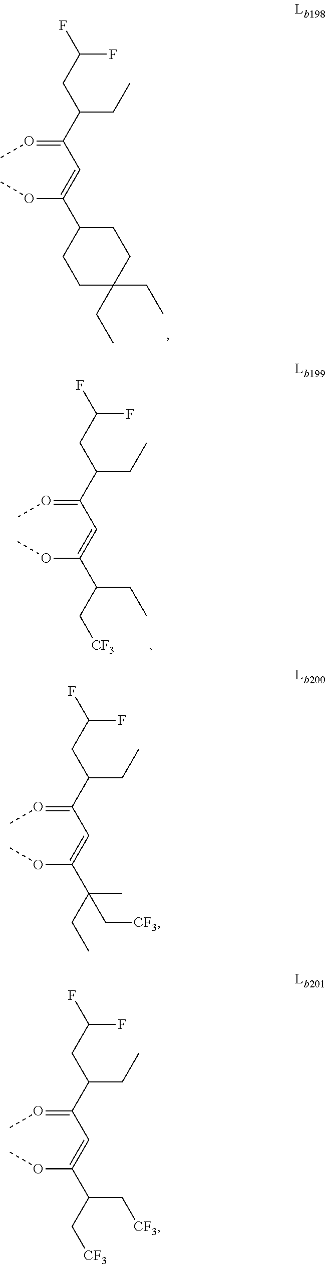 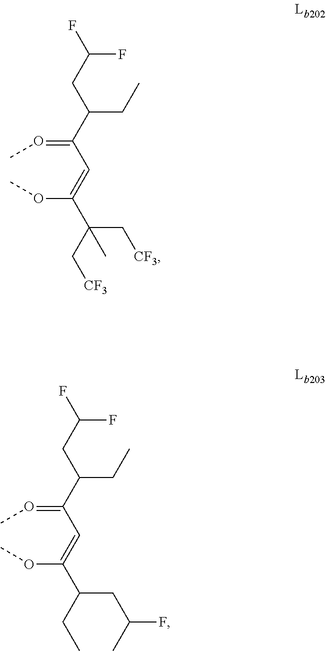 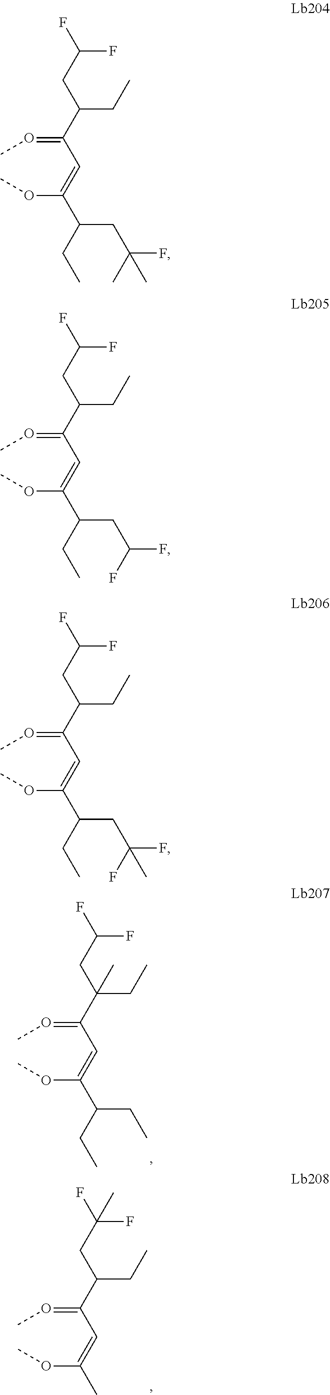 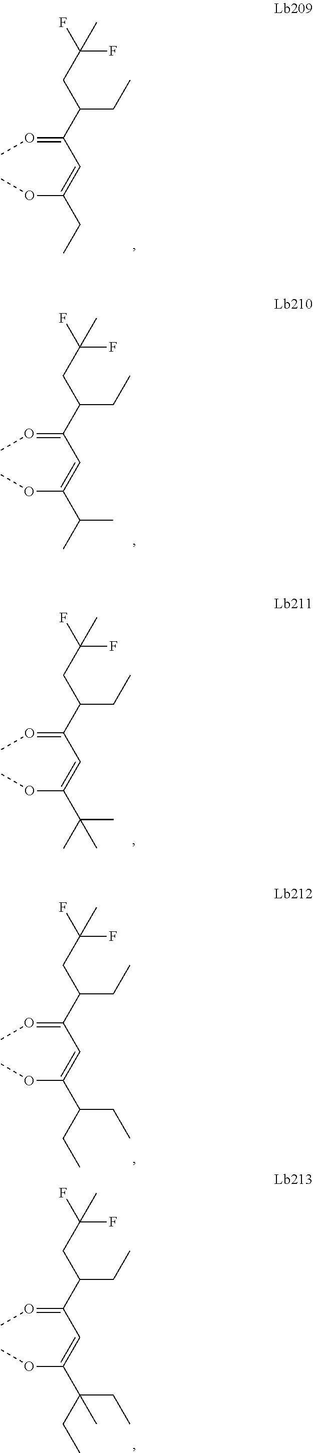 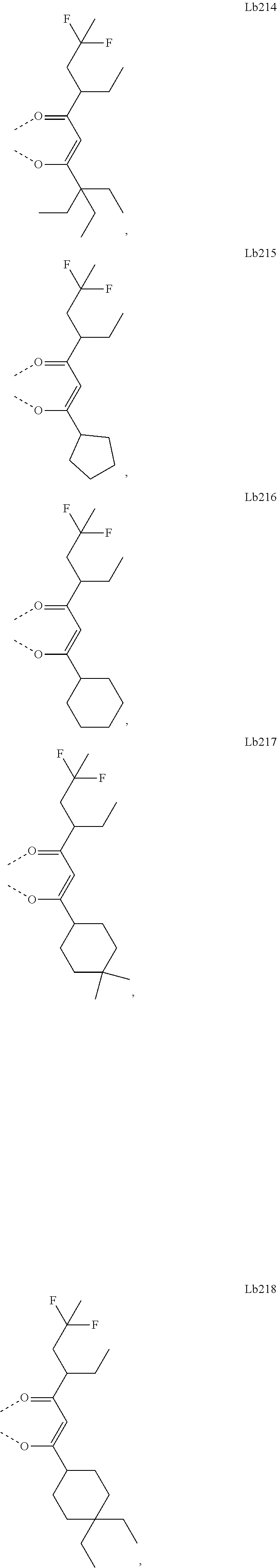 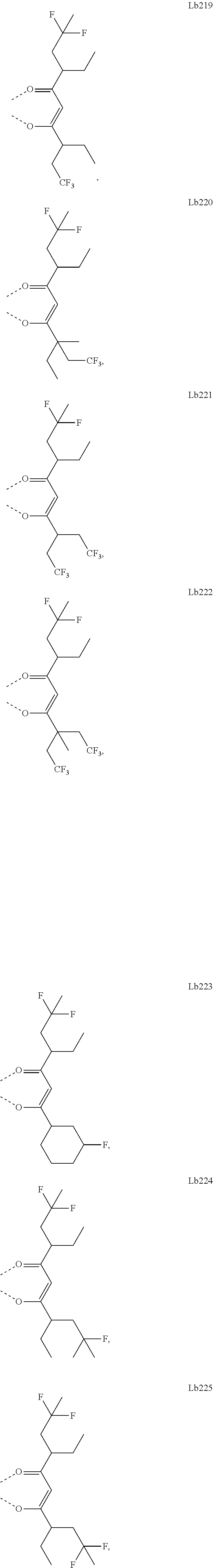 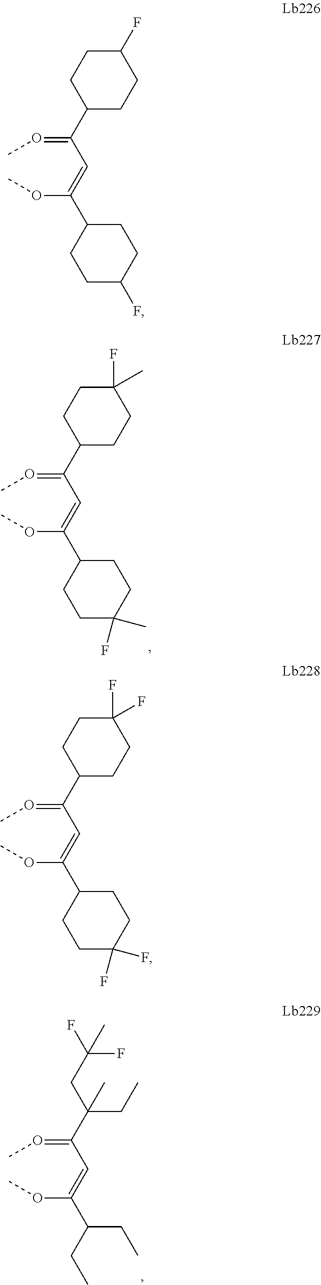 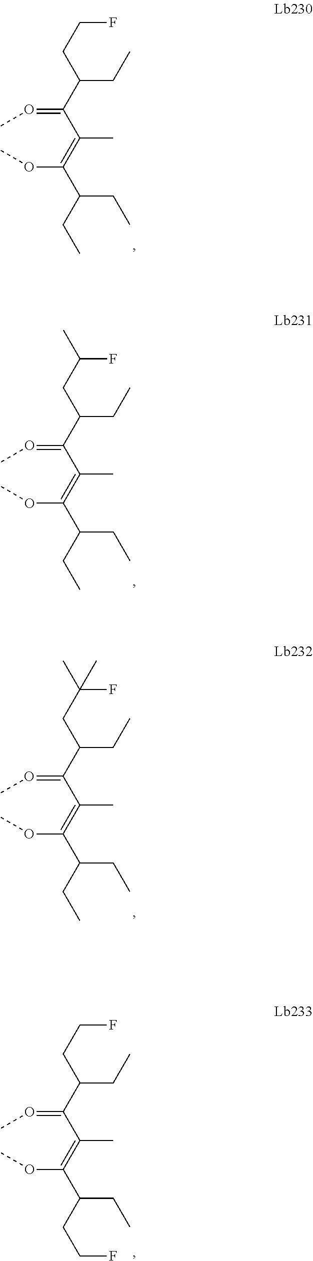 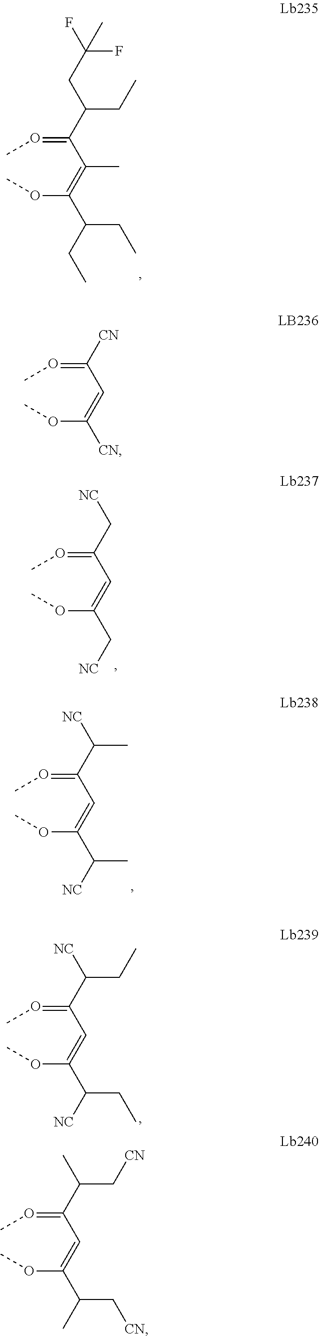 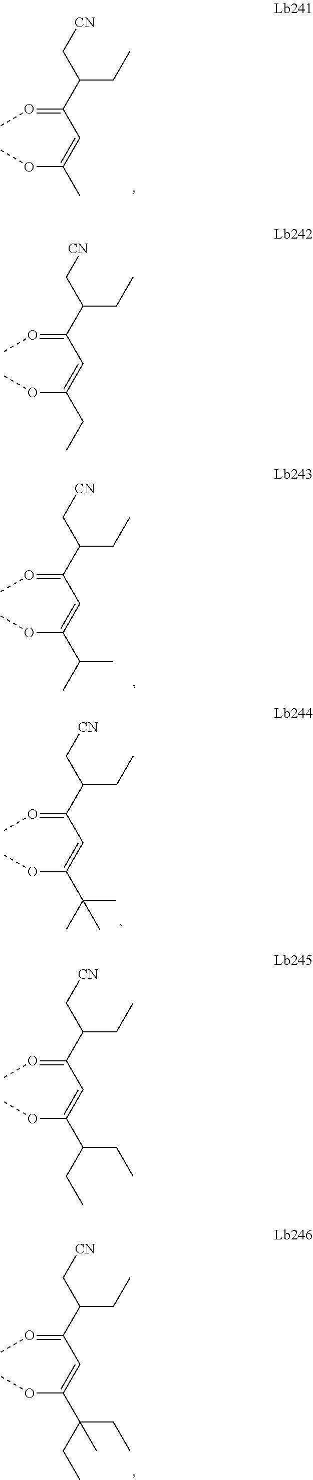 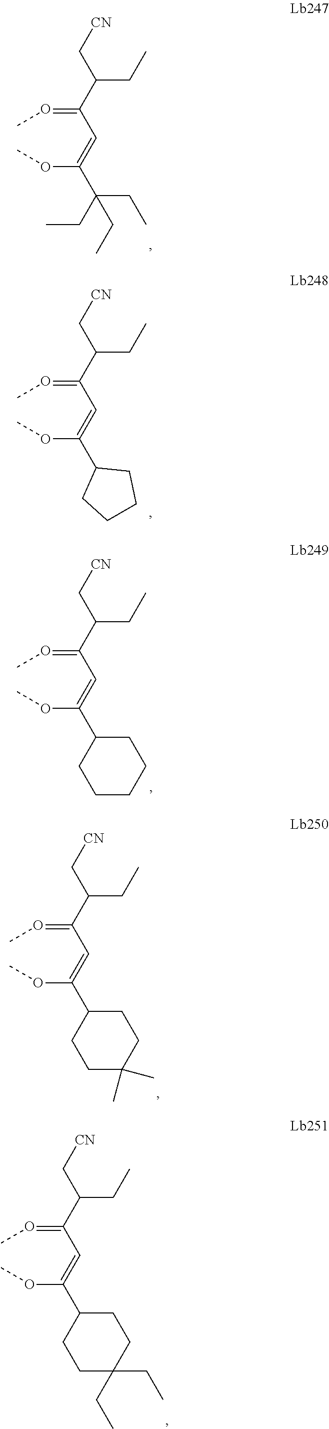 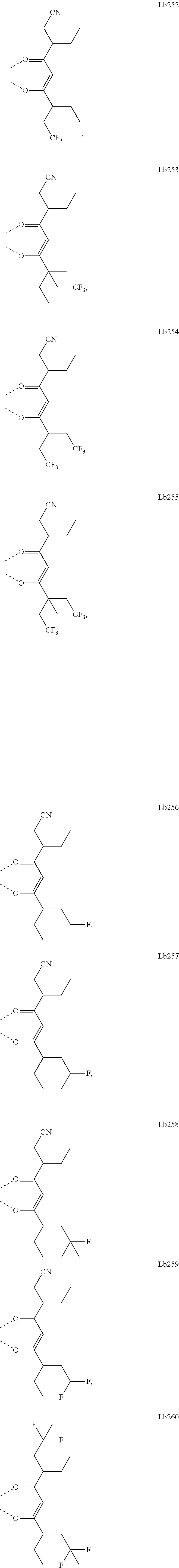 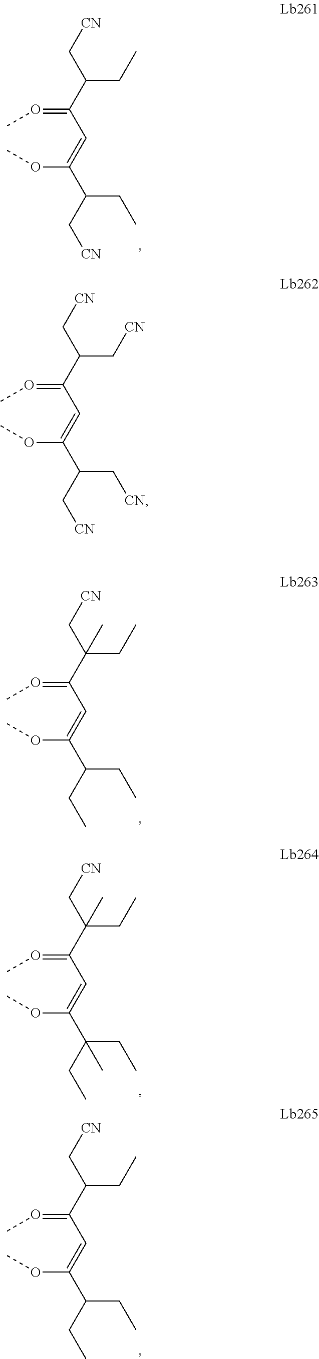 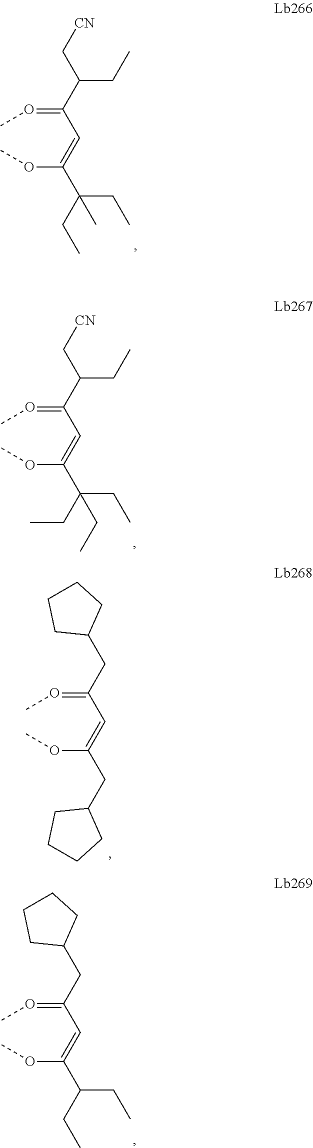 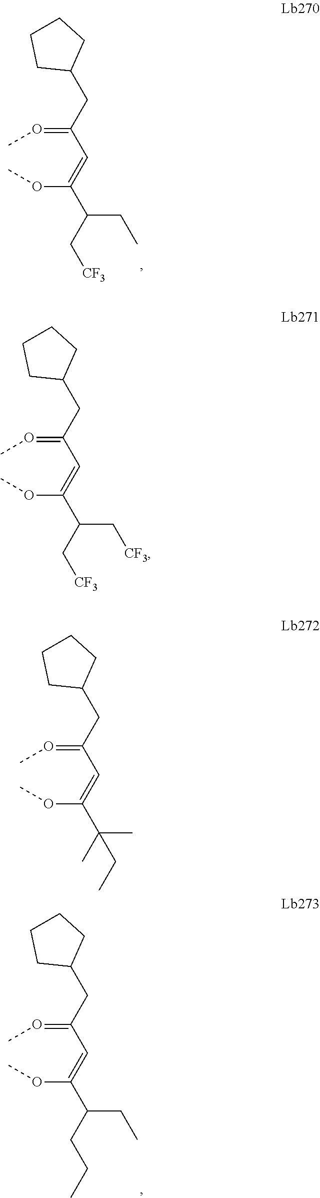 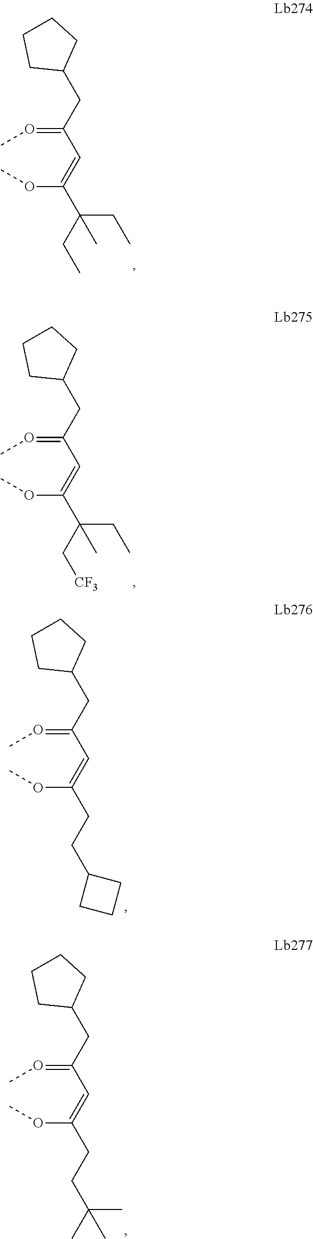 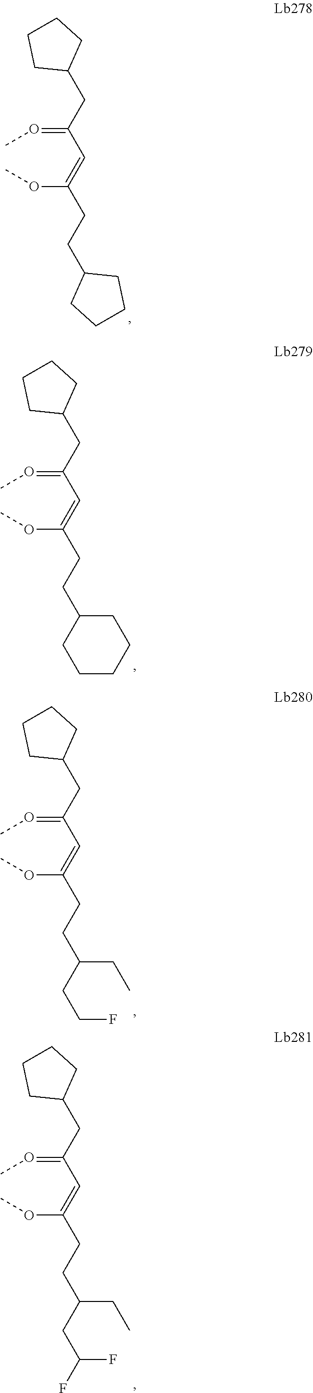 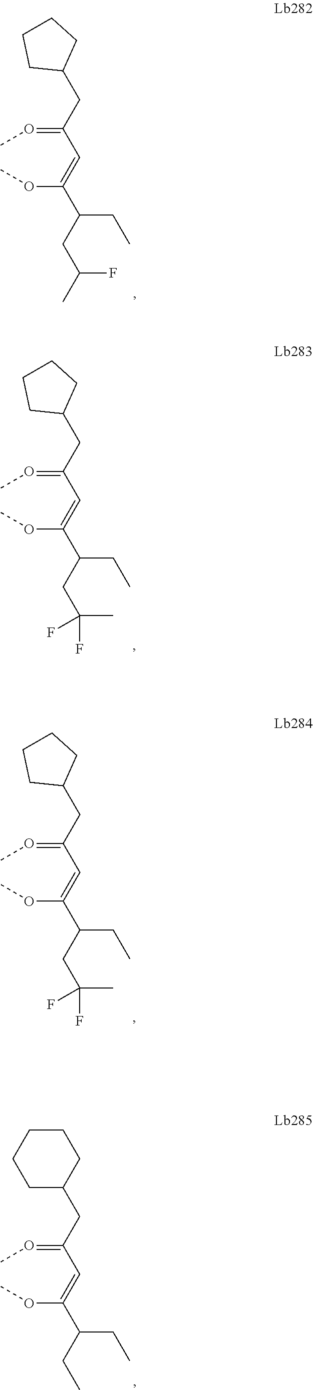 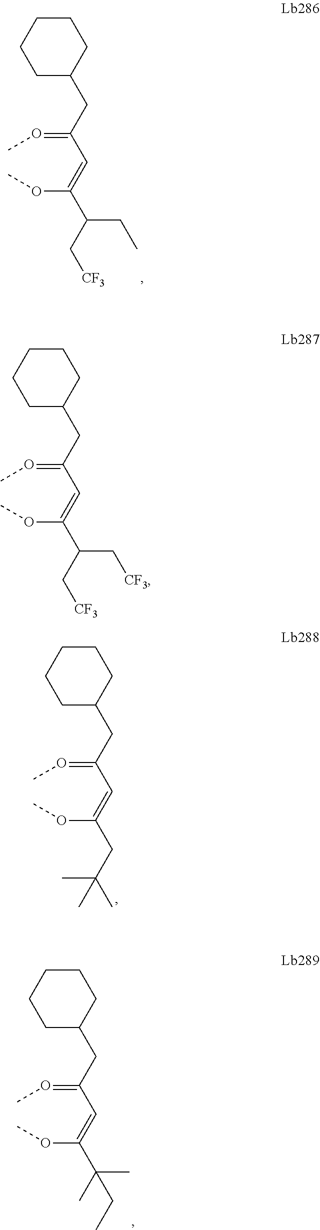 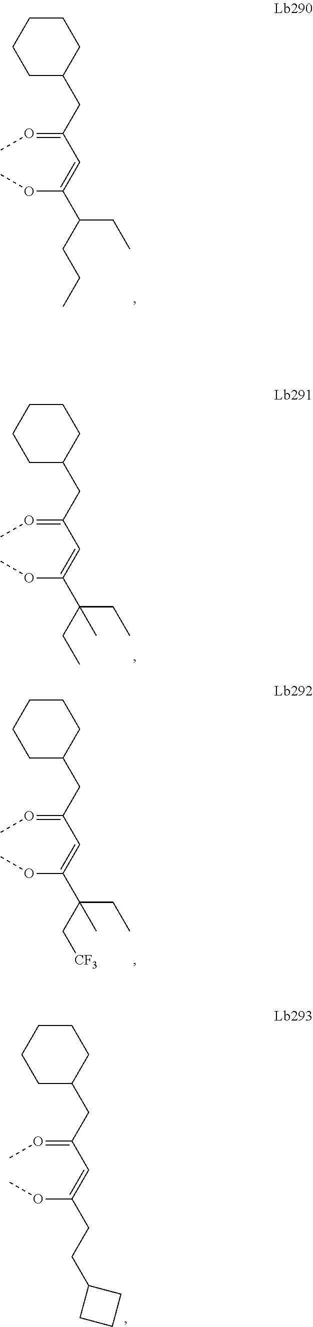 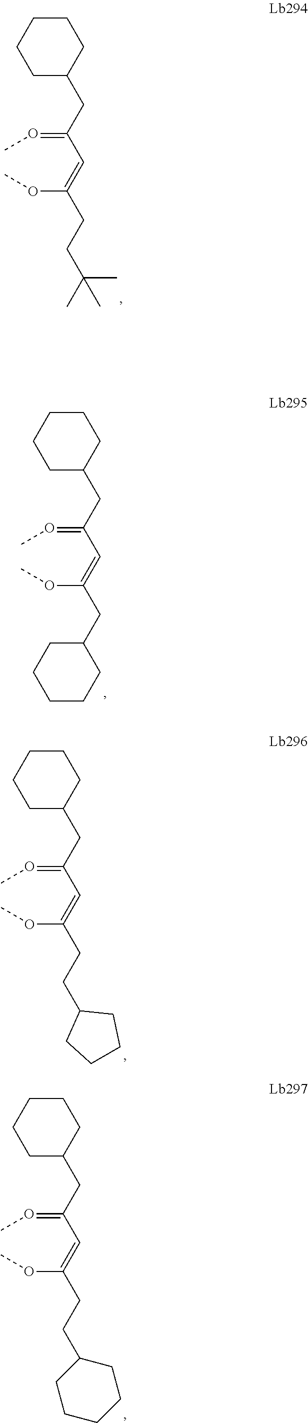 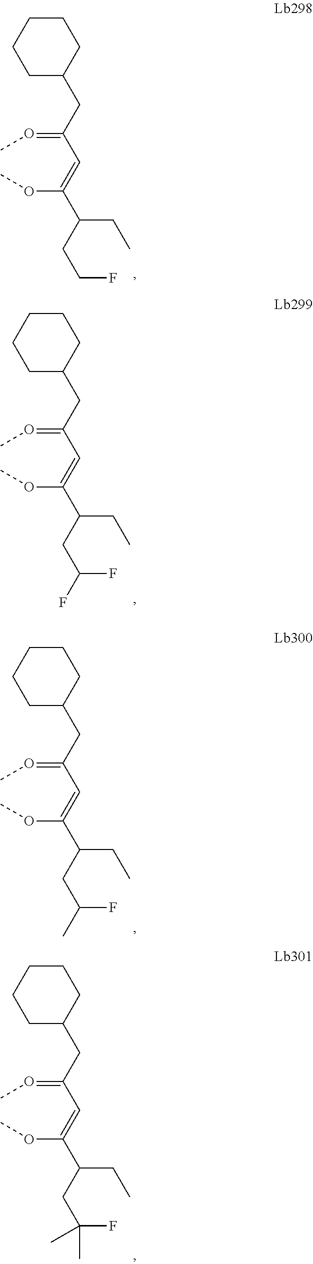 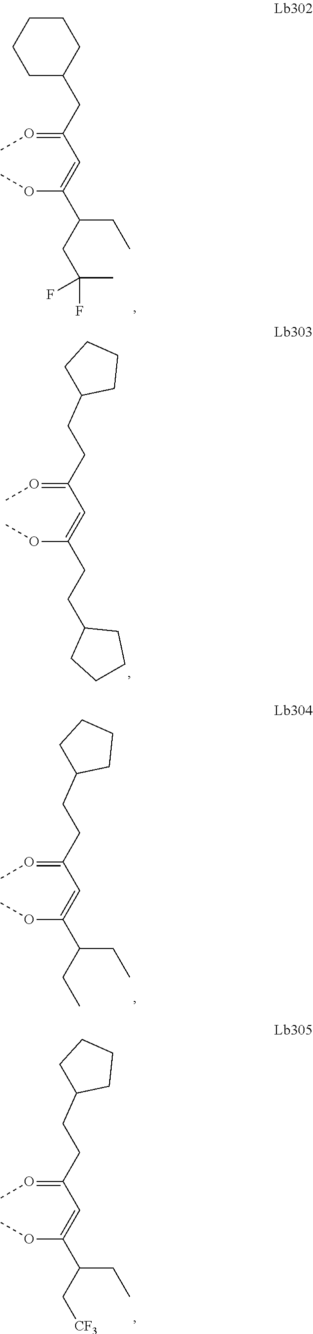 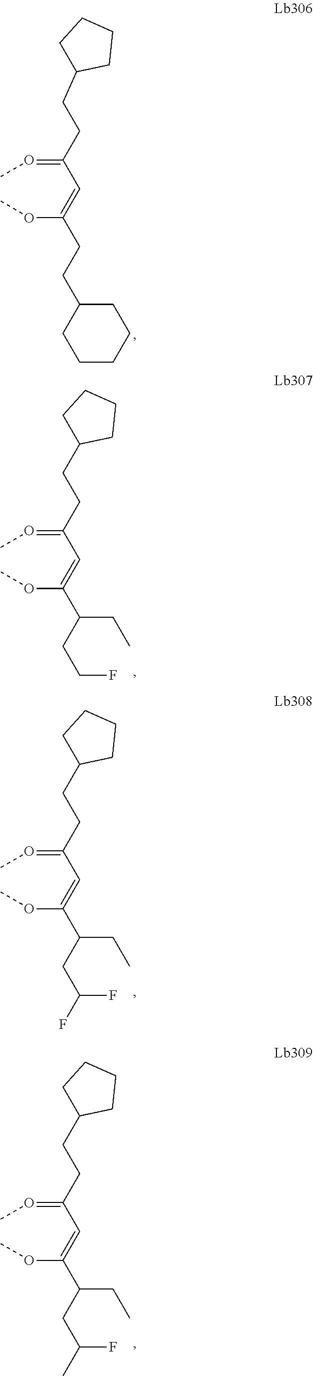 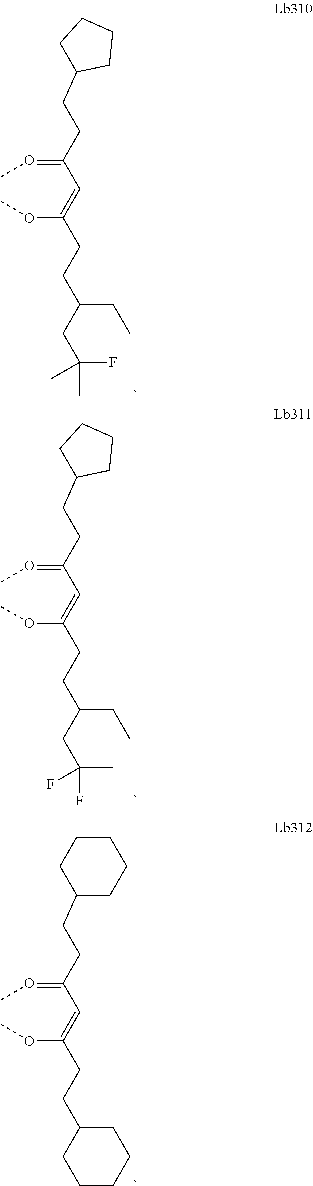 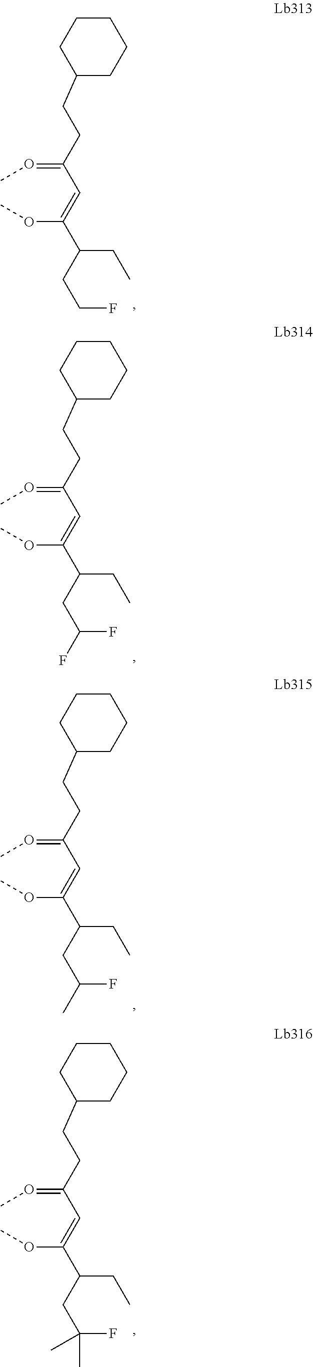 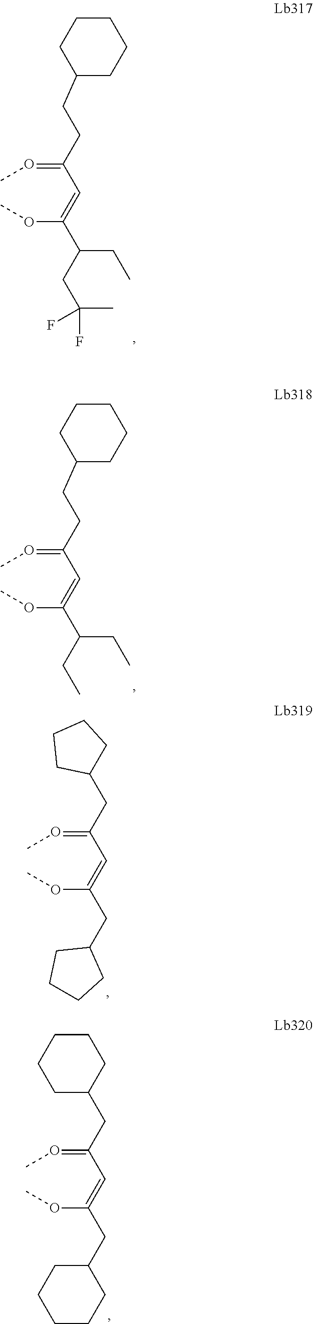 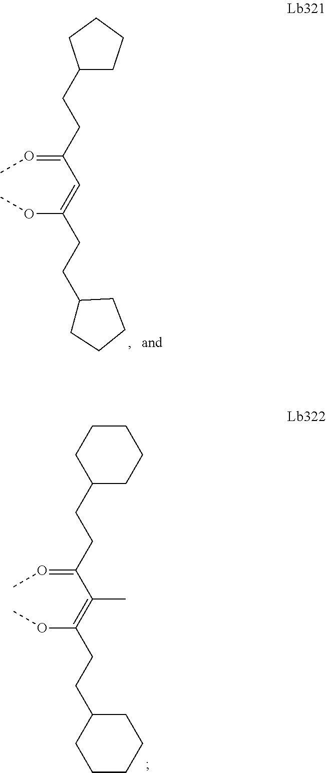
wherein L_{c} is, at each occurrence identically or differently, selected from the group consisting of the following structures:

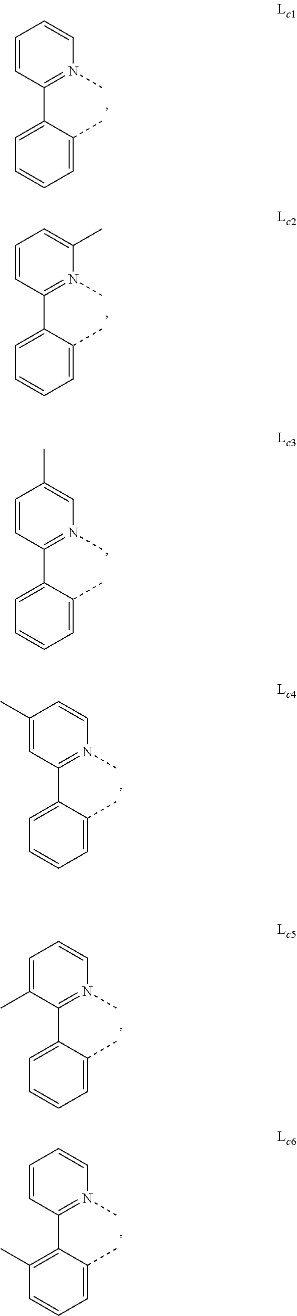

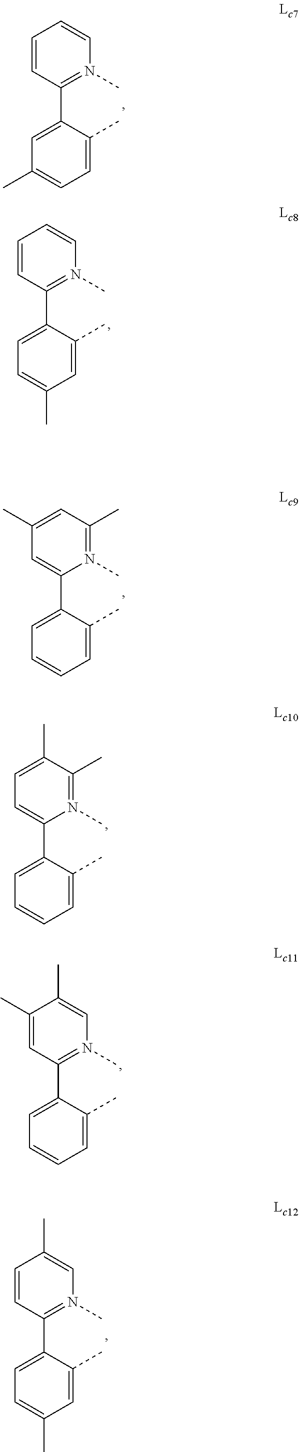

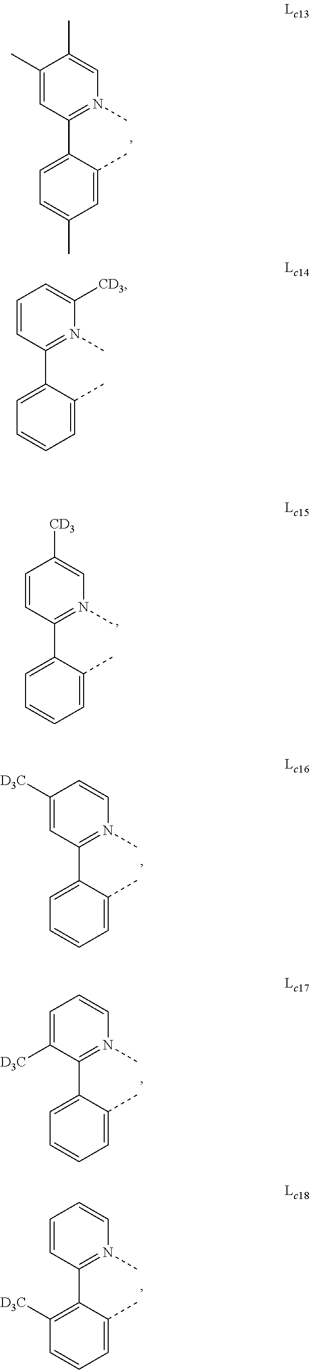

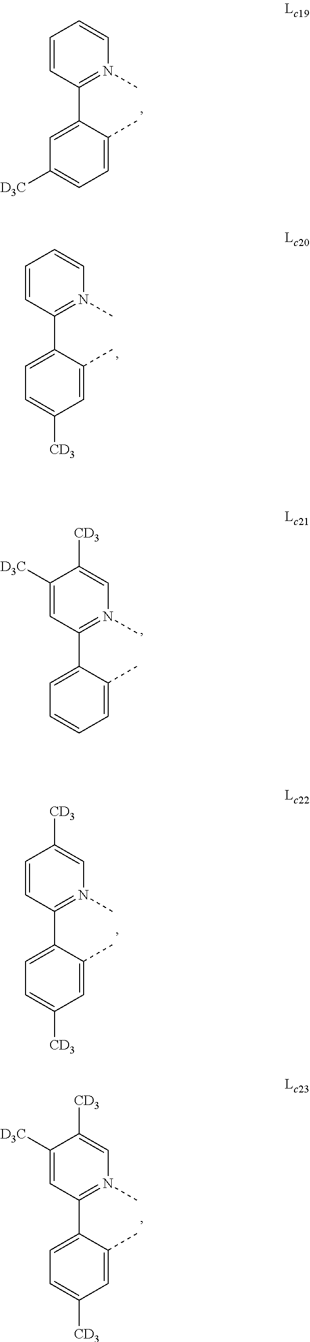

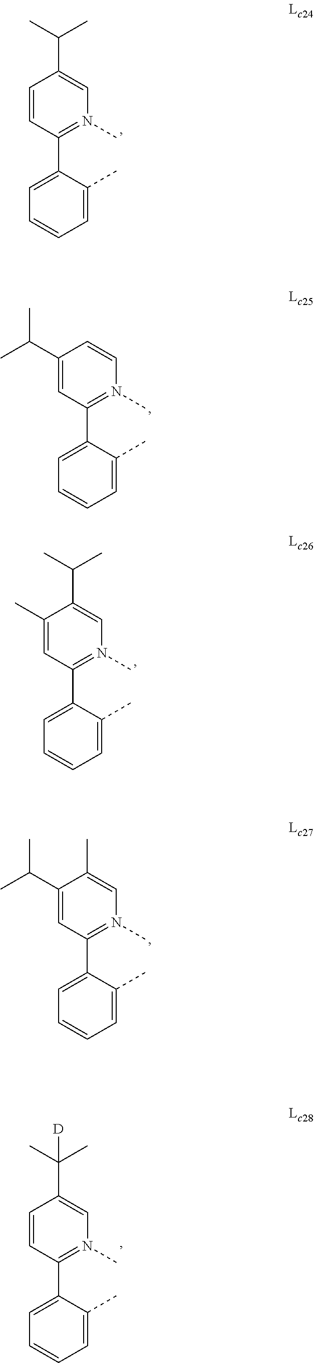

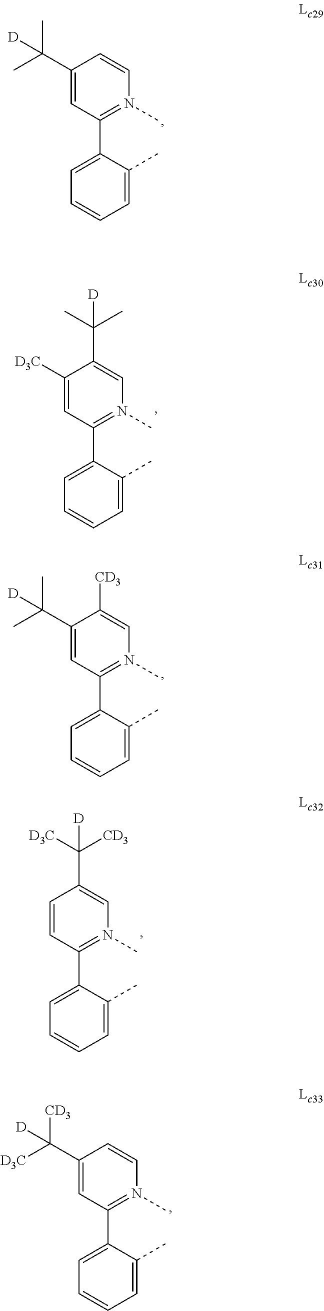

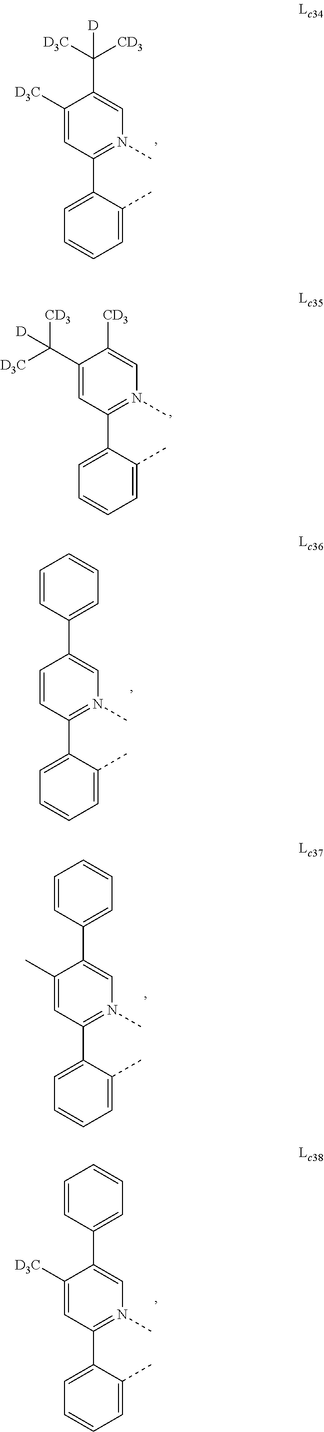

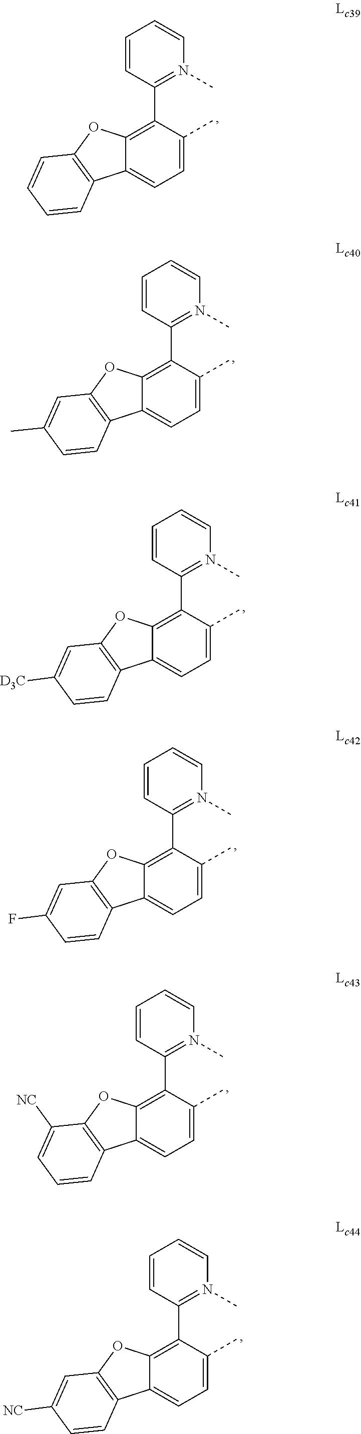

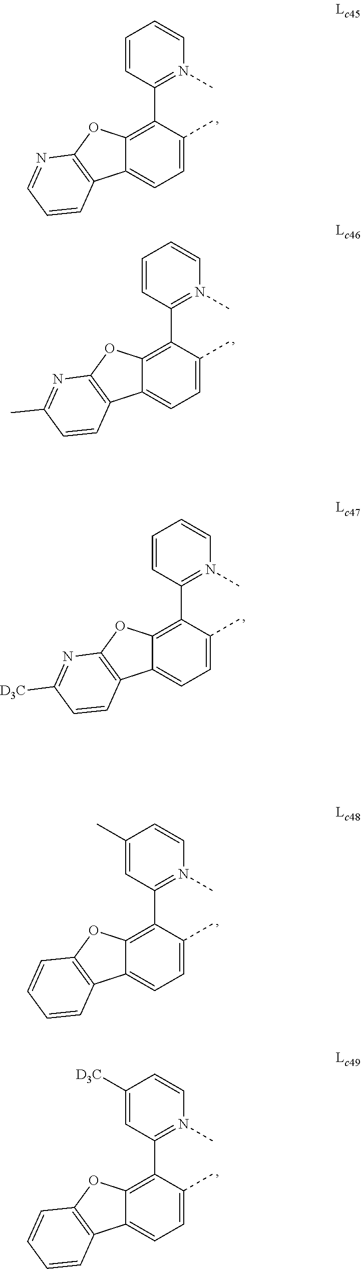

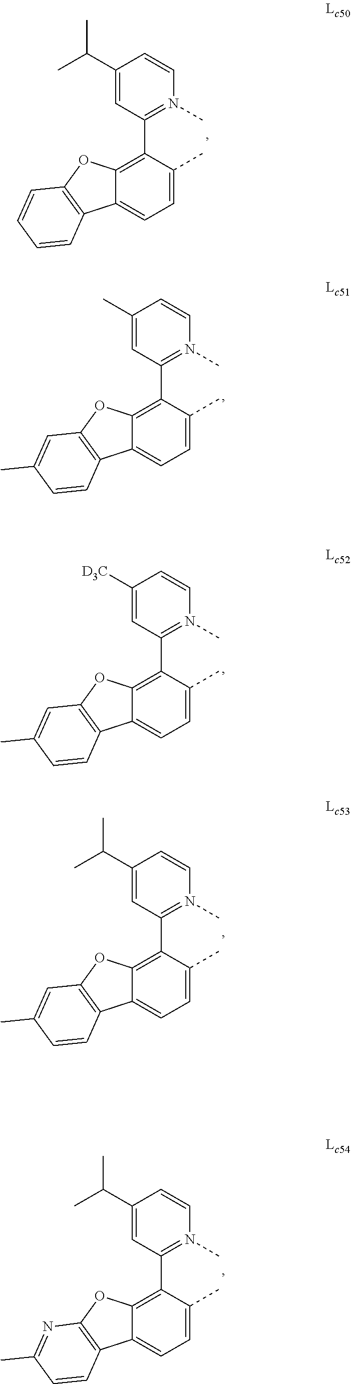

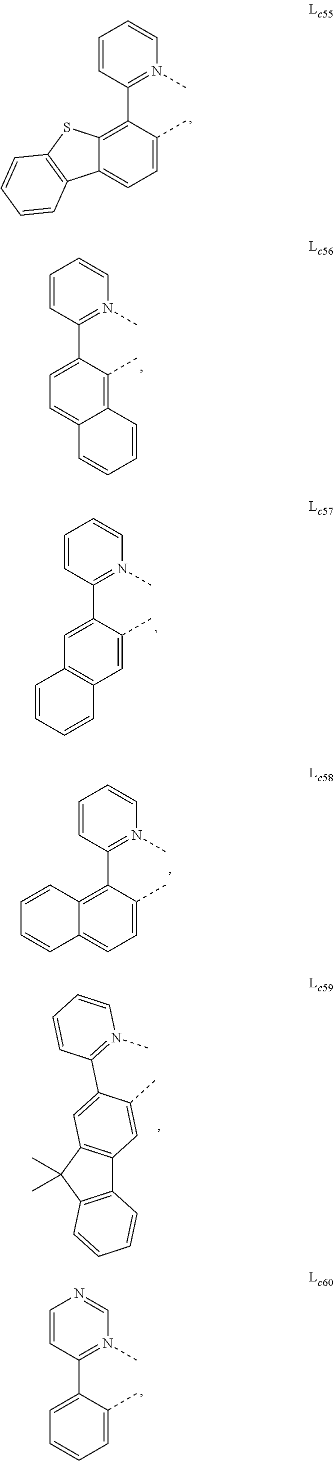

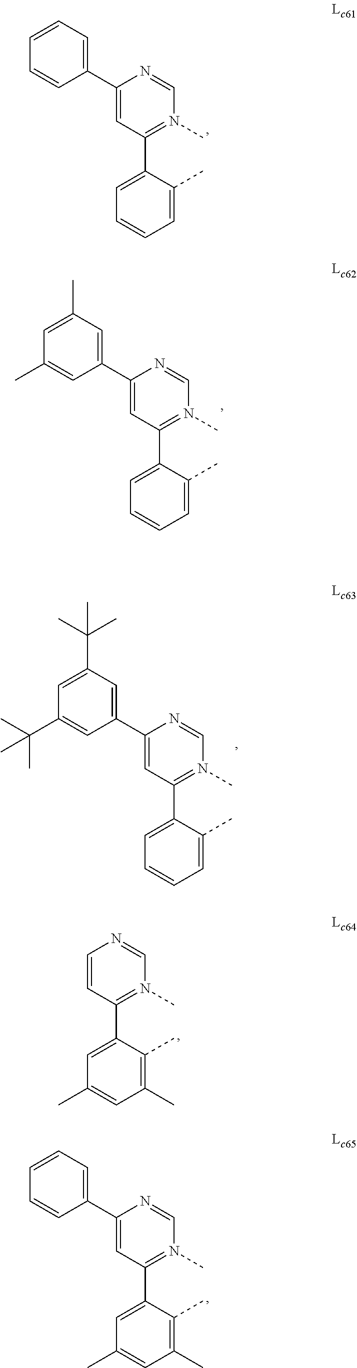

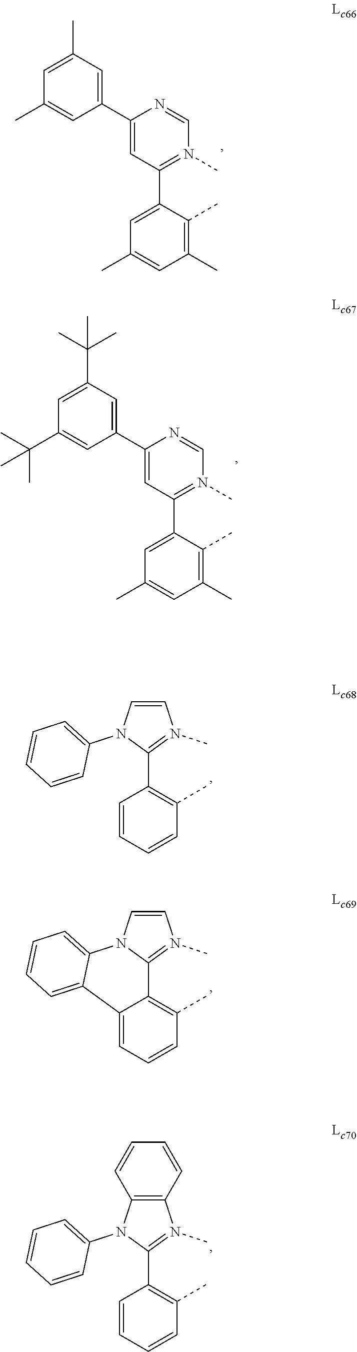

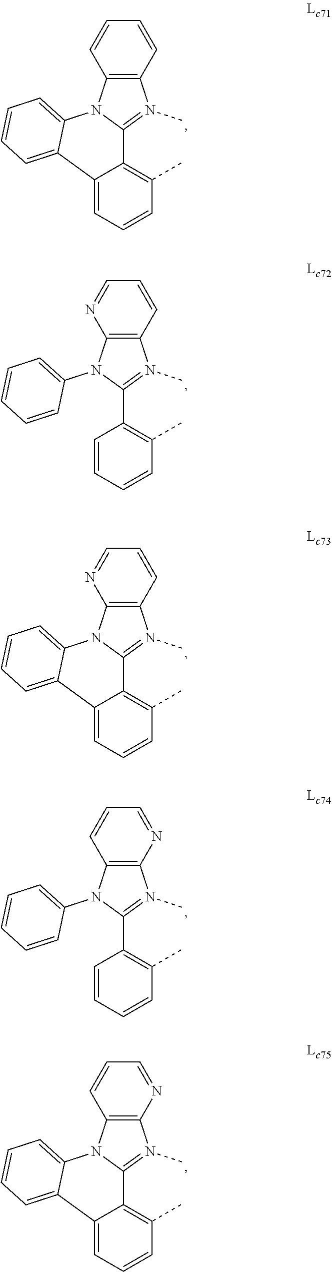

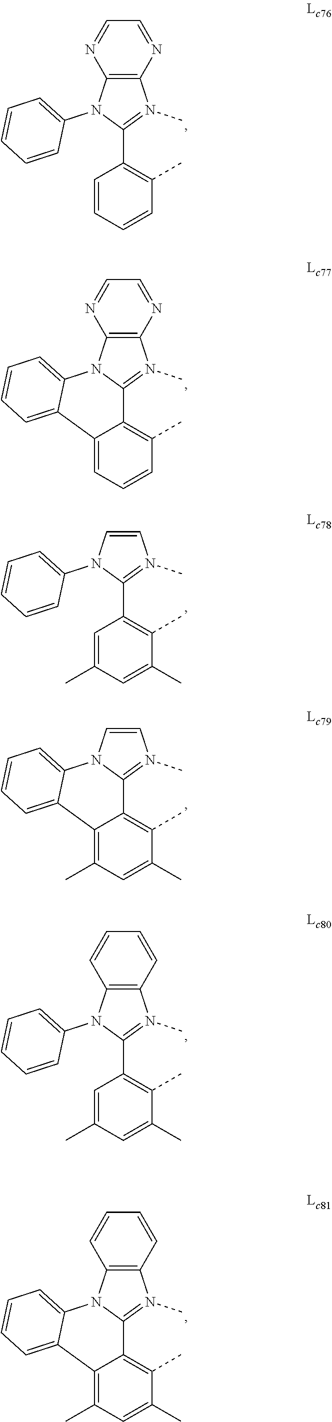

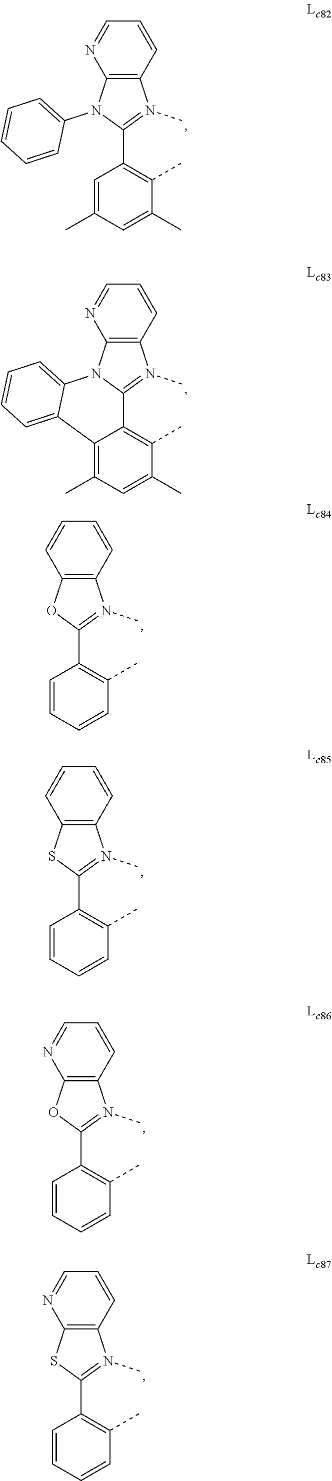

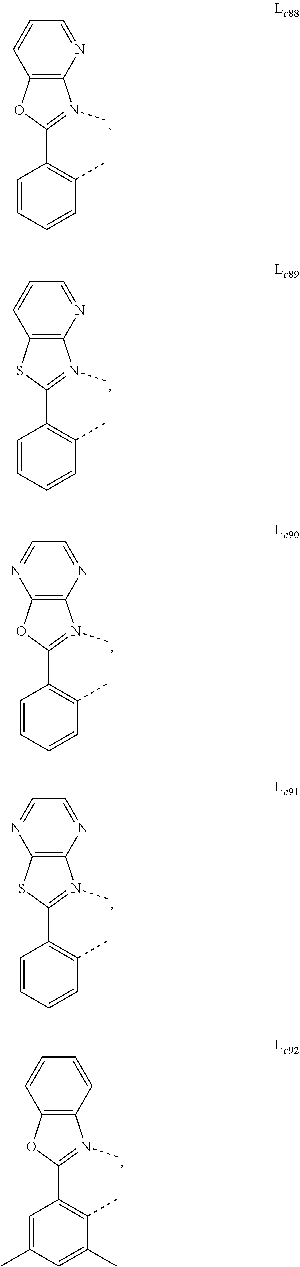

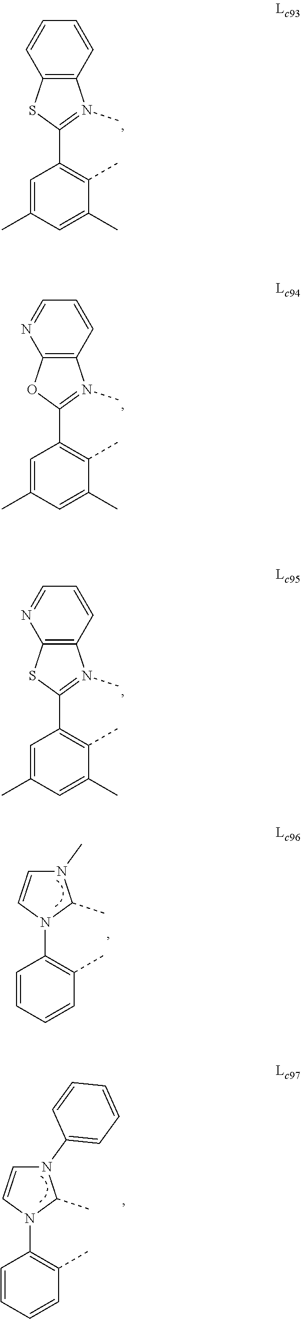

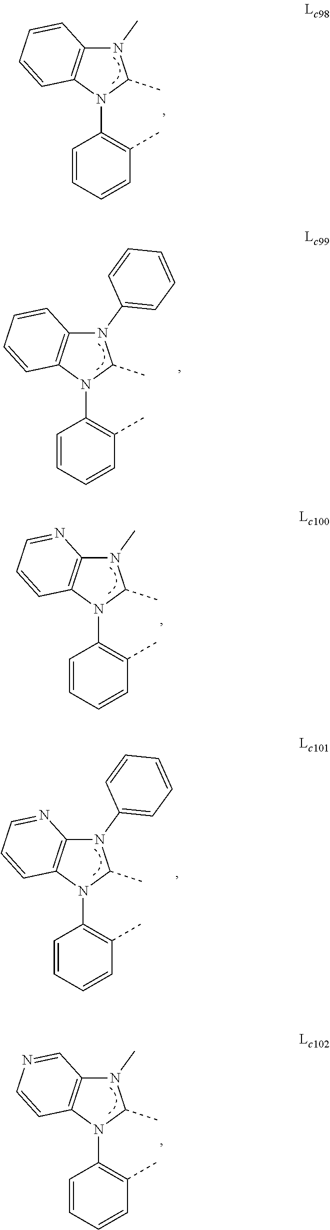

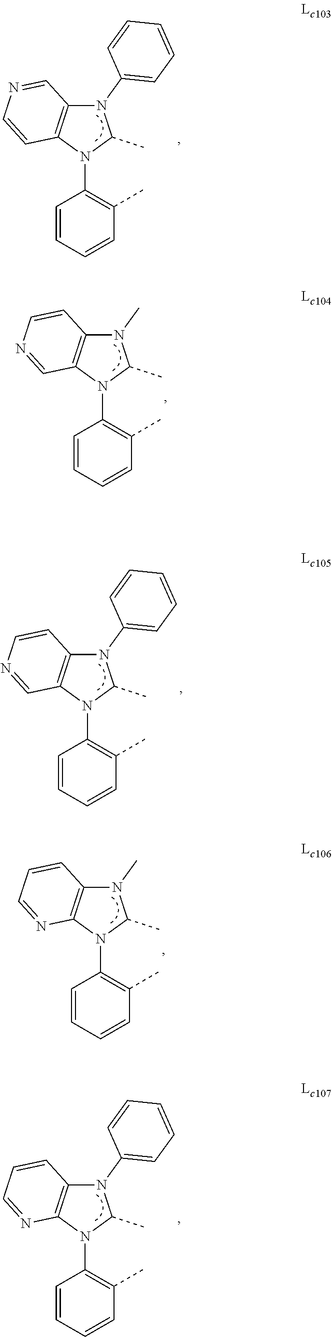

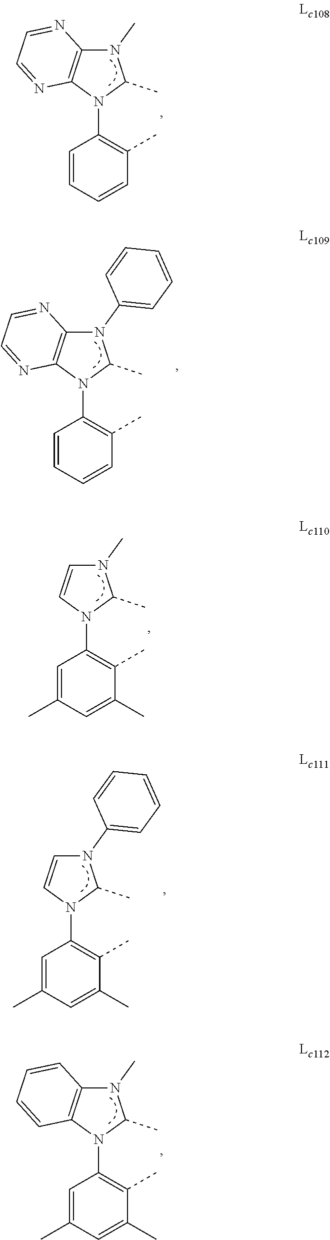

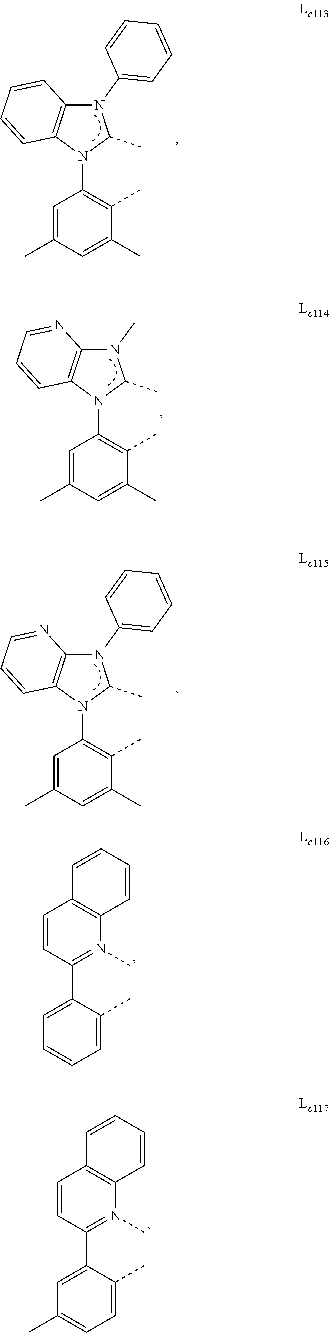

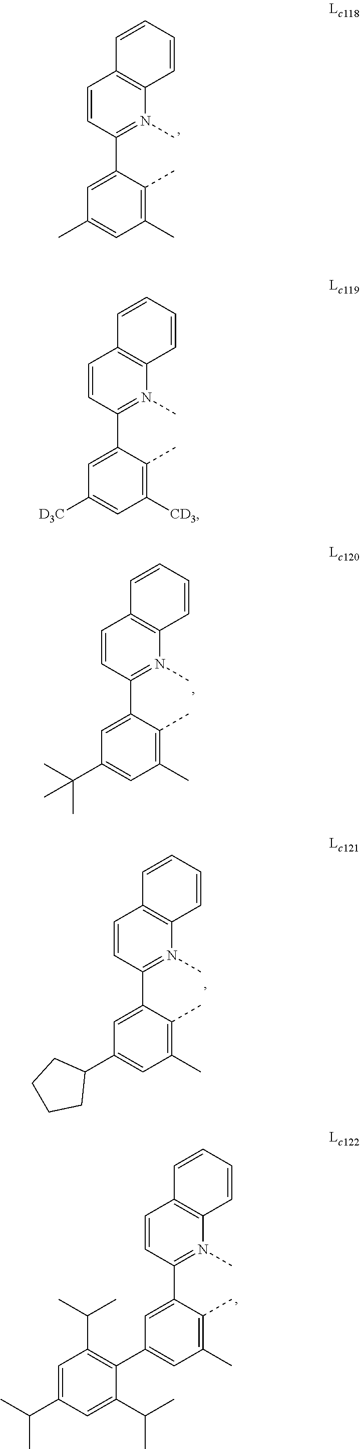

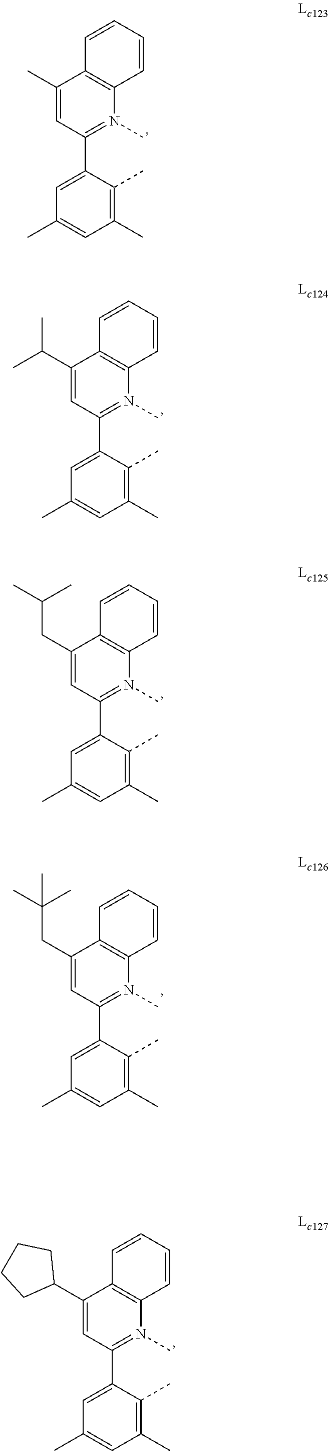

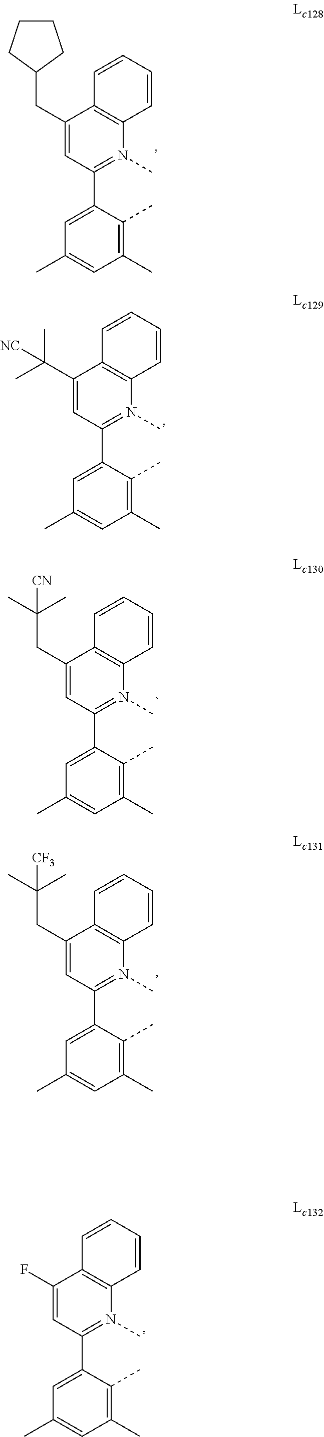

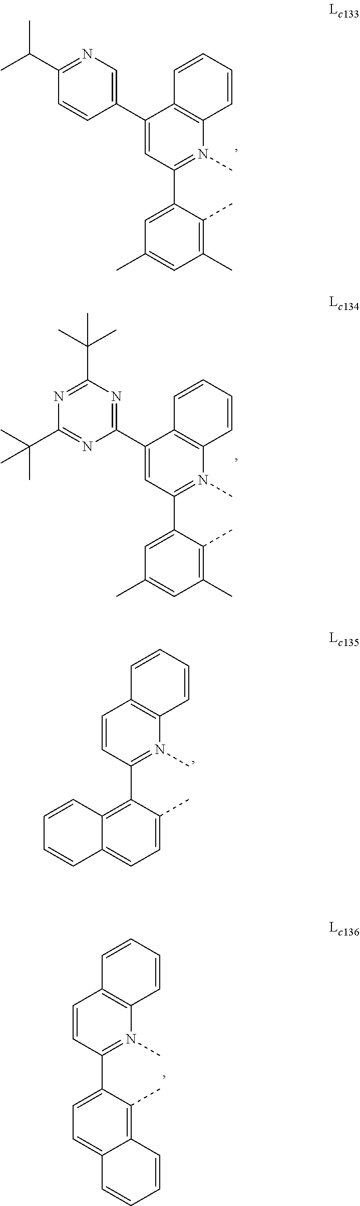

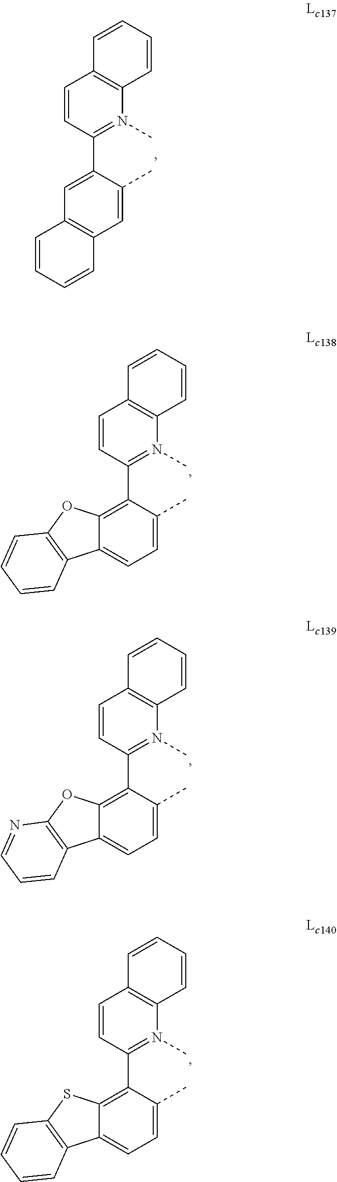

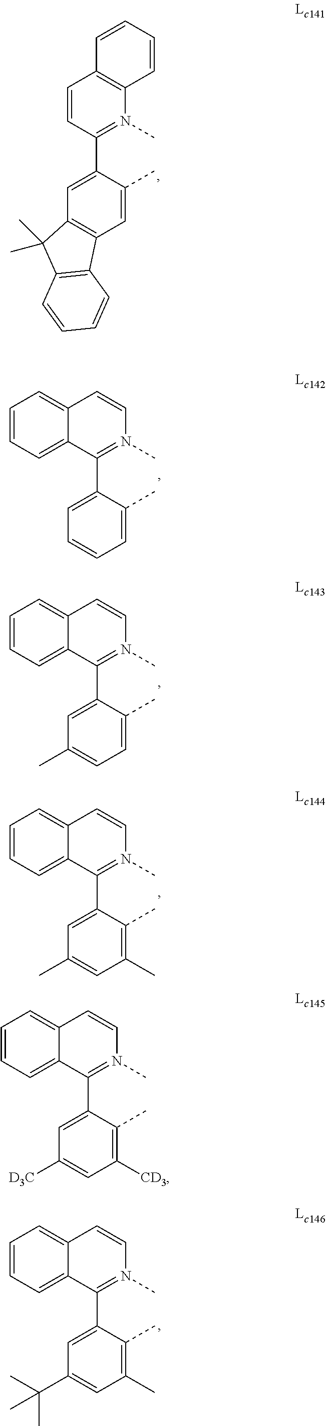

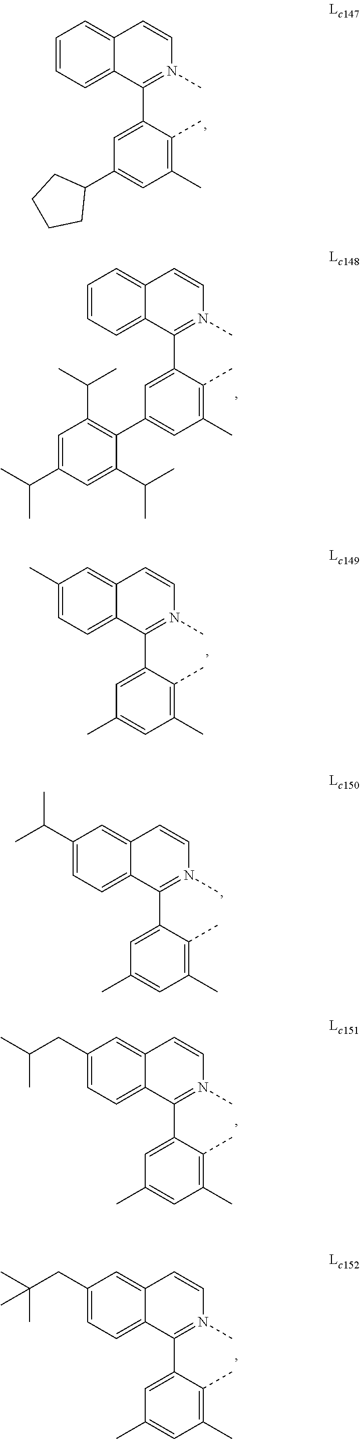

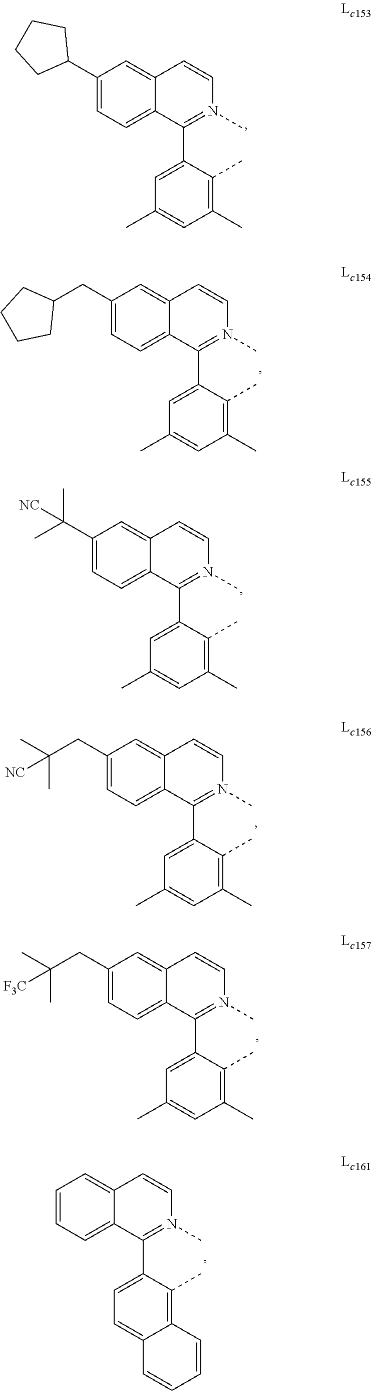

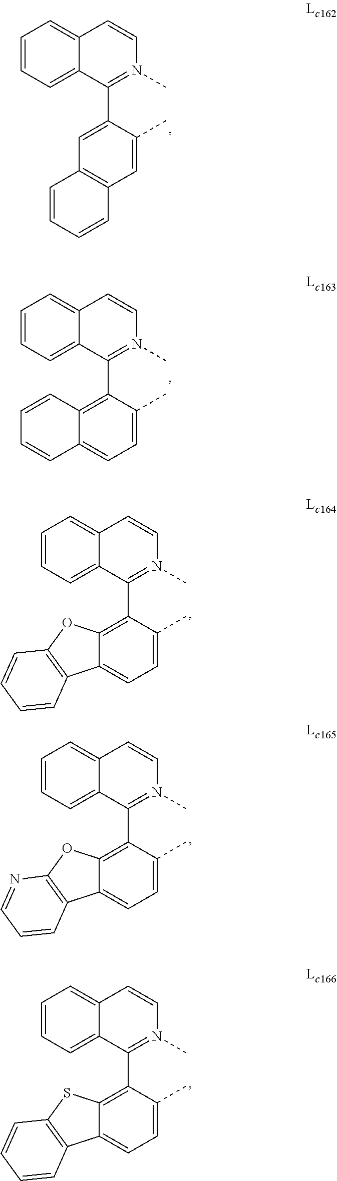

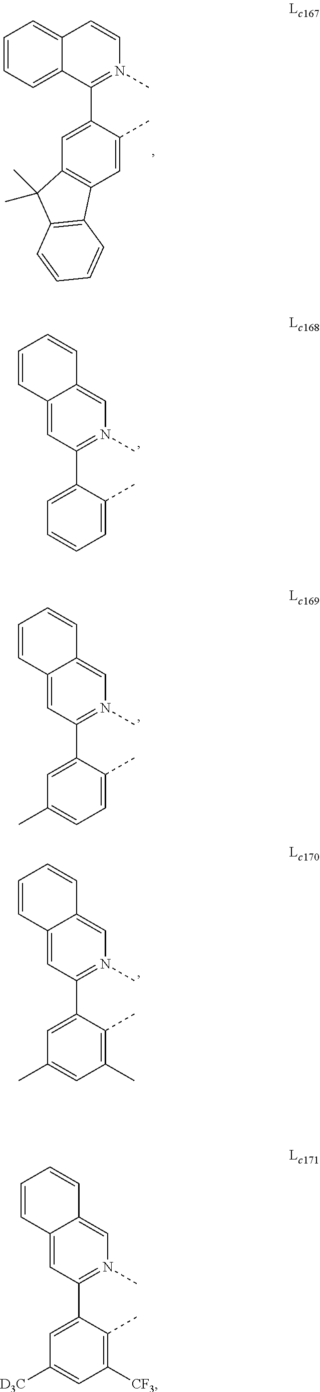

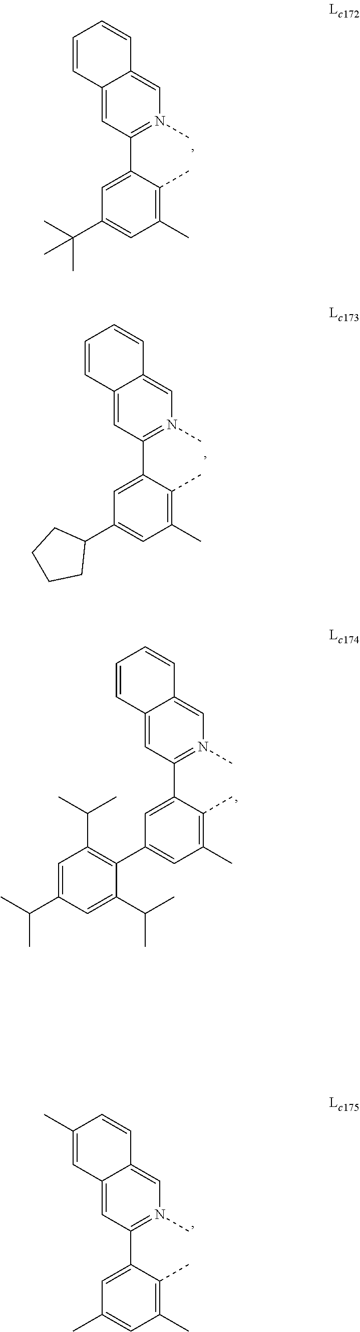

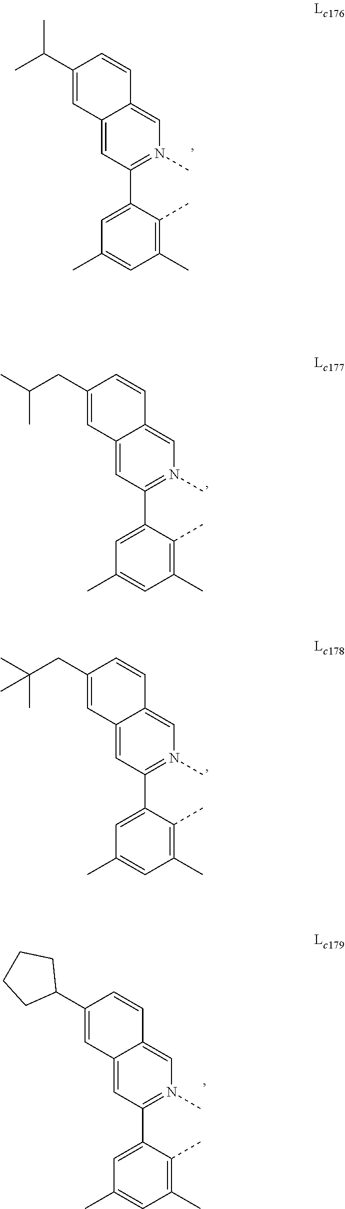

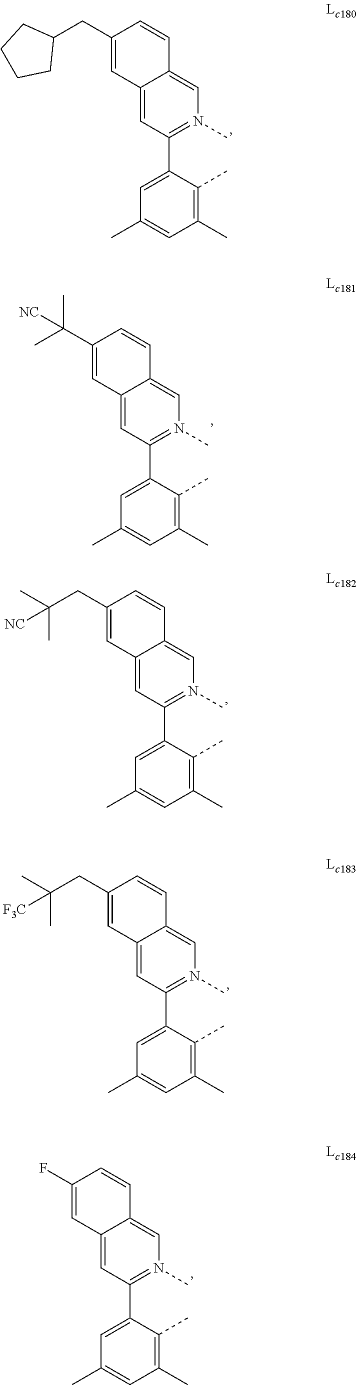

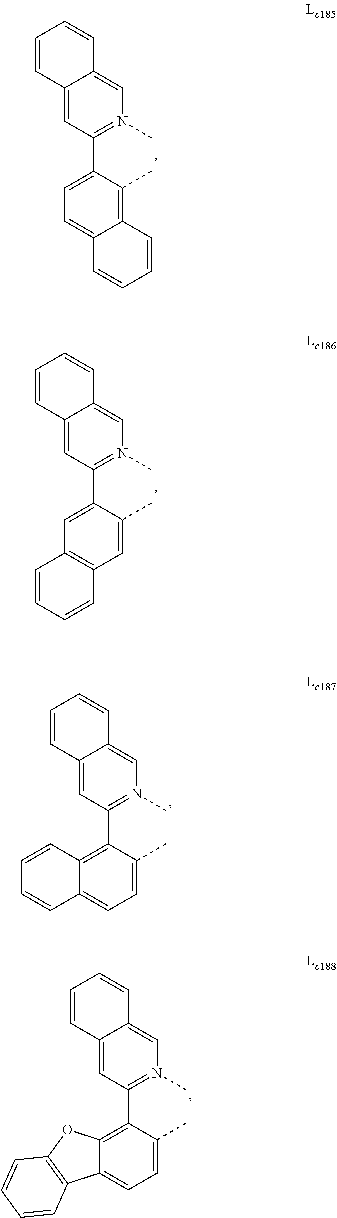

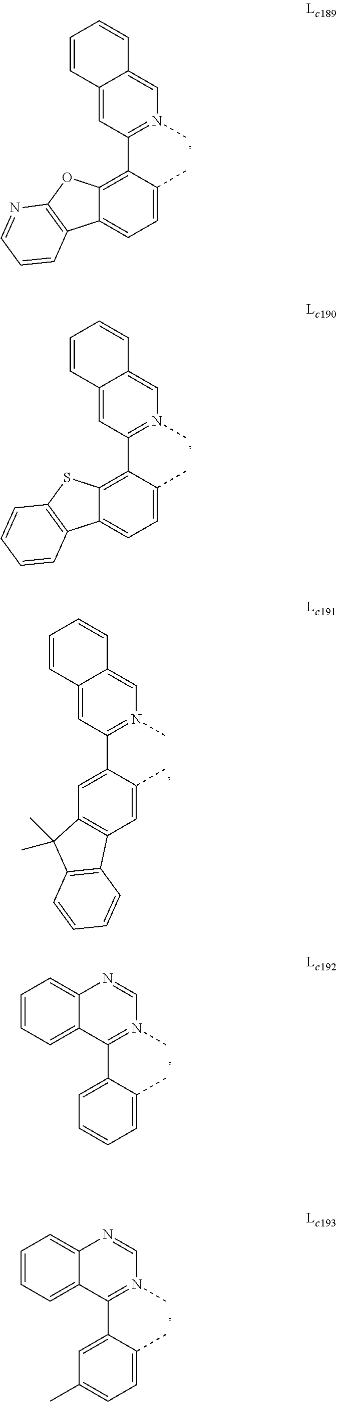

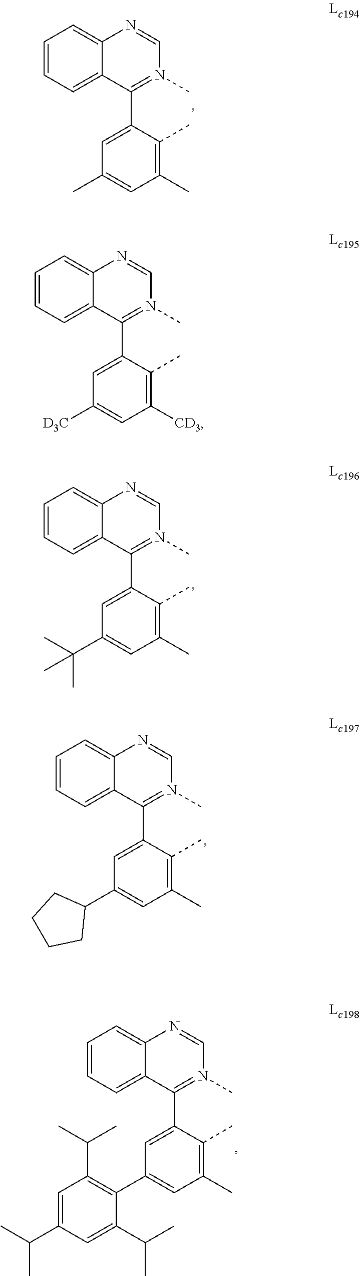

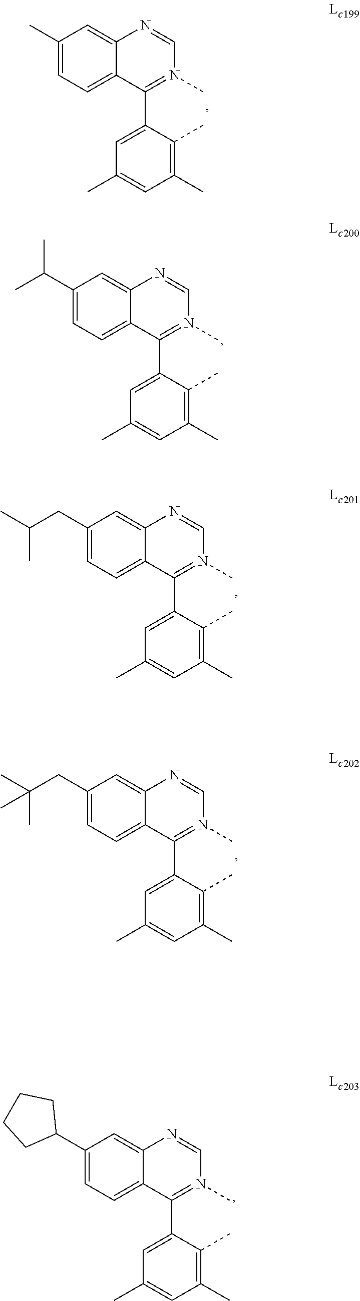

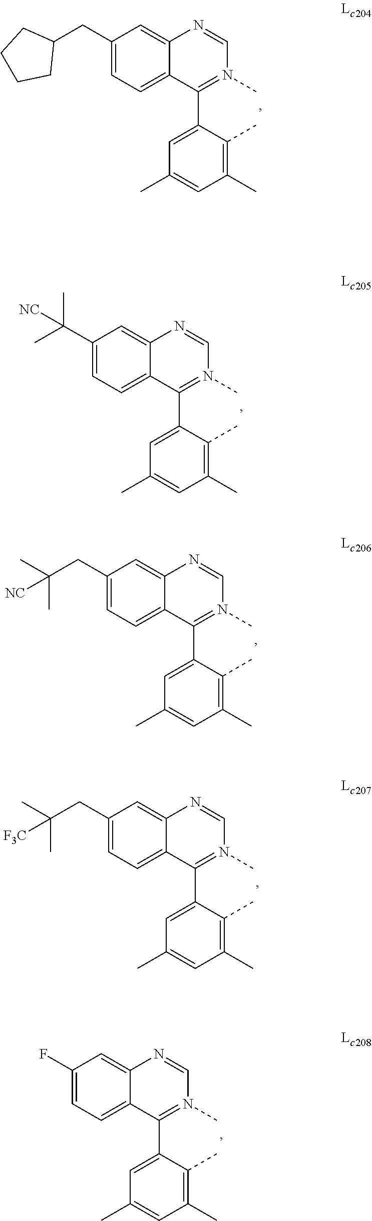

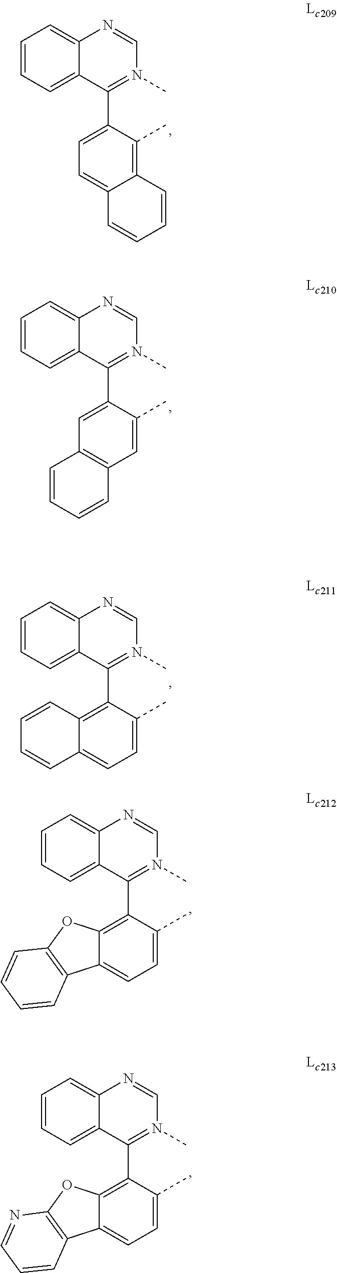

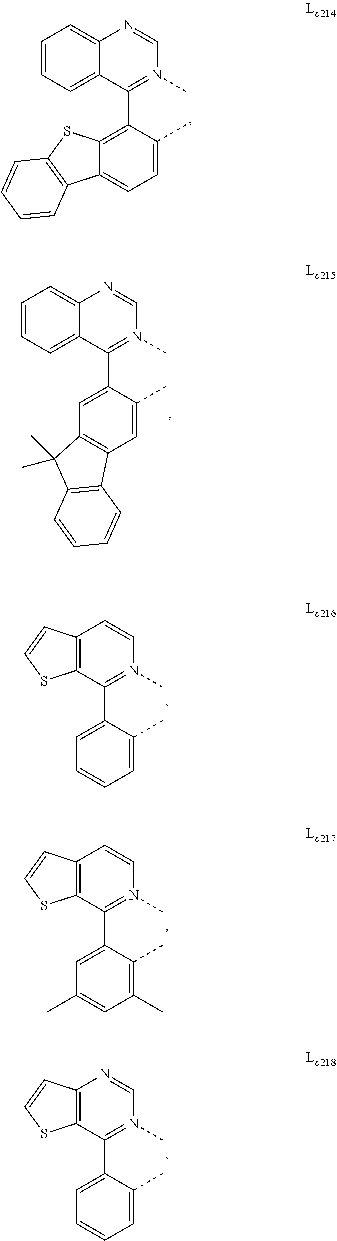

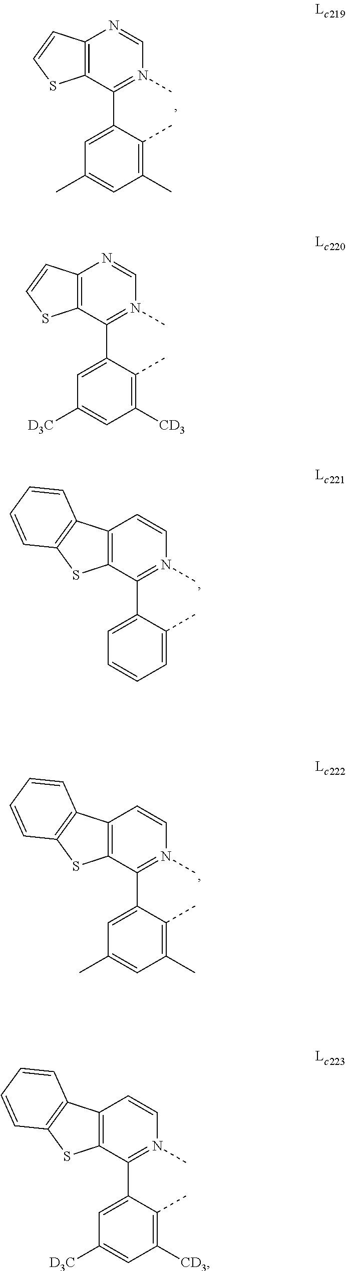

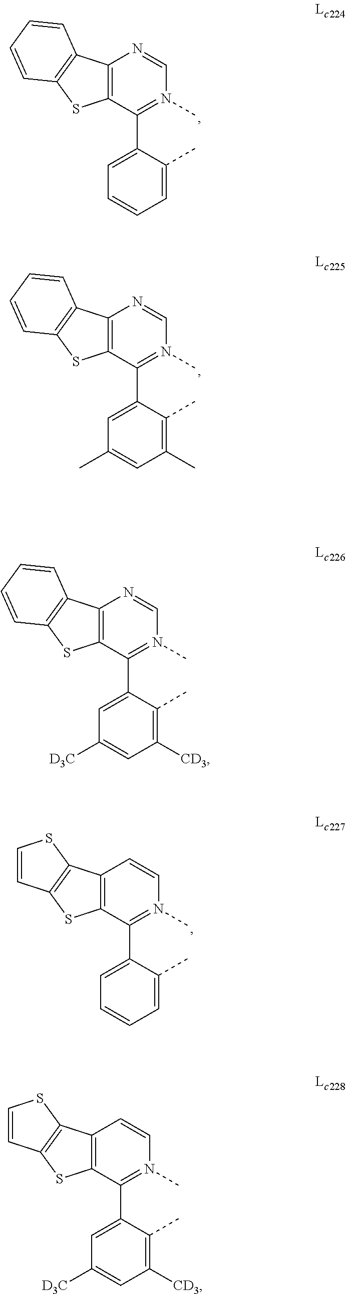

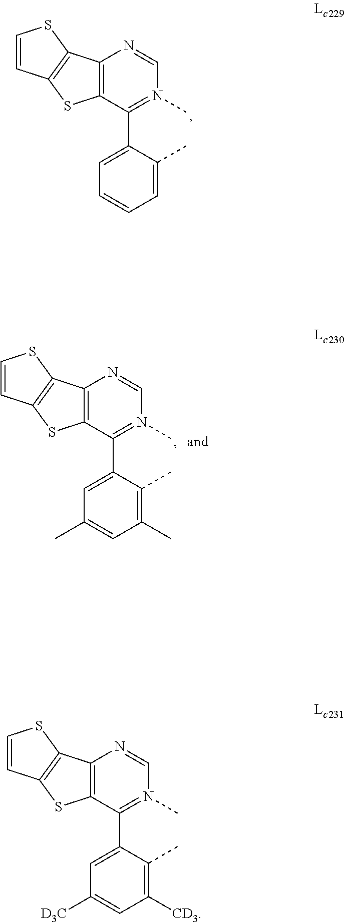

12. The metal complex of claim 11, wherein the metal complex is an Ir complex and has a structure represented by any one of Ir(Lₐ)(L_{b})(L_{c}), Ir(Lₐ)₂(L_{b}), Ir(Lₐ)₂(L_{c}) and Ir(Lₐ)(L_{c})₂; when the metal complex has a structure of Ir(Lₐ)(L_{b})(L_{c}), Lₐ is selected from any one of the group consisting of Lₐ₁ to Lₐ₉₁₂, L_{b} is selected from any one of the group consisting of L_{b1} to L_{b322}, and L_{c} is selected from any one of the group consisting of L_{c1} to L_{c231}; when the metal complex has a structure of Ir(Lₐ)₂(L_{b}), Lₐ is selected from any one or any two of the group consisting of Lₐ₁ to Lₐ₉₁₂, and L_{b} is selected from any one of the group consisting of L_{b1} to L_{b322}; when the metal complex has a structure of Ir(Lₐ)₂(L_{c}), Lₐ is selected from any one or any two of the group consisting of Lₐ₁ to Lₐ₉₁₂, and L_{c} is selected from any one of the group consisting of L_{c1} to L_{c231}; when the metal complex has a structure of Ir(Lₐ)(L_{c})₂, Lₐ is selected from any one of the group consisting of Lₐ₁ to Lₐ₉₁₂, and L_{c} is selected from any one or any two of the group consisting of L_{c1} to L_{c231};
preferably, the metal complex is selected from the group consisting of Compound 1 to Compound 378, and the Compound 1 to Compound 378 have a general formula of Ir(Lₐ)₂(L_{b}), wherein two Lₐ are identical, and Lₐ and L_{b} are selected from structures listed in the following table, respectively:

| Compound No. | Lₐ | L_{b} | Compound No. | Lₐ | L_{b} |
|---|---|---|---|---|---|
| 1 | Lₐ₁ | L_{b31} | 2 | Lₐ₁ | L_{b88} |
| 3 | Lₐ₃ | L_{b31} | 4 | Lₐ₃ | L_{b88} |
| 5 | Lₐ₅ | L_{b31} | 6 | Lₐ₅ | L_{b88} |
| 7 | Lₐ₆ | L_{b31} | 8 | Lₐ₆ | L_{b88} |
| 9 | Lₐ₇ | L_{b31} | 10 | Lₐ₇ | L_{b88} |
| 11 | Lₐ₈ | L_{b31} | 12 | Lₐ₈ | L_{b88} |
| 13 | Lₐ₁₁ | L_{b31} | 14 | Lₐ₁₁ | L_{b88} |
| 15 | Lₐ₁₃ | L_{b31} | 16 | Lₐ₁₃ | L_{b88} |
| 17 | Lₐ₁₄ | L_{b31} | 18 | Lₐ₁₄ | L_{b88} |
| 19 | Lₐ₂₁ | L_{b31} | 20 | Lₐ₂₁ | L_{b88} |
| 21 | Lₐ₂₂ | L_{b31} | 22 | Lₐ₂₂ | L_{b88} |
| 23 | Lₐ₇₈ | L_{b31} | 24 | Lₐ₇₈ | L_{b88} |
| 25 | Lₐ₈₀ | L_{b31} | 26 | Lₐ₈₀ | L_{b88} |
| 27 | Lₐ₈₁ | L_{b31} | 28 | Lₐ₈₁ | L_{b88} |
| 29 | Lₐ₈₂ | L_{b31} | 30 | Lₐ₈₂ | L_{b88} |
| 31 | Lₐ₈₃ | L_{b31} | 32 | Lₐ₈₃ | L_{b88} |
| 33 | Lₐ₈₆ | L_{b31} | 34 | Lₐ₈₆ | L_{b88} |
| 35 | Lₐ₈₈ | L_{b31} | 36 | Lₐ₈₈ | L_{b88} |
| 37 | Lₐ₈₉ | L_{b31} | 38 | Lₐ₈₉ | L_{b88} |
| 39 | Lₐ₉₇ | L_{b31} | 40 | Lₐ₉₇ | L_{b88} |
| 41 | Lₐ₂₅₃ | L_{b31} | 42 | Lₐ₂₅₃ | L_{b88} |
| 43 | Lₐ₂₅₆ | L_{b31} | 44 | Lₐ₂₅₆ | L_{b88} |
| 45 | Lₐ₂₇₈ | L_{b31} | 46 | Lₐ₂₇₈ | L_{b88} |
| 47 | Lₐ₂₈₁ | L_{b31} | 48 | Lₐ₂₈₁ | L_{b88} |
| 49 | Lₐ₂₈₂ | L_{b31} | 50 | Lₐ₂₈₂ | L_{b88} |
| 51 | Lₐ₂₈₃ | L_{b31} | 52 | Lₐ₂₈₃ | L_{b88} |
| 53 | Lₐ₂₈₆ | L_{b31} | 54 | Lₐ₂₈₆ | L_{b88} |
| 55 | Lₐ₂₉₇ | L_{b31} | 56 | Lₐ₂₉₇ | L_{b88} |
| 57 | Lₐ₃₉₃ | L_{b31} | 58 | Lₐ₃₉₃ | L_{b88} |
| 59 | Lₐ₃₉₆ | L_{b31} | 60 | Lₐ₃₉₆ | L_{b88} |
| 61 | Lₐ₄₀₀ | L_{b31} | 62 | Lₐ₄₀₀ | L_{b88} |
| 63 | Lₐ₄₁₀ | L_{b31} | 64 | Lₐ₄₁₀ | L_{b88} |
| 65 | Lₐ₆₄₉ | L_{b31} | 66 | Lₐ₆₄₉ | L_{b88} |
| 67 | Lₐ₆₅₄ | L_{b31} | 68 | Lₐ₆₅₄ | L_{b88} |
| 69 | Lₐ₆₅₅ | L_{b31} | 70 | Lₐ₆₅₅ | L_{b88} |
| 71 | Lₐ₆₈₀ | L_{b31} | 72 | Lₐ₆₈₀ | L_{b88} |
| 73 | Lₐ₆₈₅ | L_{b31} | 74 | Lₐ₆₈₅ | L_{b88} |
| 75 | Lₐ₇₀₅ | L_{b31} | 76 | Lₐ₇₀₅ | L_{b88} |
| 77 | Lₐ₇₄₈ | L_{b31} | 78 | Lₐ₇₄₈ | L_{b88} |
| 79 | Lₐ₇₅₉ | L_{b31} | 80 | Lₐ₇₅₉ | L_{b88} |
| 81 | Lₐ₈₀₄ | L_{b31} | 82 | Lₐ₈₀₄ | L_{b88} |
| 83 | Lₐ₈₀₇ | L_{b31} | 84 | Lₐ₈₀₇ | L_{b88} |
| 85 | Lₐ₁ | L_{b122} | 86 | Lₐ₁ | L_{b126} |
| 87 | Lₐ₃ | L_{b122} | 88 | Lₐ₃ | L_{b126} |
| 89 | Lₐ₅ | L_{b122} | 90 | Lₐ₅ | L_{b126} |
| 91 | Lₐ₆ | L_{b122} | 92 | Lₐ₆ | L_{b126} |
| 93 | Lₐ₇ | L_{b122} | 94 | Lₐ₇ | L_{b126} |
| 95 | Lₐ₈ | L_{b122} | 96 | Lₐ₈ | L_{b126} |
| 97 | Lₐ₁₁ | L_{b122} | 98 | Lₐ₁₁ | L_{b126} |
| 99 | Lₐ₁₃ | L_{b122} | 100 | Lₐ₁₃ | L_{b126} |
| 101 | Lₐ₁₄ | L_{b122} | 102 | Lₐ₁₄ | L_{b126} |
| 103 | Lₐ₂₁ | L_{b122} | 104 | Lₐ₂₁ | L_{b126} |
| 105 | Lₐ₂₂ | L_{b122} | 106 | Lₐ₂₂ | L_{b126} |
| 107 | Lₐ₇₈ | L_{b122} | 108 | Lₐ₇₈ | L_{b126} |
| 109 | Lₐ₈₀ | L_{b122} | 110 | Lₐ₈₀ | L_{b126} |
| 111 | Lₐ₈₁ | L_{b122} | 112 | Lₐ₈₁ | L_{b126} |
| 113 | Lₐ₈₂ | L_{b122} | 114 | Lₐ₈₂ | L_{b126} |
| 115 | Lₐ₈₃ | L_{b122} | 116 | Lₐ₈₃ | L_{b126} |
| 117 | Lₐ₈₆ | L_{b122} | 118 | Lₐ₈₆ | L_{b126} |
| 119 | Lₐ₈₈ | L_{b122} | 120 | Lₐ₈₈ | L_{b126} |
| 121 | Lₐ₈₉ | L_{b122} | 122 | Lₐ₈₉ | L_{b126} |
| 123 | Lₐ₉₇ | L_{b122} | 124 | Lₐ₉₇ | L_{b126} |
| 125 | Lₐ₂₅₃ | L_{b122} | 126 | Lₐ₂₅₃ | L_{b126} |
| 127 | Lₐ₂₅₆ | L_{b122} | 128 | Lₐ₂₅₆ | L_{b126} |
| 129 | Lₐ₂₇₈ | L_{b122} | 130 | Lₐ₂₇₈ | L_{b126} |
| 131 | Lₐ₂₈₁ | L_{b122} | 132 | Lₐ₂₈₁ | L_{b126} |
| 133 | Lₐ₂₈₂ | L_{b122} | 134 | Lₐ₂₈₂ | L_{b126} |
| 135 | Lₐ₂₈₃ | L_{b122} | 136 | Lₐ₂₈₃ | L_{b126} |
| 137 | Lₐ₂₈₆ | L_{b122} | 138 | Lₐ₂₈₆ | L_{b126} |
| 139 | Lₐ₂₉₇ | L_{b122} | 140 | Lₐ₂₉₇ | L_{b126} |
| 141 | Lₐ₃₉₃ | L_{b122} | 142 | Lₐ₃₉₃ | L_{b126} |
| 143 | Lₐ₃₉₆ | L_{b122} | 144 | Lₐ₃₉₆ | L_{b126} |
| 145 | Lₐ₄₀₀ | L_{b122} | 146 | Lₐ₄₀₀ | L_{b126} |
| 147 | Lₐ₄₁₀ | L_{b122} | 148 | Lₐ₄₁₀ | L_{b126} |
| 149 | Lₐ₆₄₉ | L_{b122} | 150 | Lₐ₆₄₉ | L_{b126} |
| 151 | Lₐ₆₅₄ | L_{b122} | 152 | Lₐ₆₅₄ | L_{b126} |
| 153 | Lₐ₆₅₅ | L_{b122} | 154 | Lₐ₆₅₅ | L_{b126} |
| 155 | Lₐ₆₈₀ | L_{b122} | 156 | Lₐ₆₈₀ | L_{b126} |
| 157 | Lₐ₆₈₅ | L_{b122} | 158 | Lₐ₆₈₅ | L_{b126} |
| 159 | Lₐ₇₀₅ | L_{b122} | 160 | Lₐ₇₀₅ | L_{b126} |
| 161 | Lₐ₇₄₈ | L_{b122} | 162 | Lₐ₇₄₈ | L_{b126} |
| 163 | Lₐ₇₅₉ | L_{b122} | 164 | Lₐ₇₅₉ | L_{b126} |
| 165 | Lₐ₈₀₄ | L_{b122} | 166 | Lₐ₈₀₄ | L_{b126} |
| 167 | Lₐ₈₀₇ | L_{b122} | 168 | Lₐ₈₀₇ | L_{b126} |
| 169 | Lₐ₁ | L_{b122} | 170 | Lₐ₁ | L_{b126} |
| 171 | Lₐ₃ | L_{b122} | 172 | Lₐ₃ | L_{b126} |
| 173 | Lₐ₅ | L_{b122} | 174 | Lₐ₅ | L_{b126} |
| 175 | Lₐ₆ | L_{b122} | 176 | Lₐ₆ | L_{b126} |
| 177 | Lₐ₇ | L_{b122} | 178 | Lₐ₇ | L_{b126} |
| 179 | Lₐ₈ | L_{b122} | 180 | Lₐ₈ | L_{b126} |
| 181 | Lₐ₁₁ | L_{b122} | 182 | Lₐ₁₁ | L_{b126} |
| 183 | Lₐ₁₃ | L_{b122} | 184 | Lₐ₁₃ | L_{b126} |
| 185 | Lₐ₁₄ | L_{b122} | 186 | Lₐ₁₄ | L_{b126} |
| 187 | Lₐ₂₁ | L_{b122} | 188 | Lₐ₂₁ | L_{b126} |
| 189 | Lₐ₂₂ | L_{b122} | 190 | Lₐ₂₂ | L_{b126} |
| 191 | Lₐ₇₈ | L_{b122} | 192 | Lₐ₇₈ | L_{b126} |
| 193 | Lₐ₈₀ | L_{b122} | 194 | Lₐ₈₀ | L_{b126} |
| 195 | Lₐ₈₁ | L_{b122} | 196 | Lₐ₈₁ | L_{b126} |
| 197 | Lₐ₈₂ | L_{b122} | 198 | Lₐ₈₂ | L_{b126} |
| 199 | Lₐ₈₃ | L_{b122} | 200 | Lₐ₈₃ | L_{b126} |
| 201 | Lₐ₈₆ | L_{b122} | 202 | Lₐ₈₆ | L_{b126} |
| 203 | Lₐ₈₈ | L_{b122} | 204 | Lₐ₈₈ | L_{b126} |
| 205 | Lₐ₈₉ | L_{b122} | 206 | Lₐ₈₉ | L_{b126} |
| 207 | Lₐ₉₇ | L_{b122} | 208 | Lₐ₉₇ | L_{b126} |
| 209 | Lₐ₂₅₃ | L_{b122} | 210 | Lₐ₂₅₃ | L_{b126} |
| 211 | Lₐ₂₅₆ | L_{b122} | 212 | Lₐ₂₅₆ | L_{b126} |
| 213 | Lₐ₂₇₈ | L_{b122} | 214 | Lₐ₂₇₈ | L_{b126} |
| 215 | Lₐ₂₈₁ | L_{b122} | 216 | Lₐ₂₈₁ | L_{b126} |
| 217 | Lₐ₂₈₂ | L_{b122} | 218 | Lₐ₂₈₂ | L_{b126} |
| 219 | Lₐ₂₈₃ | L_{b122} | 220 | Lₐ₂₈₃ | L_{b126} |
| 221 | Lₐ₂₈₆ | L_{b122} | 222 | Lₐ₂₈₆ | L_{b126} |
| 223 | Lₐ₂₉₇ | L_{b122} | 224 | Lₐ₂₉₇ | L_{b126} |
| 225 | Lₐ₃₉₃ | L_{b122} | 226 | Lₐ₃₉₃ | L_{b126} |
| 227 | Lₐ₃₉₆ | L_{b122} | 228 | Lₐ₃₉₆ | L_{b126} |
| 229 | Lₐ₄₀₀ | L_{b122} | 230 | Lₐ₄₀₀ | L_{b126} |
| 231 | Lₐ₄₁₀ | L_{b122} | 232 | Lₐ₄₁₀ | L_{b126} |
| 233 | Lₐ₆₄₉ | L_{b122} | 234 | Lₐ₆₄₉ | L_{b126} |
| 235 | Lₐ₆₅₄ | L_{b122} | 236 | Lₐ₆₅₄ | L_{b126} |
| 237 | Lₐ₆₅₅ | L_{b122} | 238 | Lₐ₆₅₅ | L_{b126} |
| 239 | Lₐ₆₈₀ | L_{b122} | 240 | Lₐ₆₈₀ | L_{b126} |
| 241 | Lₐ₆₈₅ | L_{b122} | 242 | Lₐ₆₈₅ | L_{b126} |
| 243 | Lₐ₇₀₅ | L_{b122} | 244 | Lₐ₇₀₅ | L_{b126} |
| 245 | Lₐ₇₄₈ | L_{b122} | 246 | Lₐ₇₄₈ | L_{b126} |
| 247 | Lₐ₇₅₉ | L_{b122} | 248 | Lₐ₇₅₉ | L_{b126} |
| 249 | Lₐ₈₀₄ | L_{b122} | 250 | Lₐ₈₀₄ | L_{b126} |
| 251 | Lₐ₈₀₇ | L_{b122} | 252 | Lₐ₈₀₇ | L_{b126} |
| 253 | Lₐ₁ | L_{b139} | 254 | Lₐ₁ | L_{b135} |
| 255 | Lₐ₃ | L_{b139} | 256 | Lₐ₃ | L_{b135} |
| 257 | Lₐ₅ | L_{b139} | 258 | Lₐ₅ | L_{b135} |
| 259 | Lₐ₆ | L_{b139} | 260 | Lₐ₆ | L_{b135} |
| 261 | Lₐ₇ | L_{b139} | 262 | Lₐ₇ | L_{b135} |
| 263 | Lₐ₈ | L_{b139} | 264 | Lₐ₈ | L_{b135} |
| 265 | Lₐ₁₁ | L_{b139} | 266 | Lₐ₁₁ | L_{b135} |
| 267 | Lₐ₁₃ | L_{b139} | 268 | Lₐ₁₃ | L_{b135} |
| 269 | Lₐ₁₄ | L_{b139} | 270 | Lₐ₁₄ | L_{b135} |
| 271 | Lₐ₂₁ | L_{b139} | 272 | Lₐ₂₁ | L_{b135} |
| 273 | Lₐ₂₂ | L_{b139} | 274 | Lₐ₂₂ | L_{b135} |
| 275 | Lₐ₇₈ | L_{b139} | 276 | Lₐ₇₈ | L_{b135} |
| 277 | Lₐ₈₀ | L_{b139} | 278 | Lₐ₈₀ | L_{b135} |
| 279 | Lₐ₈₁ | L_{b139} | 280 | Lₐ₈₁ | L_{b135} |
| 281 | Lₐ₈₂ | L_{b139} | 282 | Lₐ₈₂ | L_{b135} |
| 283 | Lₐ₈₃ | L_{b139} | 284 | Lₐ₈₃ | L_{b135} |
| 285 | Lₐ₈₆ | L_{b139} | 286 | Lₐ₈₆ | L_{b135} |
| 287 | Lₐ₈₈ | L_{b139} | 288 | Lₐ₈₈ | L_{b135} |
| 289 | Lₐ₈₉ | L_{b139} | 290 | Lₐ₈₉ | L_{b135} |
| 291 | Lₐ₉₇ | L_{b139} | 292 | Lₐ₉₇ | L_{b135} |
| 293 | Lₐ₂₅₃ | L_{b139} | 294 | Lₐ₂₅₃ | L_{b135} |
| 295 | Lₐ₂₅₆ | L_{b139} | 296 | Lₐ₂₅₆ | L_{b135} |
| 297 | Lₐ₂₇₈ | L_{b139} | 298 | Lₐ₂₇₈ | L_{b135} |
| 299 | Lₐ₂₈₁ | L_{b139} | 300 | Lₐ₂₈₁ | L_{b135} |
| 301 | Lₐ₂₈₂ | L_{b139} | 302 | Lₐ₂₈₂ | L_{b135} |
| 303 | Lₐ₂₈₃ | L_{b139} | 304 | Lₐ₂₈₃ | L_{b135} |
| 305 | Lₐ₂₈₆ | L_{b139} | 306 | Lₐ₂₈₆ | L_{b135} |
| 307 | Lₐ₂₉₇ | L_{b139} | 308 | Lₐ₂₉₇ | L_{b135} |
| 309 | Lₐ₃₉₃ | L_{b139} | 310 | Lₐ₃₉₃ | L_{b135} |
| 311 | Lₐ₃₉₆ | L_{b139} | 312 | Lₐ₃₉₆ | L_{b135} |
| 313 | Lₐ₄₀₀ | L_{b139} | 314 | Lₐ₄₀₀ | L_{b135} |
| 315 | Lₐ₄₁₀ | L_{b139} | 316 | Lₐ₄₁₀ | L_{b135} |
| 317 | Lₐ₆₄₉ | L_{b139} | 318 | Lₐ₆₄₉ | L_{b135} |
| 319 | Lₐ₆₅₄ | L_{b139} | 320 | Lₐ₆₅₄ | L_{b135} |
| 321 | Lₐ₆₅₅ | L_{b139} | 322 | Lₐ₆₅₅ | L_{b135} |
| 323 | Lₐ₆₈₀ | L_{b139} | 324 | Lₐ₆₈₀ | L_{b135} |
| 325 | Lₐ₆₈₅ | L_{b139} | 326 | Lₐ₆₈₅ | L_{b135} |
| 327 | Lₐ₇₀₅ | L_{b139} | 328 | Lₐ₇₀₅ | L_{b135} |
| 329 | Lₐ₇₄₈ | L_{b139} | 330 | Lₐ₇₄₈ | L_{b135} |
| 331 | Lₐ₇₅₉ | L_{b139} | 332 | Lₐ₇₅₉ | L_{b135} |
| 333 | Lₐ₈₀₄ | L_{b139} | 334 | Lₐ₈₀₄ | L_{b135} |
| 335 | Lₐ₈₀₇ | L_{b139} | 336 | Lₐ₈₀₇ | L_{b135} |
| 337 | Lₐ₁ | L_{b80} | 338 | Lₐ₂₅₆ | L_{b80} |
| 339 | Lₐ₃ | L_{b80} | 340 | Lₐ₂₇₈ | L_{b80} |
| 341 | Lₐ₅ | L_{b80} | 342 | Lₐ₂₈₁ | L_{b80} |
| 343 | Lₐ₆ | L_{b80} | 344 | Lₐ₂₈₂ | L_{b80} |
| 345 | Lₐ₇ | L_{b80} | 346 | Lₐ₂₈₃ | L_{b80} |
| 347 | Lₐ₈ | L_{b80} | 348 | Lₐ₂₈₆ | L_{b80} |
| 349 | Lₐ₁₁ | L_{b80} | 350 | Lₐ₂₉₇ | L_{b80} |
| 351 | Lₐ₁₃ | L_{b80} | 352 | Lₐ₃₉₃ | L_{b80} |
| 353 | Lₐ₁₄ | L_{b80} | 354 | Lₐ₃₉₆ | L_{b80} |
| 355 | Lₐ₂₁ | L_{b80} | 356 | Lₐ₄₀₀ | L_{b80} |
| 357 | Lₐ₂₂ | L_{b80} | 358 | Lₐ₄₁₀ | L_{b80} |
| 359 | Lₐ₇₈ | L_{b80} | 360 | Lₐ₆₄₉ | L_{b80} |
| 361 | Lₐ₈₀ | L_{b80} | 362 | Lₐ₆₅₄ | L_{b80} |
| 363 | Lₐ₈₁ | L_{b80} | 364 | Lₐ₆₅₅ | L_{b80} |
| 365 | Lₐ₈₂ | L_{b80} | 366 | Lₐ₆₈₀ | L_{b80} |
| 367 | Lₐ₈₃ | L_{b80} | 368 | Lₐ₆₈₅ | L_{b80} |
| 369 | Lₐ₈₆ | L_{b80} | 370 | Lₐ₇₀₅ | L_{b80} |
| 371 | Lₐ₈₈ | L_{b80} | 372 | Lₐ₇₄₈ | L_{b80} |
| 373 | Lₐ₈₉ | L_{b80} | 374 | Lₐ₇₅₉ | L_{b80} |
| 375 | Lₐ₉₇ | L_{b80} | 376 | Lₐ₈₀₄ | L_{b80} |
| 377 | Lₐ₂₅₃ | L_{b80} | 378 | Lₐ₈₀₇ | L_{b80} |

13. An electroluminescent device, comprising:
an anode,
a cathode, and
an organic layer disposed between the anode and the cathode, wherein the organic layer comprises the metal complex of claim 1.

14. The electroluminescent device of claim 13, wherein the organic layer is an emissive layer, and the compound is a luminescent material.

15. The electroluminescent device of claim 13, wherein the device emits red light or white light.

16. The electroluminescent device of claim 14, wherein the emissive layer further comprises at least one host material; preferably, the at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

17. A compound composition, comprising the metal complex of claim 1.
